(19) United States
(12) Patent Application Publication
(10) Pub. No.: US 2024/0188441 A1
(43) Pub. Date: Jun. 6, 2024

(54) LIGHT-EMITTING DEVICE INCLUDING CONDENSED CYCLIC COMPOUND, ELECTRONIC APPARATUS AND ELECTRONIC DEVICE INCLUDING THE LIGHT-EMITTING DEVICE, AND THE CONDENSED CYCLIC COMPOUND

(71) Applicant: Samsung Display Co., LTD., Yongin-si (KR)

(72) Inventors: Kyoung Sunwoo, Yongin-si (KR); Sunyoung Pak, Yongin-si (KR); Junha Park, Yongin-si (KR); Munki Sim, Yongin-si (KR); Chanseok Oh, Yongin-si (KR)

(73) Assignee: Samsung Display Co., LTD., Yongin-si (KR)

(21) Appl. No.: 18/499,398

(22) Filed: Nov. 1, 2023

(30) Foreign Application Priority Data
Nov. 3, 2022 (KR) 10-2022-0145517

(51) Int. Cl. H10K 85/60; C07F 5/02; C09K 11/02; C09K 11/06

(52) U.S. Cl. CPC H10K 85/658; C07F 5/027; C09K 11/02; C09K 11/06; H10K 85/654; H10K 85/6572; H10K 50/121

(57) ABSTRACT

Embodiments provide a condensed cyclic compound, a light-emitting device including the condensed cyclic compound, an electronic apparatus including the light-emitting device, and an electronic device including the light-emitting device. The light-emitting device includes a first electrode, a second electrode facing the first electrode, an interlayer between the first electrode and the second electrode and including an emission layer, and the condensed cyclic compound, which is represented by Formula 1, wherein Formula 1 is explained in the specification:

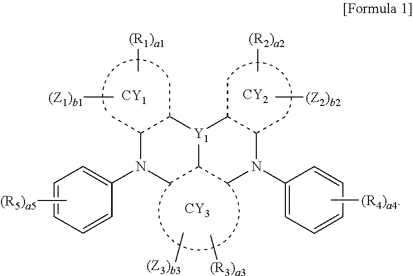

### CROSS-REFERENCE TO RELATED APPLICATION(S)

This application claims priority to and benefits of Korean Patent Application No. 10-2022-0145517 under 35. U.S.C. § 119, filed on Nov. 3, 2022 in the Korean Intellectual Property Office, the entire contents of which are incorporated herein by reference.

### BACKGROUND

### 1. Technical Field

Embodiments include a light-emitting device including a condensed cyclic compound, an electronic apparatus and electronic device including the light-emitting device, and the condensed cyclic compound.

### 2. Description of the Related Art

Among light-emitting devices, self-emissive devices have wide viewing angles, high contrast ratios, short response times, and excellent characteristics in terms of luminance, driving voltage, and response speed.

In a light-emitting device, a first electrode is located on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons transition from an excited state to a ground state to thereby generate light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a light-emitting device including a condensed cyclic compound, an electronic apparatus including the light-emitting device, and the condensed cyclic compound.

Additional aspects will be set forth in part in the description which follows and, in part, will be apparent from the description, or may be learned by practice of the embodiments of the disclosure.

Embodiments provide a light-emitting device which may include:
a first electrode,
a second electrode facing the first electrode,
an interlayer between the first electrode and the second electrode and including an emission layer, and
a condensed cyclic compound represented by Formula 1.

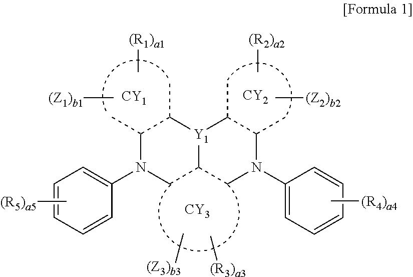

In Formula 1,
Y₁ may be B or N,
rings CY₁ to CY₃ may each independently be a C₃-C₃₀ carbocyclic group or a C₁-C₃₀ heterocyclic group,
R₁ to R₃ may each independently be a C₃-C₆₀ carbocyclic group substituted with L_{D} or a C₁-C₆₀ heterocyclic group substituted with L_{D},
L_{D} may include a C₁-C₆₀ alkyl group unsubstituted or substituted with deuterium or —Si(Q₁)(Q₂)(Q₃),
when two or more of L_{D} are included, the two or more L_{D} may be identical to or different from each other,
R₄ and R₅ may each independently be a C₁-C₆₀ alkyl group unsubstituted or substituted with R₁₀ₐ or a C₃-C₆₀ carbocyclic group unsubstituted or substituted with R₁₀ₐ,
Z₁ to Z₃ may each independently be a C₃-C₆₀ carbocyclic group unsubstituted or substituted with R_{10b} or a π electron-rich C₃-C₆₀ cyclic group unsubstituted or substituted with R_{10b},
a1 to a3 may each independently be an integer from 0 to 3,
a sum of a1 to a3 may be 1 or more,
a4 and a5 may each independently be an integer from 2 to 5,
b1 to b3 may each independently be an integer from 0 to 3,
a sum of b1 to b3 may be 1 or more, and
R₁₀ₐ and R_{10b} may each independently be
deuterium, —F, —Cl, —Br, —I, a hydroxyl group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof,
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof, or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁ to Q₃, Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, a nitro group, a C₂-C₆₀ alkenyl group, a C₂-C₆₀ alkynyl group, a C₁-C₆₀ alkoxy group, a C₁-C₆₀ alkyl group unsubstituted or substituted with deuterium, —F, a cyano group, or a combination thereof; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

In an embodiment, the interlayer may include the condensed cyclic compound.

In an embodiment, the emission layer may include the condensed cyclic compound.

In an embodiment, the emission layer may further include at least one of a first host, a second host, and a phosphorescent sensitizer.

In an embodiment, the first host may include a compound represented by Formula 5, which is explained below.

In an embodiment, the second host may include a moiety represented by Formula 7, which is explained below.

In an embodiment, the emission layer may emit blue light.

In an embodiment, the first electrode may be an anode, the second electrode may be a cathode,
the interlayer may further include a hole transport region between the first electrode and the emission layer, and an electron transport region between the emission layer and the second electrode,
the hole transport region may include a hole injection layer, a hole transport layer, an emission auxiliary layer, an electron blocking layer, or a combination thereof, and
the electron transport region may include a hole blocking layer, an electron transport layer, an electron injection layer, or a combination thereof.

Embodiments provide an electronic apparatus which may include the light-emitting device.

In an embodiment, the electronic apparatus may further include:
a thin-film transistor; and
a color filter, a color conversion layer, a touch screen layer, a polarizing layer, or a combination thereof, wherein
the thin-film transistor may include a source electrode and a drain electrode, and
the first electrode of the light-emitting device may be electrically connected to the source electrode or the drain electrode.

Embodiments provide an electronic device which may include the light-emitting device, wherein the electronic device may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall including multiple displays tiled together, a theater screen, a stadium screen, a phototherapy device, or a sign

Embodiments provide a condensed cyclic compound which may be represented by Formula 1, which is explained herein.

In an embodiment, Y₁ may be B.

In an embodiment, ring CY₁ may be represented by one of Formulae CY1-1 to CY1-4, which are explained below.

In an embodiment, ring CY₂ may be represented by one of Formulae CY2-1 to CY2-4, which are explained below.

In an embodiment, ring CY₃ may be represented by one of Formulae CY3-1 to CY3-3, which are explained below.

In an embodiment, R₁ to R₃ may each independently be a group represented by one of Formulae 1-2-1 to 1-2-16, which are explained below.

In an embodiment, in Formula 1, L_{D} may be a methyl group, an ethyl group, a propyl group, an iso-propyl group, a butyl group, an isobutyl group, a sec-butyl group, a tert-butyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, a 3-cyclohexylpentyl group, or a deuterated derivative group thereof.

In an embodiment, in Formula 1, a moiety represented by

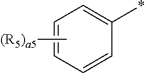

and a moiety represented by

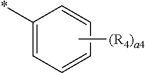

may each independently be a group represented by one of Formulae 1-3-1 to 1-3-34, which are explained below.

In an embodiment, the condensed cyclic compound may satisfy one of Conditions i to ix, which are explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will be more apparent by describing in detail embodiments thereof with reference to the accompanying drawings, in which:

FIG. 1 is a schematic cross-sectional view of a light-emitting device according to an embodiment;

FIG. 2 is a schematic cross-sectional view of an electronic apparatus according to an embodiment;

FIG. 3 is a schematic cross-sectional view of an electronic apparatus according to another embodiment;

FIG. 4 is a schematic perspective view of an electronic device according to an embodiment;

FIG. 5 is a schematic perspective view of an exterior of a vehicle as an electronic device according to an embodiment; and

FIGS. 6A to 6C are each a schematic diagram of an interior of a vehicle as an electronic device according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Embodiments provide a light-emitting device which may include:
a first electrode;
a second electrode facing the first electrode;
an interlayer between the first electrode and the second electrode and including an emission layer; and
a condensed cyclic compound represented by Formula 1:

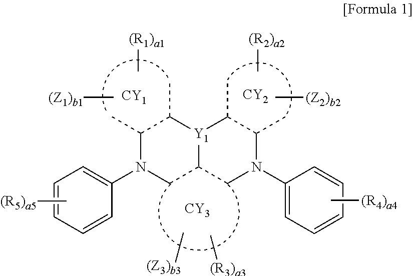

In Formula 1,
Y₁ may be B or N,
rings CY₁ to CY₃ may each independently be a C₃-C₃₀ carbocyclic group or a C₁-C₃₀ heterocyclic group,
R₁ to R₃ may each independently be a C₃-C₆₀ carbocyclic group substituted with L_{D} or a C₁-C₆₀ heterocyclic group substituted with L_{D},
L_{D} may be a C₁-C₆₀ alkyl group unsubstituted or substituted with deuterium or —Si(Q₁)(Q₂)(Q₃),
when two or more of L_{D} are included, the two or more L_{D} may be identical to or different from each other,
R₄ and R₅ may each independently be a C₁-C₆₀ alkyl group unsubstituted or substituted with R₁₀ₐ or a C₃-C₆₀ carbocyclic group unsubstituted or substituted with R₁₀ₐ,
Z₁ to Z₃ may each independently be a C₃-C₆₀ carbocyclic group unsubstituted or substituted with R_{10b} or a π electron-rich C₃-C₆₀ cyclic group unsubstituted or substituted with R_{10b},
a1 to a3 may each independently be an integer from 0 to 3,
a sum of a1 to a3 may be 1 or more,
a4 and a5 may each independently be an integer from 2 to 5,
b1 to b3 may each independently be an integer from 0 to 3,
a sum of b1 to b3 may be 1 or more,
R₁₀ₐ and R_{10b} may each independently be:
deuterium, —F, —Cl, —Br, —I, a hydroxyl group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀) alkyl group, a C₂-C₆₀ alkenyl group, a C₂-C₆₀ alkynyl group, a C₁-C₆₀) alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₂-C₆₀ alkenyl group; a C₂-C₆₀ alkynyl group; a C₁-C₆₀ alkoxy group; a C₁-C₆₀ alkyl group unsubstituted or substituted with deuterium, —F, a cyano group, or a combination thereof; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

In the light-emitting device according to an embodiment, the interlayer may include the condensed cyclic compound represented by Formula 1.

In the light-emitting device according to an embodiment, the emission layer may include the condensed cyclic compound represented by Formula 1.

In the light-emitting device according to an embodiment, the condensed cyclic compound may be a fluorescent dopant.

In the light-emitting device according to an embodiment, the emission layer may further include at least one of a first host, a second host, and a phosphorescent sensitizer.

In the light-emitting device according to an embodiment, the emission layer may further include a first host and/or a second host, wherein the first host may be an electron transport host and the second host may be a hole transport host.

In the light-emitting device according to an embodiment, the first host may include at least one azine moiety, and the second host may include at least one carbazole moiety.

In the light-emitting device according to an embodiment, the first host may include a compound represented by Formula 5:

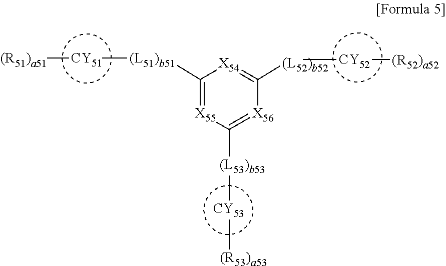

In Formula 5,
X₅₄ to X₅₆ may each independently be C(R₅₀), CH, or N,
at least one of X₅₄ to X₅₆ may each be N,
rings CY₅₁ to CY₅₃ may each independently be a C₅-C₆₀ carbocyclic group or a C₁-C₆₀ heterocyclic group,
L₅₁ to L₅₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
b51 to b53 may each independently be an integer from 0 to 3,
when b51 is 0, *-(L₅₁)_{b51}-*′ may be a single bond,
when b52 is 0, *-(L₅₂)_{b52}-*′ may be a single bond,
when b53 is 0, *-(L₅₃)_{ab3}-*′ may be a single bond,
* and *′ each indicate a binding site to a neighboring atom,
R₅₀ to R₅₃ may each independently be as described for R₁₀ₐ in Formula 1, and
a51 to a53 may each independently be an integer from 0 to 10.

In an embodiment, in Formula 5, rings CY₅₁ to CY₅₃ may each independently be a first ring, a second ring, a group in which two or more first rings are condensed with each other, a group in which two or more second rings are condensed with each other, or a group in which at least one first ring and at least one second ring are condensed with each other, wherein
the first ring may include a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group, and
the second ring may include a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group.

In an embodiment, in Formula 5, rings CY₅₁ to CY₅₃ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, in Formula 5, L₅₁ to L₅₃ may each independently be a benzene group, a naphthalene group, an anthracene group, a phenanthrene group, a triphenylene group, a pyrene group, a chrysene group, cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

In an embodiment, the first host may include at least one of Compounds ETH1 to ETH35:

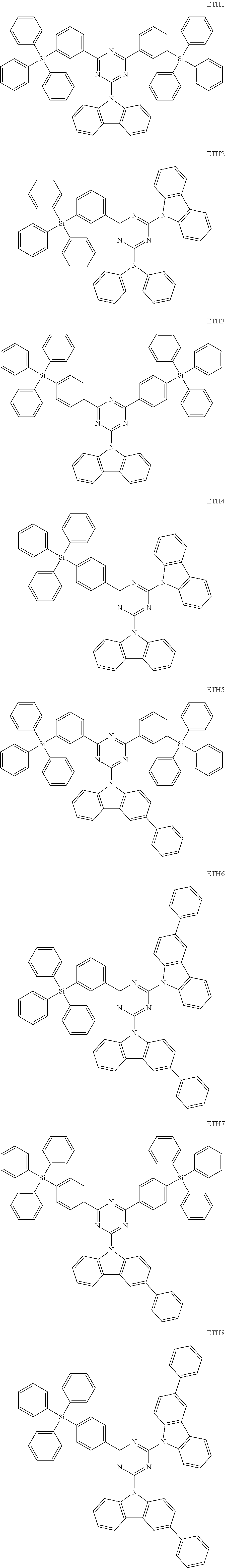

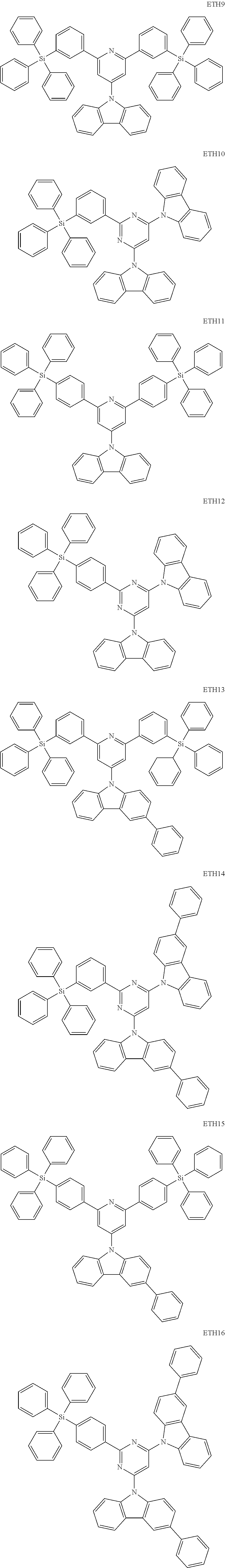

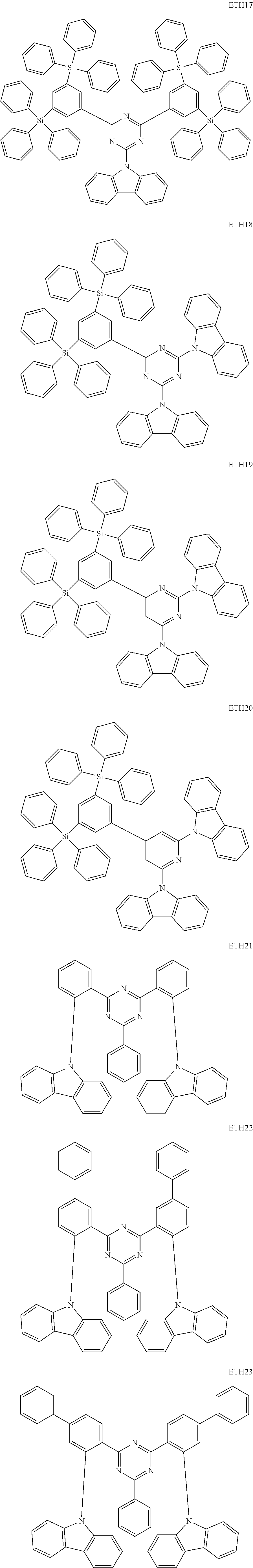

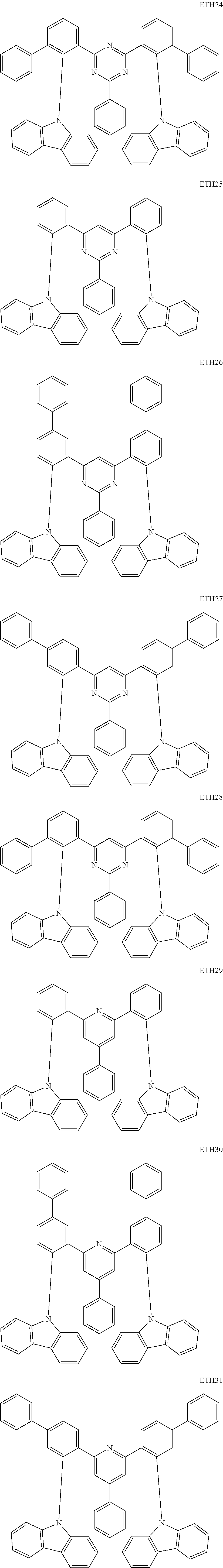

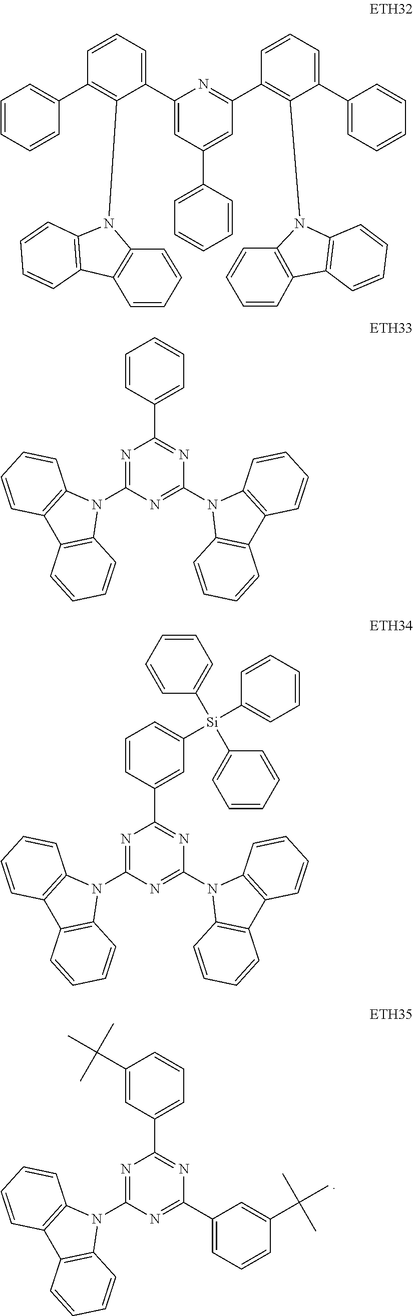

In the light-emitting device according to an embodiment, the second host may include a moiety represented by Formula 7:

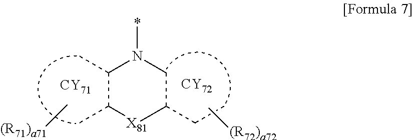

In Formula 7,
rings CY₇₁ and CY₇₂ may each independently be a C₅-C₆₀ carbocyclic group or a C₁-C₆₀ heterocyclic group,
X₈₁ may be a single bond, O, S, N(R₈₁), B(R₈₁), C(R₈₁ₐ)(R_{81b}), or Si(R₈₁ₐ)(R_{81b}),
R₇₁, R₇₂, R₈₁, R₈₁ₐ and R_{81b} may each independently be as described for R₁₀ₐ in Formula 1,
a71 and a72 may each independently be an integer from 0 to 10, and
indicates a binding site to a neighboring atom.

In an embodiment, in Formula 7, rings CY₇₁ and CY₇₂ may each independently be a first ring, a second ring, a group in which two or more first rings are condensed with each other, a group in which two or more second rings are condensed with each other, or a group in which at least one first ring and at least one second ring are condensed with each other, wherein
the first ring may include a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group, and
the second ring may include a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group.

In an embodiment, in Formula 7, rings CY₇₁ and CY₇₂ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, the second host may include a compound represented by one of Formulae 7-1 to 7-5:

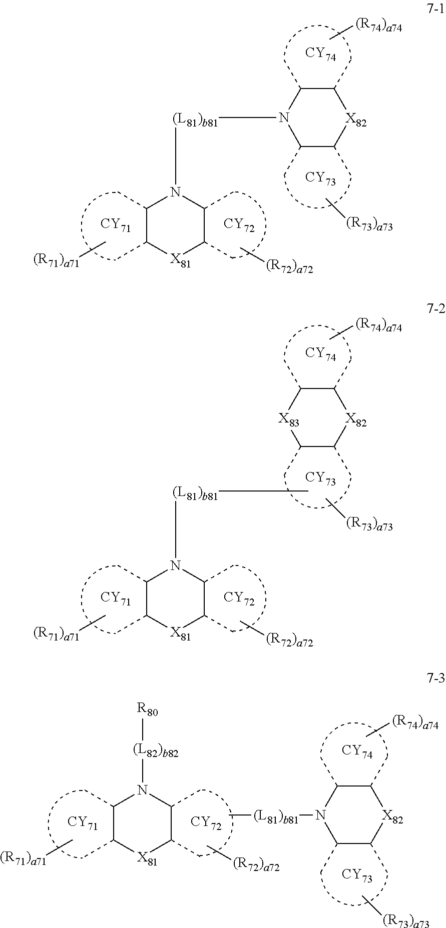

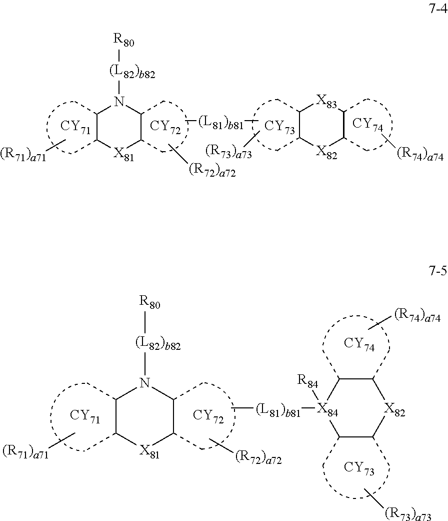

In Formulae 7-1 to 7-5,
ring CY₇₁, ring CY₇₂, X₈₁, R₇₁, R₇₂, a71, and a72 are as described herein,
ring CY₇₃, ring CY₇₄, R₇₃, R₇₄, a73, and a74 are respectively as described for ring CY₇₁, ring CY₇₂, R₇₁, R₇₂, a71, and a72 in Formula 7,
L₈₁ and L₈₂ may each independently be *—C(Q₄)(Q₅)-*′, *—Si(Q₄)(Q₅)-′, a substituted or unsubstituted C₅-C₃₀ carbocyclic group, or a substituted or unsubstituted C₁-C₃₀ heterocyclic group, wherein Q₄ and Q₅ may each independently be as described for Q₁,
b81 and b82 may each be an integer from 0 to 5, wherein,
when b81 is 0, *-(L₈₁)_{b81}-*′ may be a single bond, and when b81 is 2 or more, two or more of L₈₁(s) may be identical to or different from each other,
when b82 is 0, *-(L₈₂)_{b82}-*′ may be a single bond, and when b82 is 2 or more, two or more of L₈₂(s) may be identical to or different from each other,
X₈₂ may be a single bond, O, S, N(R₈₂), B(R₈₂), C(R₈₂ₐ)(R_{82b}), or Si(R₈₂ₐ)(R_{82b}),
X₈₃ may be a single bond, O, S, N(R₈₃), B(R₈₃), C(R₈₃ₐ)(R_{83b}), or Si(R₈₃ₐ)(R_{83b}),
in Formulae 7-2 and 7-4, X₈₂ and X₈₃ may each not be a single bond at the same time,
X₈₄ may be C or Si,
R₈₀, R₈₂, R₈₃, R₈₂ₐ, R_{82b}, R₈₃ₐ, R_{83b}, and R₈₄ may each independently be as described for R₈₁, and
and *′ each indicate a binding site to a neighboring atom.

In the light-emitting device according to an embodiment,
a moiety represented by

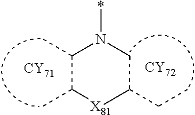

in Formulae 7-1 and 7-2 may be a moiety represented by one of Formulae CY71-1 (1) to CY71-1 (8),
a moiety represented by

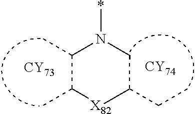

in Formulae 7-1 and 7-3 may be a moiety represented by one of Formulae CY71-2(1) to CY71-2(8),
a moiety represented by

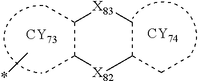

in Formulae 7-2 and 7-4 may be a moiety represented by one of Formulae CY71-3(1) to CY71-3(32),
a moiety represented by

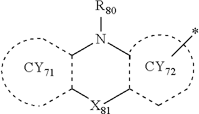

in Formulae 7-3 to 7-5 may be a moiety represented by one of Formulae CY71-4(1) to CY71-4(32), and
a moiety represented by

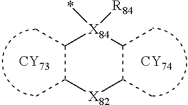

in Formula 7-5 may be a moiety represented by one of Formulae CY71-5(1) to CY71-5(8):

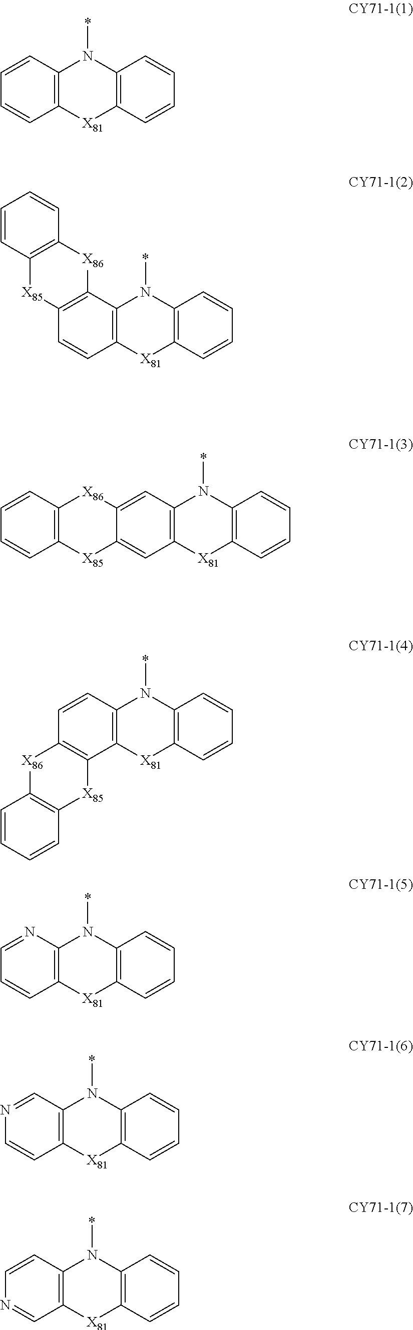

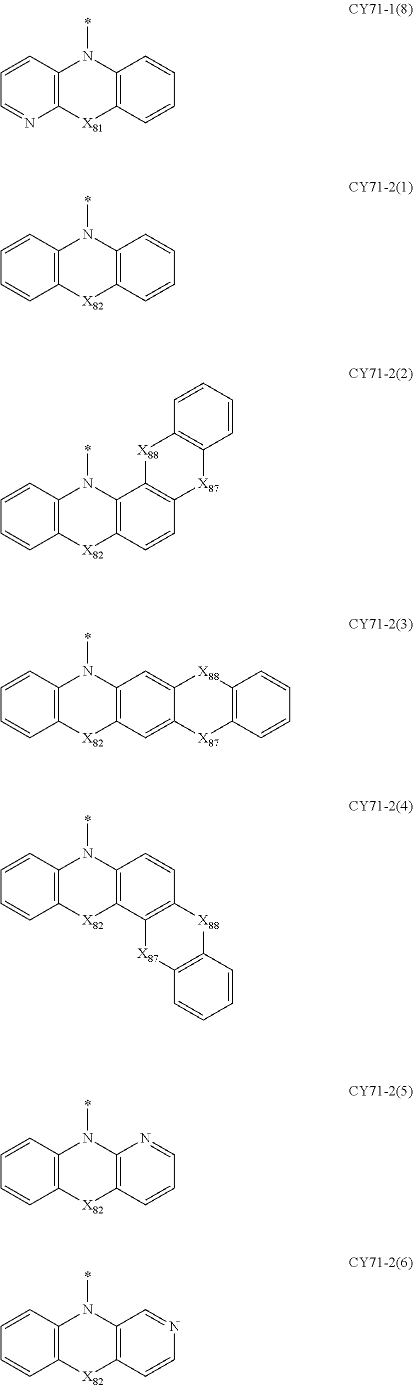

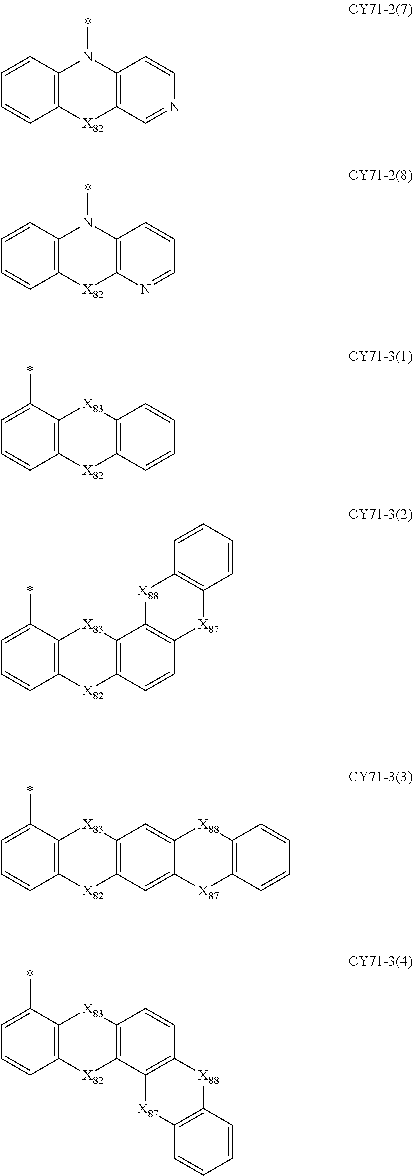

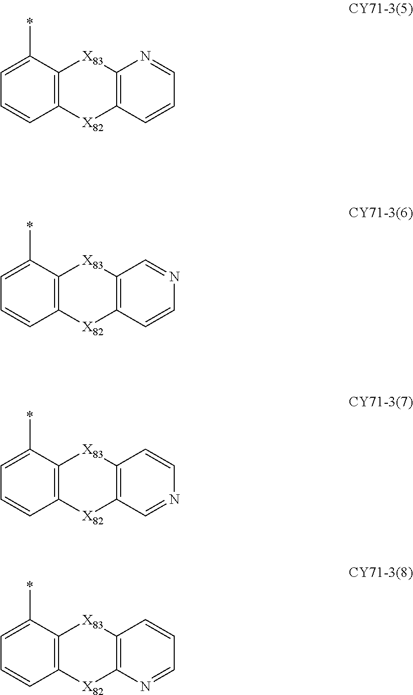

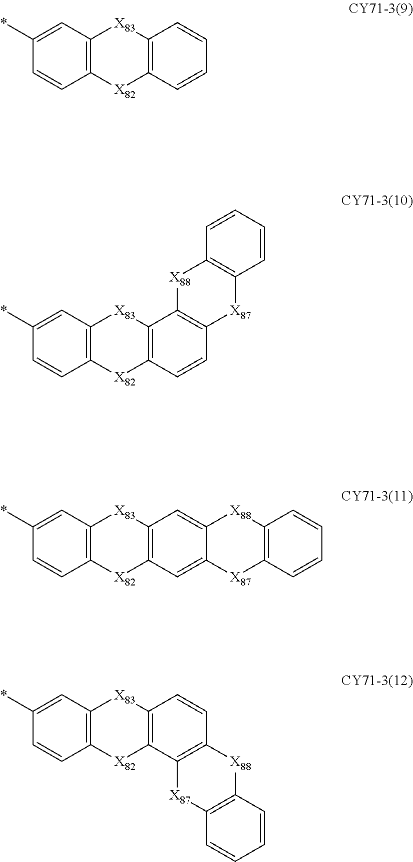

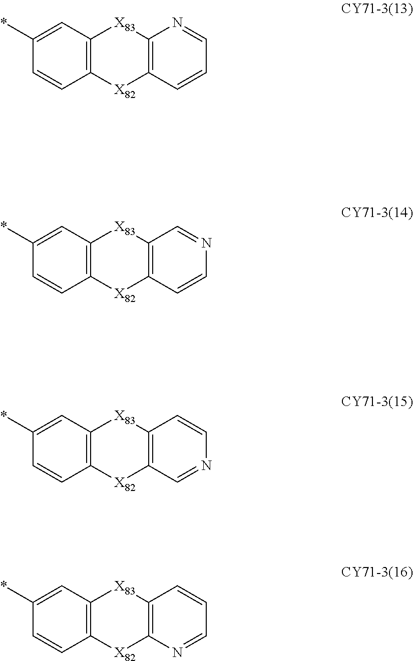

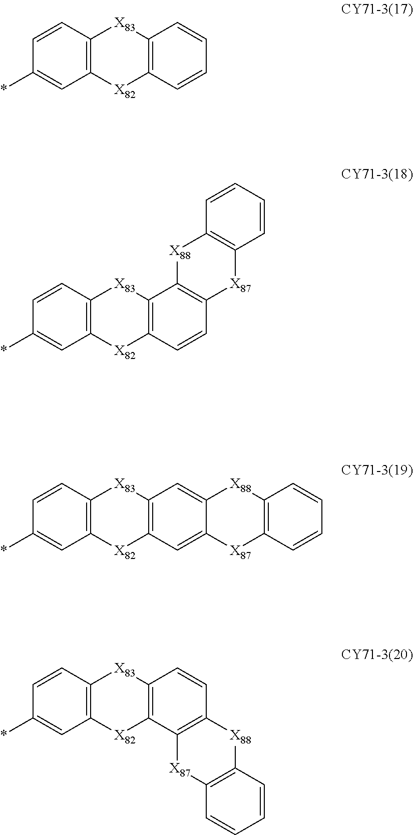

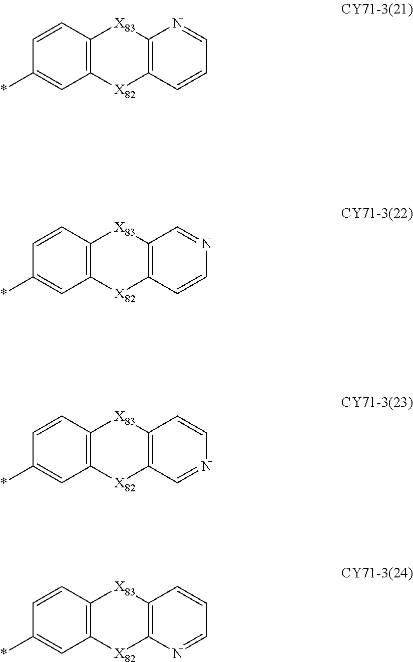

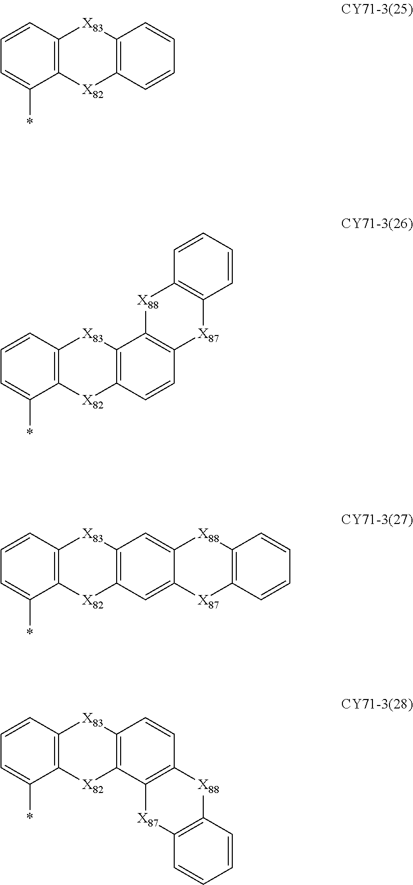

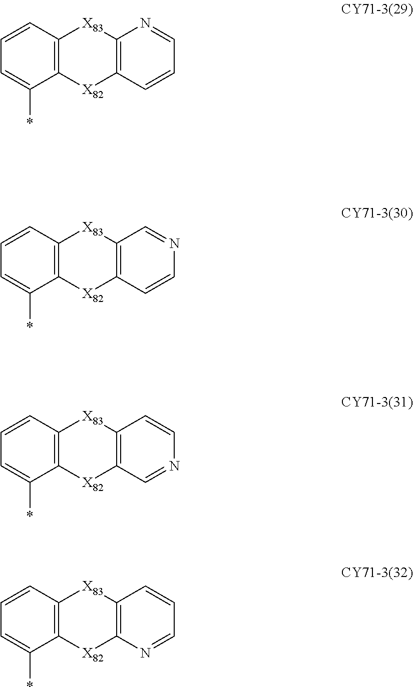

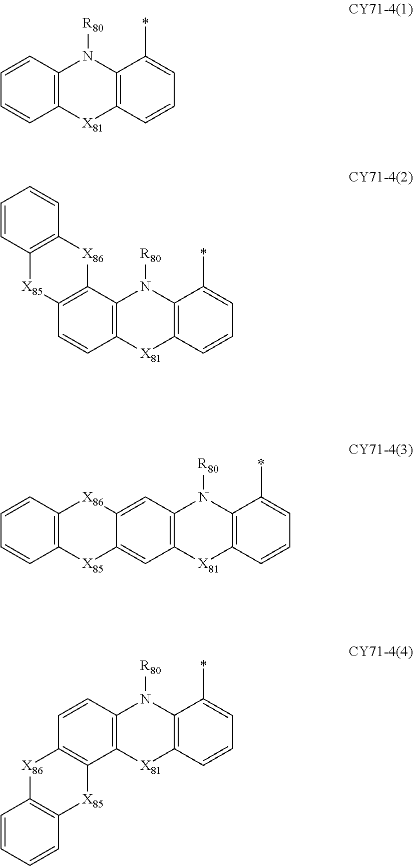

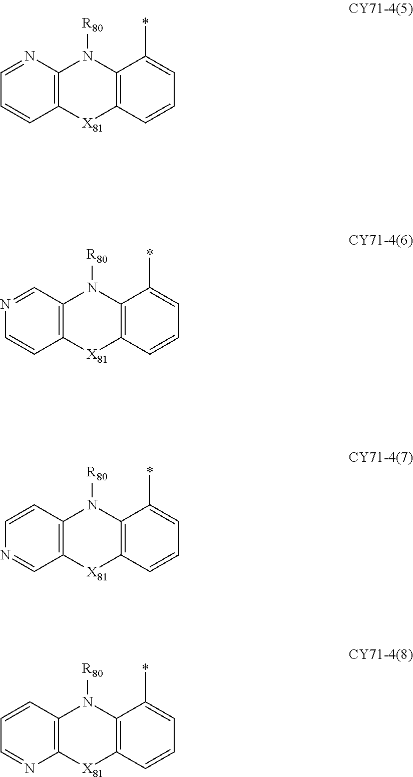

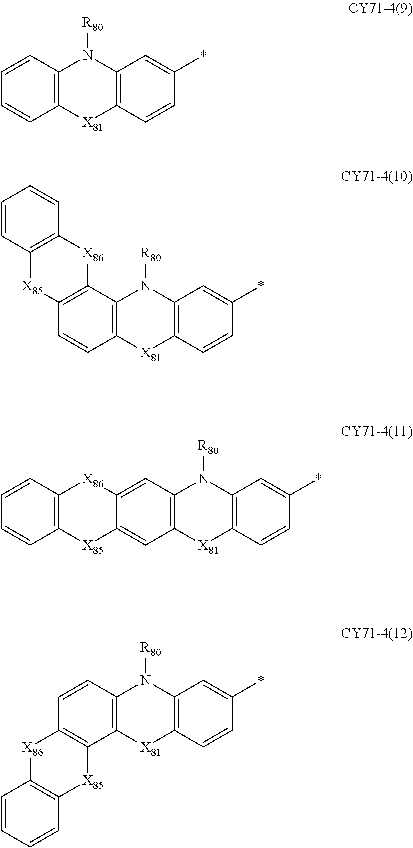

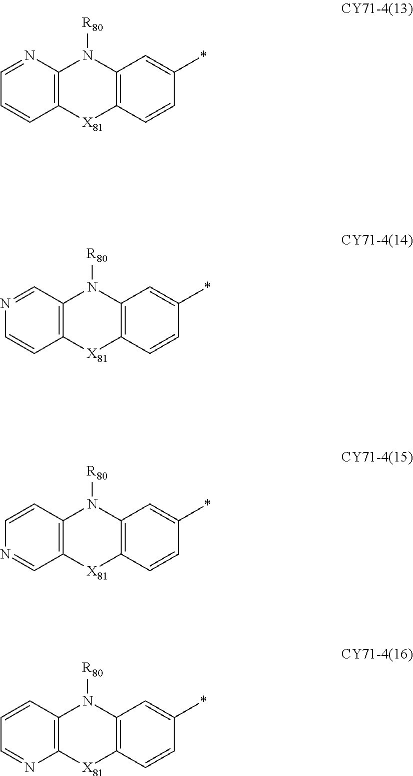

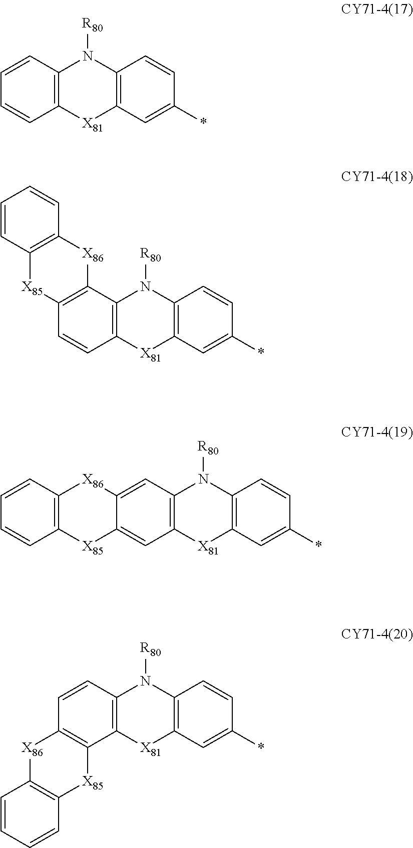

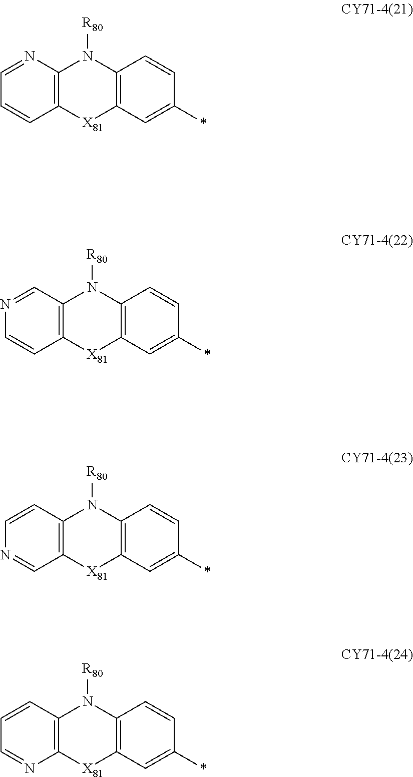

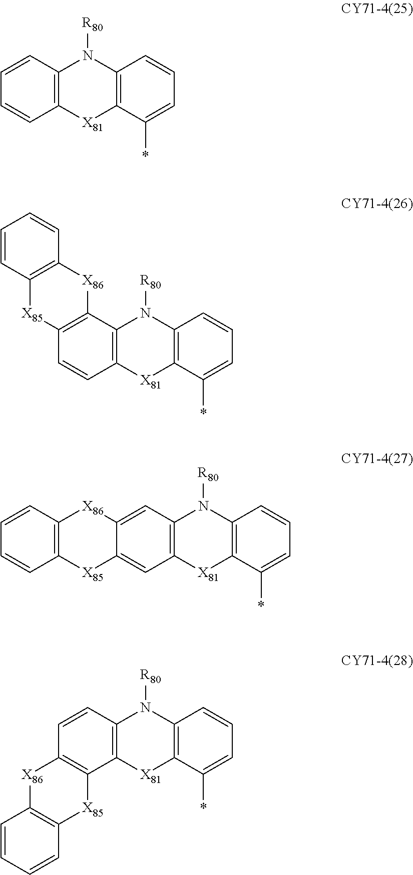

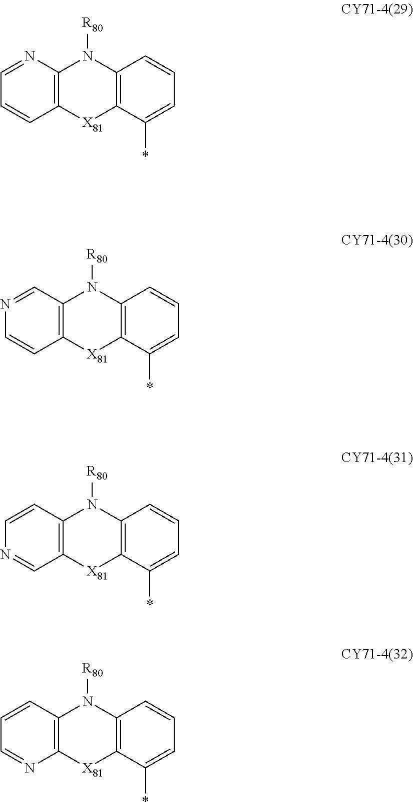

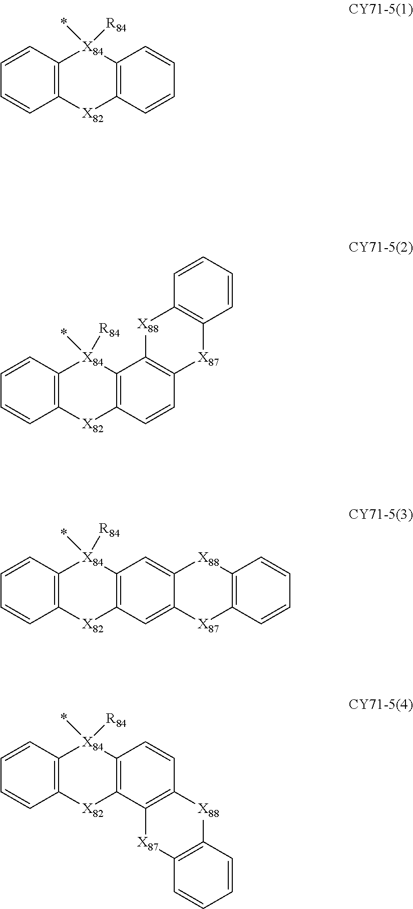

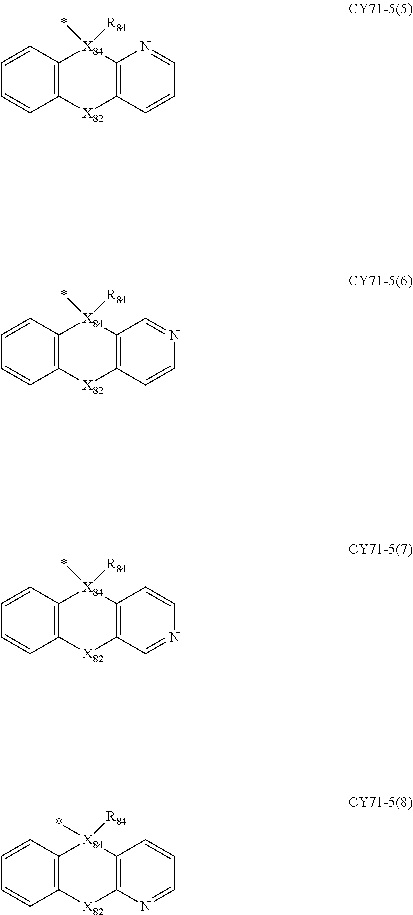

In Formulae CY71-1 (1) to CY71-1 (8), CY71-2(1) to CY71-2(8), CY₇₁-(1) to CY71-3(32), CY71-4(1) to CY71-4(32), and CY71-5(1) to CY71-5(8),
X₈₁ to X₈₄, R₈₀, and R₈₄ are as described herein,
X₈₅ may be a single bond, O, S, N(R₈₅), B(R₈₅), C(R₈₅ₐ)(R_{85b}), or Si(R₈₅ₐ)(R_{85b}),
X₈₆ may be a single bond, O, S, N(R₈₆), B(R₈₆), C(R₈₆ₐ)(R_{86b}), or Si(R₈₆ₐ)(R_{86b}),
in Formulae CY71-1 (1) to CY71-1 (8) and CY71-4(1) to CY71-4(32), X₈₅ and X₈₆ may each not be a single bond at the same time,
X₈₇ may be a single bond, O, S, N(R₈₇), B(R₈₇), C(R₈₇ₐ)(R_{87b}), or Si(R₈₇ₐ)(R_{87b}),
X₈₈ may be a single bond, O, S, N(R₈₈), B(R₈₈), C(R₈₈ₐ)(R_{88b}), or Si(R₈₈ₐ)(R_{88b}),
in Formulae CY71-2(1) to CY71-2(8), CY71-3(1) to CY71-3(32) and CY71-5(1) to CY71-5(8), X₈₇ and X₈₈ may each not be a single bond at the same time, and
R₈₅ to R₈₈, R₈₅ₐ, R_{85b}, R₈₆ₐ, R_{86b}, R₈₇ₐ, R_{87b}, R₈₈ₐ and R_{88b} are each independently as described for R₈₁.

In the light-emitting device according to an embodiment, the second host may include at least one of Compounds HTH1 to HTH44:

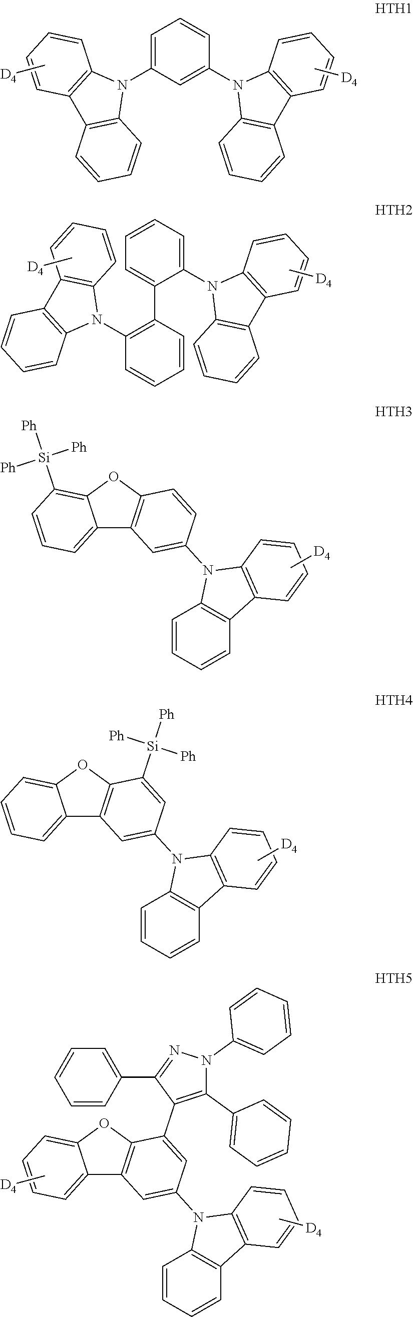

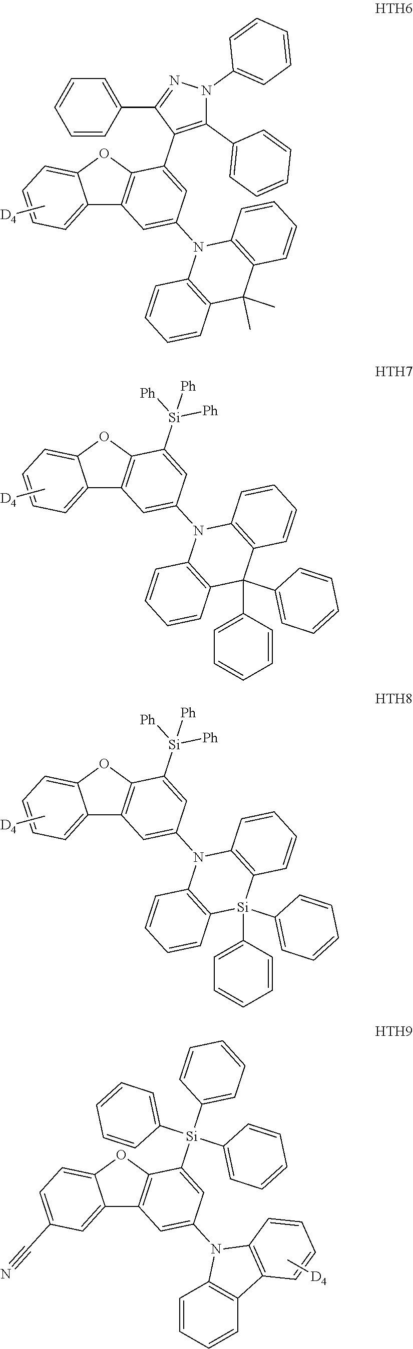

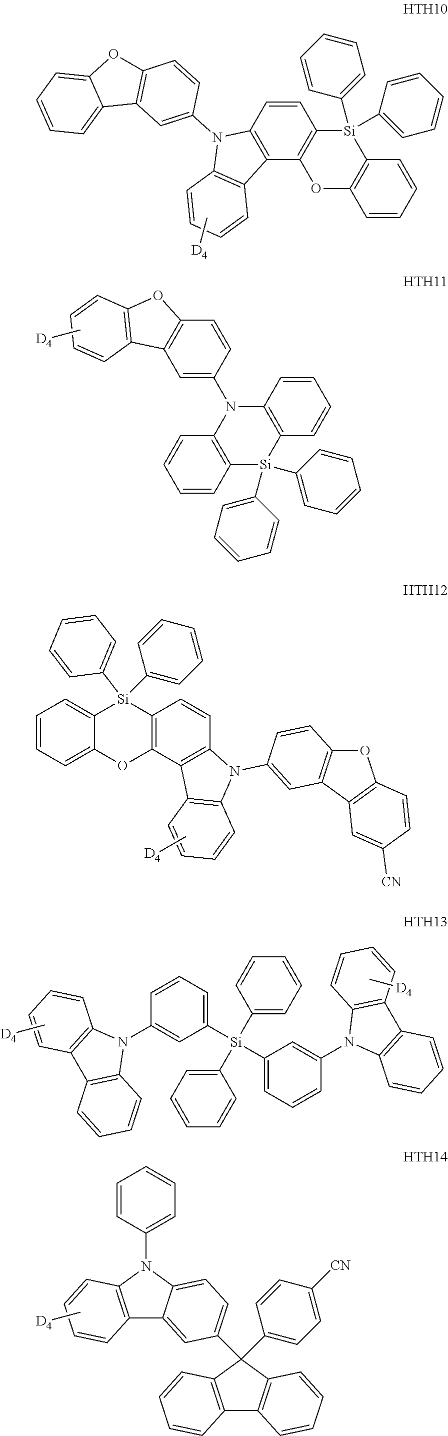

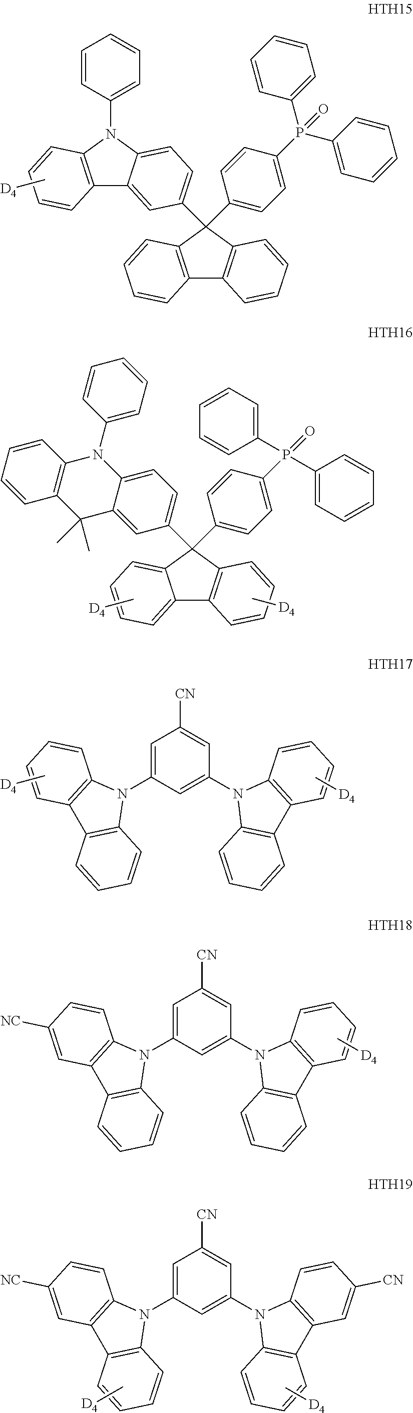

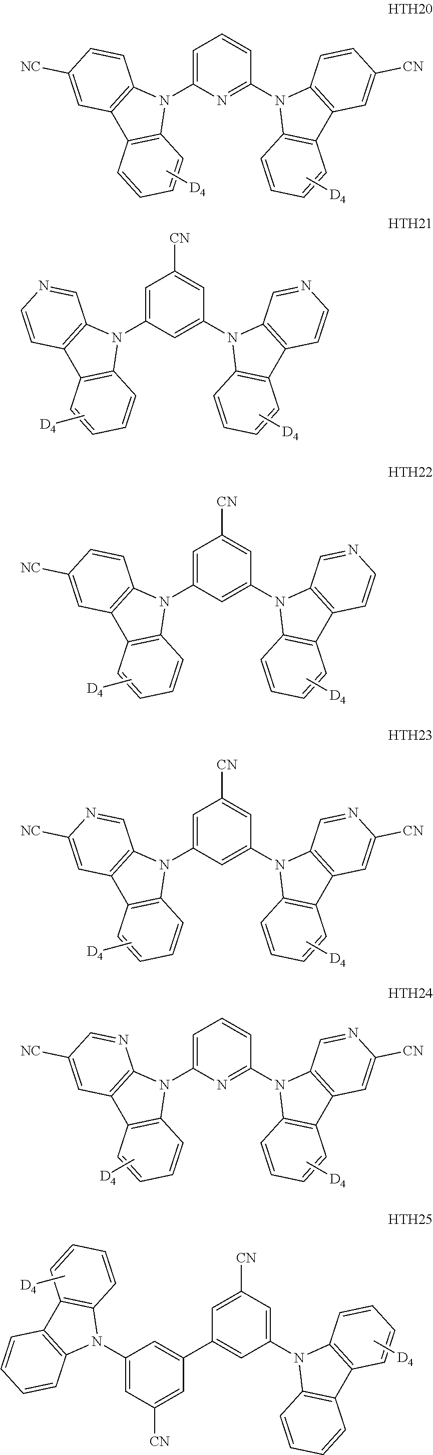

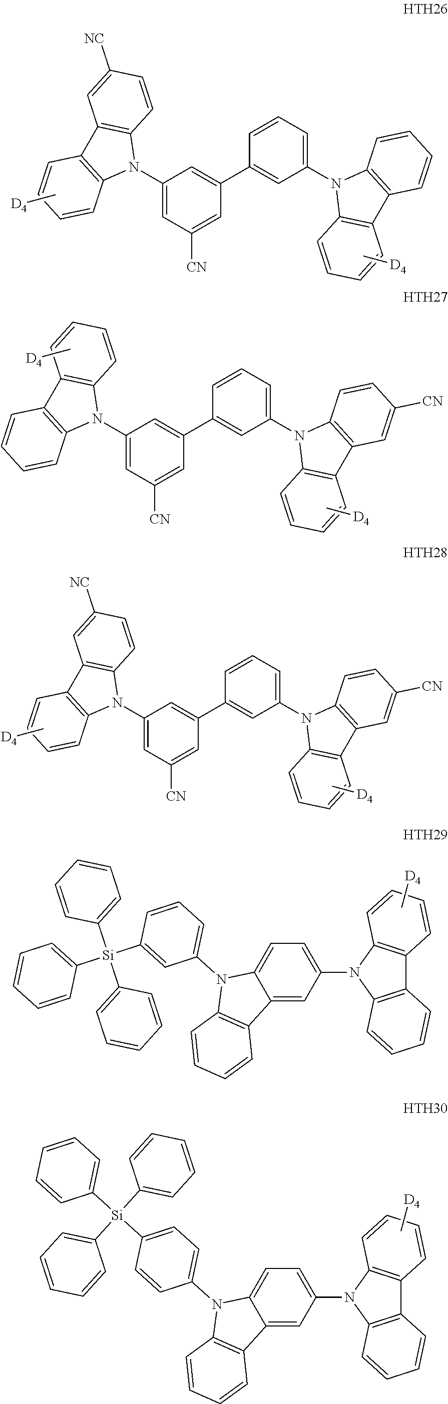

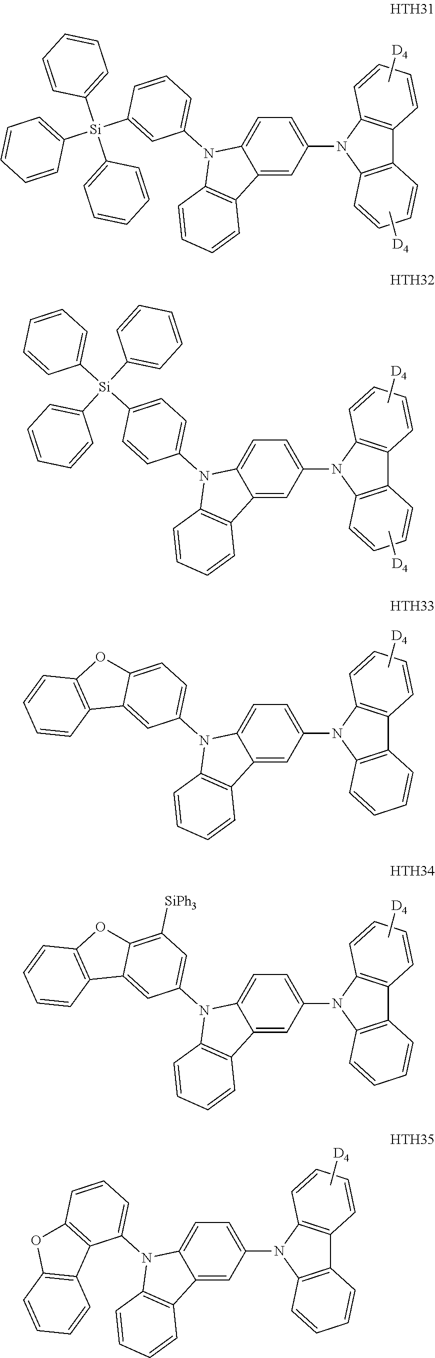

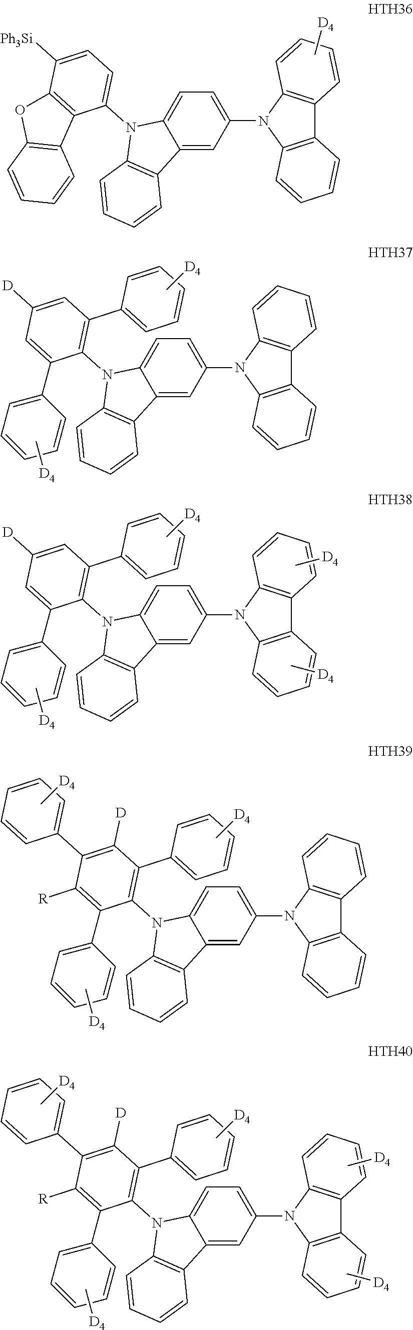

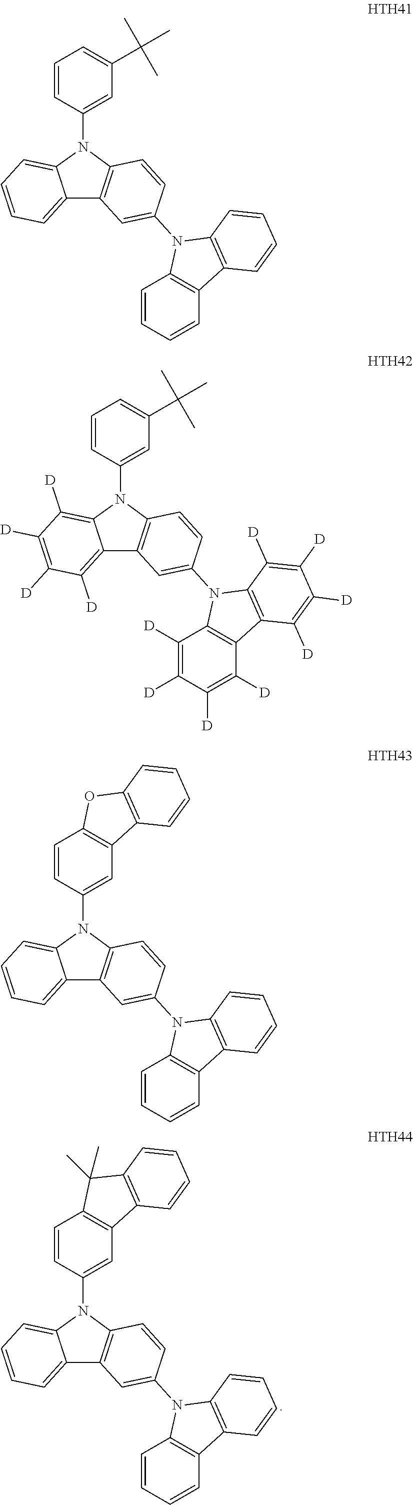

In the light-emitting device according to an embodiment, the first and second hosts may form an exciplex, wherein the condensed cyclic compound and the first host may not form an exciplex, or the condensed cyclic compound and the second host may not form an exciplex.

In the light-emitting device according to an embodiment, the emission layer may further include a phosphorescent sensitizer, the phosphorescent sensitizer may include at least one carbene moiety and Pt, and a bond between the carbene moiety and Pt may be a coordinate bond.

In the light-emitting device according to an embodiment, the phosphorescent sensitizer may be one of PS-1 to PS-4:

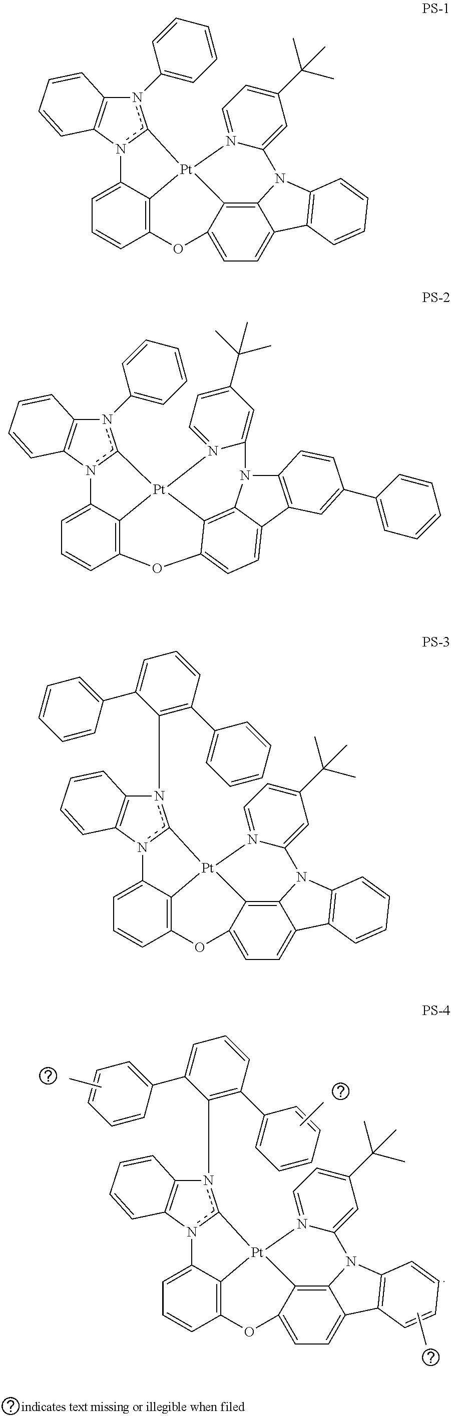

In the light-emitting device according to an embodiment, with respect to a total weight of the emission layer, an amount of the phosphorescent sensitizer may be greater than an amount of the condensed cyclic compound represented by Formula 1.

In the light-emitting device according to an embodiment, the emission layer may emit fluorescence.

In the light-emitting device according to an embodiment, the emission layer may emit delayed fluorescence.

In the light-emitting device according to an embodiment, the emission layer may emit blue light.

In the light-emitting device according to an embodiment, the first electrode may be an anode; the second electrode may be a cathode; the interlayer may further include a hole transport region between the first electrode and the emission layer, and an electron transport region between the emission layer and the second electrode,
the hole transport region may include a hole injection layer, a hole transport layer, an emission auxiliary layer, an electron blocking layer, or a combination thereof, and
the electron transport region may include a hole blocking layer, an electron transport layer, an electron injection layer, or a combination thereof.

The light-emitting device according to an embodiment may further include a first capping layer and/or a second capping layer, wherein the first capping layer may be located on a surface of the first electrode, and the second capping layer may be located on a surface of the second electrode.

In the light-emitting device according to an embodiment, at least one of the first capping layer and the second capping layer may include the condensed cyclic compound represented by Formula 1.

Another embodiment provides an electronic apparatus which may include the light-emitting device.

In an embodiment, the electronic apparatus may further include a thin-film transistor; and
a color filter, a color conversion layer, a touch screen layer, a polarizing layer, or a combination thereof.

In an embodiment, the thin-film transistor may include a source electrode and a drain electrode, and the first electrode of the light-emitting device may be electrically connected to the source electrode or the drain electrode.

Another embodiment provides an electronic device which may include the light-emitting device.

In an embodiment, electronic device may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall including multiple displays tiled together, a theater screen, a stadium screen, a phototherapy device, or a sign.

Another embodiment provides a condensed cyclic compound which may be represented by Formula 1:

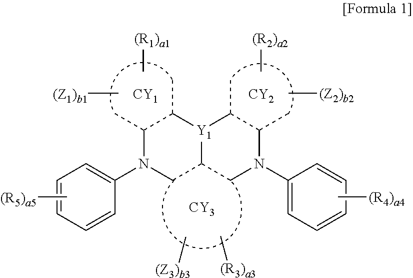

In Formula 1,
Y₁ may be B or N,
rings CY₁ to CY₃ may each independently be a C₃-C₃₀ carbocyclic group or a C₁-C₃₀ heterocyclic group,
R₁ to R₃ may each independently be a C₃-C₆₀ carbocyclic group substituted with L_{D} or a C₁-C₆₀ heterocyclic group substituted with L_{D},
L_{D} may be a C₁-C₆₀ alkyl group unsubstituted or substituted with deuterium or —Si(Q₁)(Q₂)(Q₃),
when two or more of L_{D} are included, the two or more L_{D} may be identical to or different from each other,
R₄ and R₅ may each independently be a C₁-C₆₀ alkyl group unsubstituted or substituted with R₁₀ₐ or a C₃-C₆₀ carbocyclic group unsubstituted or substituted with R₁₀ₐ,
Z₁ to Z₃ may each independently be a C₃-C₆₀ carbocyclic group unsubstituted or substituted with R_{10b} or a π electron-rich C₃-C₆₀ cyclic group unsubstituted or substituted with R_{10b},
a1 to a3 may each independently be an integer from 0 to 3,
a sum of a1 to a3 may be 1 or more,
a4 and a5 may each independently be an integer from 2 to 5,
b1 to b3 may each independently be an integer from 0 to 3,
a sum of b1 to b3 may be 1 or more, and
R₁₀ₐ and R_{10b} may each independently be:
deuterium, —F, —Cl, —Br, —I, a hydroxyl group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₂-C₆₀ alkenyl group; a C₂-C₆₀ alkynyl group; a C₁-C₆₀ alkoxy group; a C₁-C₆₀ alkyl group unsubstituted or substituted with deuterium, —F, a cyano group, or a combination thereof; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

In the condensed cyclic compound according to an embodiment, Y₁ may be B.

In the condensed cyclic compound according to an embodiment, rings CY₁ to CY₃ may be identical to each other.

In the condensed cyclic compound according to an embodiment, rings CY₁ to CY₃ may be different from each other.

In the condensed cyclic compound according to an embodiment, rings CY₁ to CY₃ may each independently be a benzene group or a naphthalene group.

In the condensed cyclic compound according to an embodiment, ring CY₁ may be represented by one of Formulae CY1-1 to CY1-4:

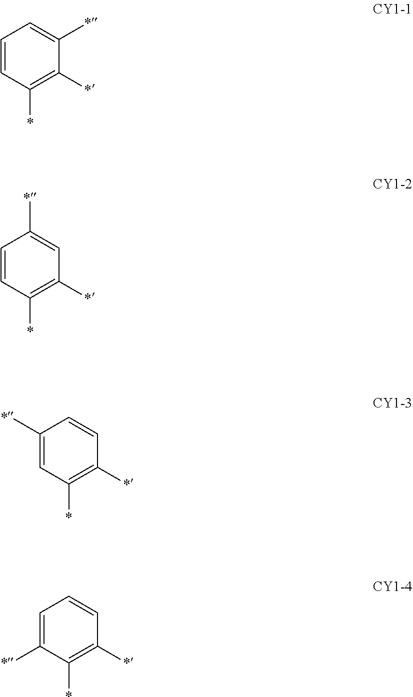

In Formulae CY1-1 to CY1-4,
* indicates a binding site to a neighboring N,
*′ indicates a binding site to a neighboring Y₁,
*″ indicates a binding site to an atom included in R₁ or an atom included in Z₁, and

Y₁, R₁, and Z₁ are as described in Formula 1.

In the condensed cyclic compound according to an embodiment, ring CY₂ may be represented by one of Formulae CY2-1 to CY2-4:

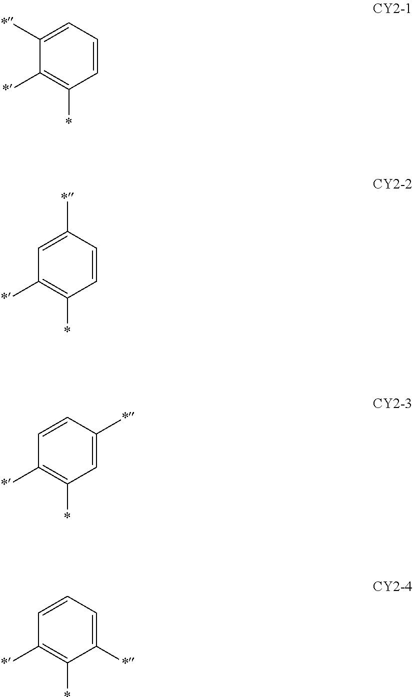

In Formulae CY2-1 to CY2-4,
indicates a binding site to a neighboring N,
′ indicates a binding site to a neighboring Y₁,
″ indicates a binding site to an atom included in R₂ or an atom included in Z₂, and
Y₁, R₂, and Z₂ are as described in Formula 1.

In the condensed cyclic compound according to an embodiment, ring CY₃ may be represented by one of Formulae CY3-1 to CY3-3:

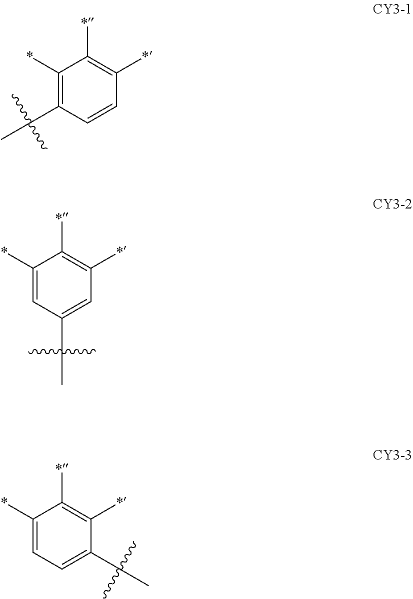

In Formulae CY3-1 to CY3-3,
and *′ each independently indicate a binding site to a neighboring N,
*″ indicates a binding site to a neighboring Y₁, and
[symbol] indicates a binding site to an atom included in R₃ or to an atom included in Z₃.

In the condensed cyclic compound according to an embodiment, R₁ to R₃ may each independently be a group represented by one of Formulae 1-2-1 to 1-2-16:

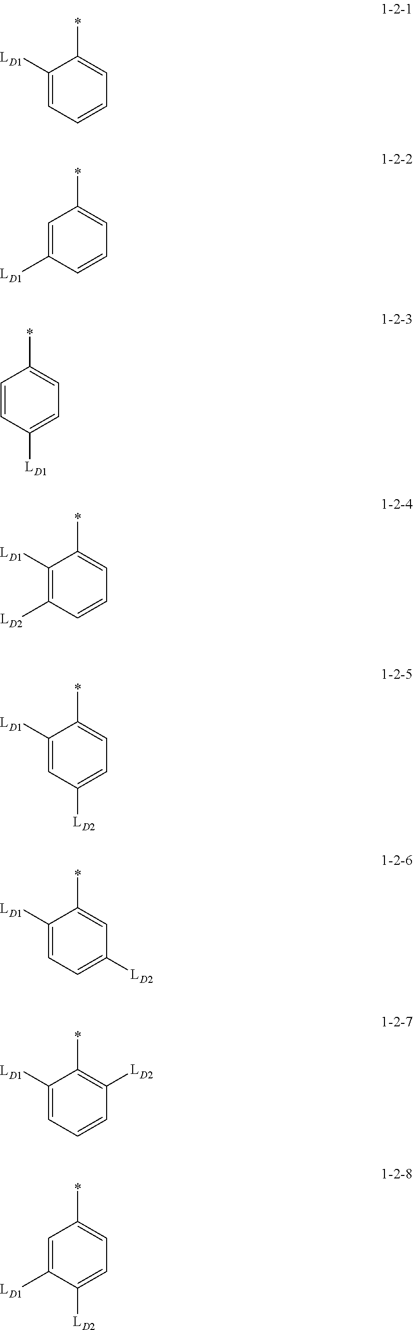

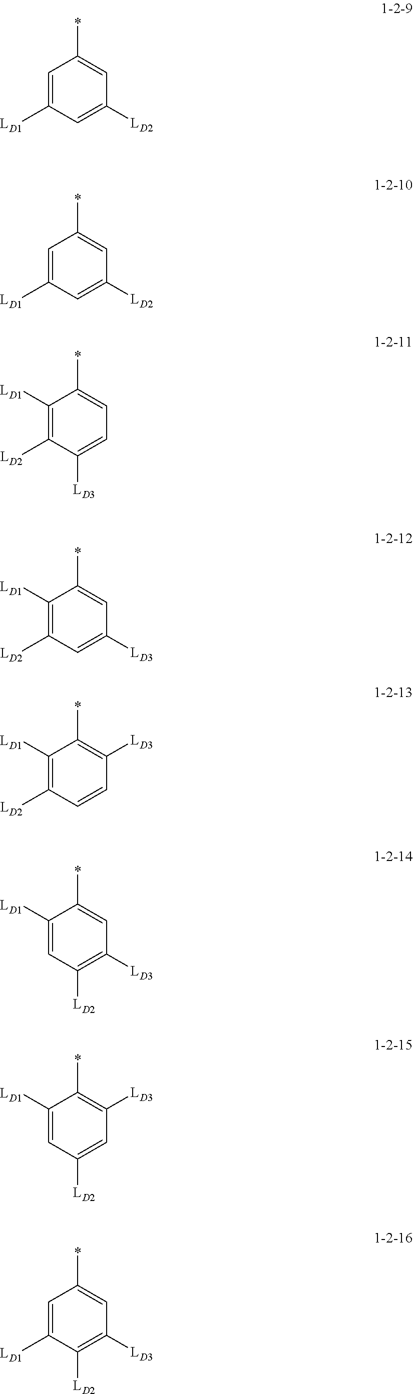

In Formulae 1-2-1 to 1-2-16,
indicates a binding site to an atom included in one of rings CY₁ to CY₃, and
L_{D1}, L_{D2}, and L_{D3} may each independently be as described for L_{D} in Formula 1.

In the condensed cyclic compound according to an embodiment, L_{D} may be a methyl group, an ethyl group, a propyl group, an isopropyl group, a butyl group, an isobutyl group, a sec-butyl group, a tert-butyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl group, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, a 3-cyclohexylpentyl group, or a deuterated derivative group thereof.

In the condensed cyclic compound according to an embodiment, the deuterated derivative group may be —CD₃, —CD₂H, —CDH₂, —C(CD₃)₃, —C(CD₃)₂H, —C(CD₃)₂D, —C(CD₃)(H)₂, —C(CD₃)(H)(D), —C(CD₃)(D)₂, —C(CD₃)₂(CH₃), —C(CD₃)(CH₃)₂, —C(CD₃)₂(CD₂H), —C(CD₃)(CD₂H)₂, —C(CD₃)₂(CDH₂), —C(CD₃)(CDH₂)₂, or —C(CD₃)(CD₂H)(CDH₂).

In the condensed cyclic compound according to an embodiment, a moiety represented by

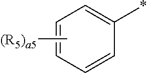

and a moiety represented by

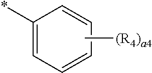

may each independently be a moiety represented by one of Formulae 1-3-1 to 1-3-34:

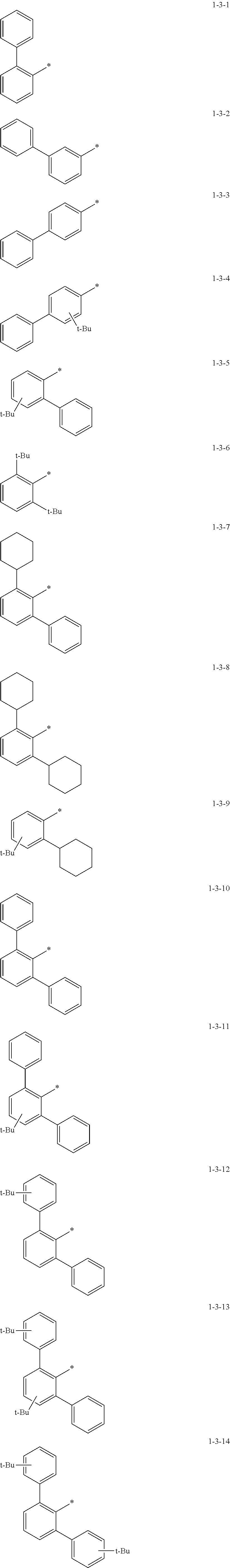

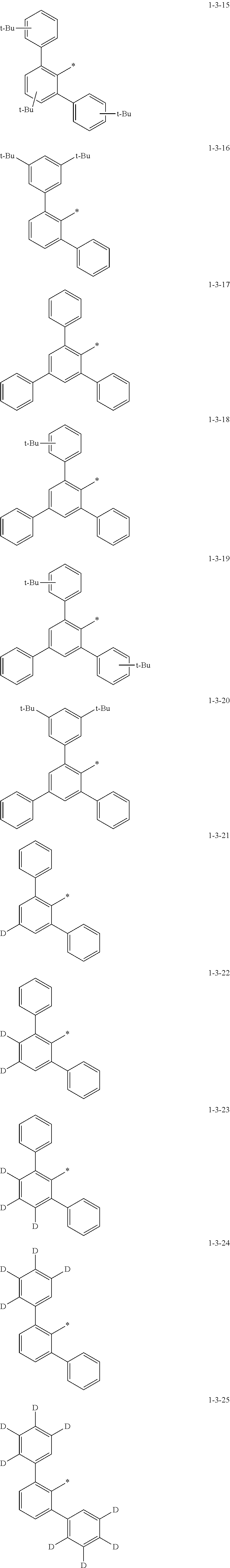

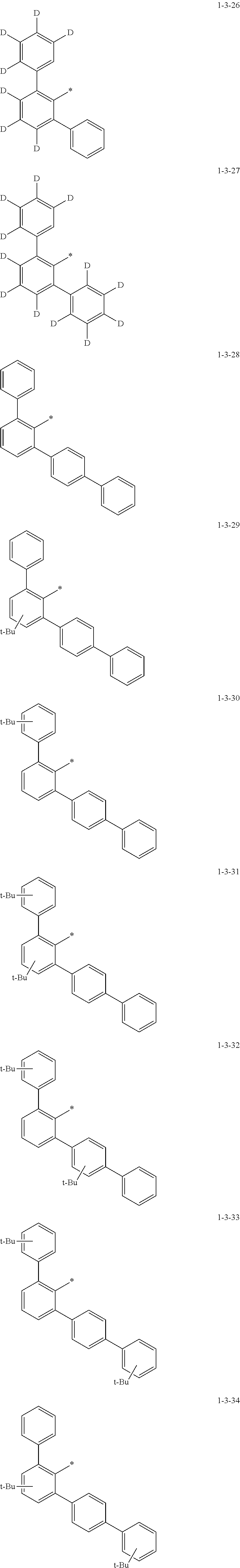

In Formulae 1-3-1 to 1-3-34,
indicates a binding site to a neighboring nitrogen atom.

In the condensed cyclic compound according to an embodiment, a sum of a1 and b1 may be 1, a sum of a2 and b2 may be 1, or a sum of a3 and b3 may be 1.

In the condensed cyclic compound according to an embodiment, one of Conditions i to ix may be satisfied.
[Condition i]
a1 is 1, a2 and a3 are each 0, b1 is 0, and b2 and b3 are each 1;
[Condition ii]
a2 is 1, a1 and a3 are each 0, b2 is 0, and b1 and b3 are each 1;
[Condition iii]
a3 is 1, a1 and a2 are each 0, b3 is 0, and b1 and b2 are each 1;
[Condition iv]
b1 is 1, b2 and b3 are each 0, a1 is 0, and a2 and a3 are each 1;
[Condition v]
b2 is 1, b1 and b3 are each 0, a2 is 0, and a1 and a3 are each 1;
[Condition vi]
b3 is 1, b1 and b2 are each 0, a3 is 0, and a1 and a2 are each 1;
[Condition vii]
a1 to a3 are each 0, and b1 to b3 are each 1;
[Condition ix]
a1 to a3 are each 1, and b1 to b3 are each 0.

In the condensed cyclic compound according to an embodiment, Z₁ to Z₂ may each independently be a group represented by one of Formulae 1-4-1 to 1-4-2:

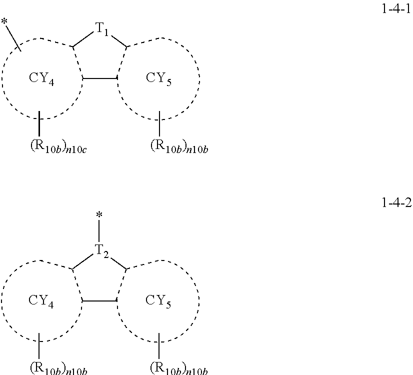

In Formulae 1-4-1 to Formula 1-4-2,
T₁ may be O, S, N(Q₅), P(Q₅), C(Q₅)(Q₆), or Si(Q₅)(Q₆),
T₂ may be N, P, C(Q₅), or Si(Q₅),
CY₄ and CY₅ may each independently be a C₃-C₆₀ carbocyclic group or a C₁-C₆₀ heterocyclic group,
n10b may be an integer from 0 to 6,
n10c may be an integer from 0 to 5,
indicates a binding site to a neighboring atom, and
R_{10b}, Q₅, and Q₆ may respectively be as described for R_{10b}, Q₁, and Q₂ in Formula 1.

In the condensed cyclic compound according to an embodiment, rings CY₄ to CY₅ may each independently be a benzene group or a naphthalene group.

In an embodiment, the condensed cyclic compound may be one of Compounds 1 to 232:

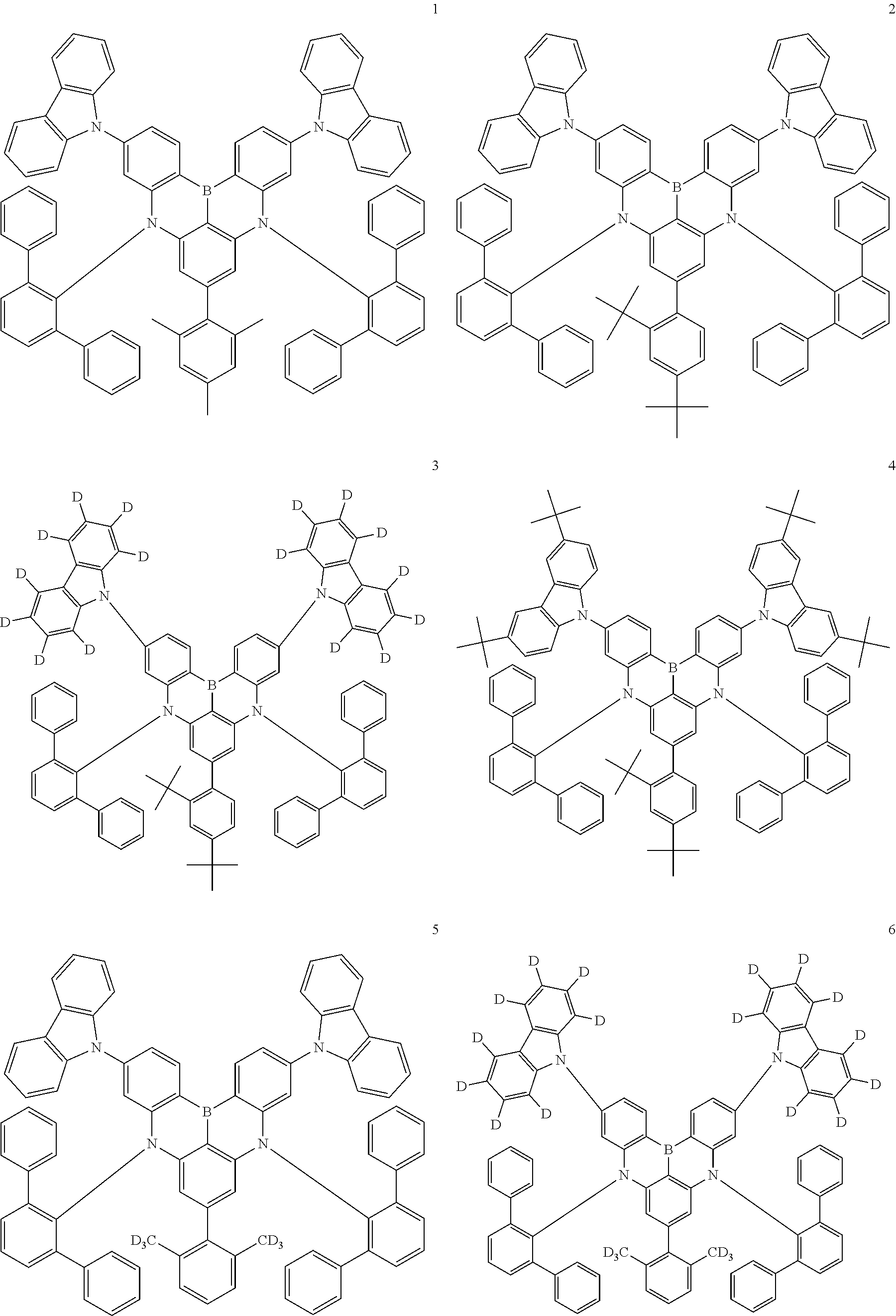

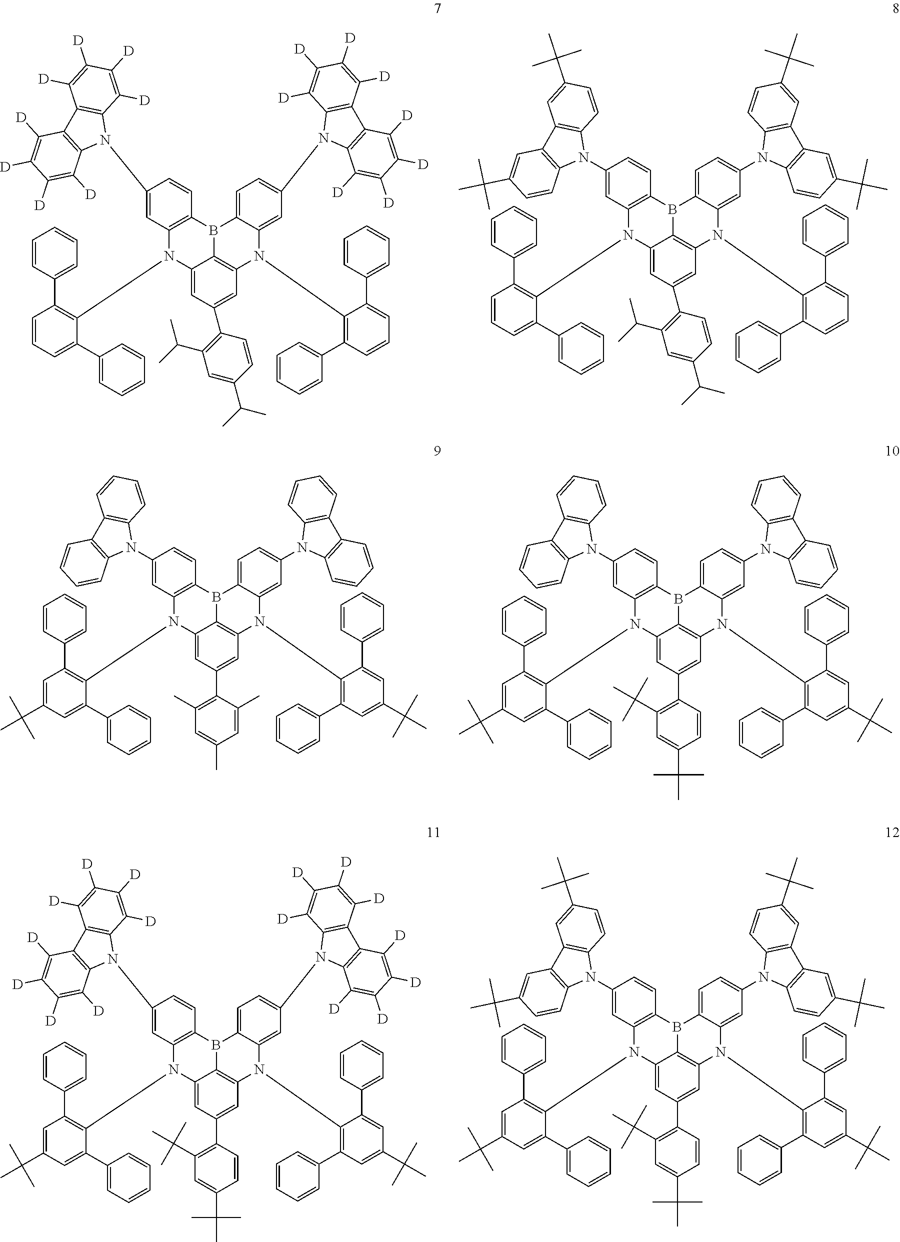

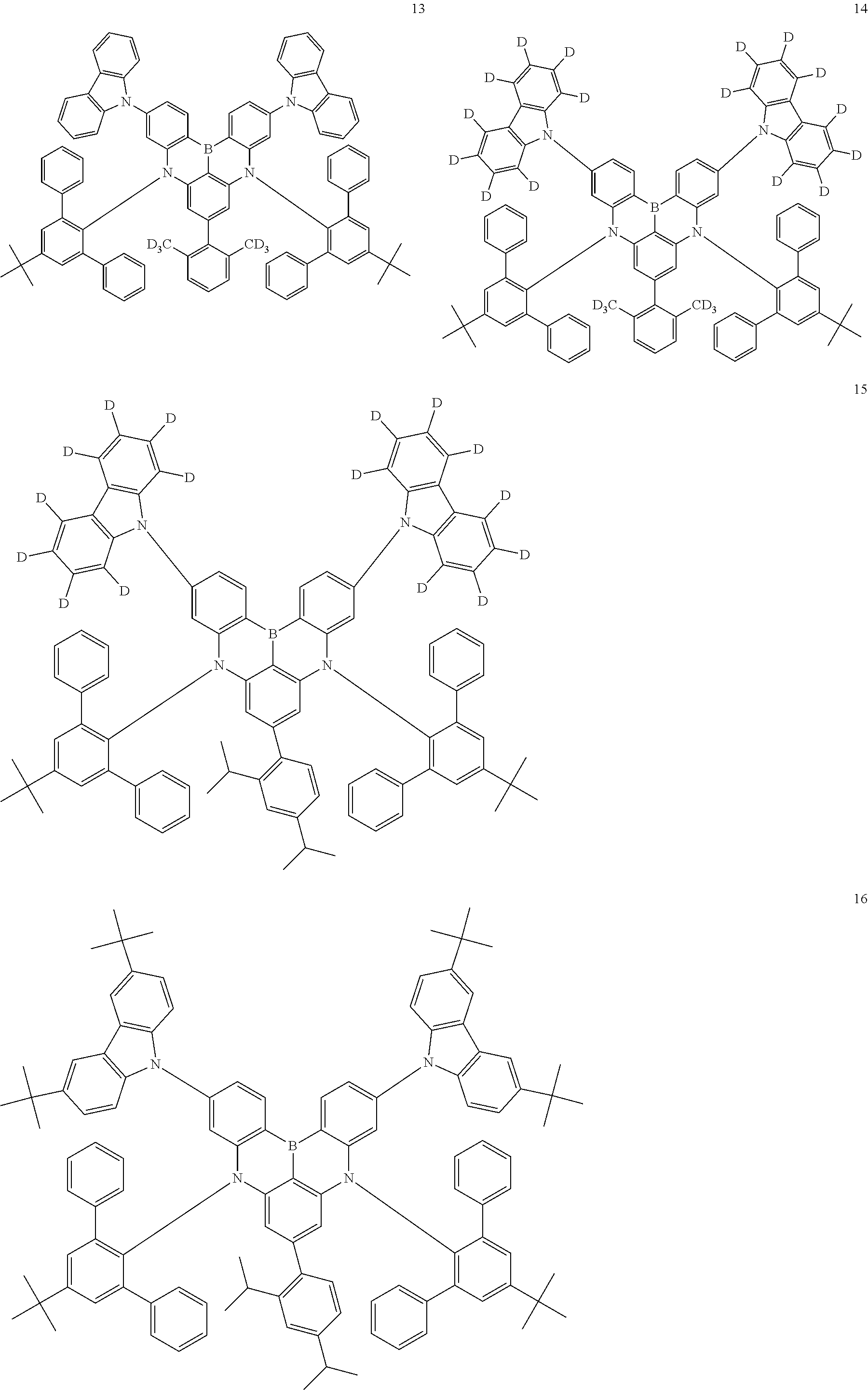

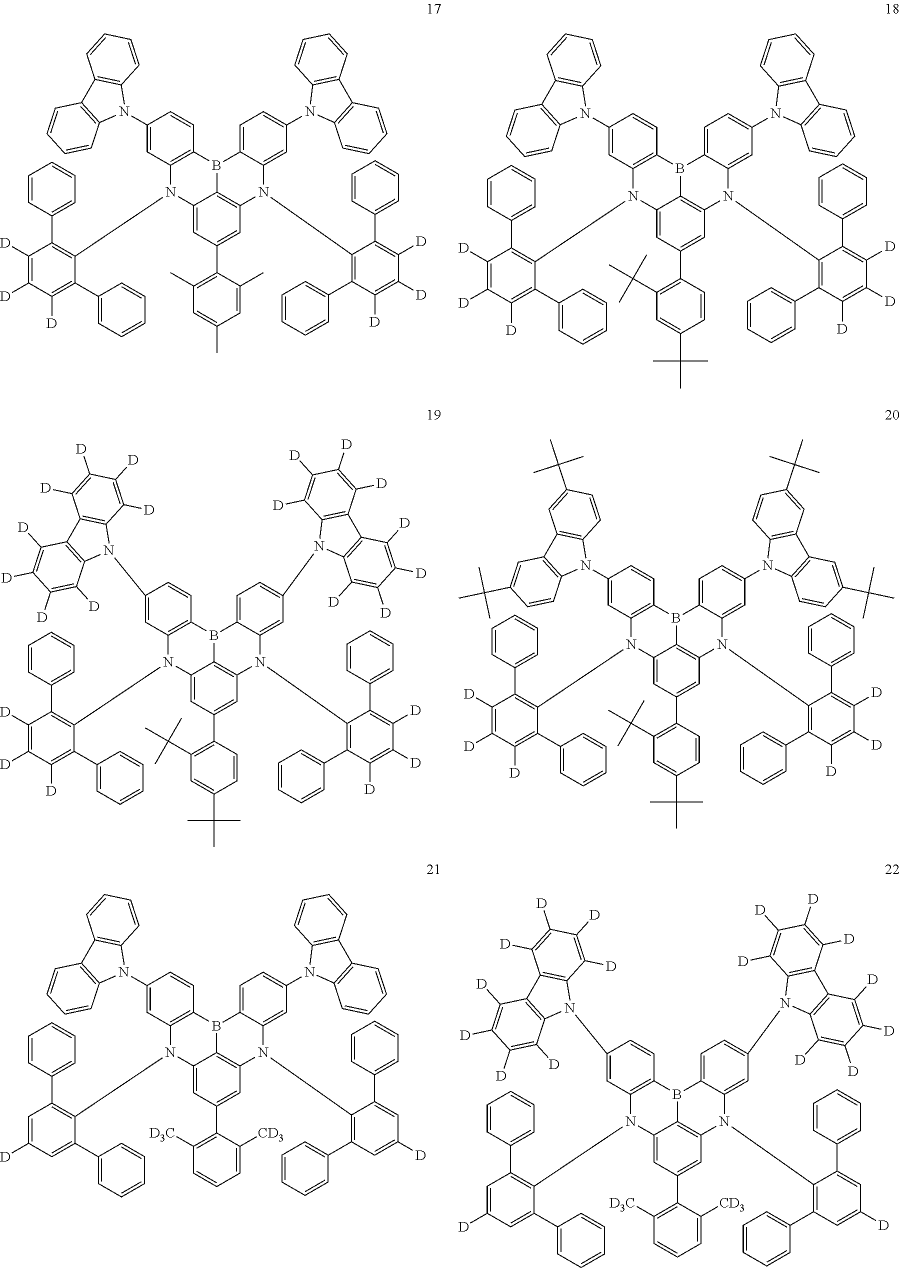

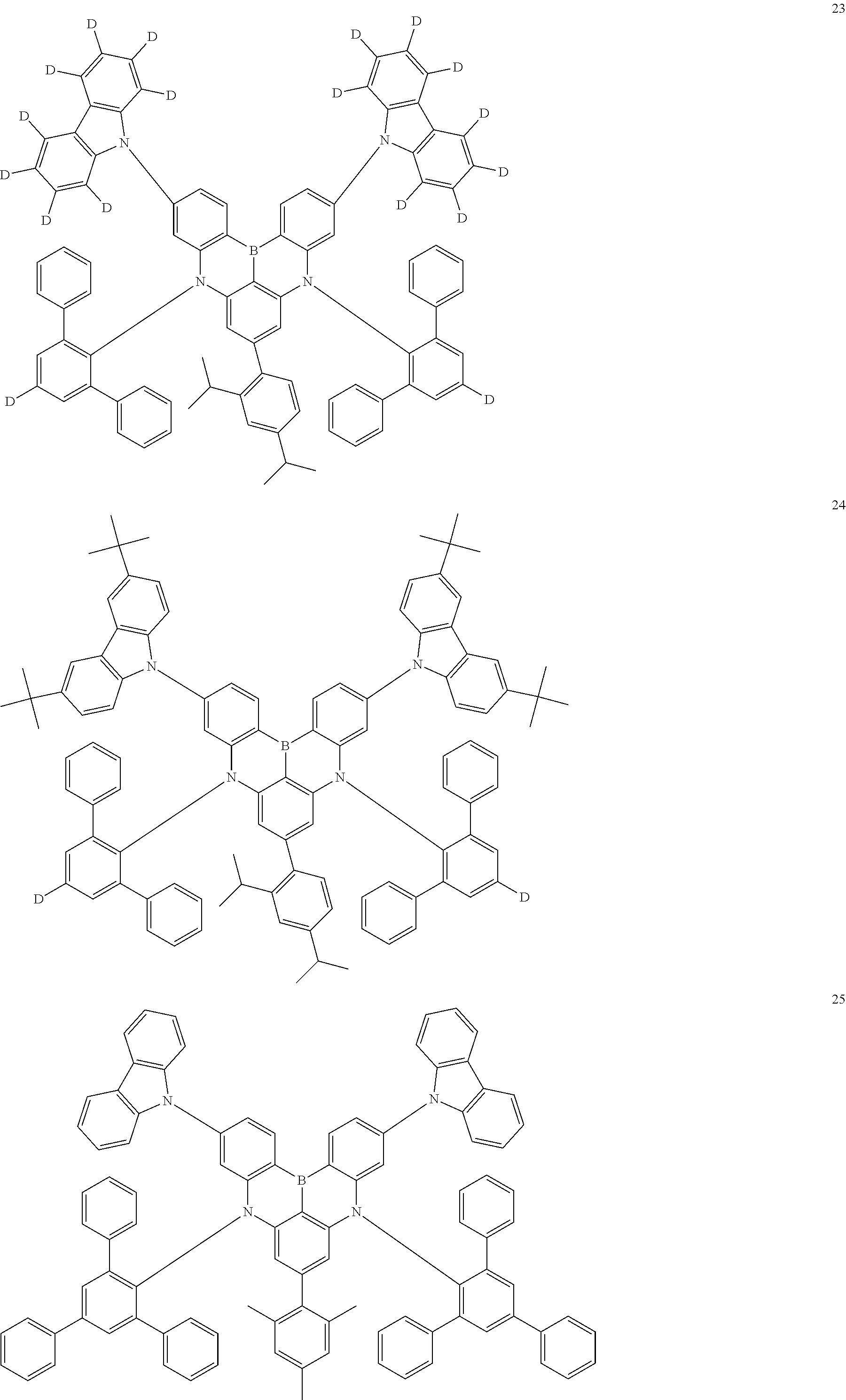

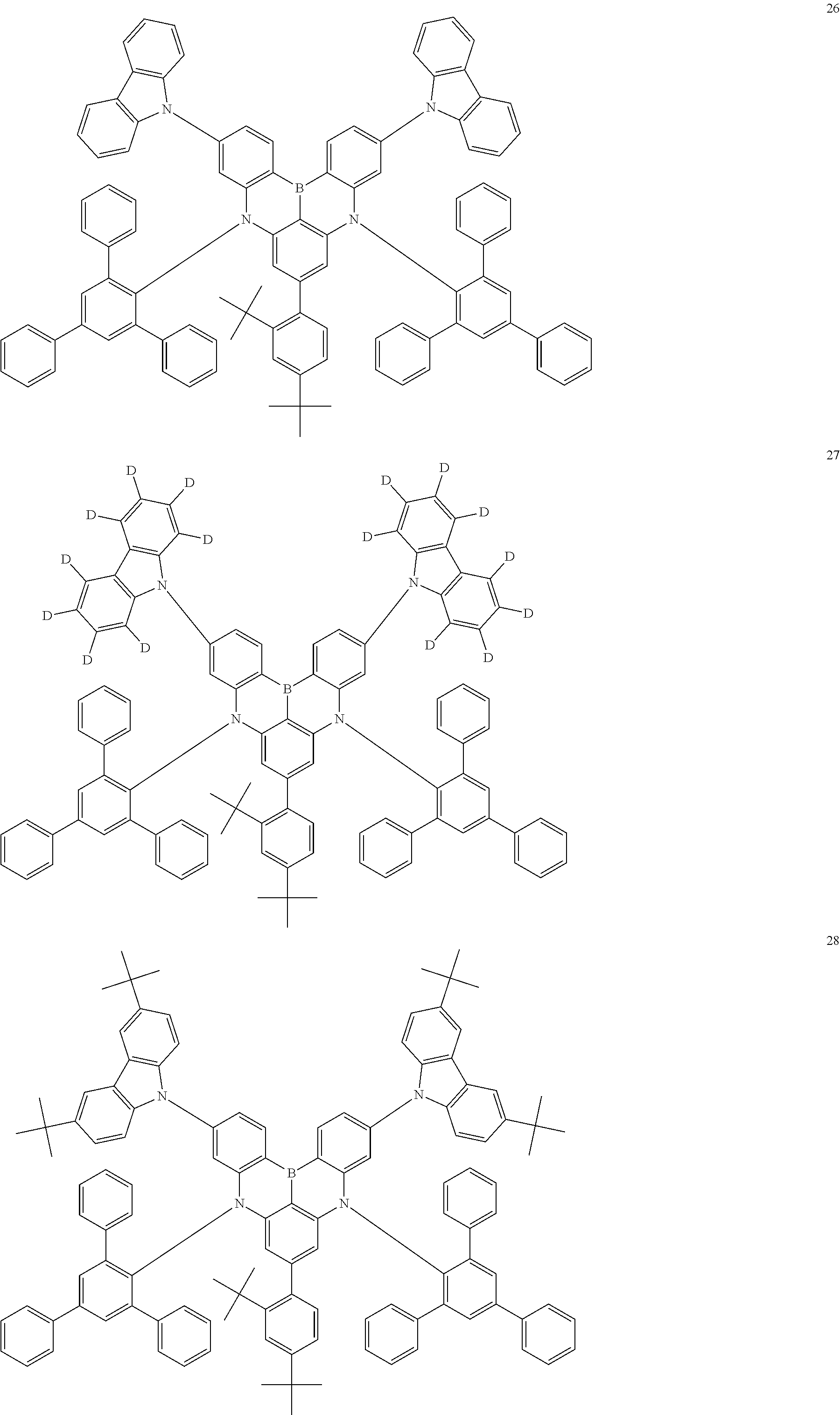

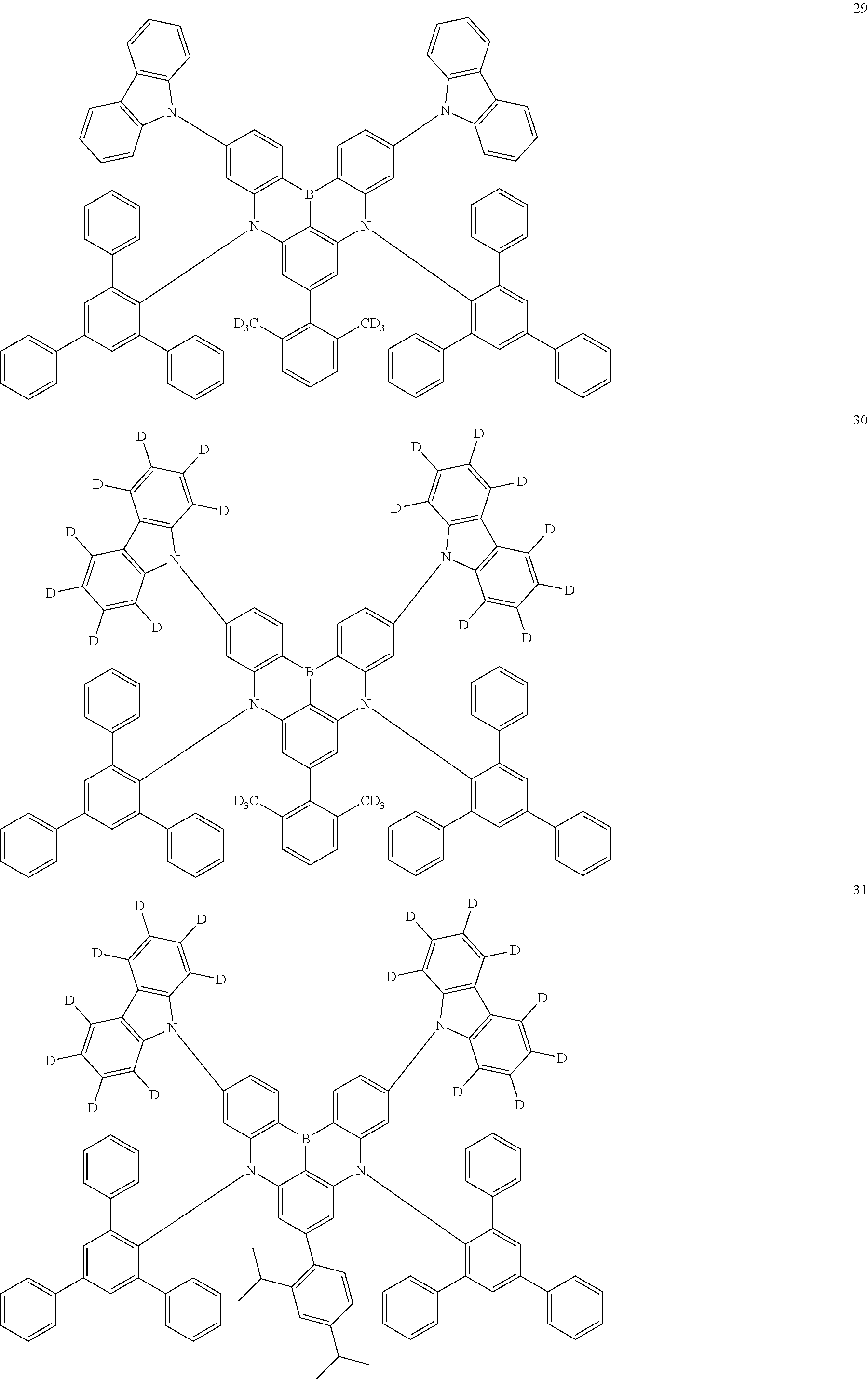

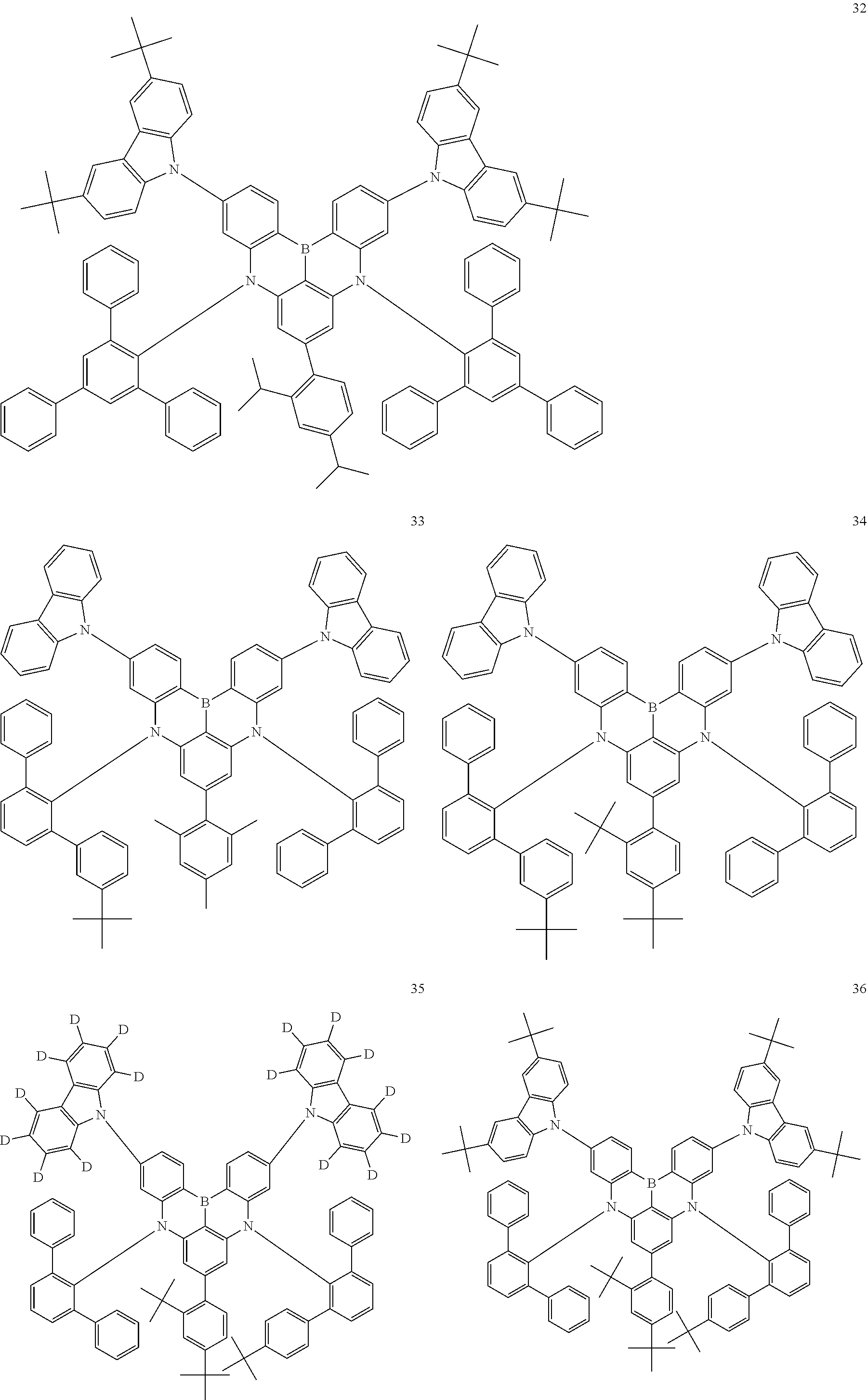

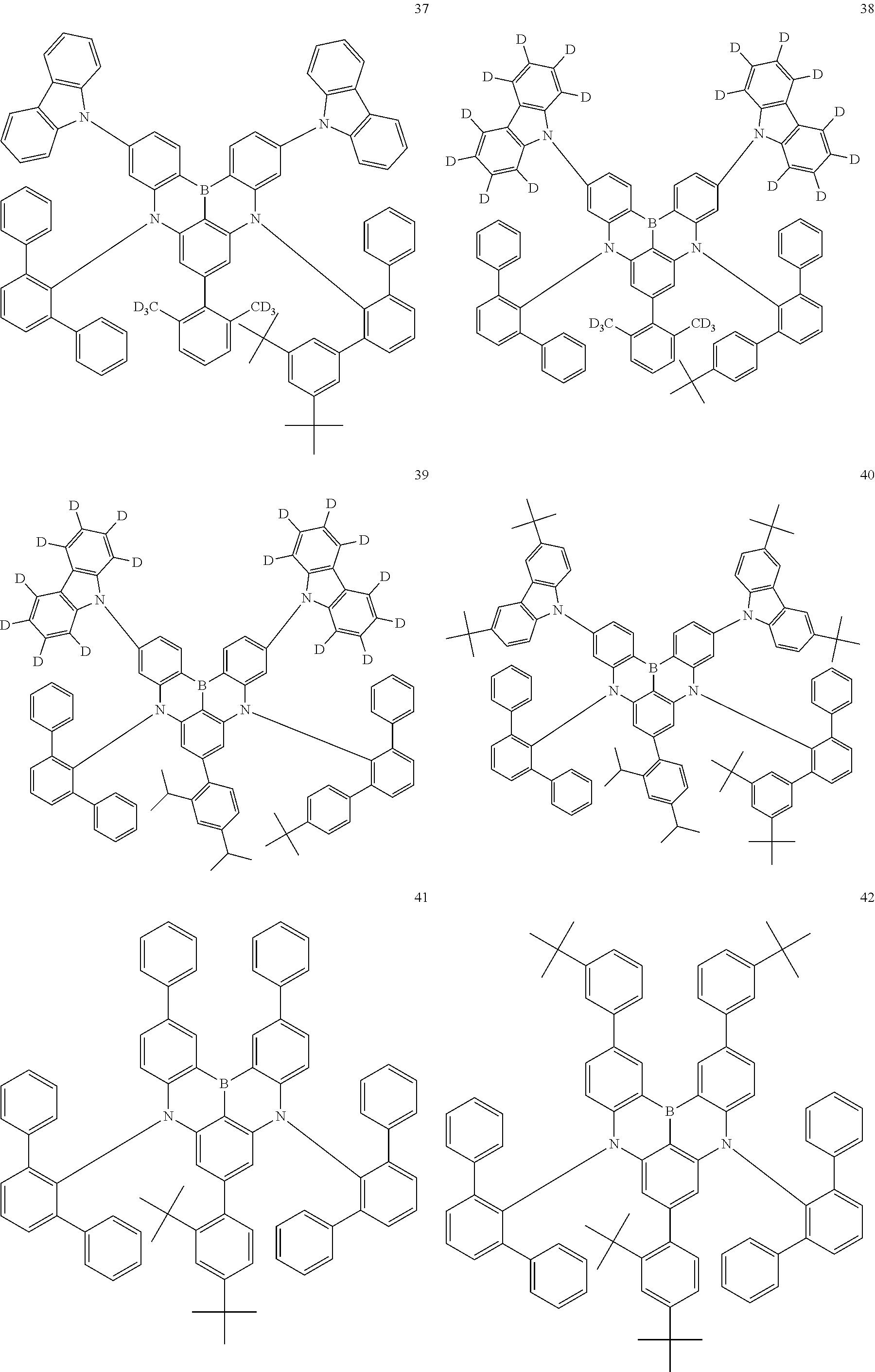

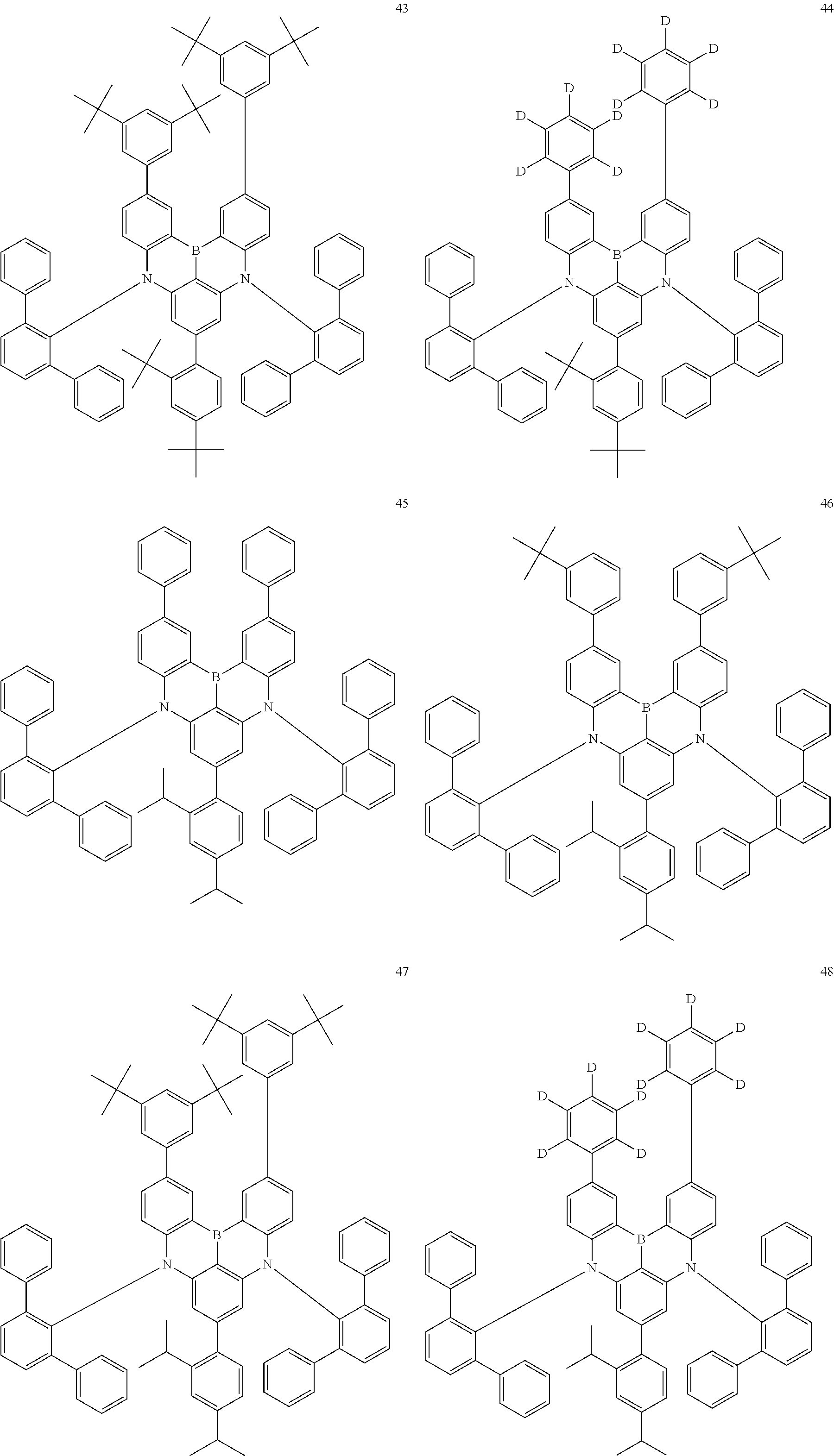

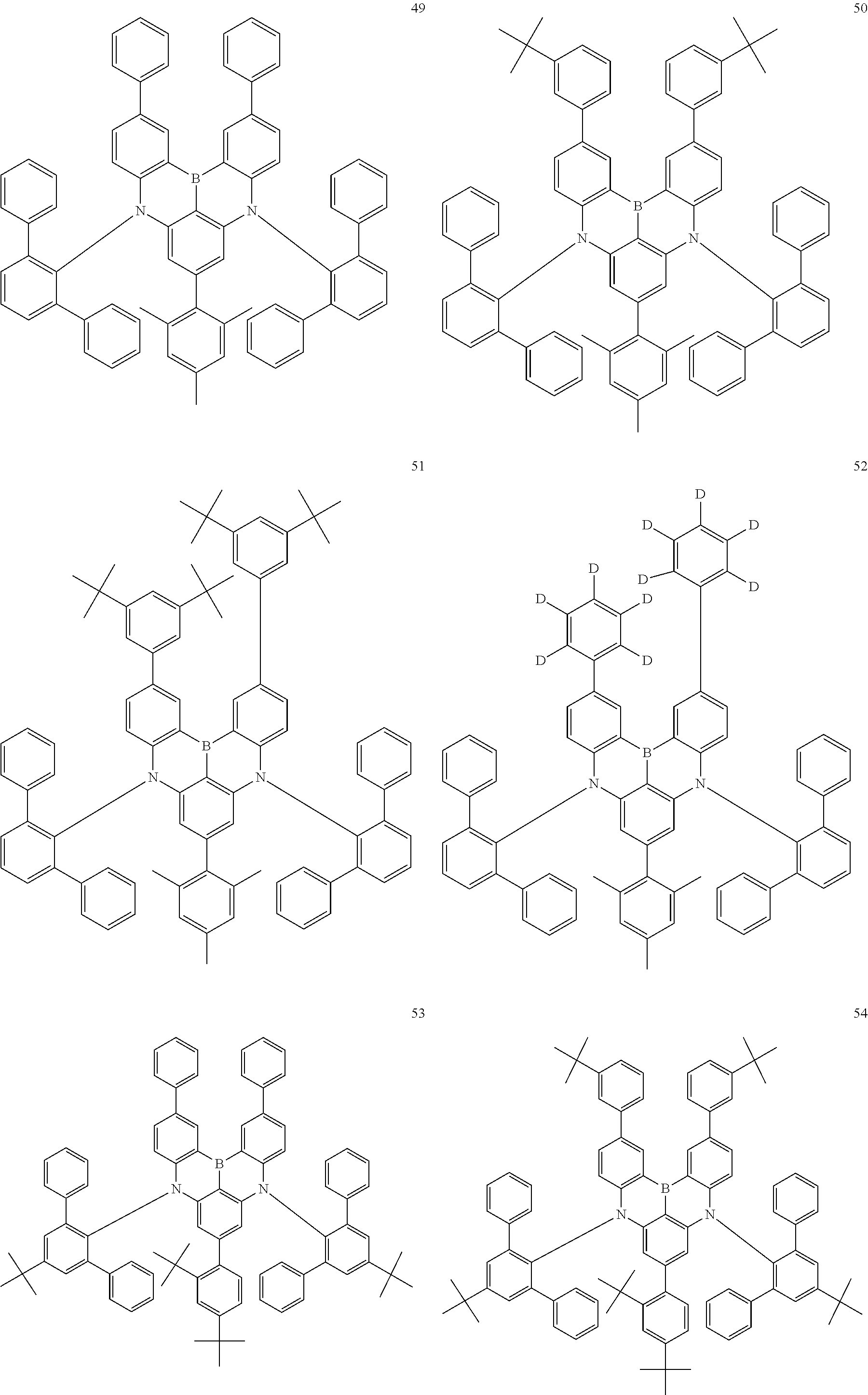

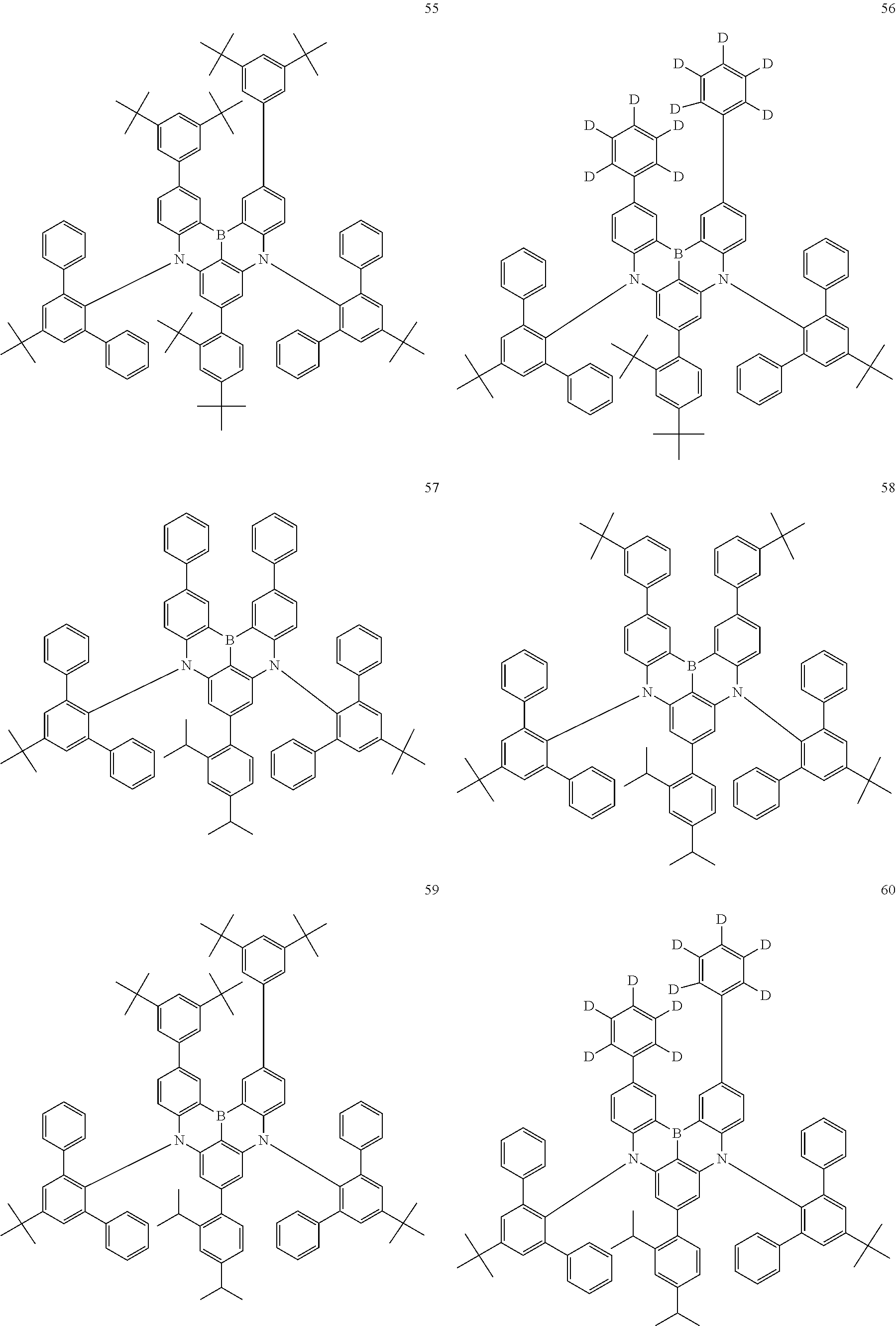

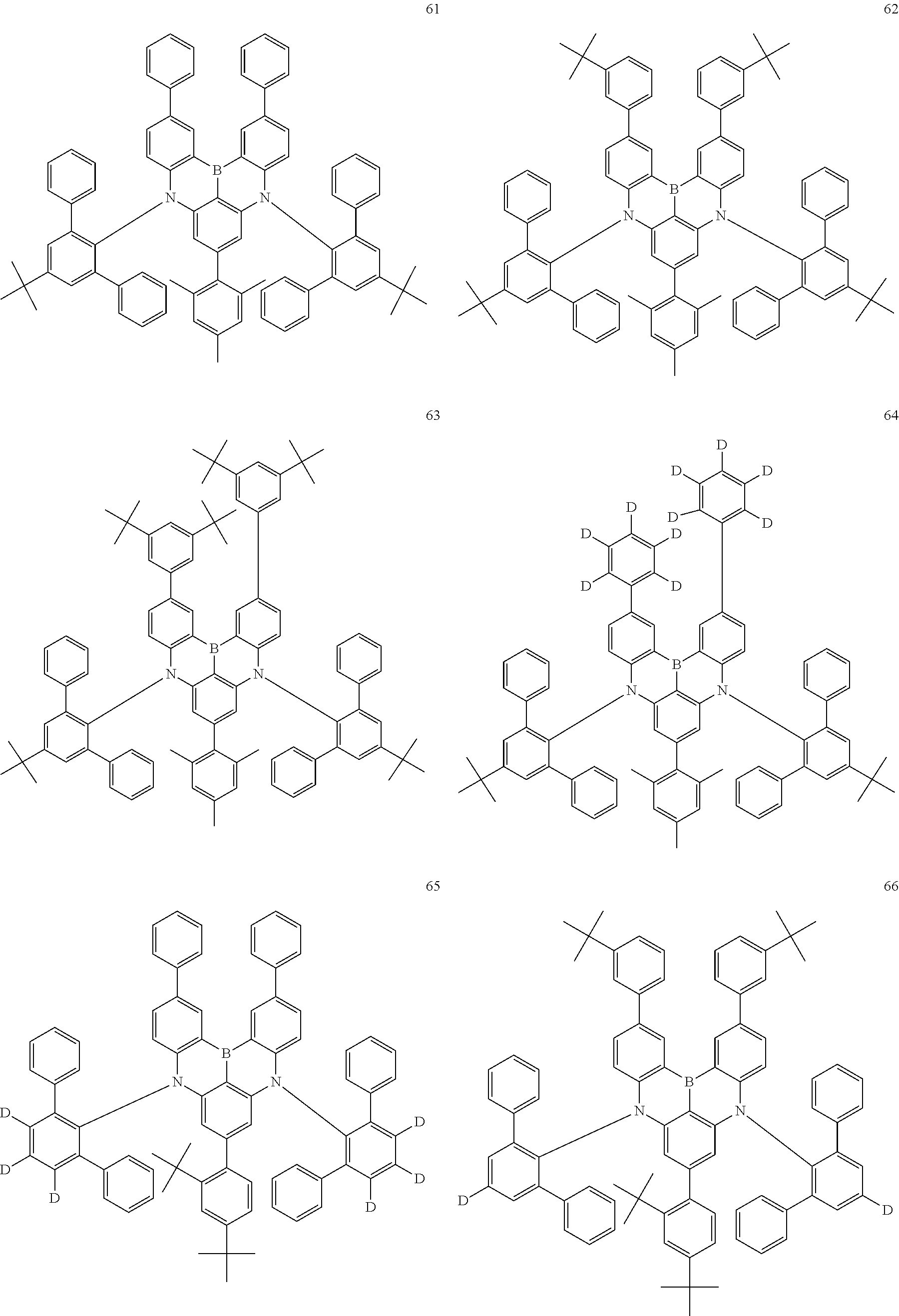

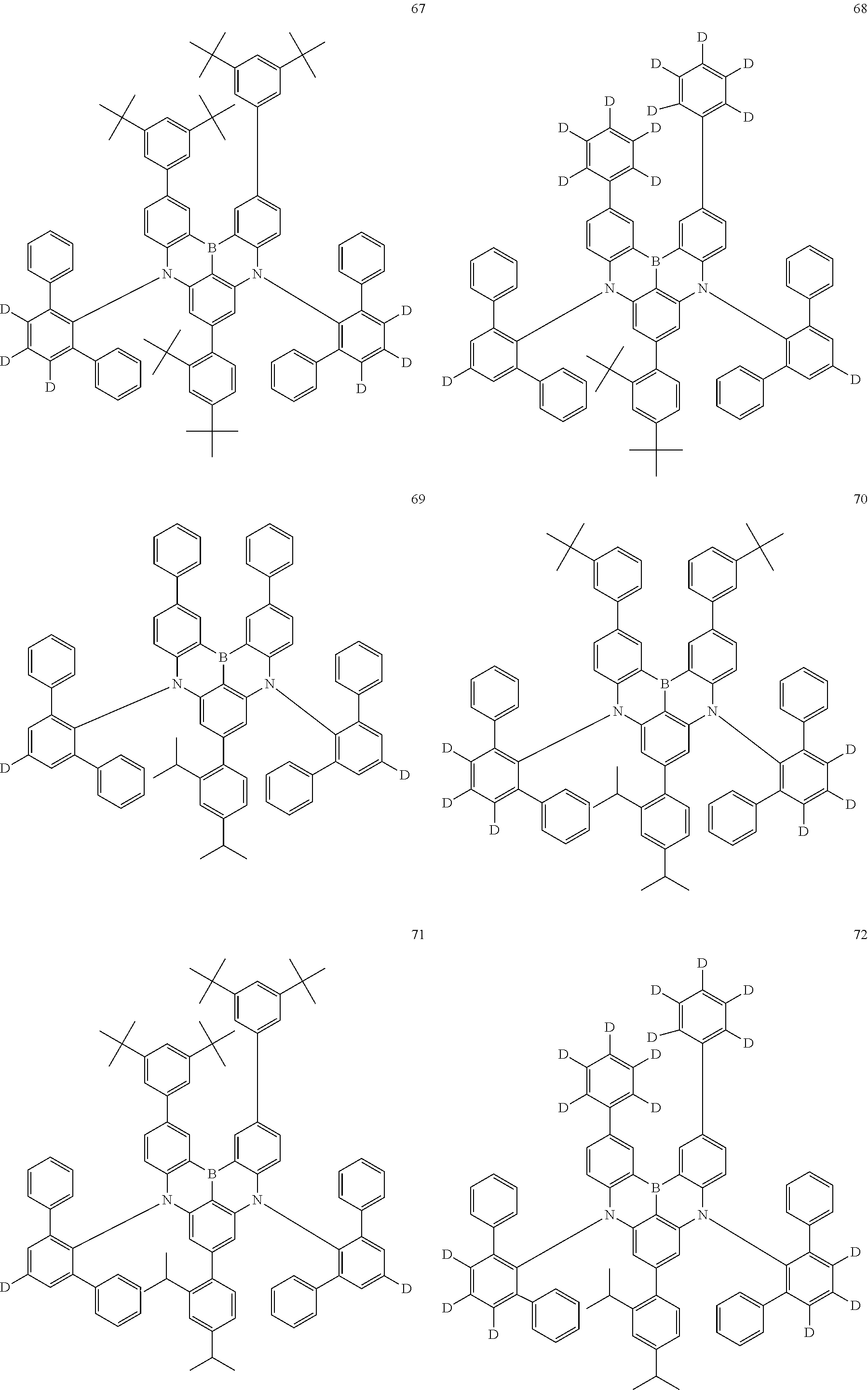

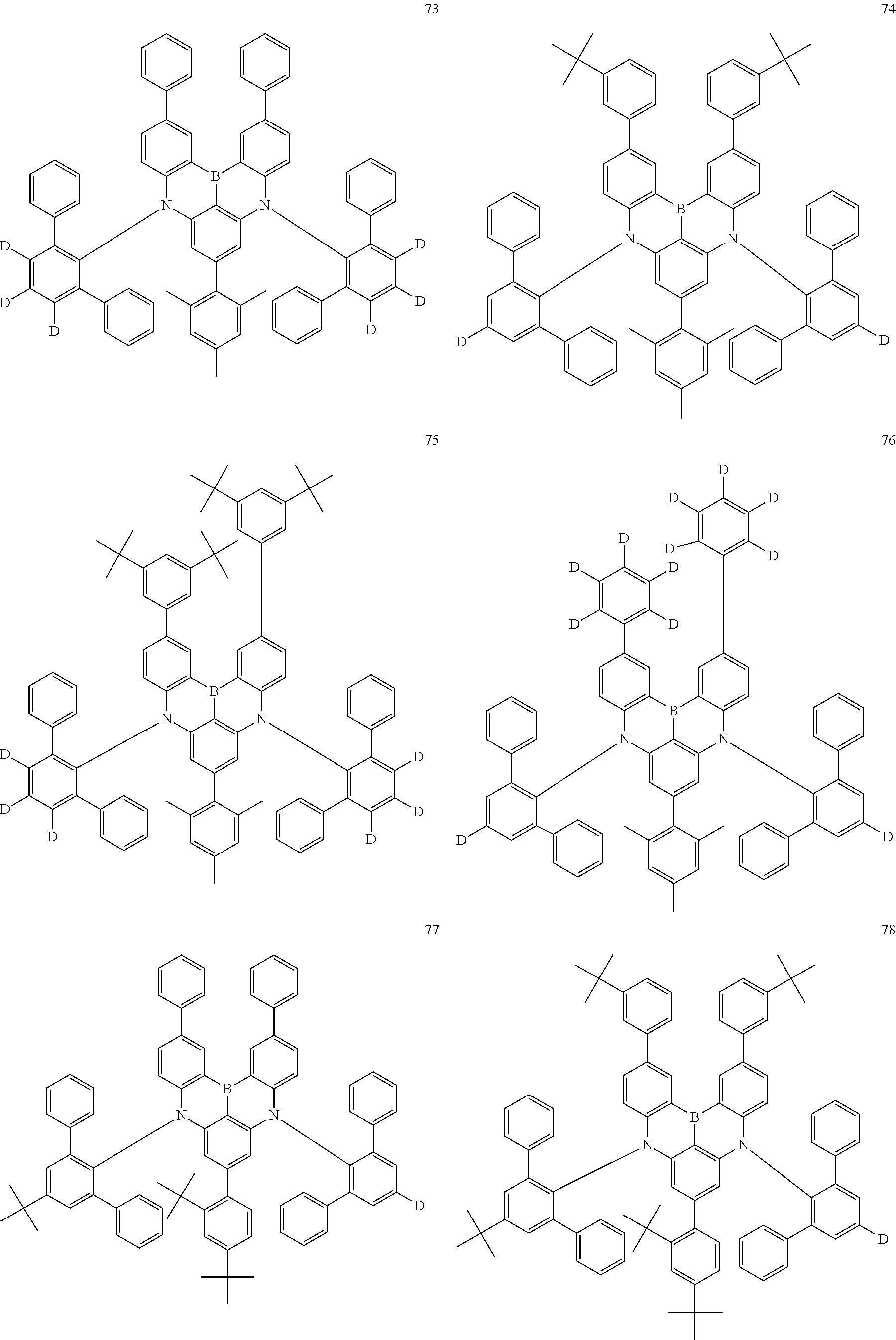

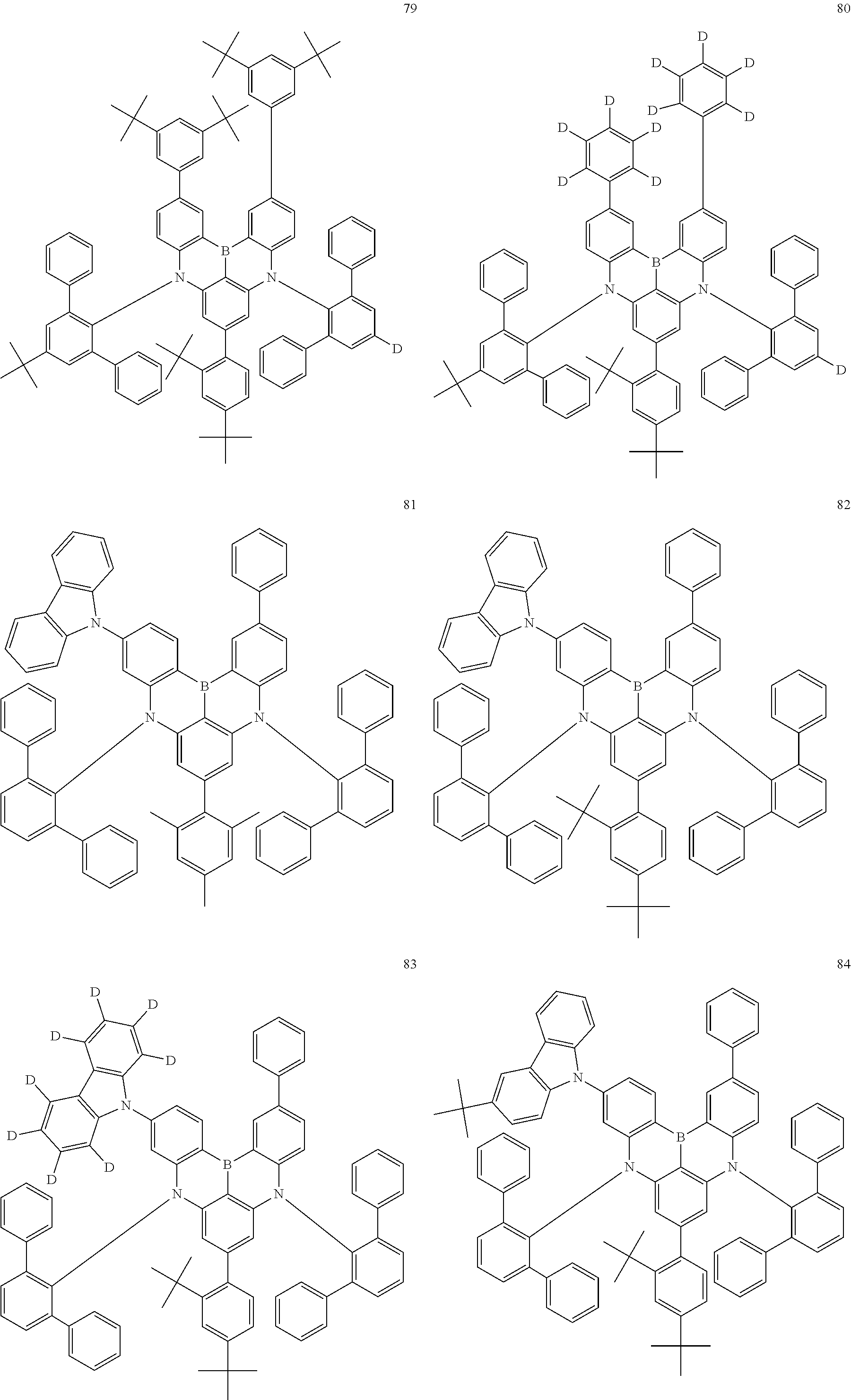

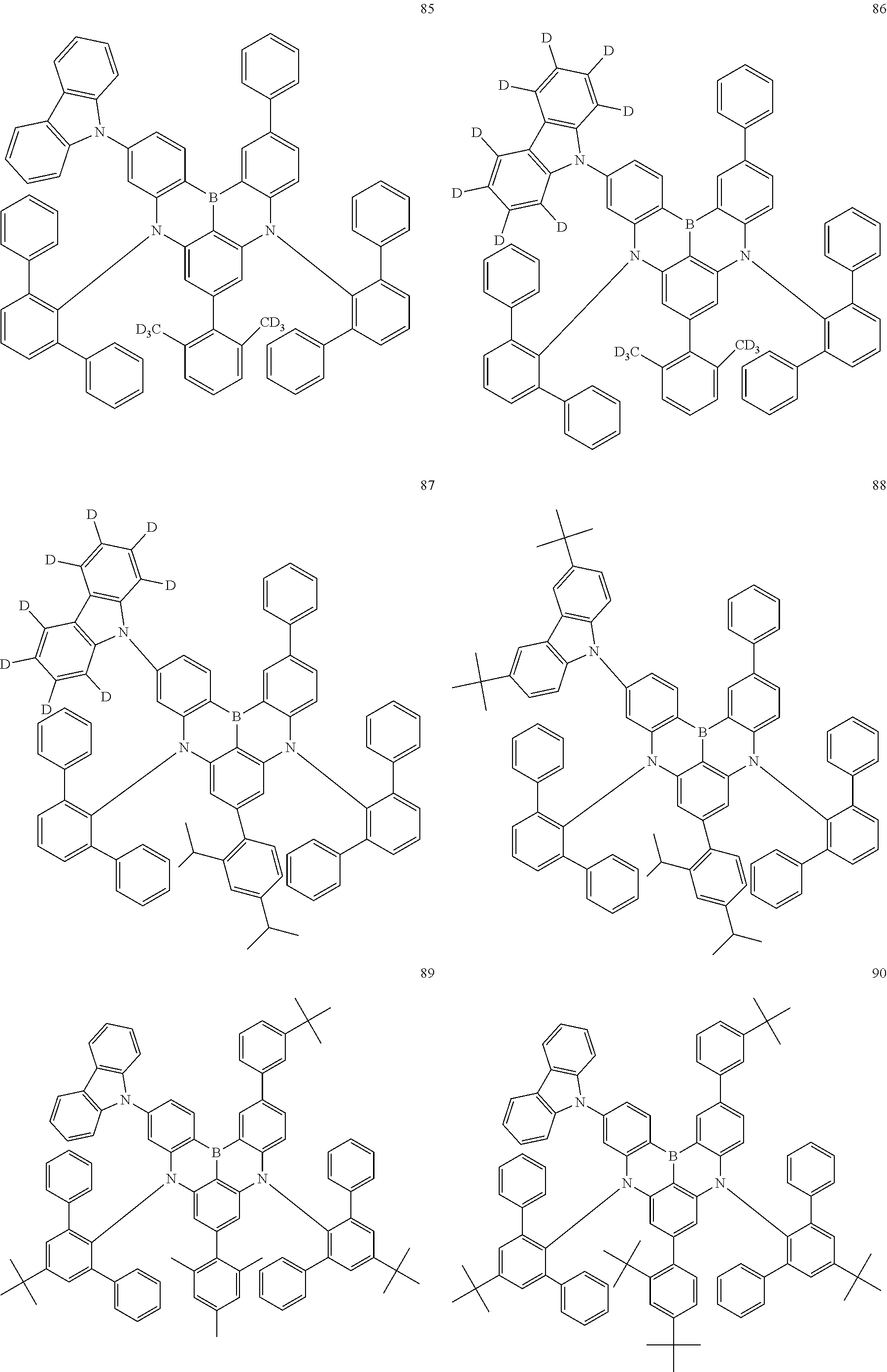

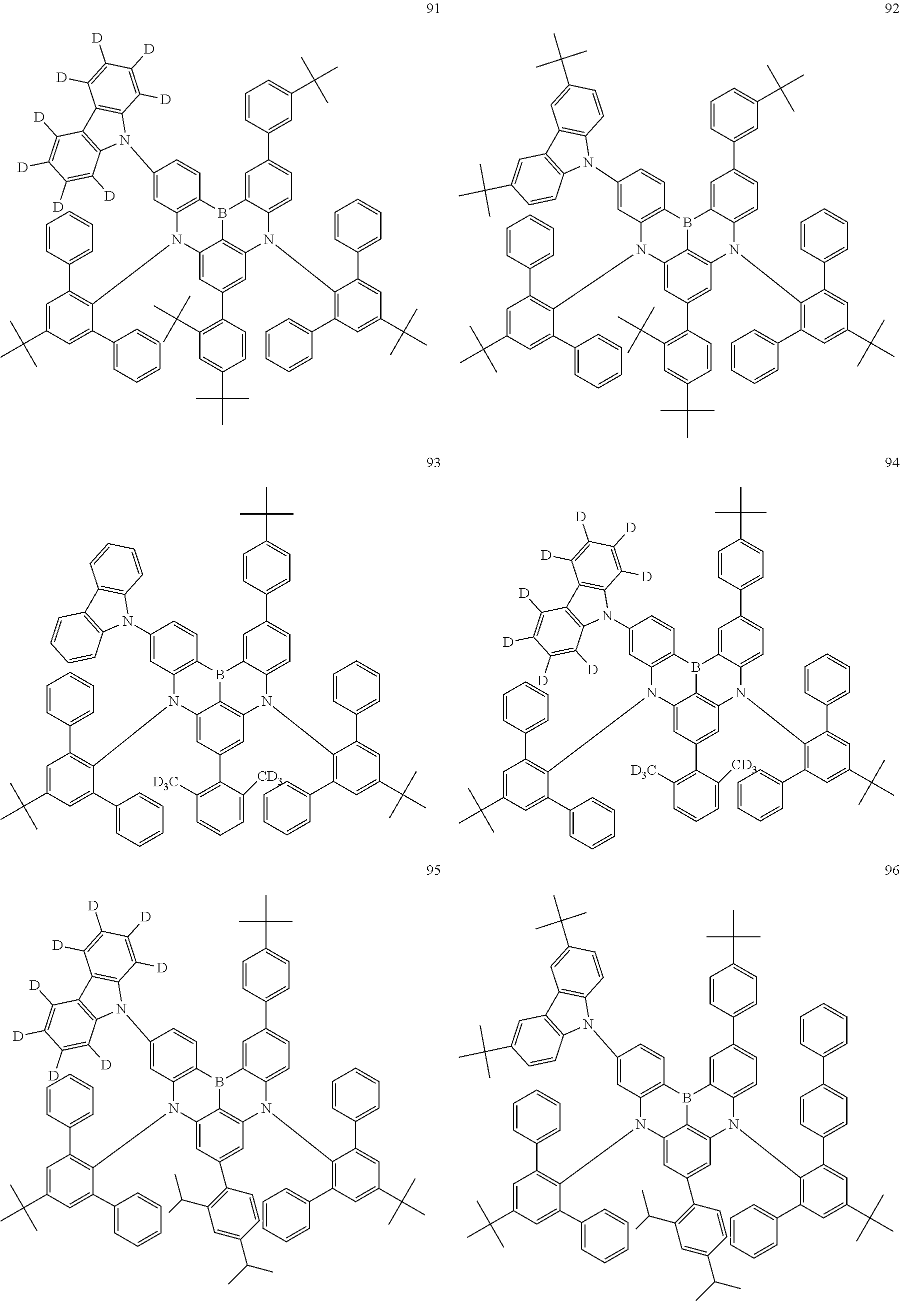

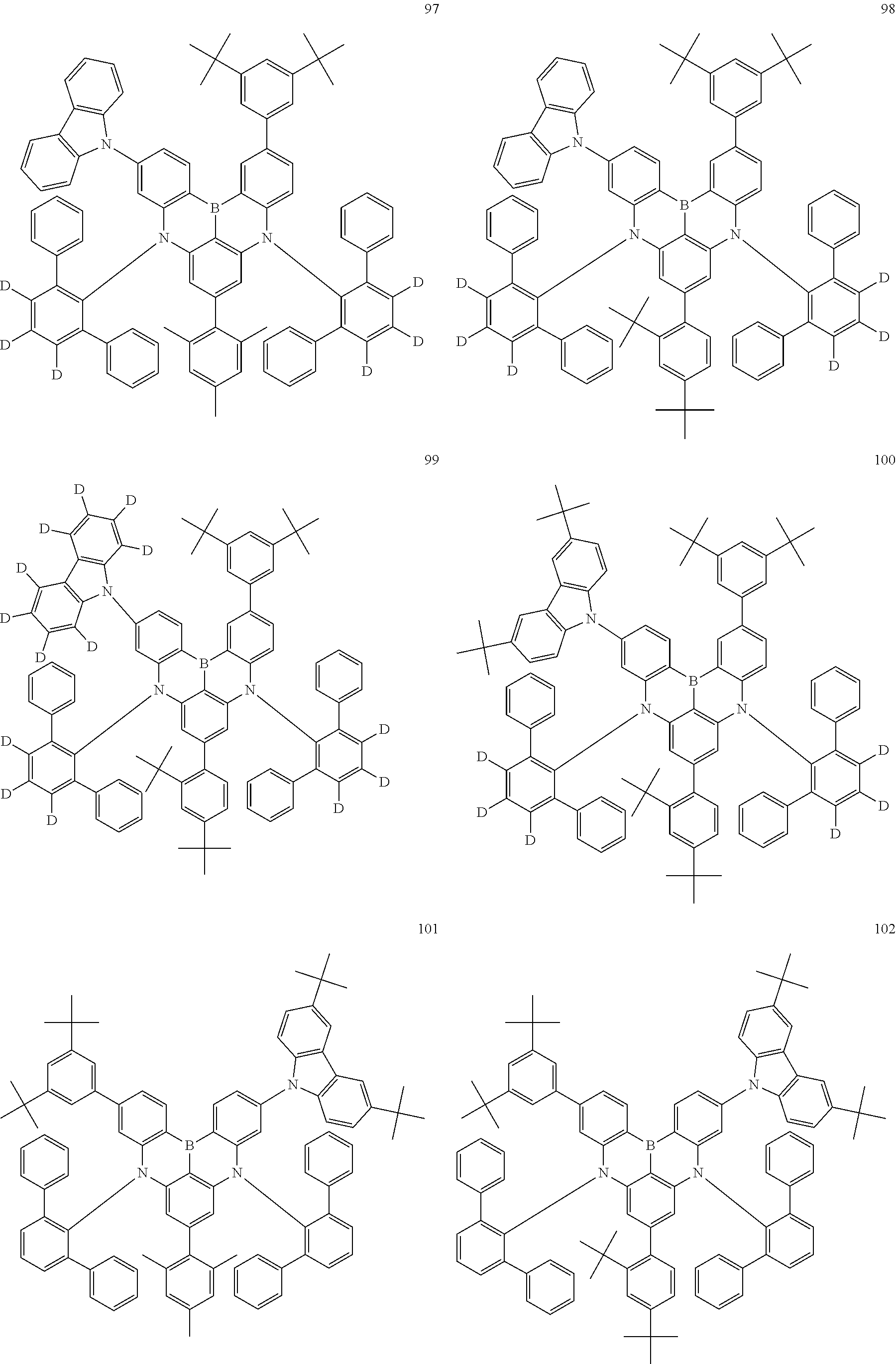

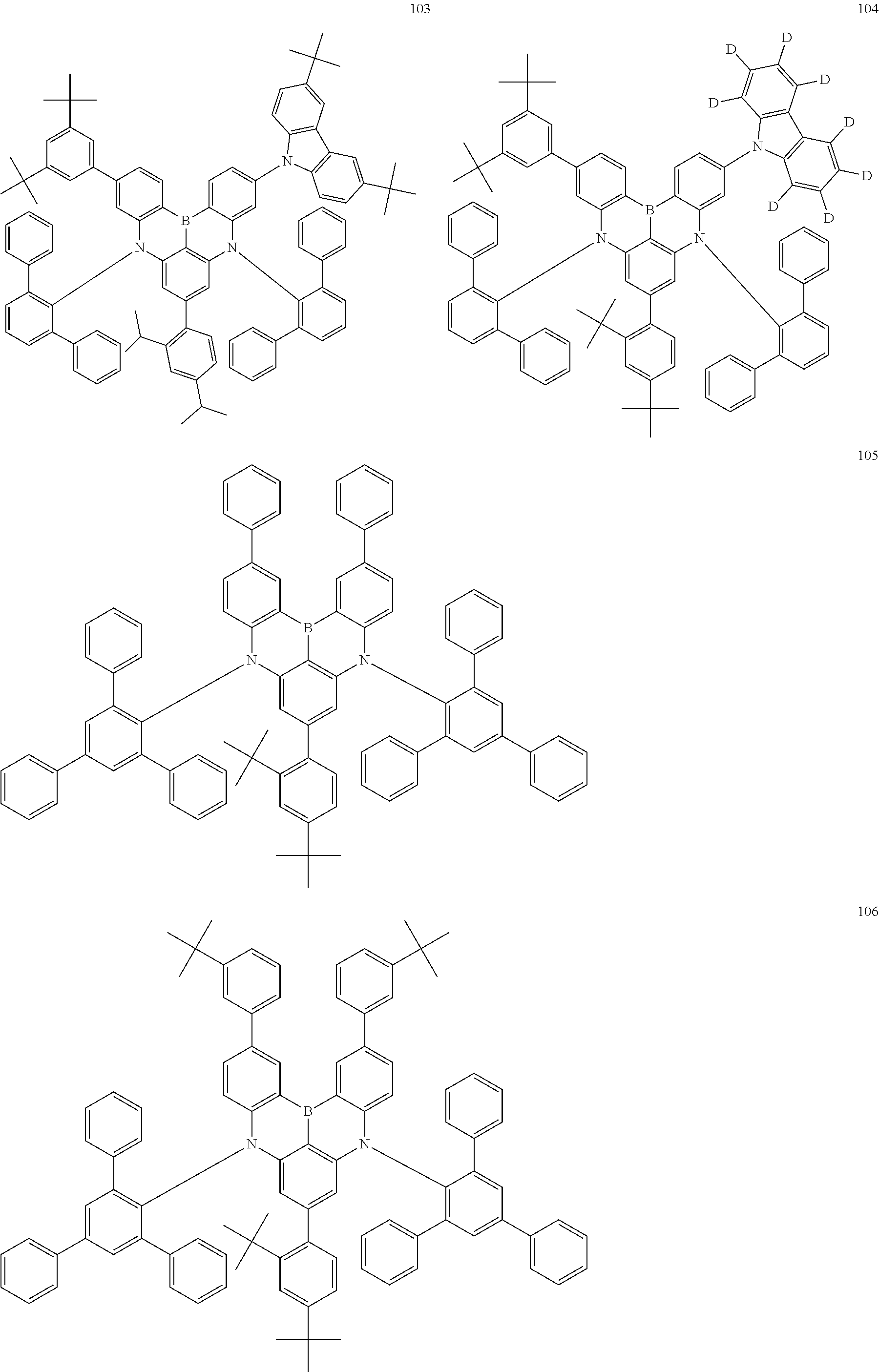

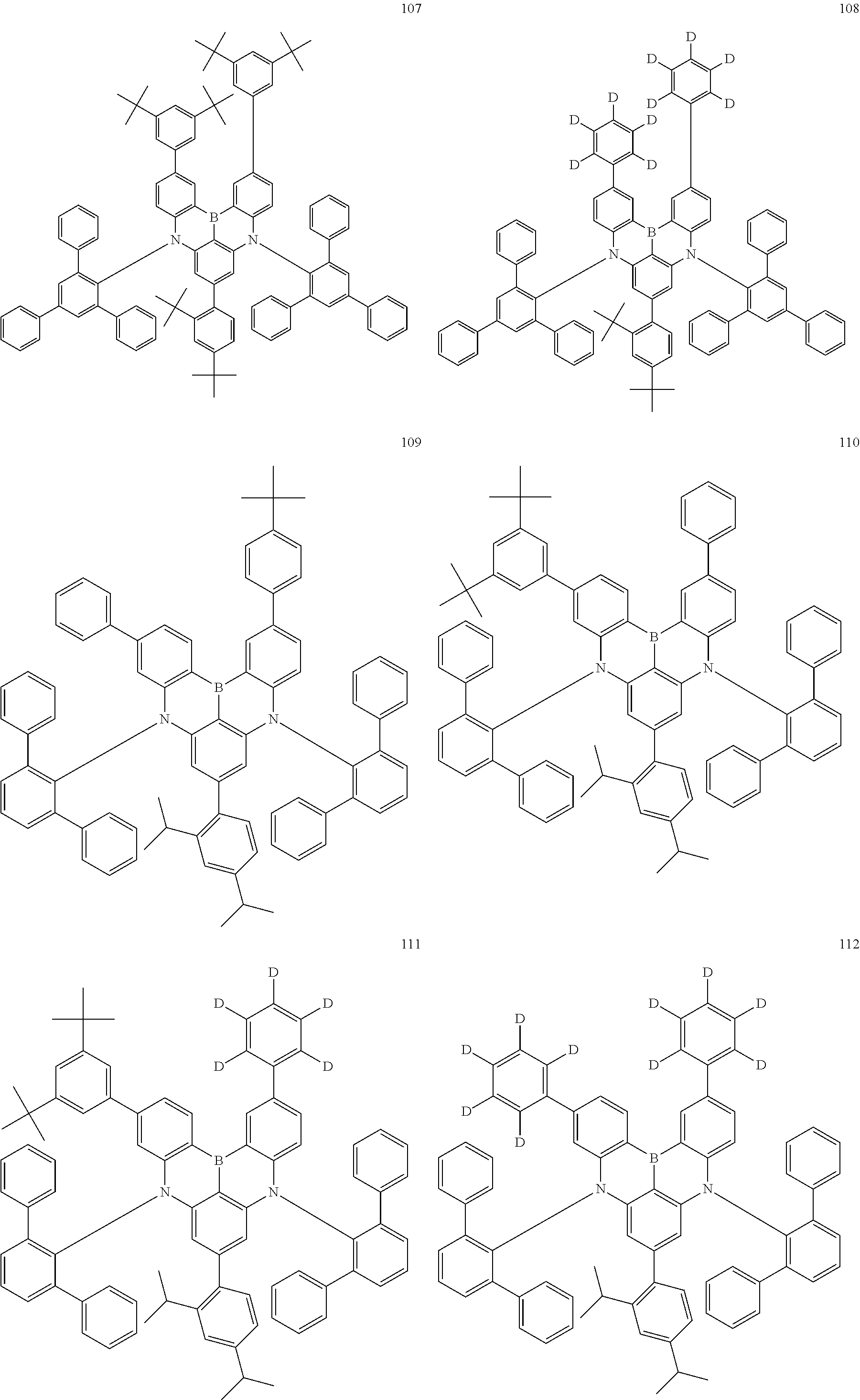

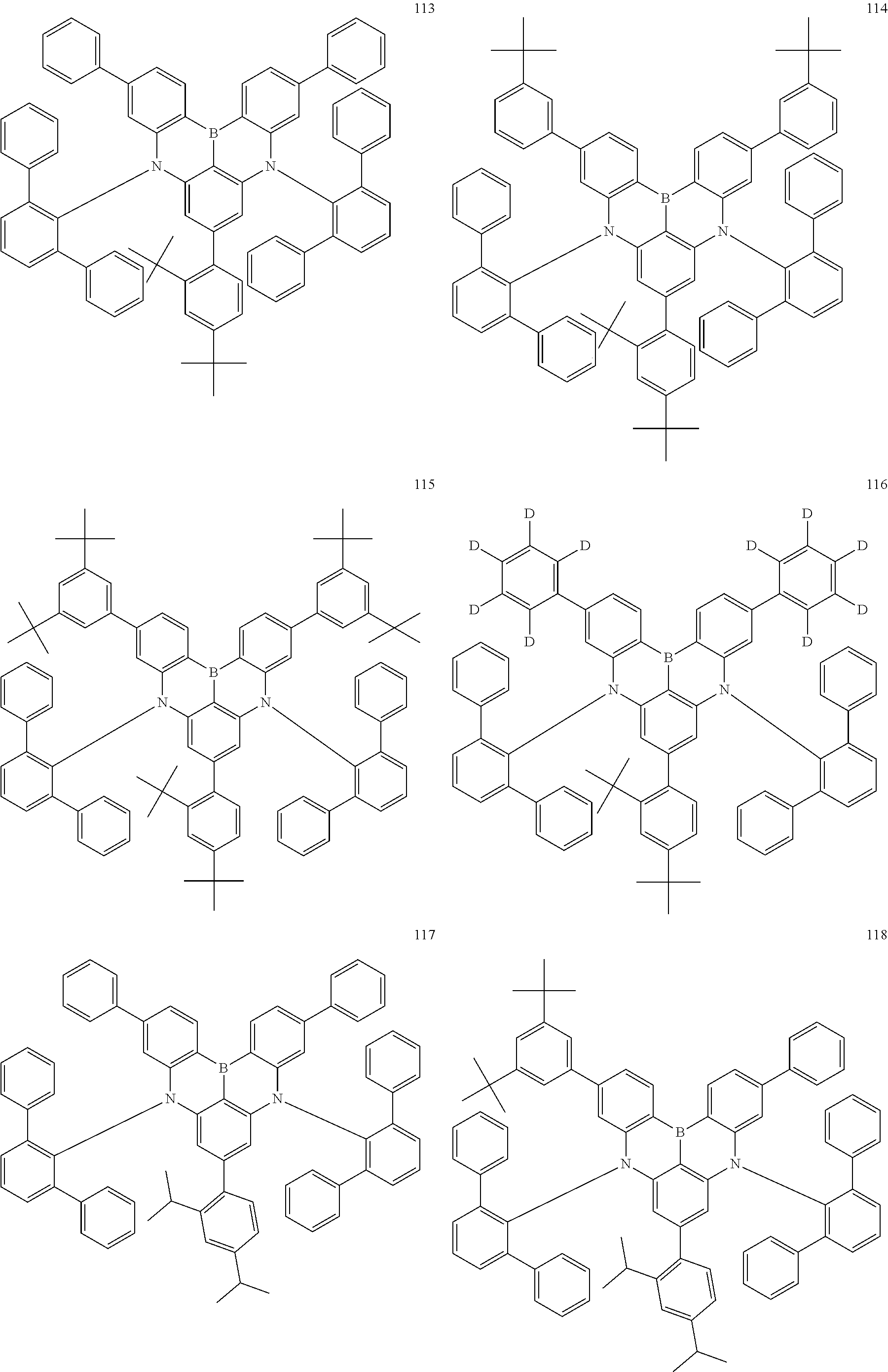

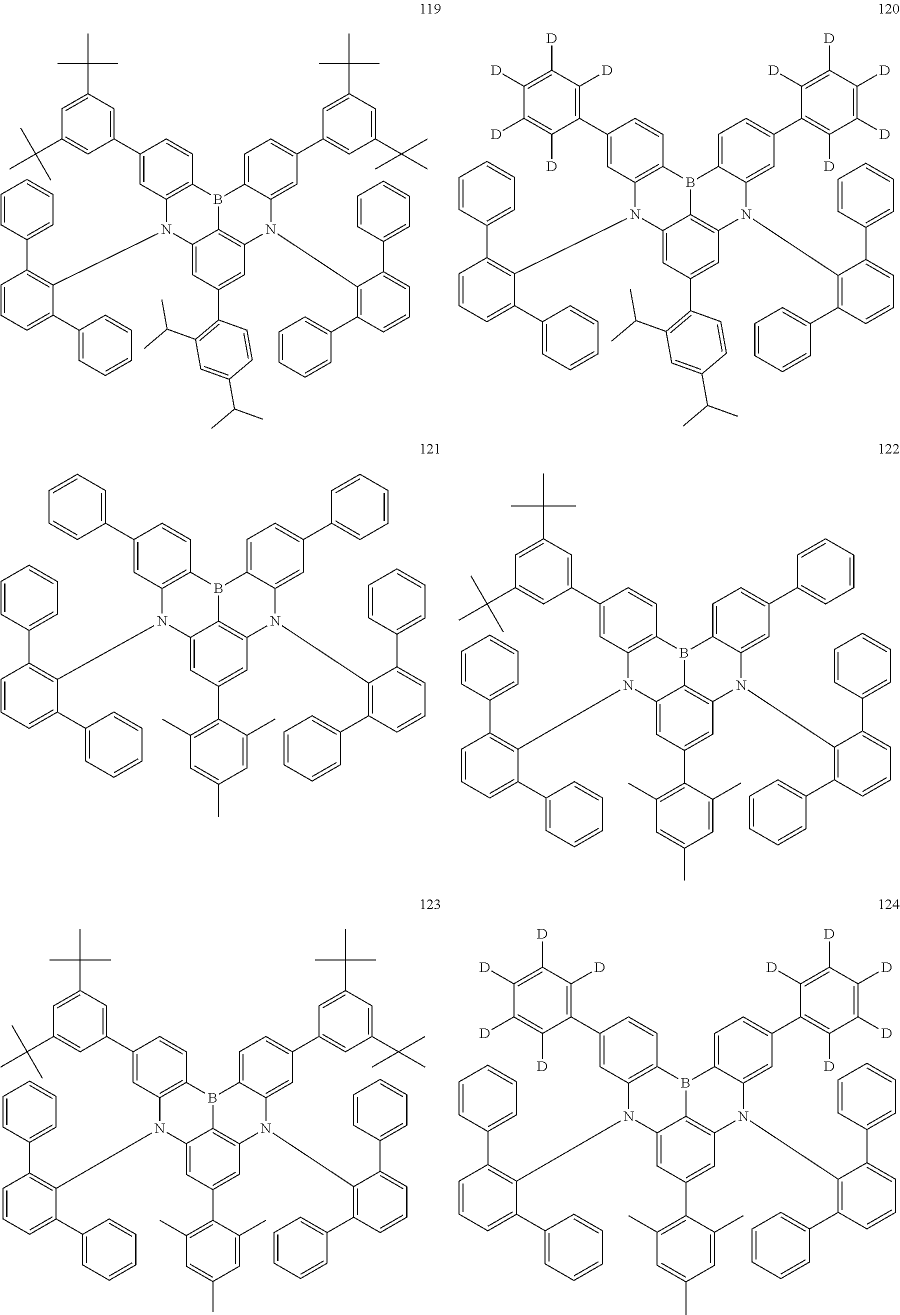

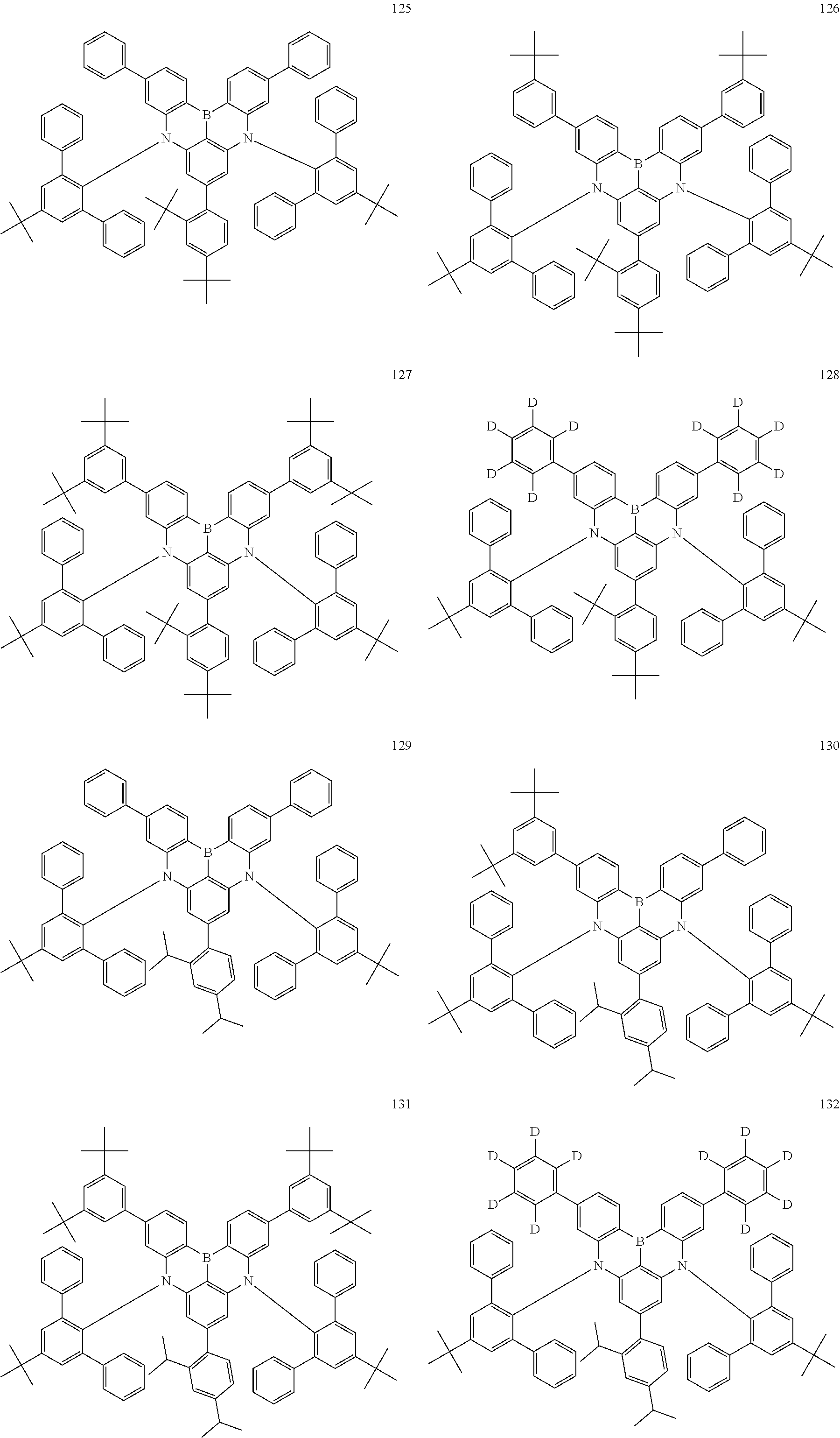

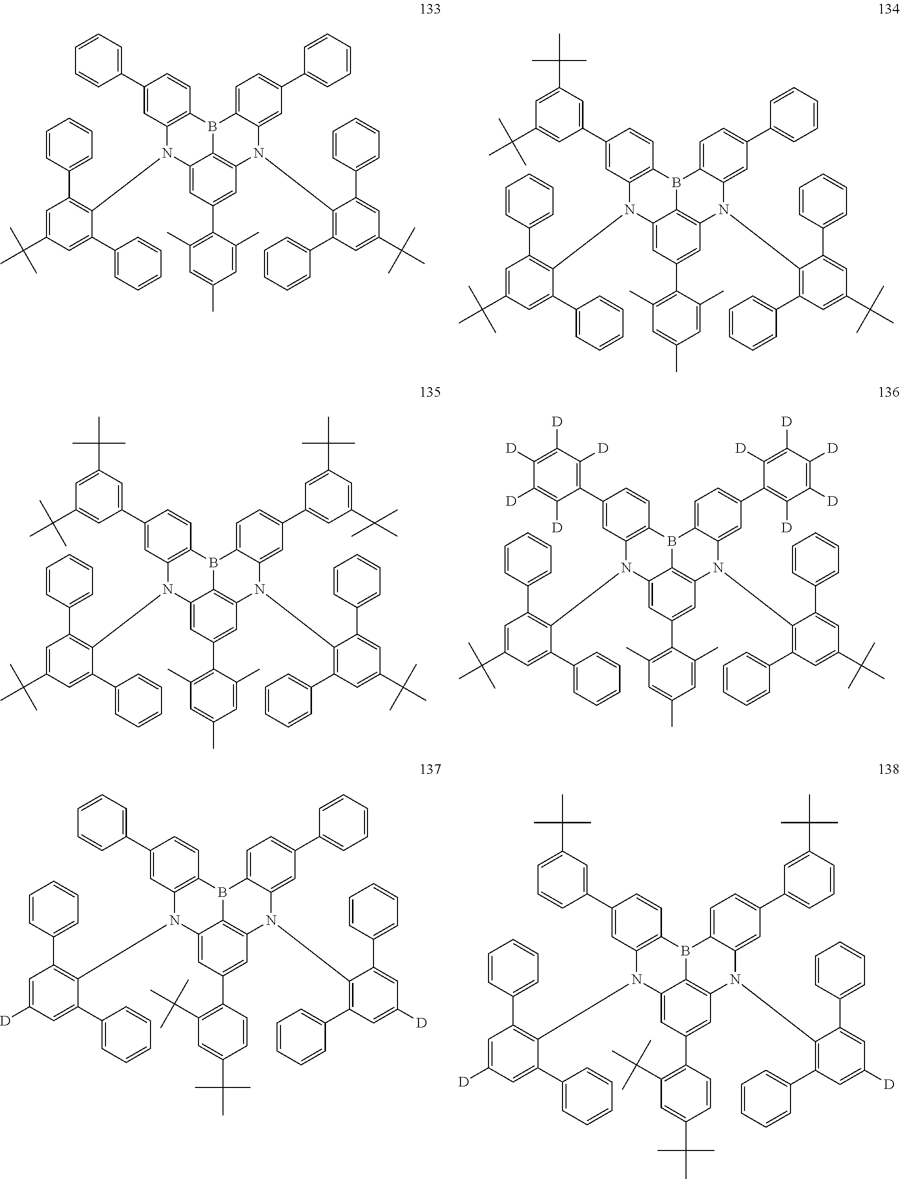

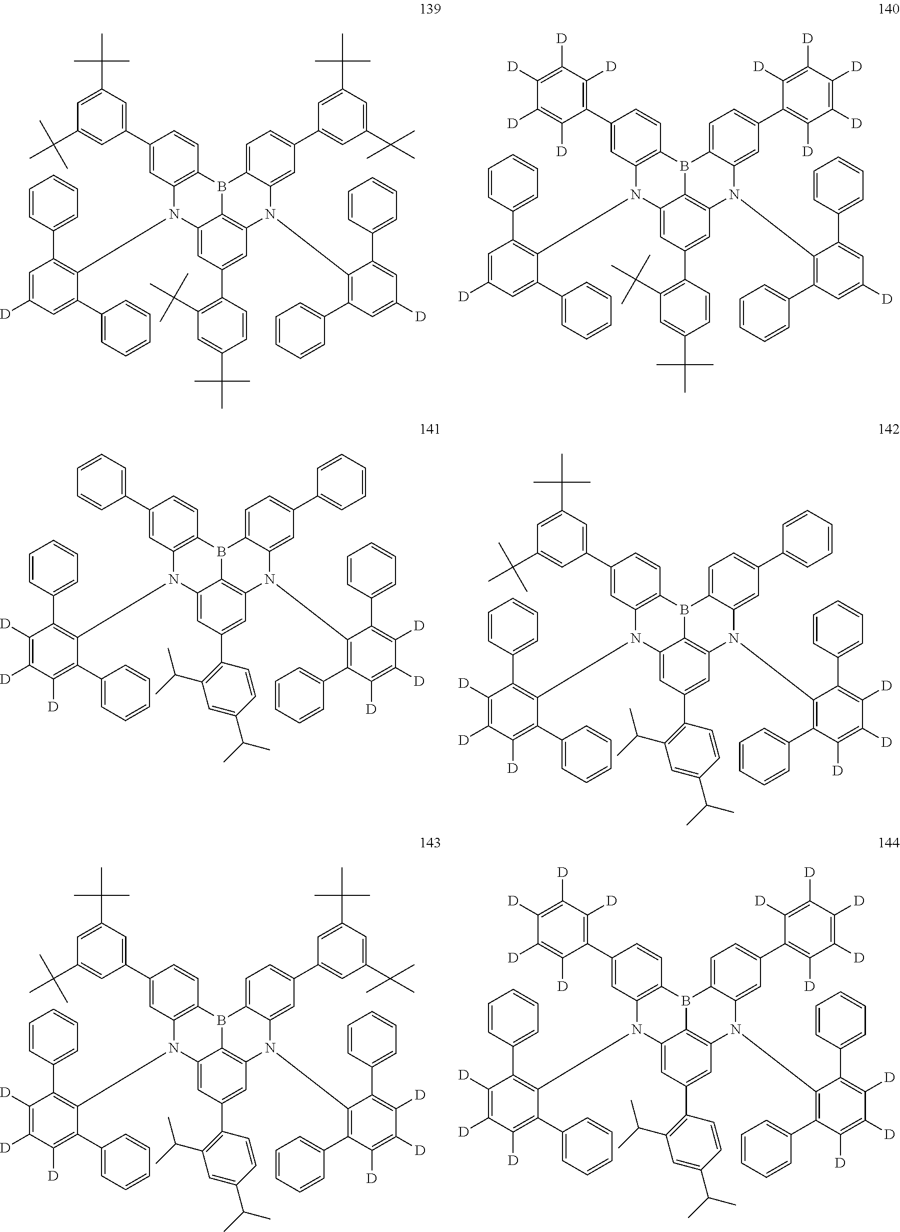

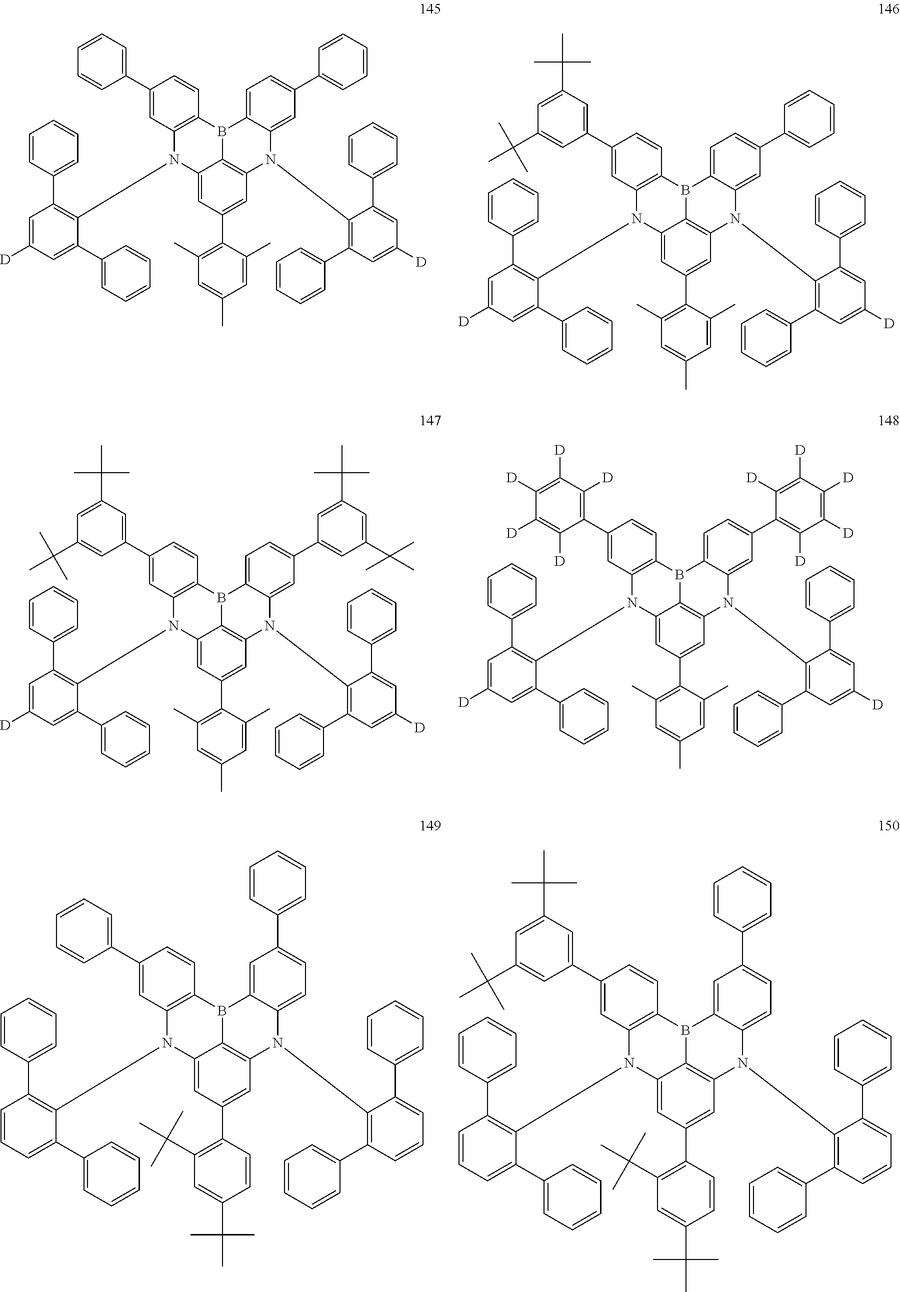

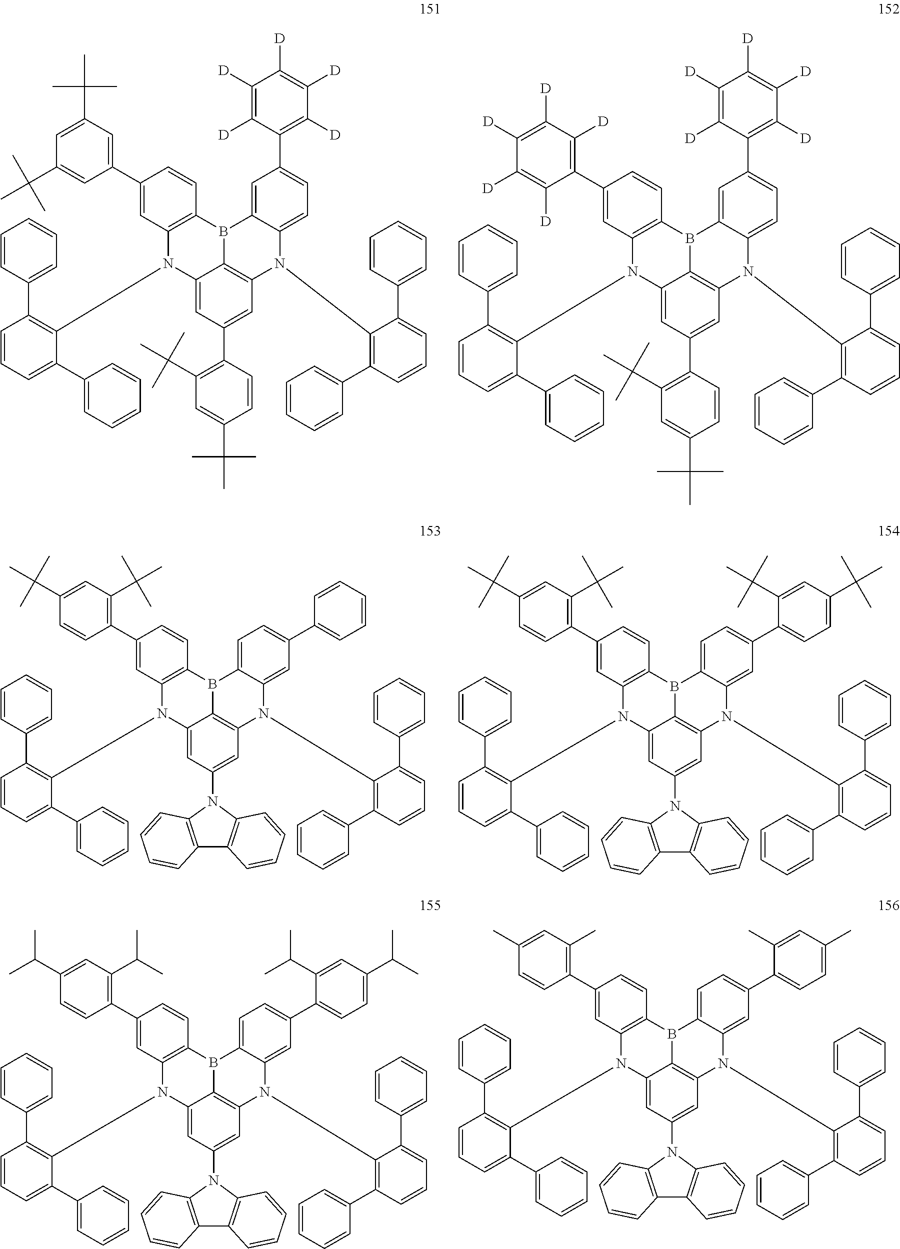

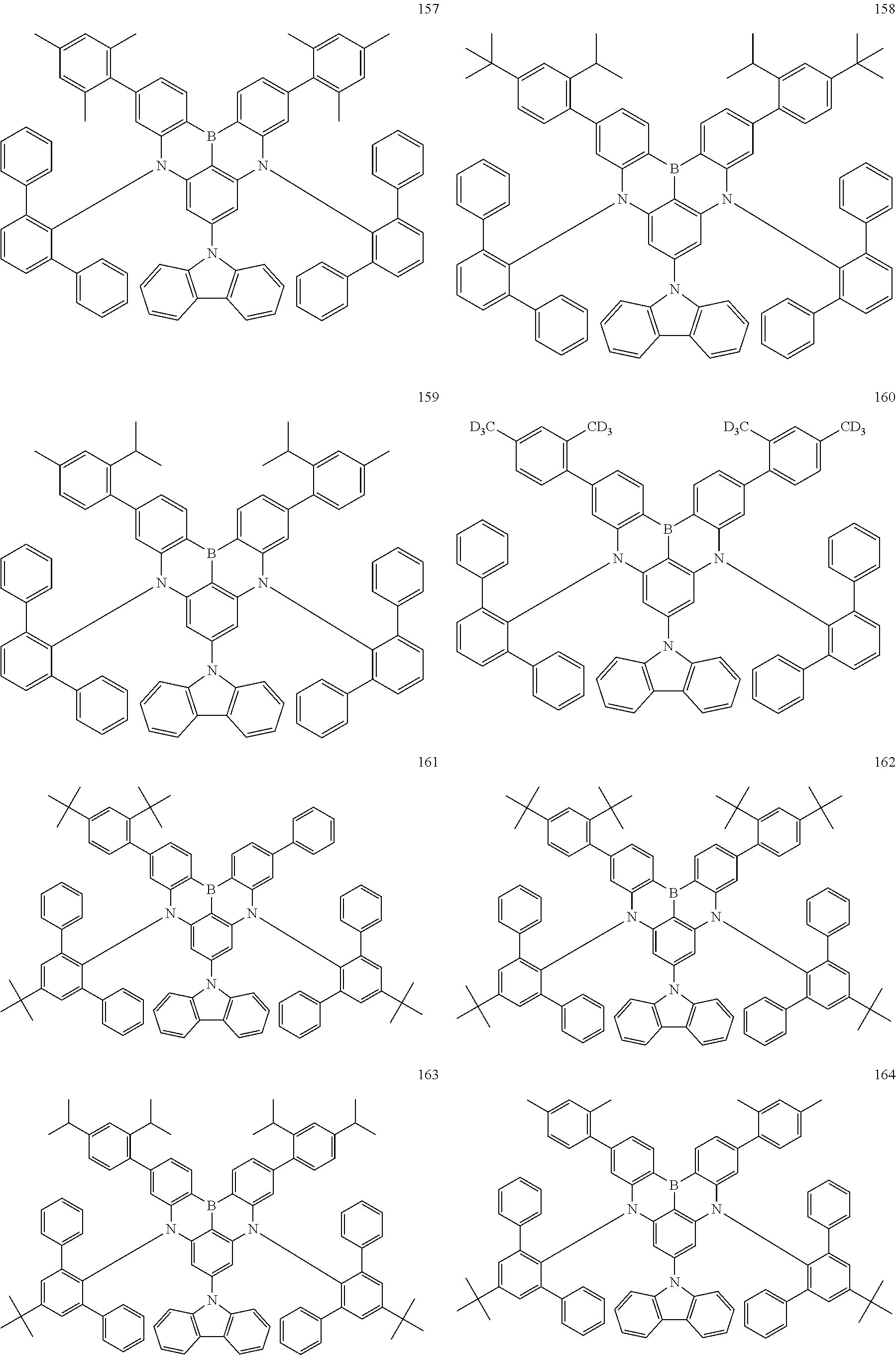

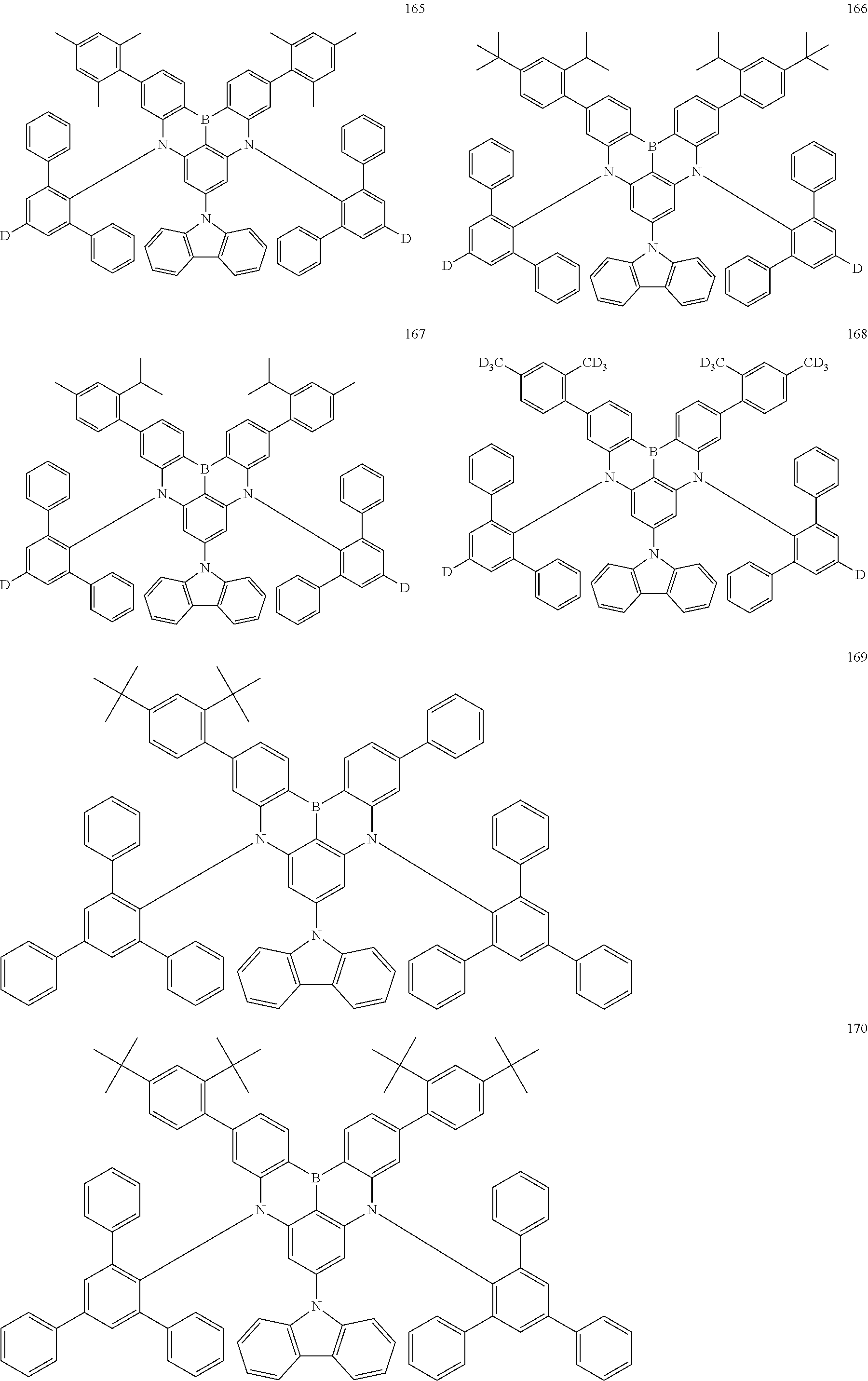

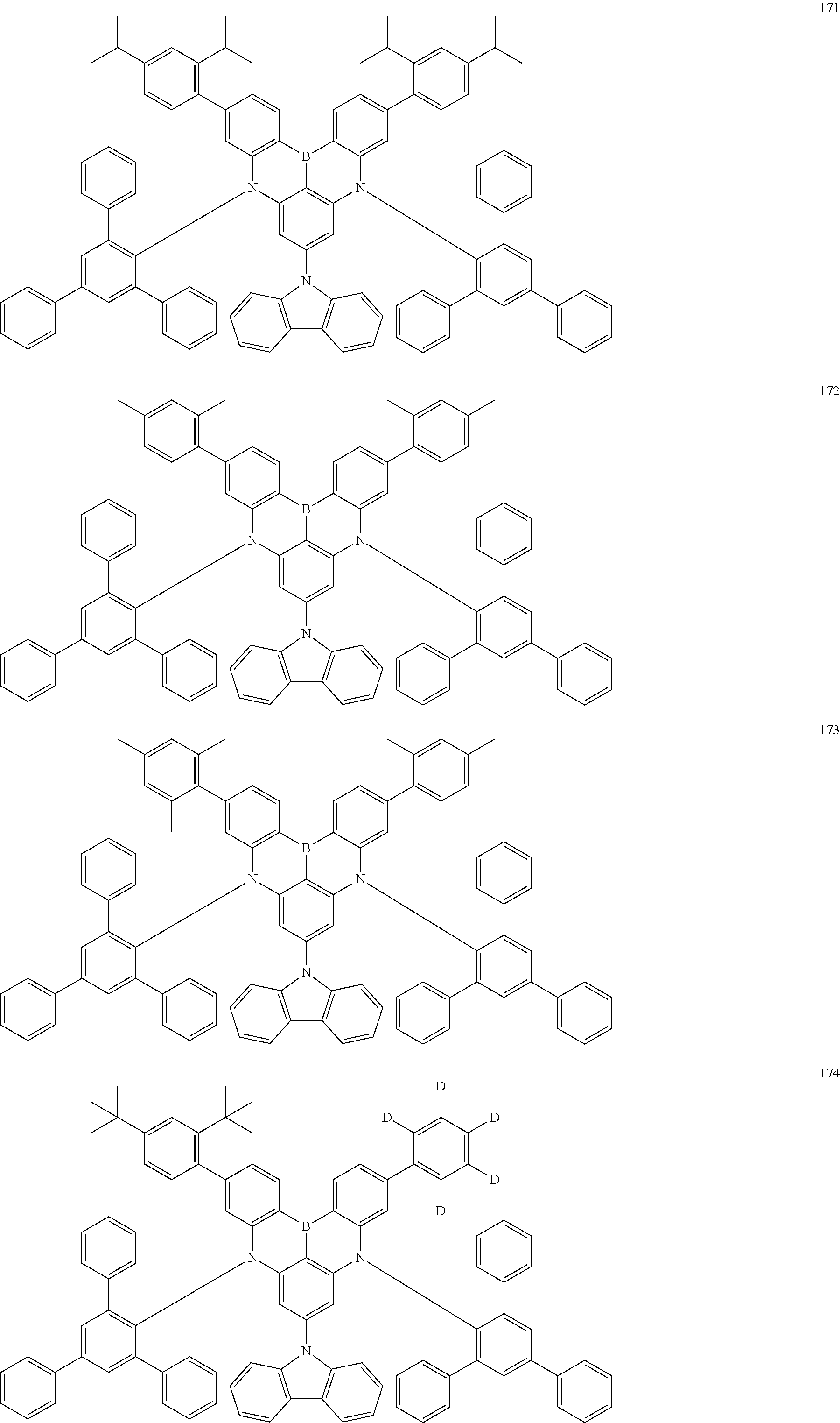

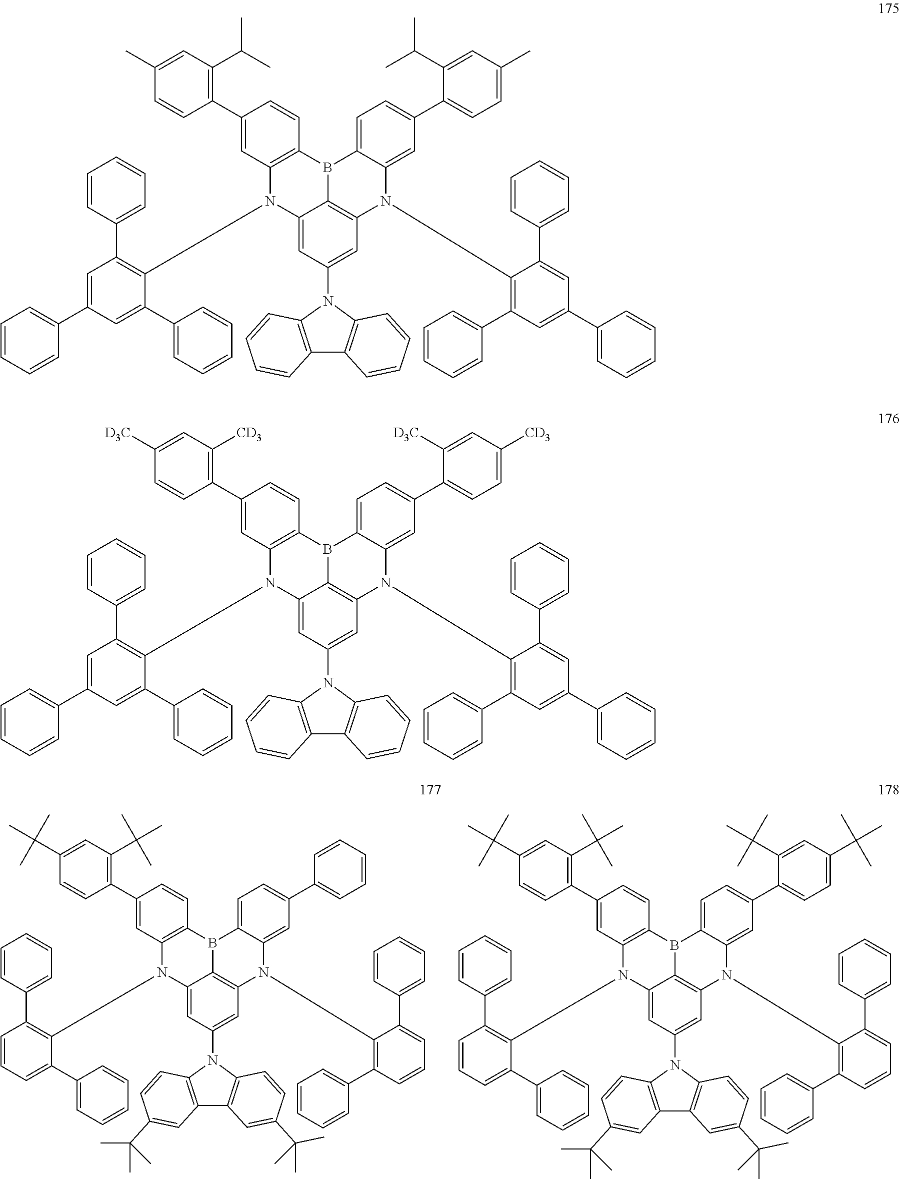

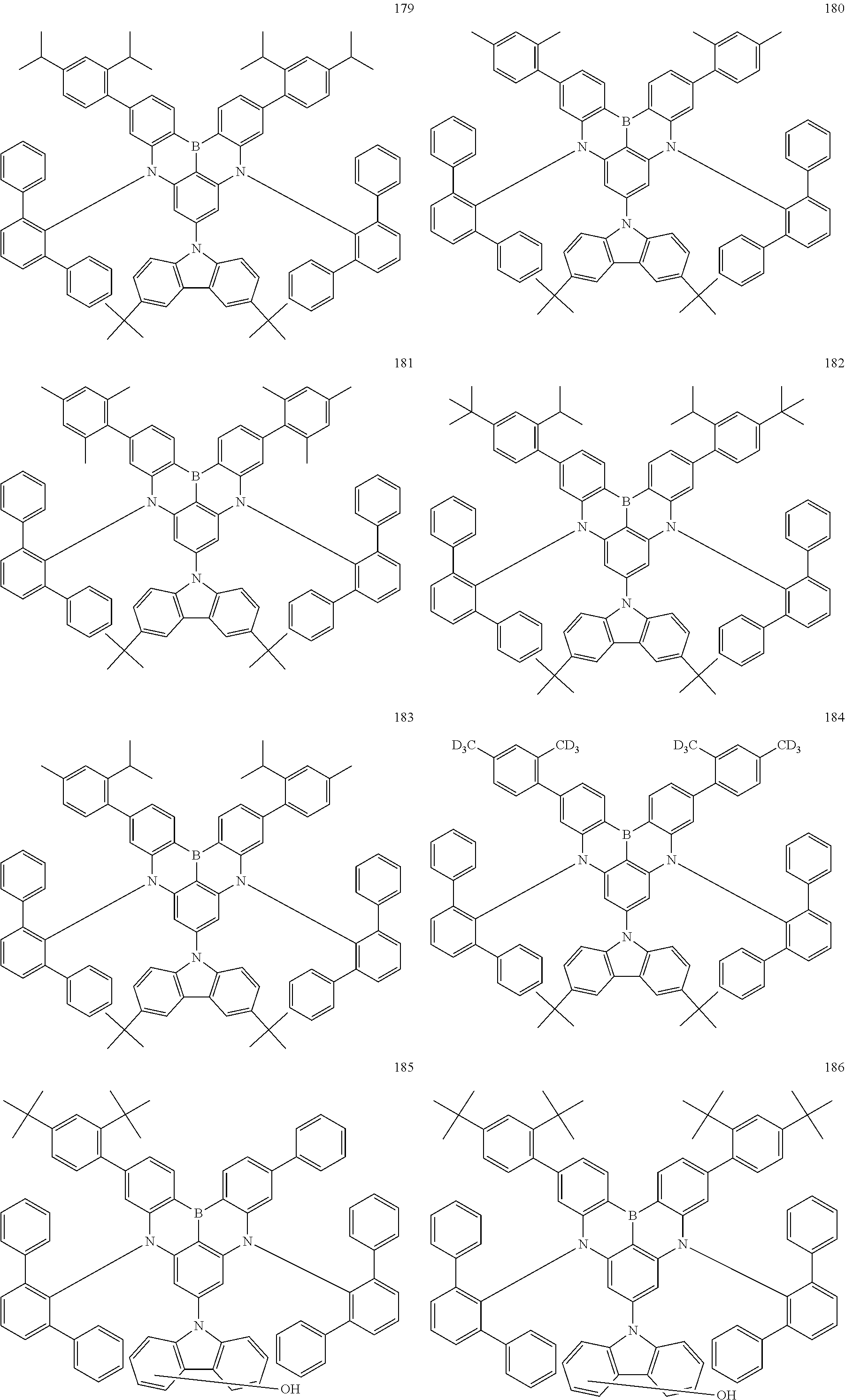

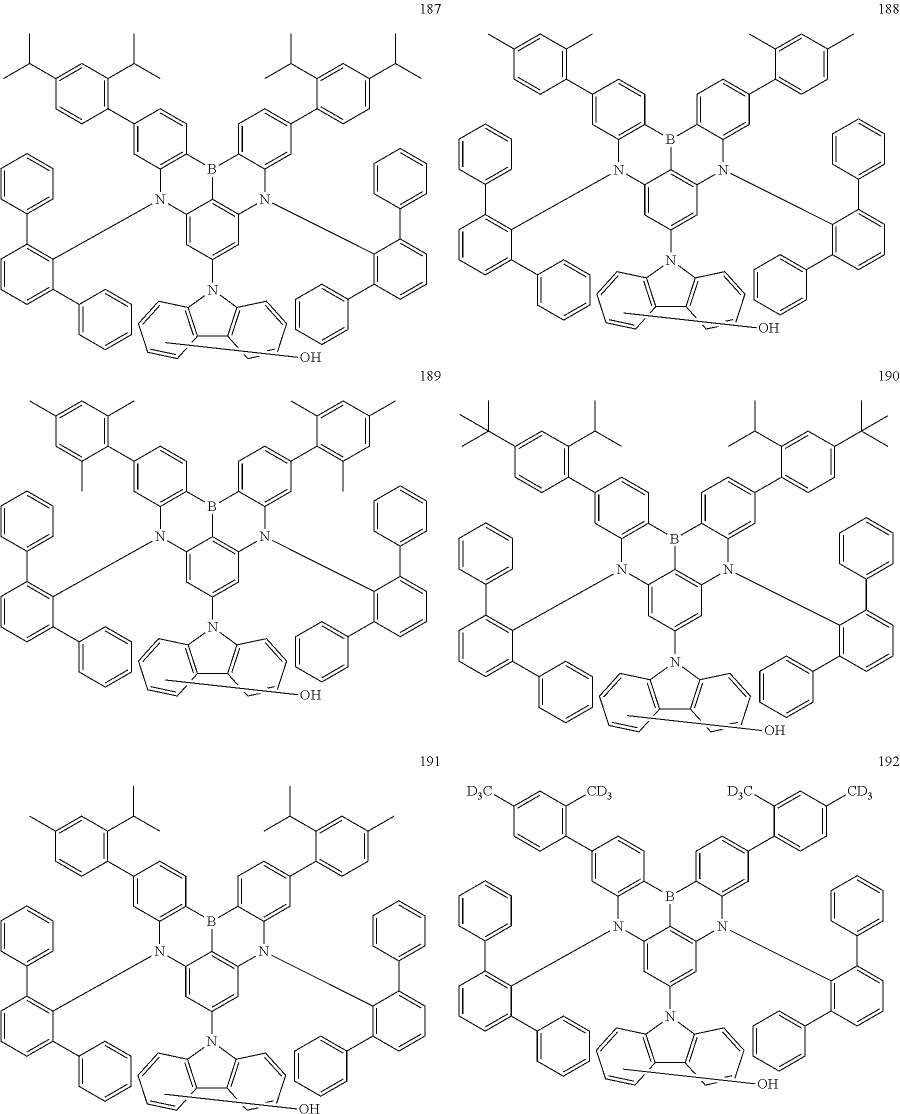

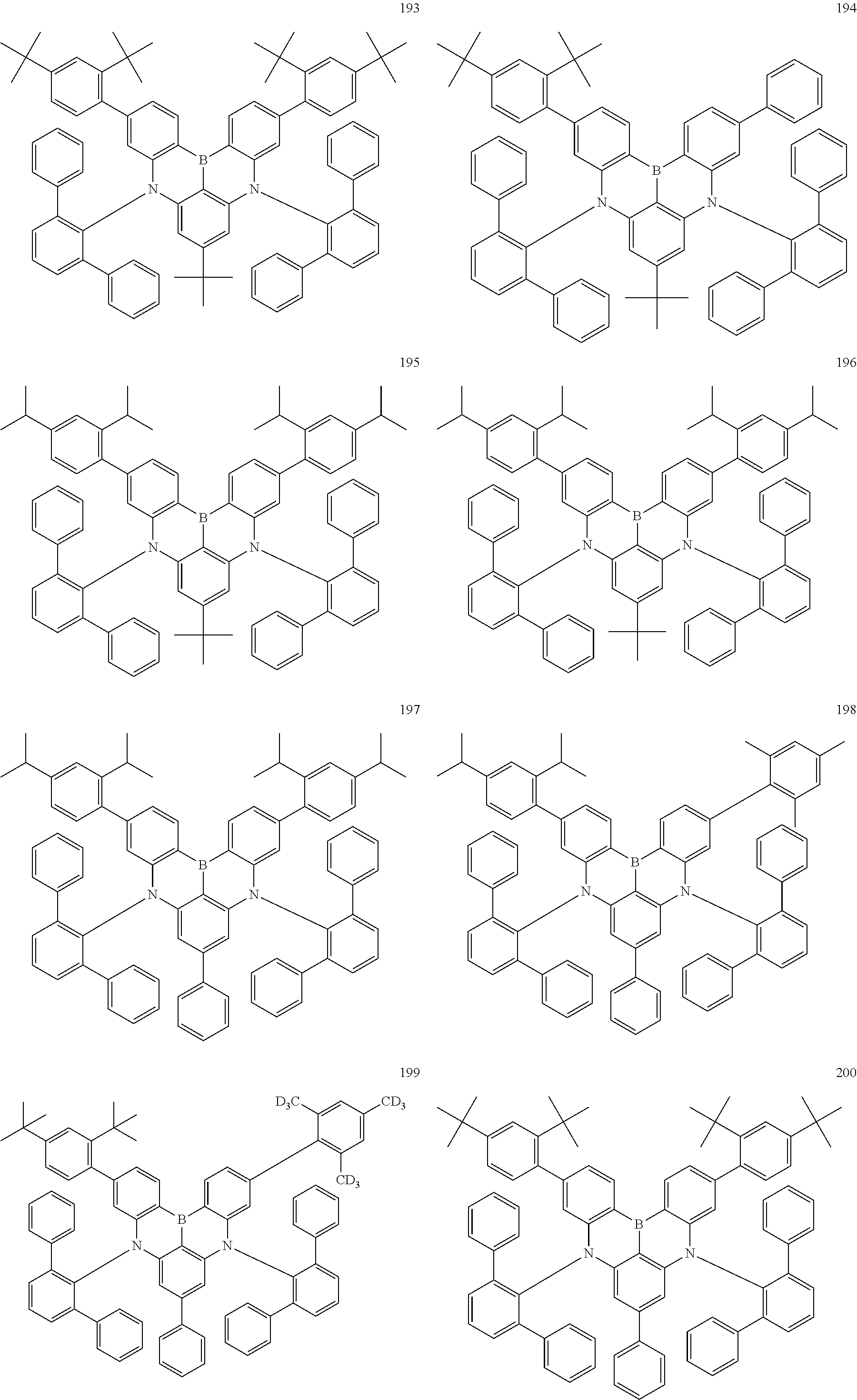

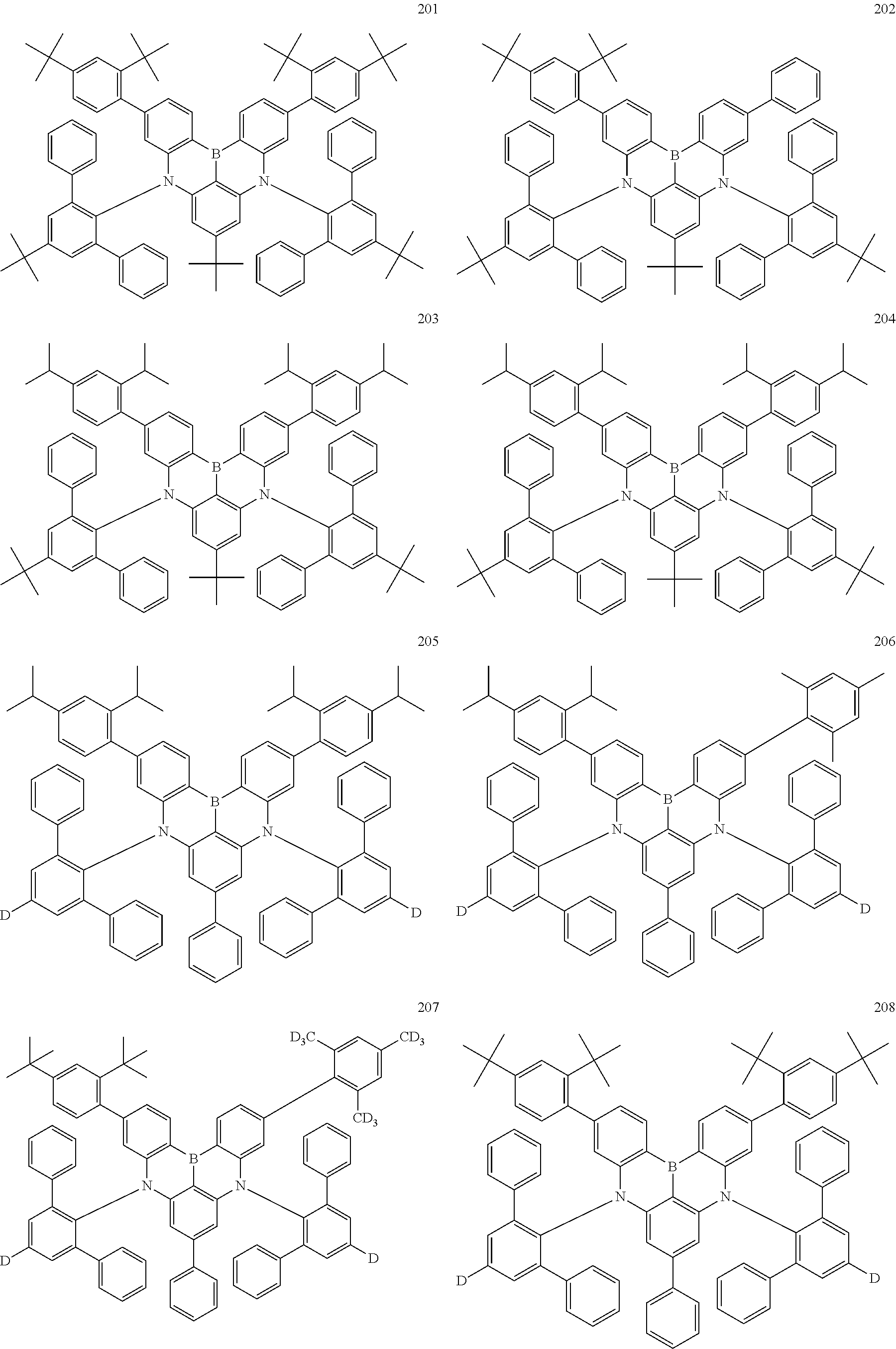

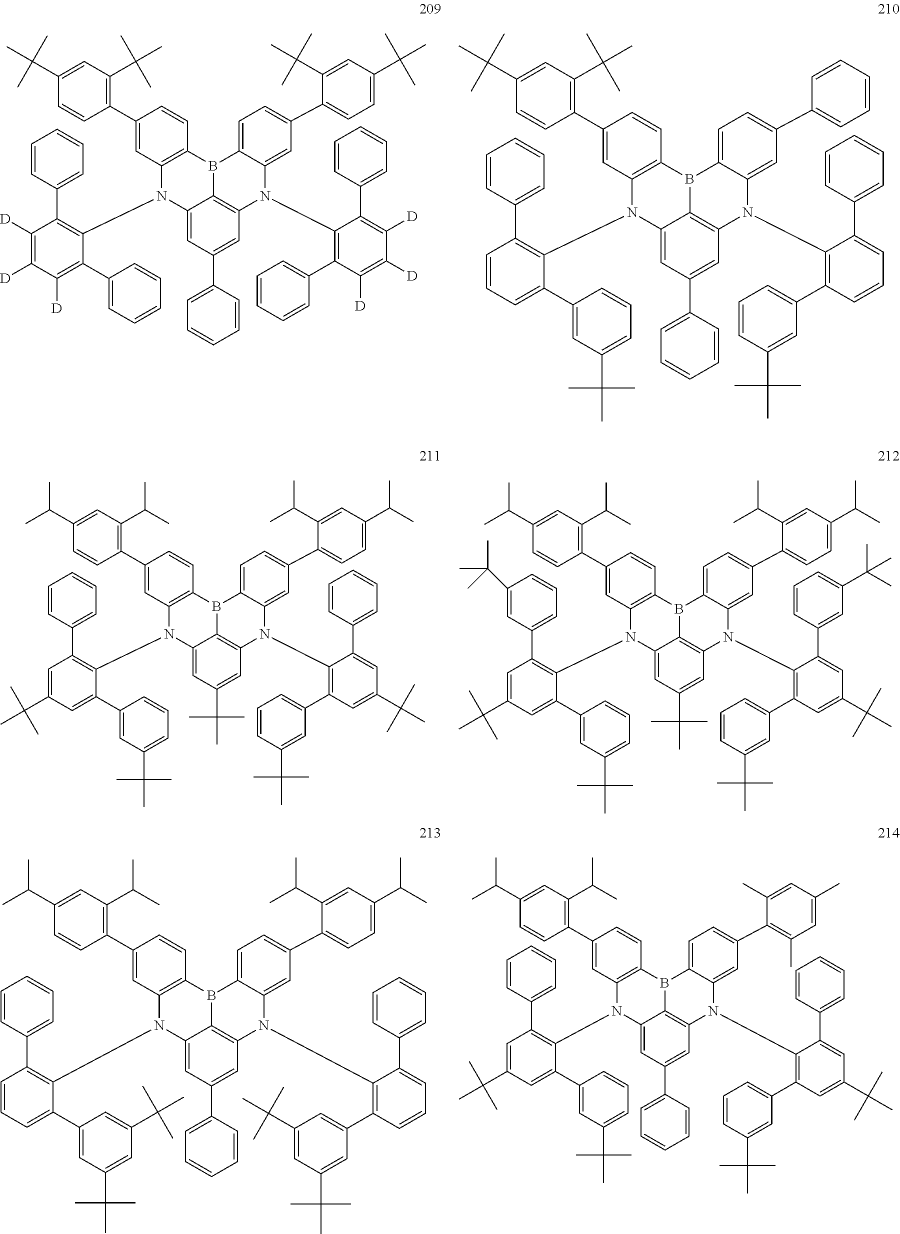

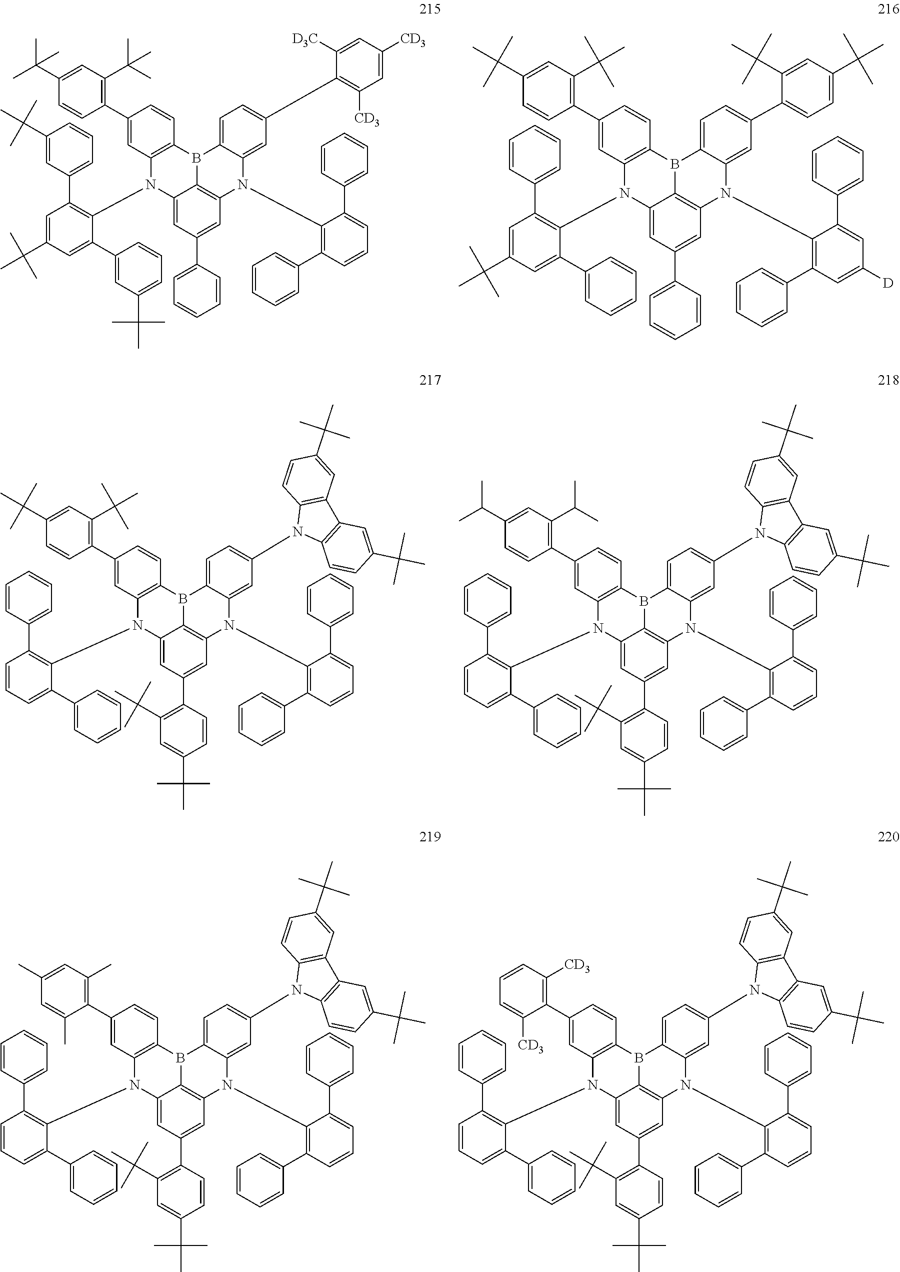

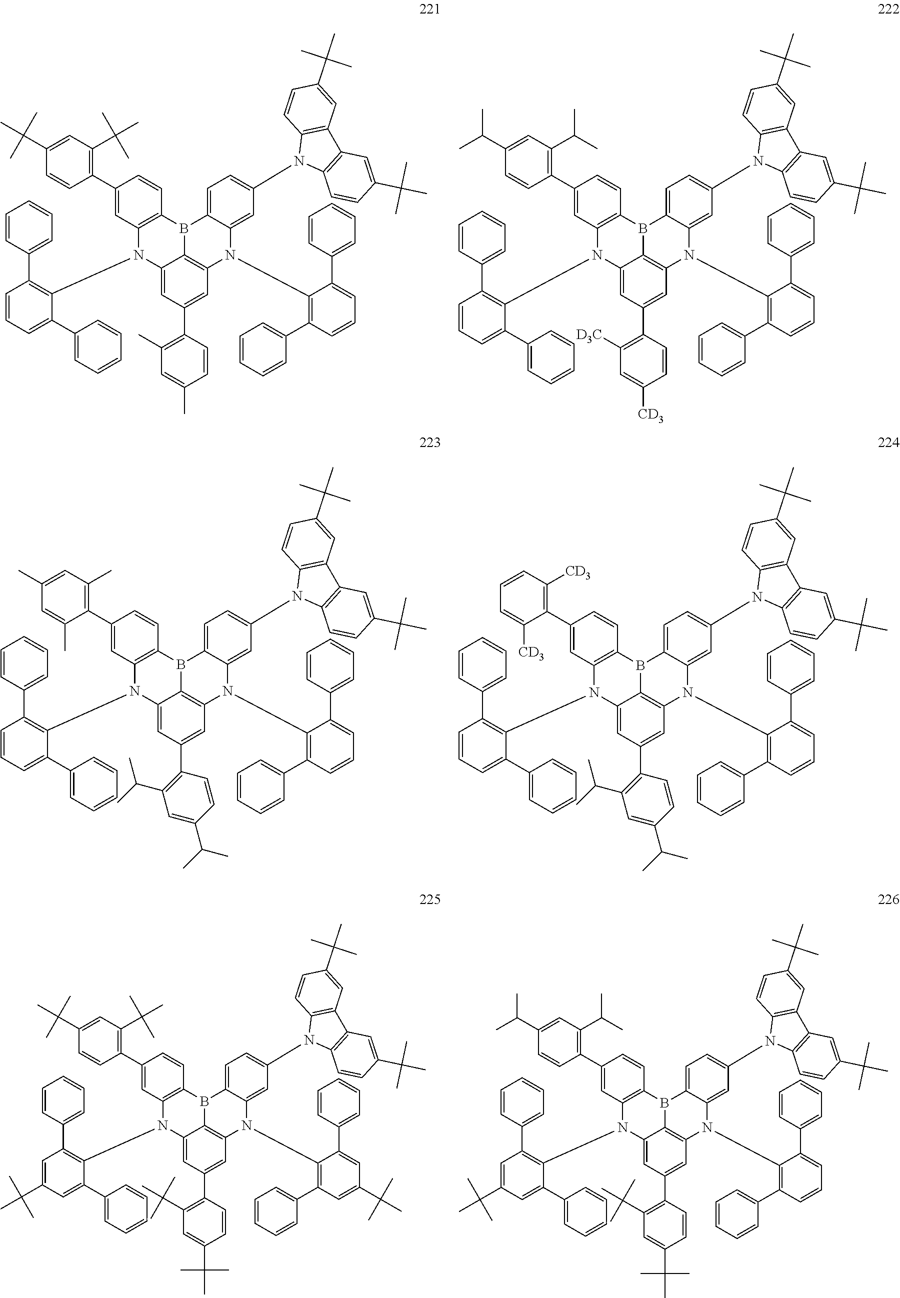

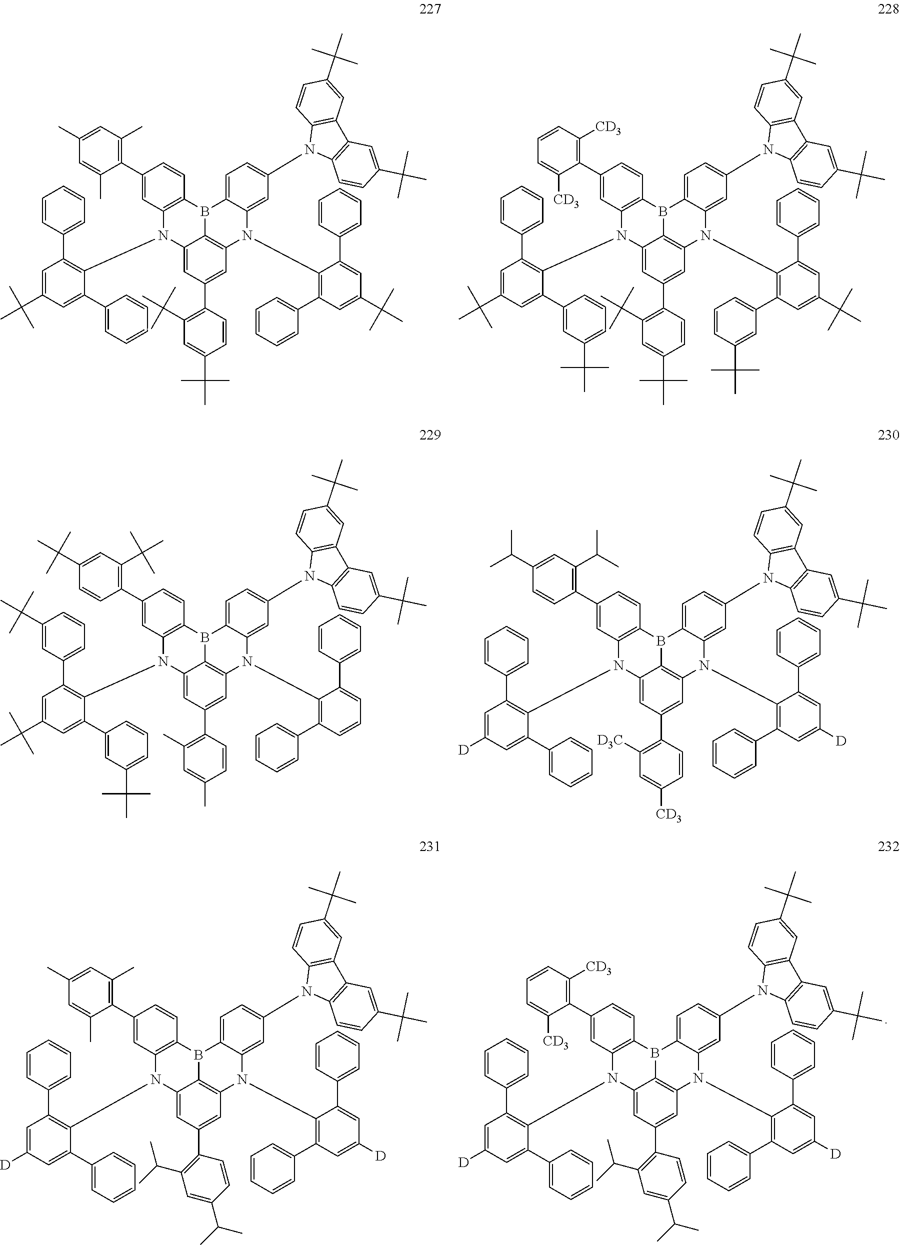

The condensed cyclic compound represented by Formula 1 may include at least one of R₁ to R₃, and R₁ to R₃ may each independently include at least one L_{D}. Shared electron pairs constituting single bonds such as C—H bonds, C—C bonds, Si—H bonds, and Si—C bonds included in L_{D} may be delocalized to a lowest unoccupied molecular orbital (LUMO) of a C₃-C₆₀ carbocyclic group or a C₁-C₆₀ heterocyclic group included in R₁ to R₃ by hyperconjugation. As a result, a LUMO energy level of the condensed cyclic compound represented by Formula 1 may increase, and the size of an energy gap between a highest occupied molecular orbital (HOMO) and the LUMO of the condensed cyclic compound represented by Formula 1 may increase.

Because R₁ to R₃ includes at least one L_{D}, an intramolecular steric hindrance due to L_{D} in a molecule of the condensed cyclic compound represented by Formula 1 may increase. As a result, an intramolecular energy transfer, for example, Dexter energy transfer may be inhibited.

The condensed cyclic compound represented by Formula 1 may include at least one of Z₁ to Z₃, and Z₁ to Z₃ may be included in the condensed cyclic compound represented by Formula 1 to function as a π electron donor. As a result, the electron density of Y₁ (for example, B) of Formula 1 may increase, and an additional reaction between Y₁ and a nucleophile or Y₁ and a host may be inhibited.

The condensed cyclic compound represented by Formula 1 may include a moiety represented by

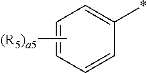

and a moiety represented by

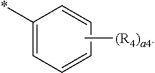

Through the two moieties, an additional intramolecular steric hindrance may be imparted to the condensed cyclic compound represented by Formula 1. As a result, an intramolecular energy transfer, for example, a dexter energy transfer may be further inhibited. The condensed cyclic compound represented by Formula 1 may have an even larger molecular structure and maintain an optimal intermolecular density.

As a result, an electronic device, such as an organic light-emitting device, including the condensed cyclic compound represented by Formula 1 may have high efficiency and a long lifespan.

Methods of synthesizing the condensed cyclic compound represented by Formula 1 may be readily understood to those of ordinary skill in the art by referring to Synthesis Examples and Examples described herein.

At least one condensed cyclic compound represented by Formula 1 may be used in a light-emitting device (for example, an organic light-emitting device). Thus, another embodiment provides a light-emitting device including a first electrode; a second electrode facing the first electrode; an interlayer between the first electrode and the second electrode and including an emission layer; and the condensed cyclic compound represented by Formula 1 as described in the specification.

In embodiments,
the first electrode of the light-emitting device may be an anode,
the second electrode of the light-emitting device may be a cathode,
the interlayer may further include a hole transport region between the first electrode and the emission layer, and an electron transport region between the emission layer and the second electrode,
the hole transport region may include a hole injection layer, a hole transport layer, an emission auxiliary layer, an electron blocking layer, or a combination thereof, and
the electron transport region may include a buffer layer, a hole blocking layer, an electron control layer, an electron transport layer, an electron injection layer, or a combination thereof.

In an embodiment, the condensed cyclic compound may be included between the first electrode and the second electrode of the light-emitting device. Thus, the condensed cyclic compound may be included in the interlayer of the light-emitting device, for example, in the emission layer of the interlayer.

In embodiments, the emission layer in the interlayer of the light-emitting device may include a dopant and a host, and the condensed cyclic compound may be included in the dopant. For example, the condensed cyclic compound may serve as a dopant. In another example, the emission layer may emit red light, green light, blue light, and/or white light. In an embodiment, the emission layer may emit blue light and the blue light may have a maximum emission wavelength in a range of, for example, about 400 nm to about 490 nm.

In embodiments, the emission layer o may include a dopant and a host, wherein the dopant may include the condensed cyclic compound and the dopant may emit blue light.

In embodiments, the dopant may include a transition metal and ligand(s) in the number of m, m may be an integer from 1 to 6, the ligand(s) in the number of m may be identical to or different from each other, at least one of the ligand(s) in the number of m may be bound to the transition metal via a carbon-transition metal bond, and the carbon-transition metal bond may be a coordinate bond. For example, at least one of the ligand(s) in the number of m may be a carbene ligand (e.g., Ir(pmp)3 or the like). The transition metal may be, for example, iridium, platinum, osmium, palladium, rhodium, or gold. The emission layer and the dopant may be as described herein.

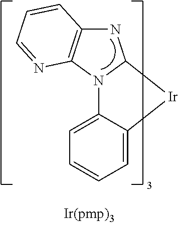

In an embodiment, the light-emitting device may include a capping layer located outside the first electrode or outside the second electrode.

In an embodiment, the light-emitting device may further include at least one of a first capping layer located outside the first electrode and a second capping layer located outside the second electrode, and at least one of the first capping layer and the second capping layer may include the condensed cyclic compound represented by Formula 1. Further details for the first capping layer and/or second capping layer are as described herein.

In an embodiment, the light-emitting device may further include:
a first capping layer outside the first electrode and including the condensed cyclic compound represented by Formula 1;
a second capping layer outside the second electrode and including the condensed cyclic compound represented by Formula 1; or
the first capping layer and the second capping layer.

The wording “(interlayer and/or capping layer) includes a condensed cyclic compound” as used herein may be understood as “(interlayer and/or capping layer) may include one kind of condensed cyclic compound represented by Formula 1 or two different kinds of condensed cyclic compounds, each independently represented by Formula 1”.

In an embodiment, the interlayer and/or the capping layer may include Compound 1 only as the condensed cyclic compound. In this regard, Compound 1 may be present in the emission layer of the light-emitting device. In some embodiments, the interlayer may include, as the condensed cyclic compound, Compound 1 and Compound 2. In this regard, Compound 1 and Compound 2 may be present in a same layer (for example, all of Compound 1 and Compound 2 may be present in the emission layer), or may be present in different layers (for example, Compound 1 may be present in the emission layer, and Compound 2 may be present in the electron transport region).

The term “interlayer” as used herein may be a single layer and/or all layers between the first electrode and the second electrode of the light-emitting device.

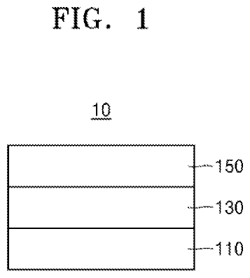

Another embodiment provides an electronic apparatus which may include the light-emitting device. The electronic apparatus may further include a thin-film transistor. In an embodiment, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or a combination thereof. Further details on the electronic apparatus may be the same as provided herein.

[Description of FIG. 1]

FIG. 1 is a schematic cross-sectional view of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described with reference to FIG. 1.

[First Electrode 110]

In FIG. 1, a substrate may be further included under the first electrode 110 or on the second electrode 150. As the substrate, a glass substrate or a plastic substrate may be used. In some embodiments, the substrate may be a flexible substrate and may include plastics with excellent heat resistance and durability, such as polyimide, polyethylene terephthalate (PET), polycarbonate, polyethylene naphthalate, polyarylate (PAR), polyetherimide, or a combination thereof.

The first electrode 110 may be formed by, for example, depositing or sputtering a material for forming the first electrode 110 on the substrate. In case that the first electrode 110 is an anode, a material for forming the first electrode 110 may be a high-work function material that facilitates the injection of holes.

The first electrode 110 may be a reflective electrode, a semi-transmissive electrode, or a transmissive electrode. In case that the first electrode 110 is a transmissive electrode, a material for forming the first electrode 110 may include indium tin oxide (ITO), indium zinc oxide (IZO), tin oxide (SnO₂), zinc oxide (ZnO), or a combination thereof. In case that the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or a combination thereof.

The first electrode 110 may have a structure consisting of a single layer or a structure including multiple layers. For example, the first electrode 110 may have a three-layered structure of ITO/Ag/ITO.

[Interlayer 130]

The interlayer 130 may be located on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to various organic materials, a metal-containing compound such as an organometallic compound, an inorganic material such as quantum dots, or the like.

In some embodiments, the interlayer 130 may include, two or more emitting units stacked between the first electrode 110 and the second electrode 150, and at least one charge generation layer between the two or more emitting units. When the interlayer 130 includes emitting units and at least one charge generation layer as described above, the light-emitting device 10 may be a tandem light-emitting device.

[Hole Transport Region in Interlayer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or a combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 110 in its respective stated order. However, the structure of the hole transport region is not limited thereto.

The hole transport region may include a compound represented by Formula 201, a compound represented by Formula 202, or a combination thereof:

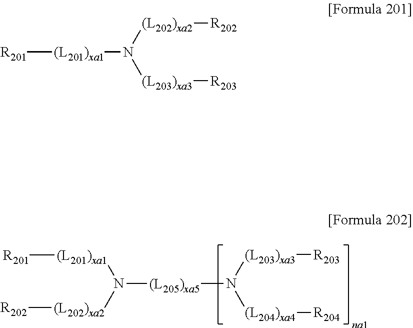

In Formulae 201 and 202,
L₂₀₁ to L₂₀₄ may each independently be a C₃-C₆₀ carbocyclic group unsubstituted or substituted with at least one R₁₀ₐ or a C₁-C₆₀) heterocyclic group unsubstituted or substituted with at least one R₁₀ₐ,
L₂₀₅ may be *—O—*′, *—S—*′, *—N(Q₂₀₁)-*′, a C₁-C₆₀) alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀) heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may independently be a C₃-C₆₀ carbocyclic group unsubstituted or substituted with at least one R₁₀ₐ, or a C₁-C₆₀) heterocyclic group unsubstituted or substituted with at least one R₁₀ₐ,
R₂₀₁ and R₂₀₂ may each optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₅-C₆₀ polycyclic group (for example, a carbazole group or the like) unsubstituted or substituted with at least one R₁₀ₐ (for example, Compound HT16),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₅-C₆₀ polycyclic group unsubstituted or substituted with at least one R₁₀ₐ, and
na1 may be an integer from 1 to 4.

In embodiments, the compound represented by Formula 201 and Formula 202 may each independently include at least one of groups represented by Formulae CY₂₀₁ to CY₂₁₇:

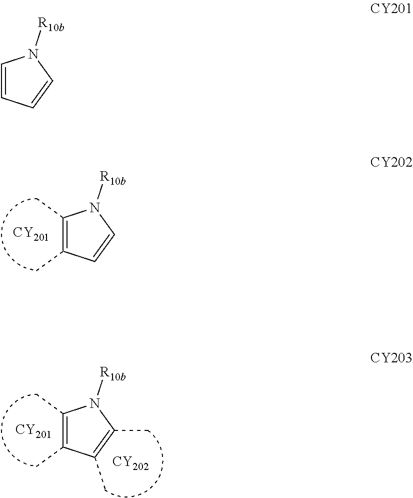

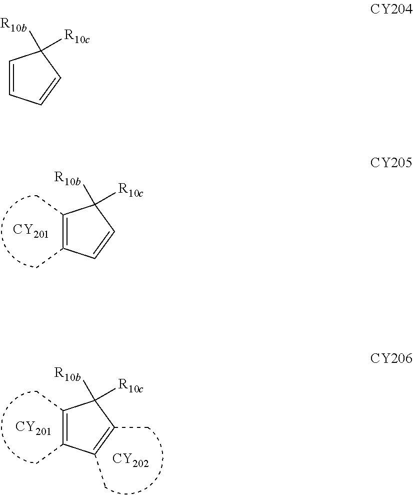

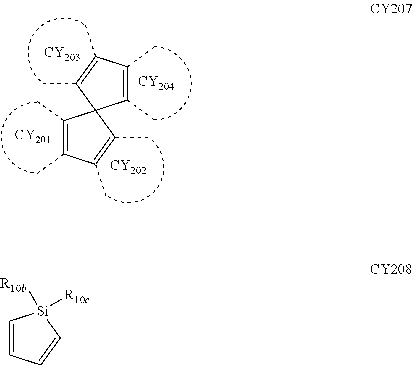

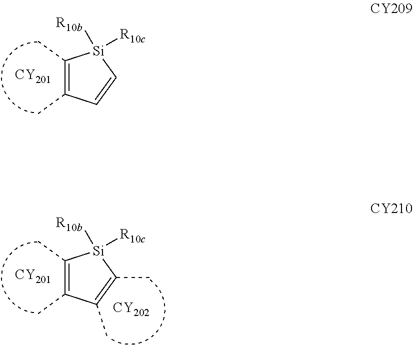

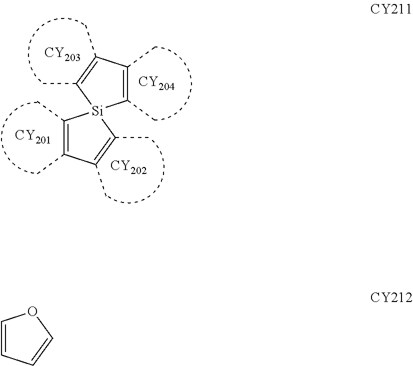

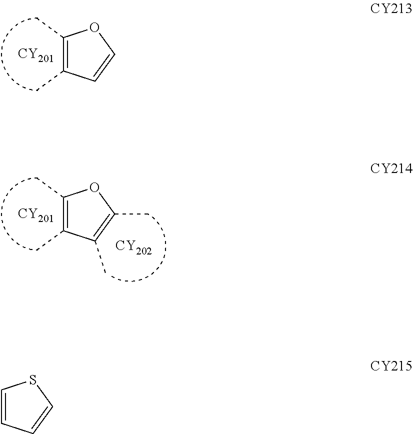

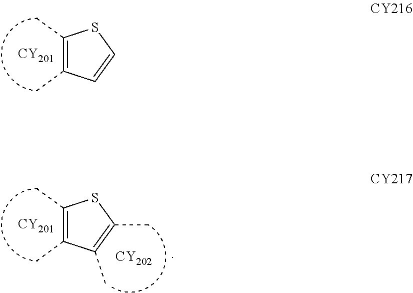

In Formulae CY201 to CY217, R_{10b} and R_{10c} may each independently be as described for R₁₀ₐ, ring CY₂₀₁ to ring CY₂₀₄ may each independently be a C₃-C₂₀ carbocyclic group or a C₁-C₆₀) heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulae CY201 to CY217 may each independently be a benzene group, a naphthalene group, a phenanthrene group, or an anthracene group.

In some embodiments, the compound represented by Formula 201 and the compound represented by Formula 202 each may include at least one of groups represented by Formulae CY201 to CY203.

In some embodiments, the compound represented by Formula 201 may include at least one of groups represented by Formulae CY201 to CY203 and at least one of groups represented by Formulae CY204 to CY217.

In some embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In some embodiments, the compound represented by Formula 201 and the compound represented by Formula 202 may each not include group represented by one of Formulae CY201 to CY203.

In some embodiments, the compound represented by Formula 201 and the compound represented by Formula 202 may each not include group represented by one of Formulae CY201 to CY203, and may each independently include at least one of groups represented by Formulae CY204 to CY217.

In some embodiments, the compound represented by Formula 201 and the compound represented by Formula 202 may each not independently include a group represented by one of Formulae CY201 to CY217.

In an embodiment, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or a combination thereof:

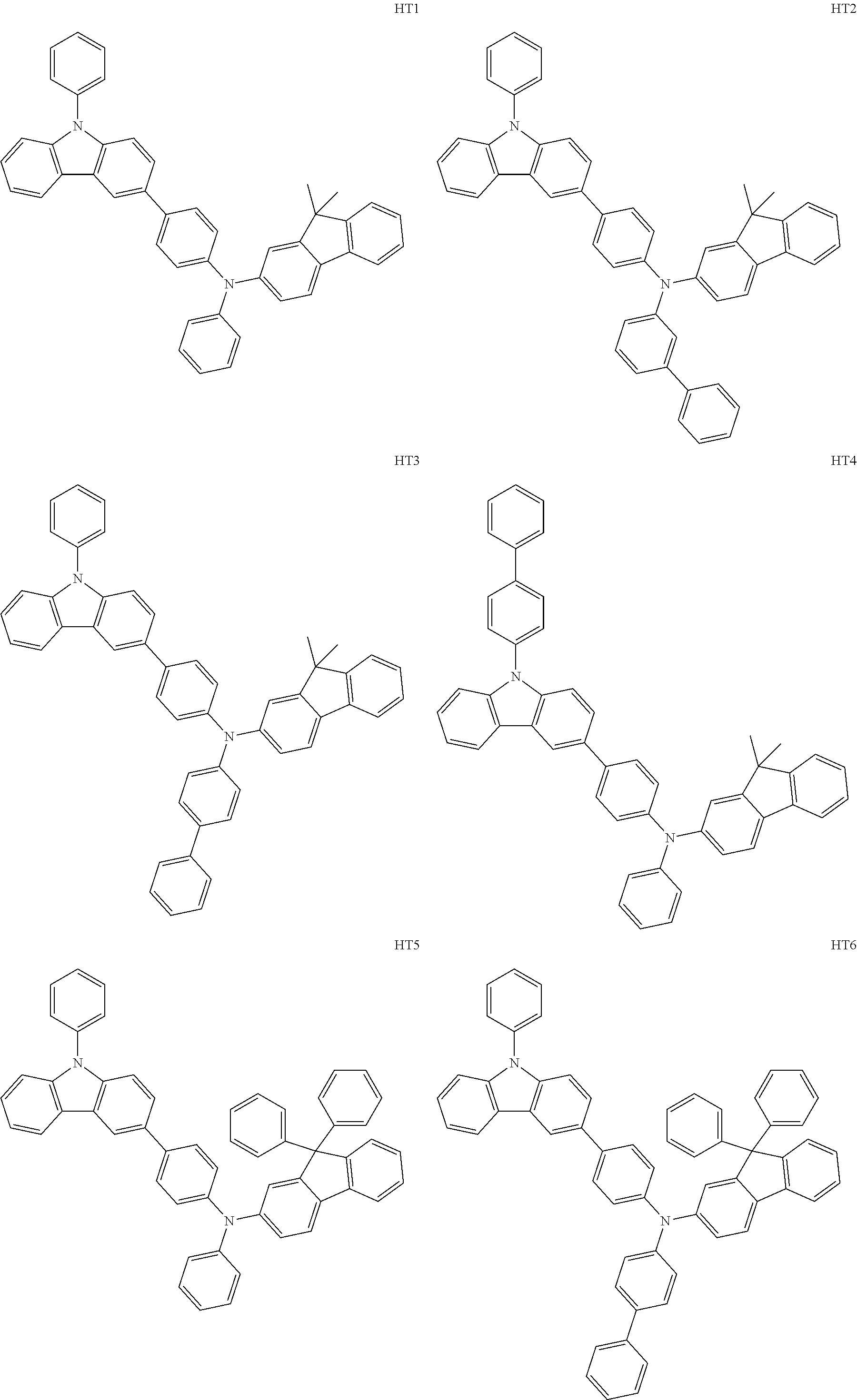

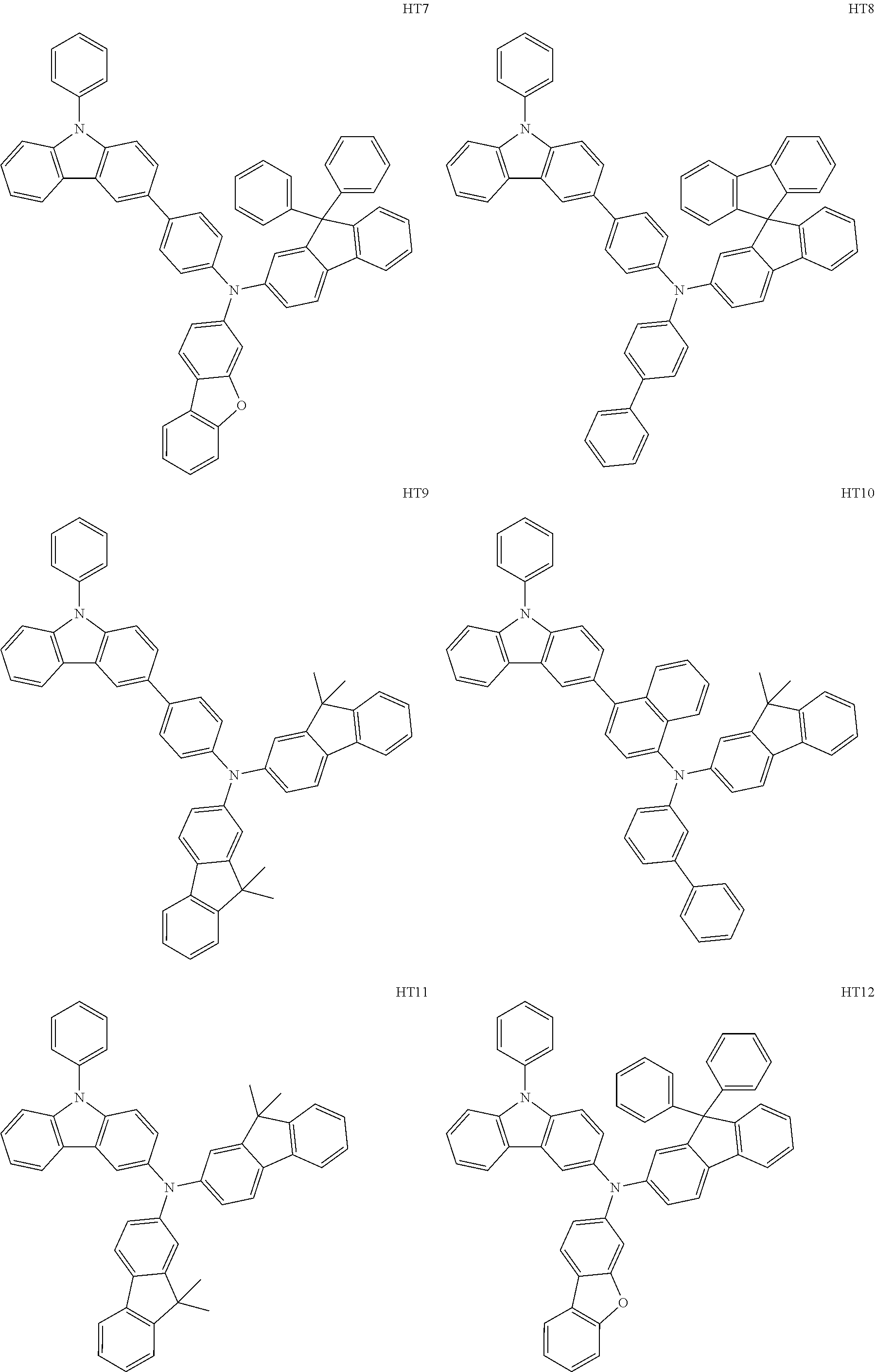

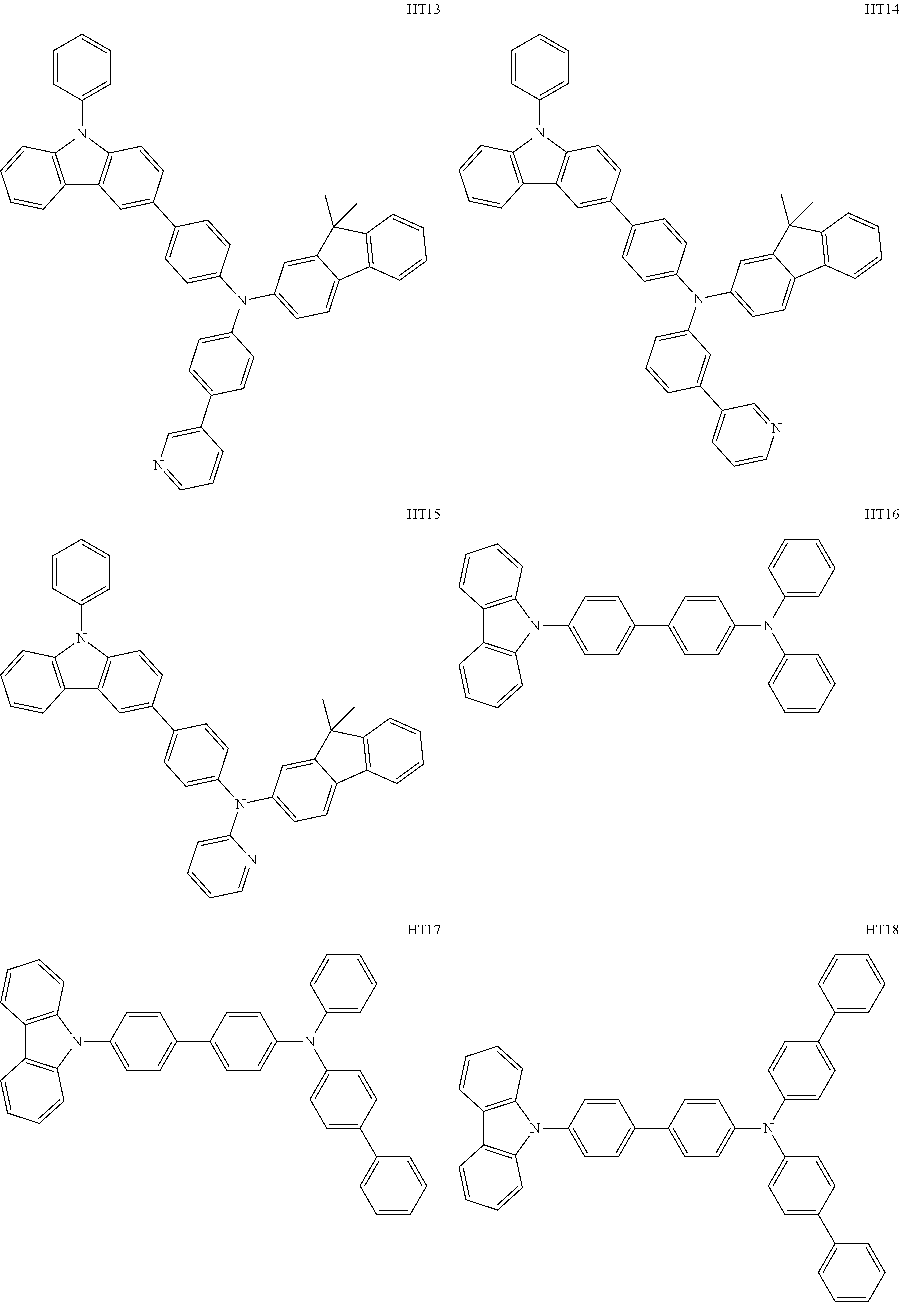

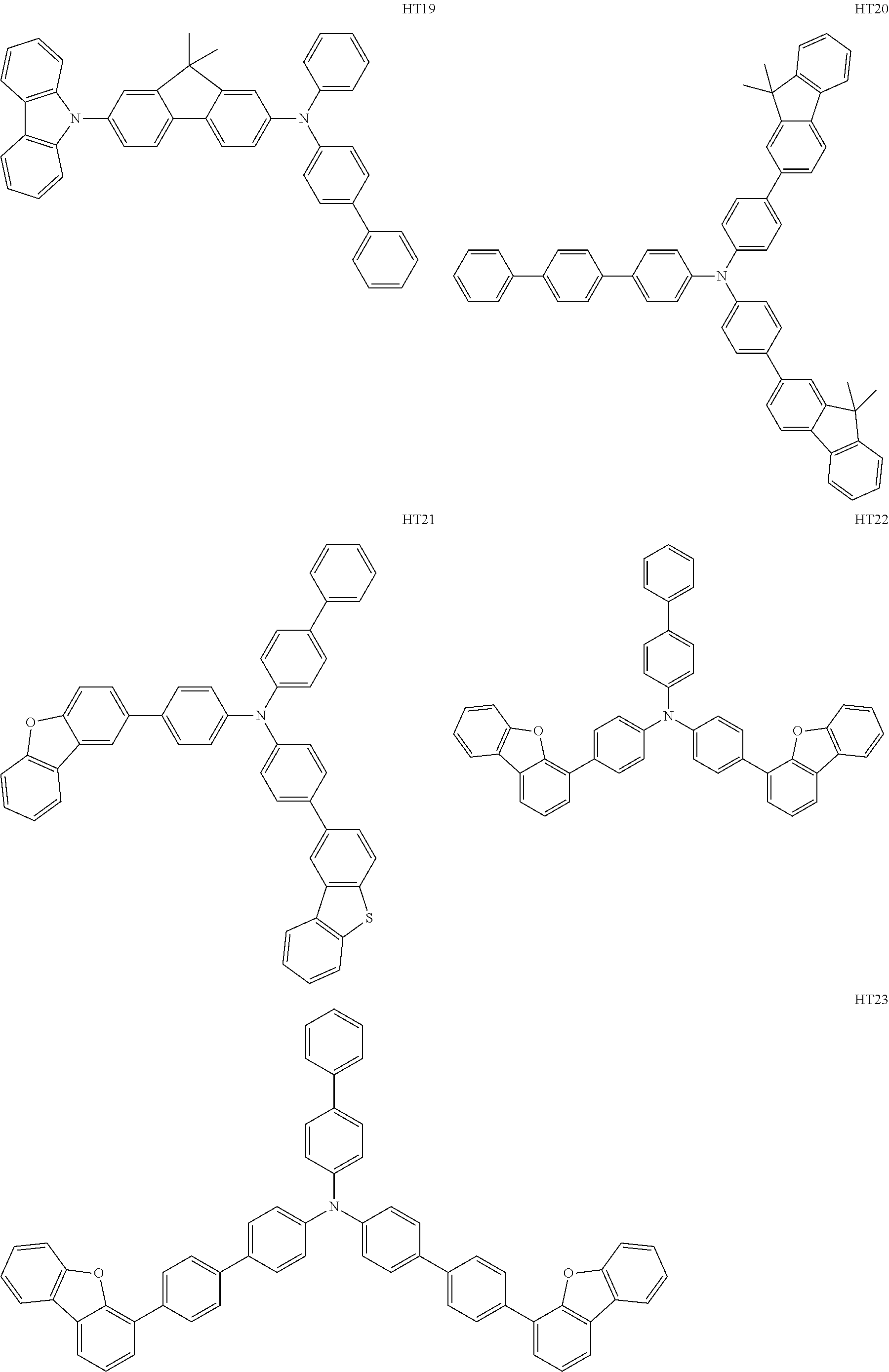

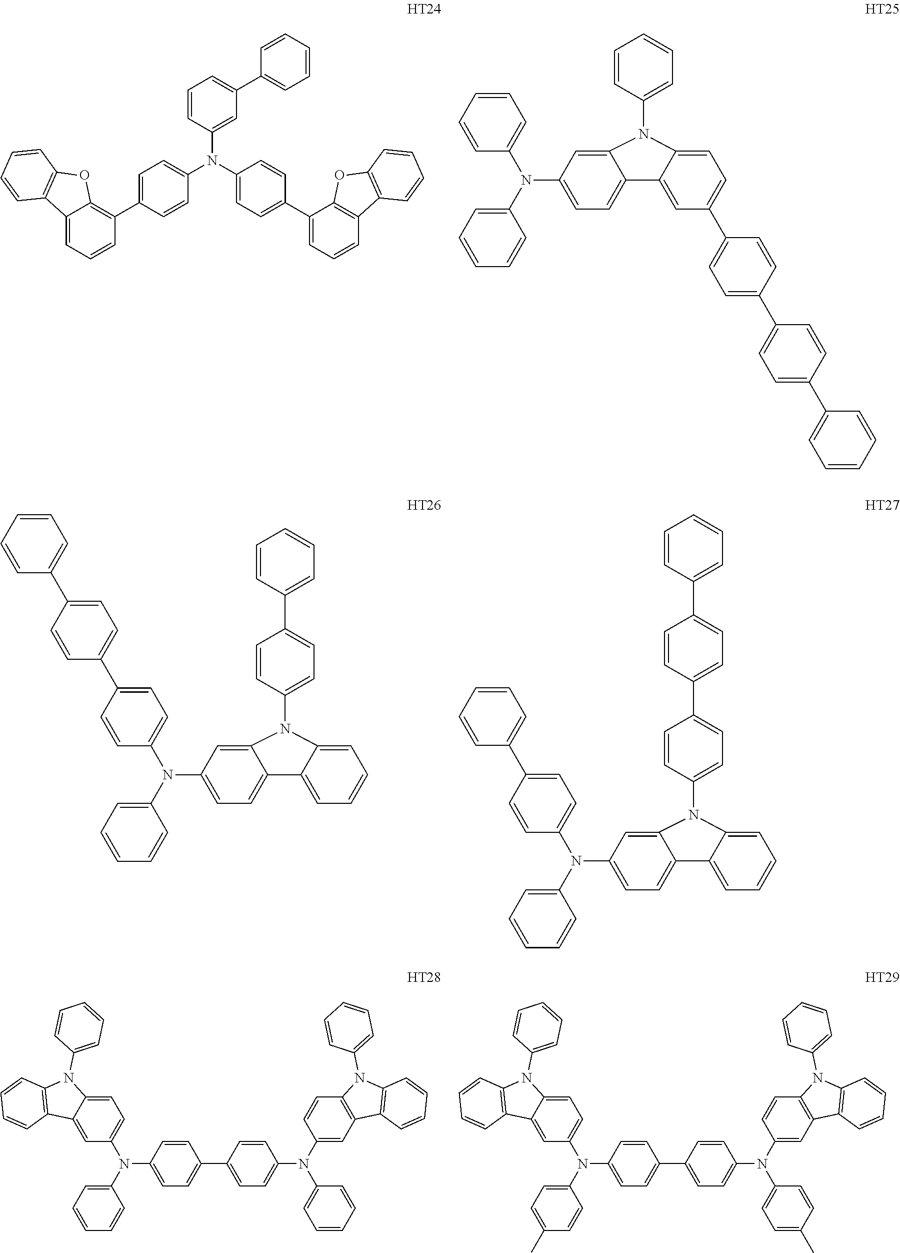

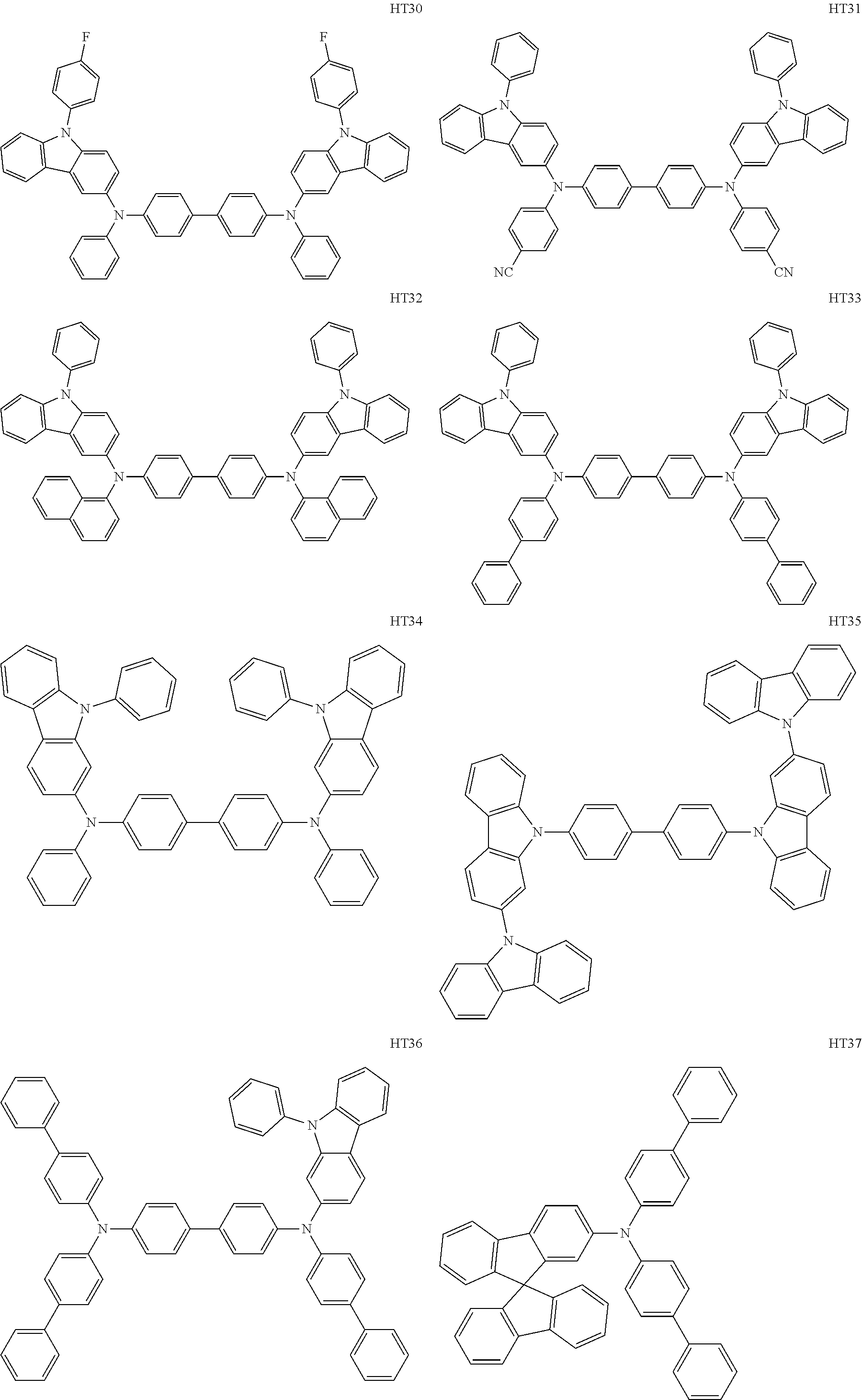

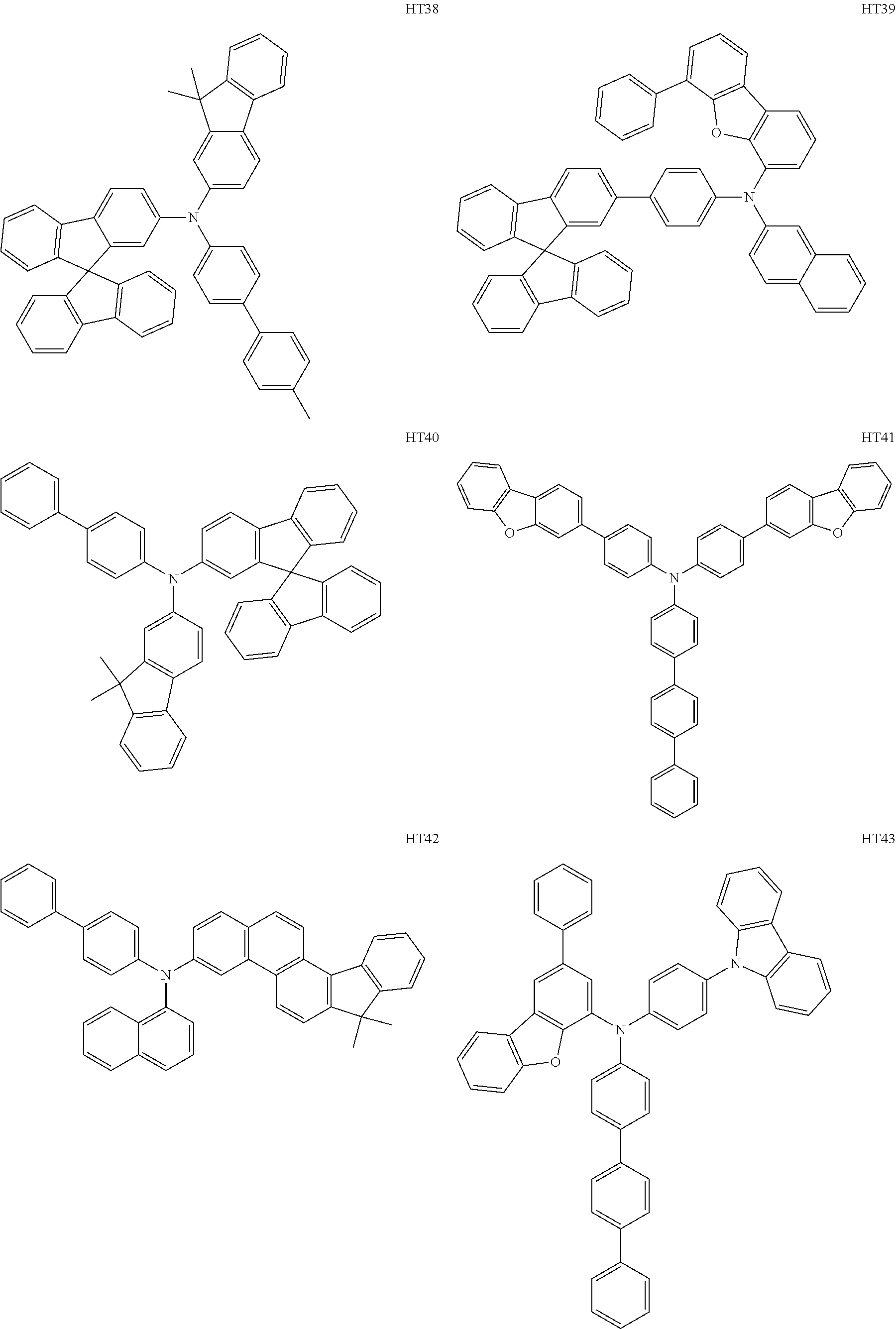

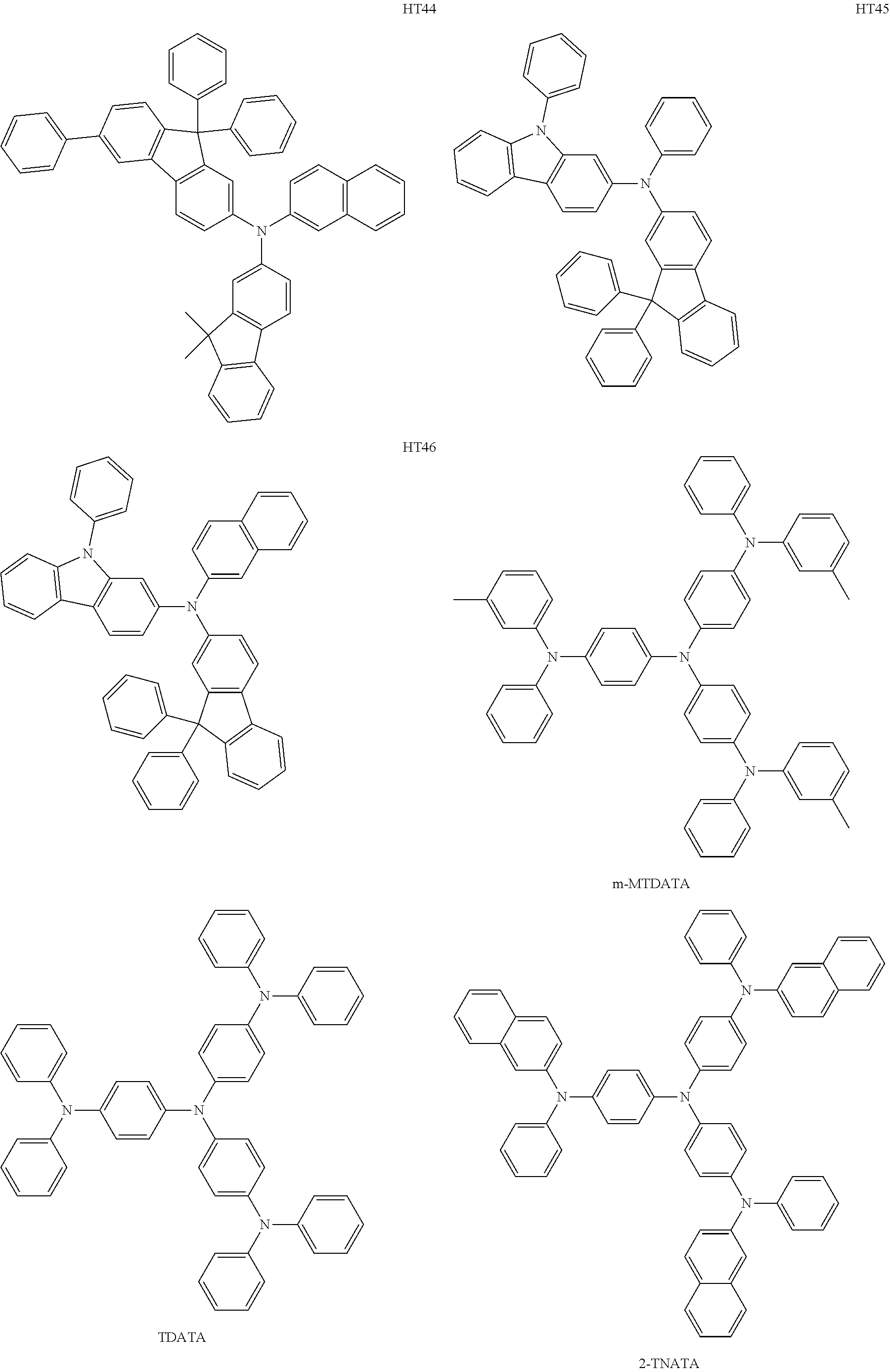

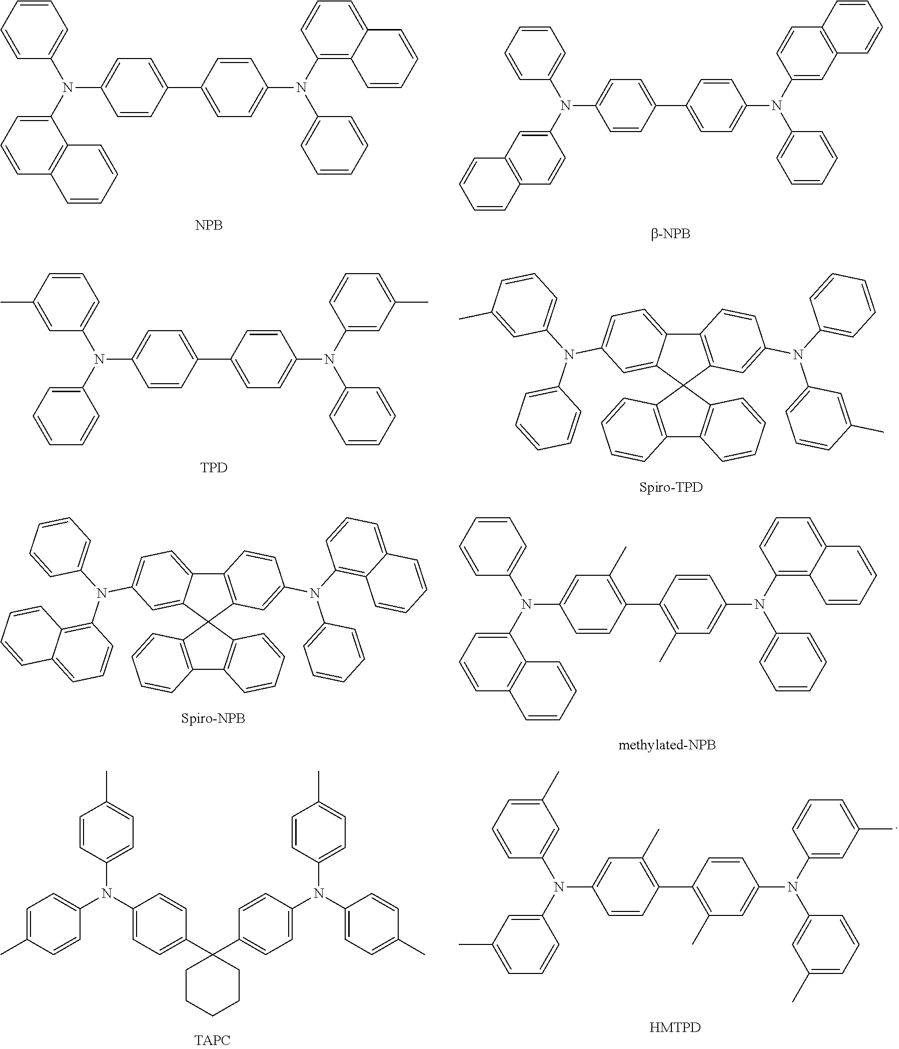

A thickness of the hole transport region may be in a range of about 50 Å to about 10,000 Å. For example, a thickness of the hole transport region may be in a range of about 100 Å to about 4,000 Å. In case that the hole transport region includes a hole injection layer, a hole transport layer, or a combination thereof, a thickness of the hole injection layer may be in a range of about 100 Å to about 9,000 Å, and a thickness of the hole transport layer may be in a range of about 50 Å to about 2,000 Å. For example, a thickness of the hole injection layer may be in a range of about 100 Å to about 1,000 Å. For example, a thickness of the hole transport layer may be in a range of about 100 Å to about 1,500 Å. In case that the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to a wavelength of light emitted by an emission layer, and the electron blocking layer may block the leakage of electrons from an emission layer to a hole transport region. Materials that may be included in the hole transport region may be included in the emission auxiliary layer and the electron blocking layer.

[p-Dopant]

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

For example, the lowest unoccupied molecular orbital (LUMO) energy level of the p-dopant may be −3.5 eV or less.

In some embodiments, the p-dopant may include a quinone derivative, a cyano group-containing compound, a compound including element EL1 and element EL2, or a combination thereof.

Examples of a quinone derivatives are TCNQ, F4-TCNQ, etc.

Examples of a cyano group-containing compound may include HAT-CN and a compound represented by Formula 221:

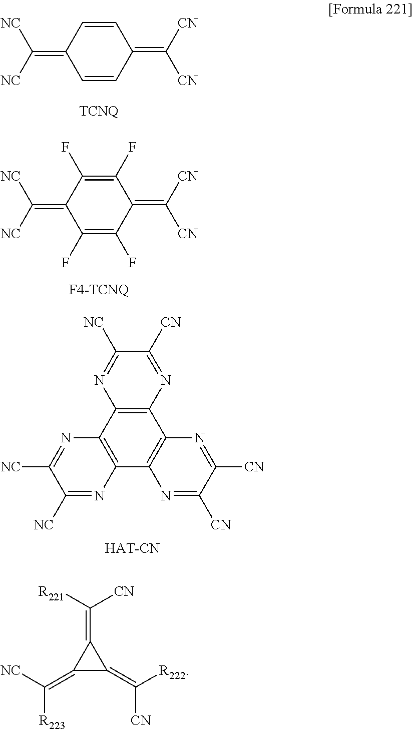

In Formula 221,

R₂₂₁ to R₂₂₃ may each independently be a C₃-C₆₀) carbocyclic group unsubstituted or substituted with at least one R₁₀ₐ or a C₁-C₆₀) heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with a cyano group; —F; —Cl; —Br; —I; a C₁-C₆₀) alkyl group substituted with a cyano group, —F, —Cl, —Br, —I, or a combination thereof; or a combination thereof.

In the compound including element EL1 and element EL2, element EL1 may be a metal, a metalloid, or a combination thereof, and element EL2 may be a non-metal, a metalloid, or a combination thereof.

Examples of a metal may include an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium I, ytterbium (Yb), lutetium (Lu), etc.).

Examples of a metalloid may include silicon (Si), antimony (Sb), and tellurium (Te).

Examples of a non-metal may include oxygen (O) and a halogen (for example, F, Cl, Br, I, etc.).

Examples of a compound including element EL1 and element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or a combination thereof.

Examples of a metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of a metal halide may include an alkali metal halide, an alkaline earth metal halide, a transition metal halide, a post-transition metal halide, and a lanthanide metal halide.

Examples of an alkali metal halogen may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and Bale.

Examples of a transition metal halide may include titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), a osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), a iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of a post-transition metal halide may include a zinc halide (for example, ZnF₂, ZnCl₂, ZnBr₂, ZnI₂, etc.), an indium halide (for example, InI₃, etc.), and a tin halide (for example, SnI₂, etc.).

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, and SmI₃.

Examples of a metalloid halide may include an antimony halide (for example, SbCl₅, etc.).

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

[Emission Layer in Interlayer 130]

In case that the light-emitting device 10 is a full-color light-emitting device, the emission layer may be patterned into a red emission layer, a green emission layer, and/or a blue emission layer, according to a subpixel. In some embodiments, the emission layer may have a stacked structure of two or more layers of a red emission layer, a green emission layer, and a blue emission layer, in which the two or more layers contact each other or are separated from each other to emit white light. In some embodiments, the emission layer may include two or more materials of a red light-emitting material, a green light-emitting material, and a blue light-emitting material, in which the two or more materials are mixed with each other in a single layer to emit white light.

The emission layer may include a host and a dopant. The dopant may include a phosphorescent dopant, a fluorescent dopant, or a combination thereof.

The amount of the dopant in the emission layer may be from about 0.01 part by weight to about 15 parts by weight based on 100 parts by weight of the host.

In some embodiments, the emission layer may include a quantum dot.

The emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. In case that the thickness of the emission layer is within these ranges, excellent light-emission characteristics may be obtained without a substantial increase in driving voltage.

[Host]

In some embodiments, the host may include a compound represented by Formula 301 below:

[Ar₃₀₁]_{xb11}-[(L₃₀₁)_{xb1}-R₃₀₁]_{xb21} [Formula 301]

In Formula 301,
Ar₃₀₁ and L₃₀₁ may each independently be a C₃-C₆₀ carbocyclic group unsubstituted or substituted with at least one R₁₀ₐ or a C₁-C₆₀) heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀) heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be as described for Q₁.

For example, when xb11 is 2 or more, two or more of Ar₃₀₁(s) may be linked to each other via a single bond.

In some embodiments, the host may include a compound represented by Formula 301-1, a compound represented by Formula 301-2, or a combination thereof:

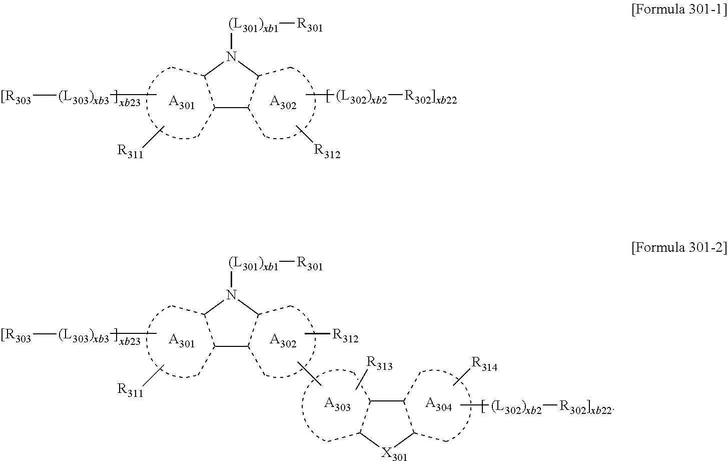

In Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀) heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2, L₃₀₁, xb1, and R₃₀₁ may each be as described herein,
L₃₀₂ to L₃₀₄ may each independently be as described for L₃₀₁,
xb2 to xb4 may each independently be as described for xb1, and
R₃₀₂ to R₃₀₅ and R₃₁₁ to R₃₁₄ may each independently be as described for R₃₀₁.

In some embodiments, the host may include an alkali earth metal complex, a post-transition metal complex, or a combination thereof. For example, the host may include a Be complex (for example, Compound H55), an Mg complex, a Zn complex, or a combination thereof.

In some embodiments, the host may include one of Compounds H1 to H128, 9,10-di(2-naphthyl)anthracene (I), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or a combination thereof:

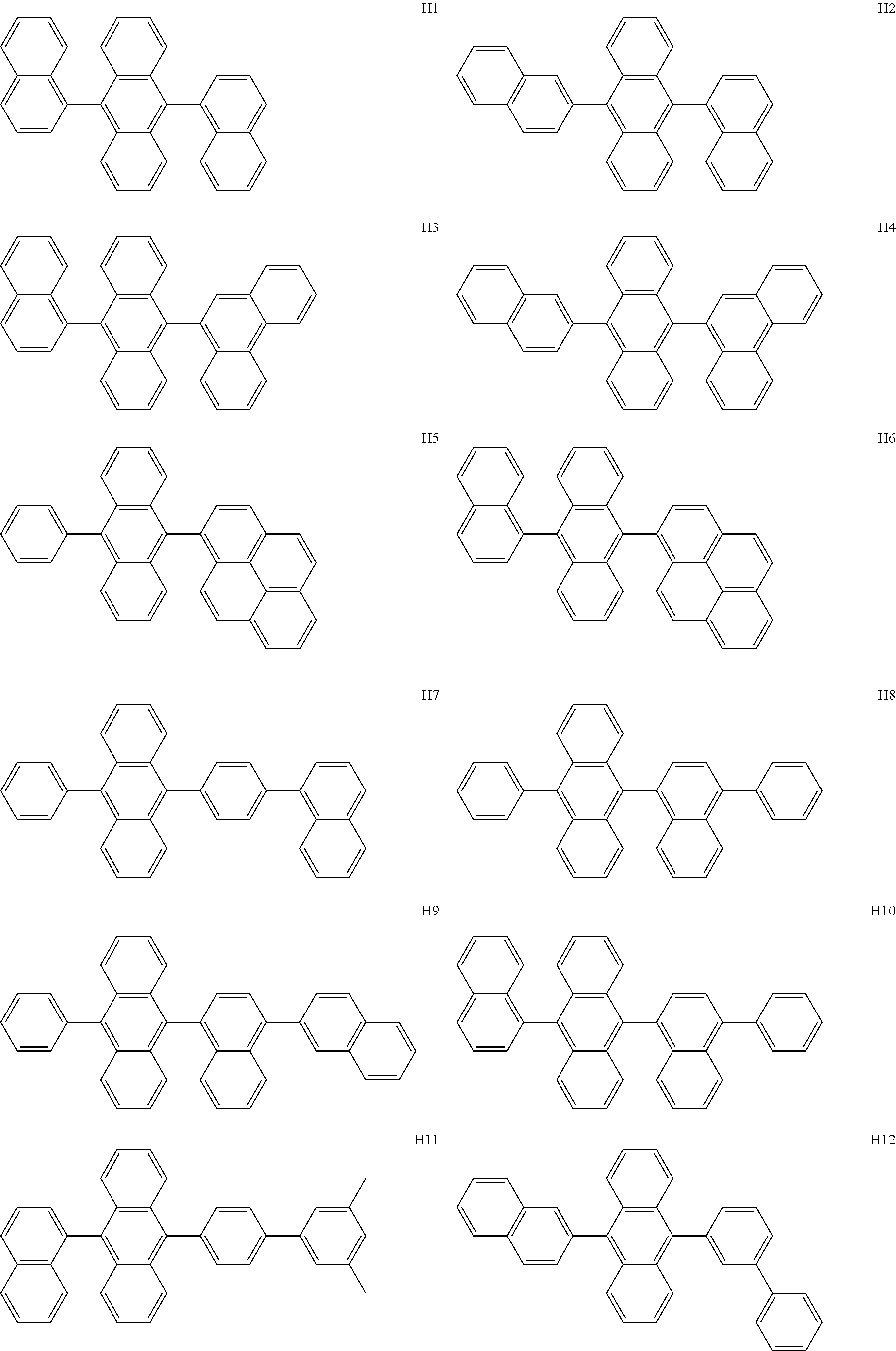

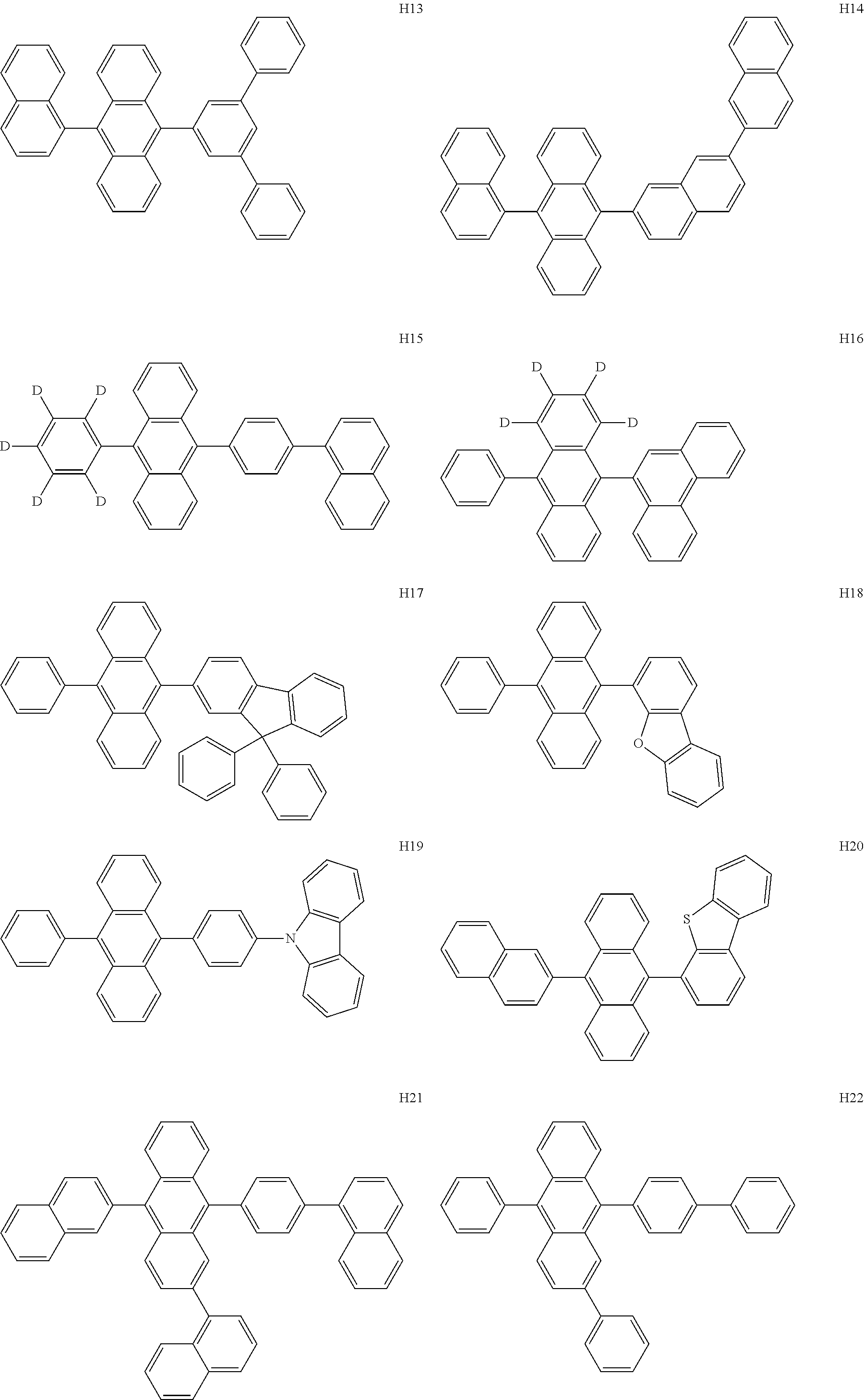

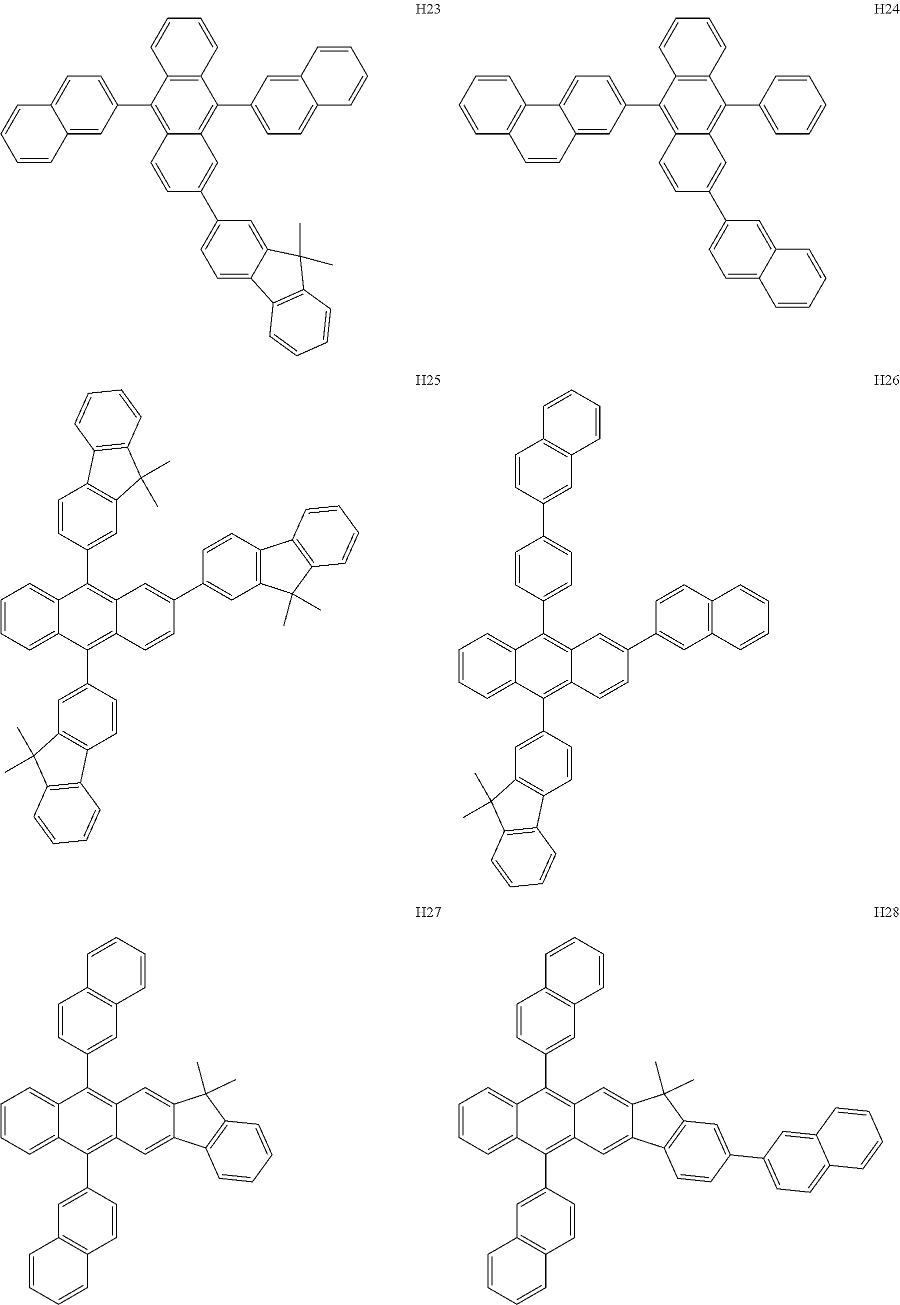

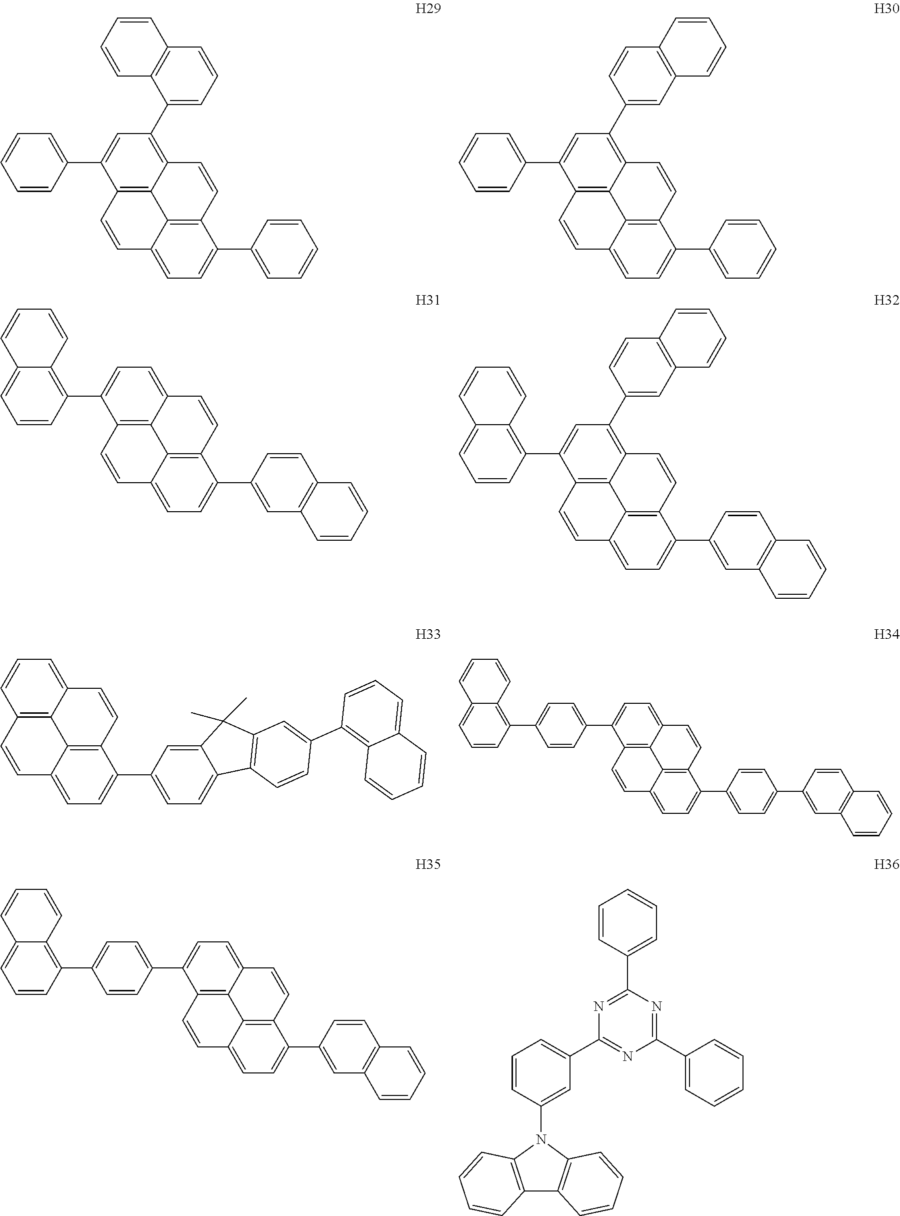

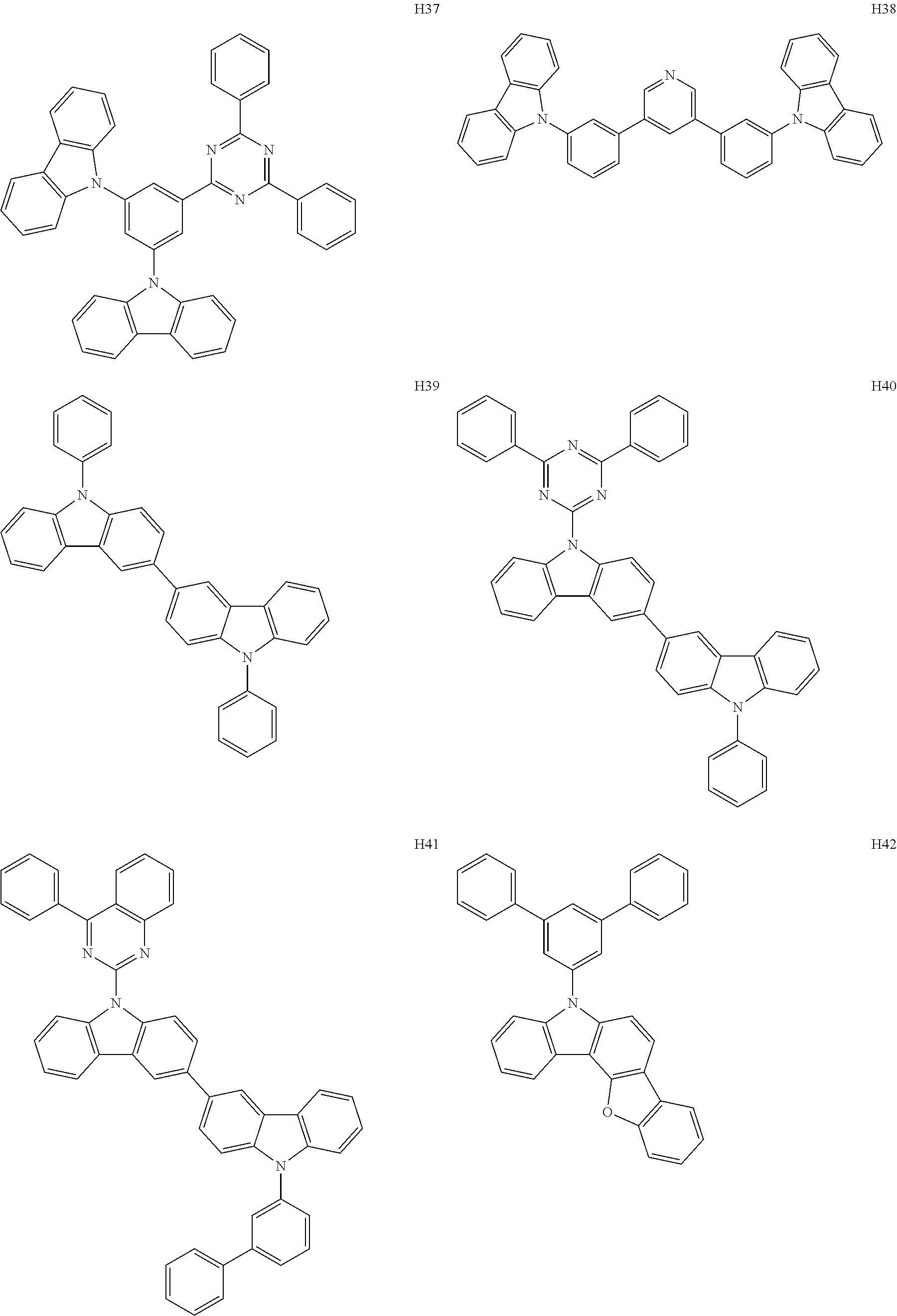

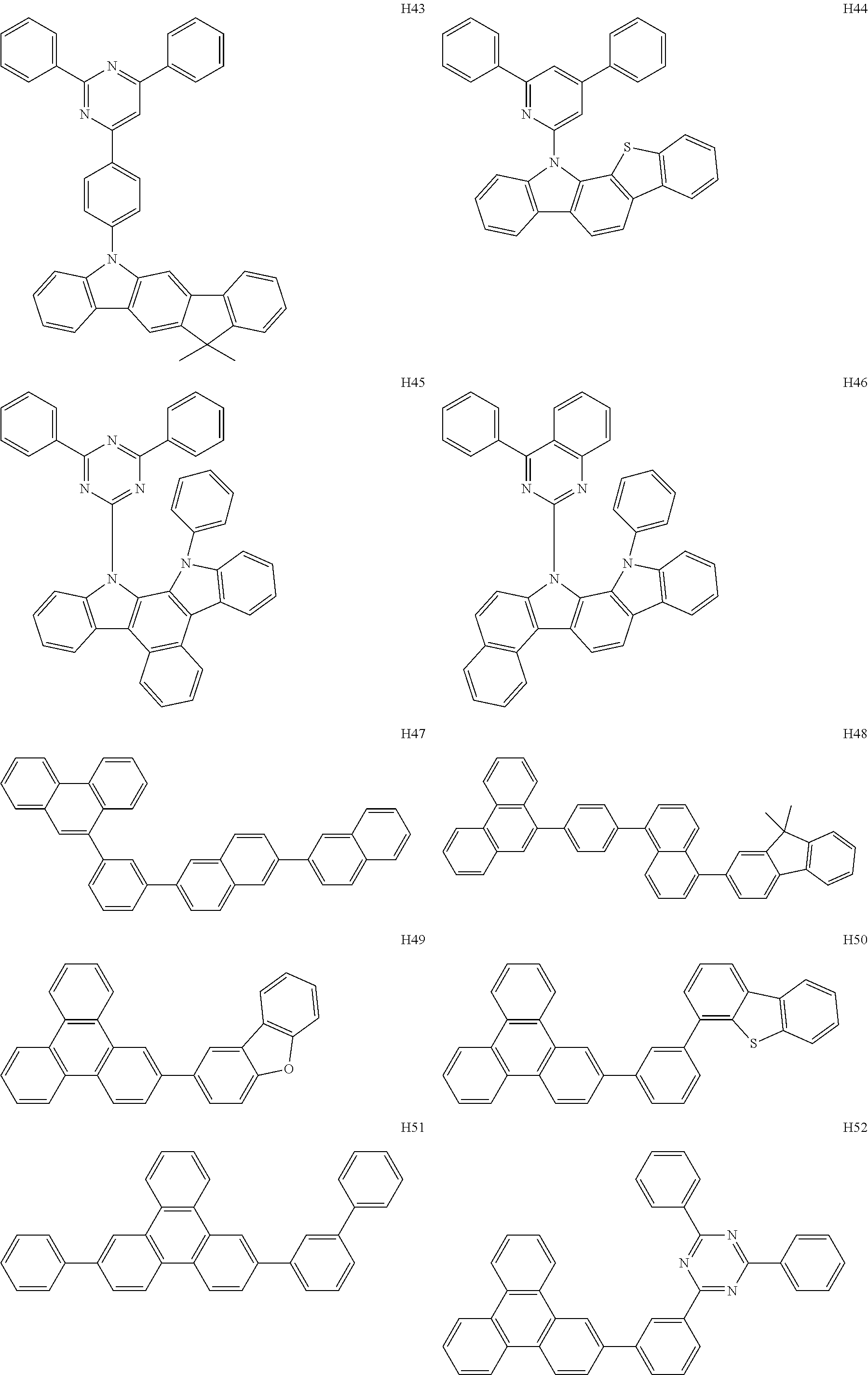

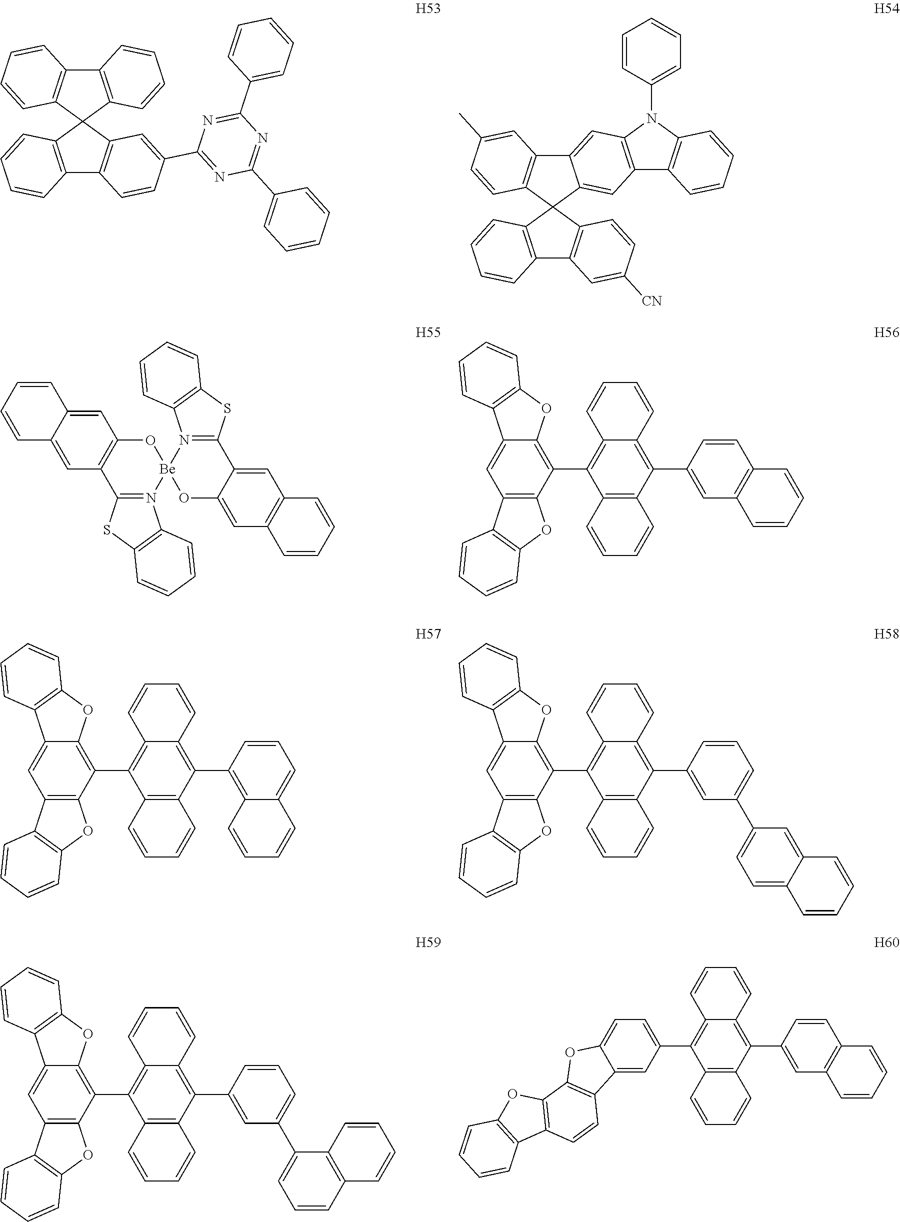

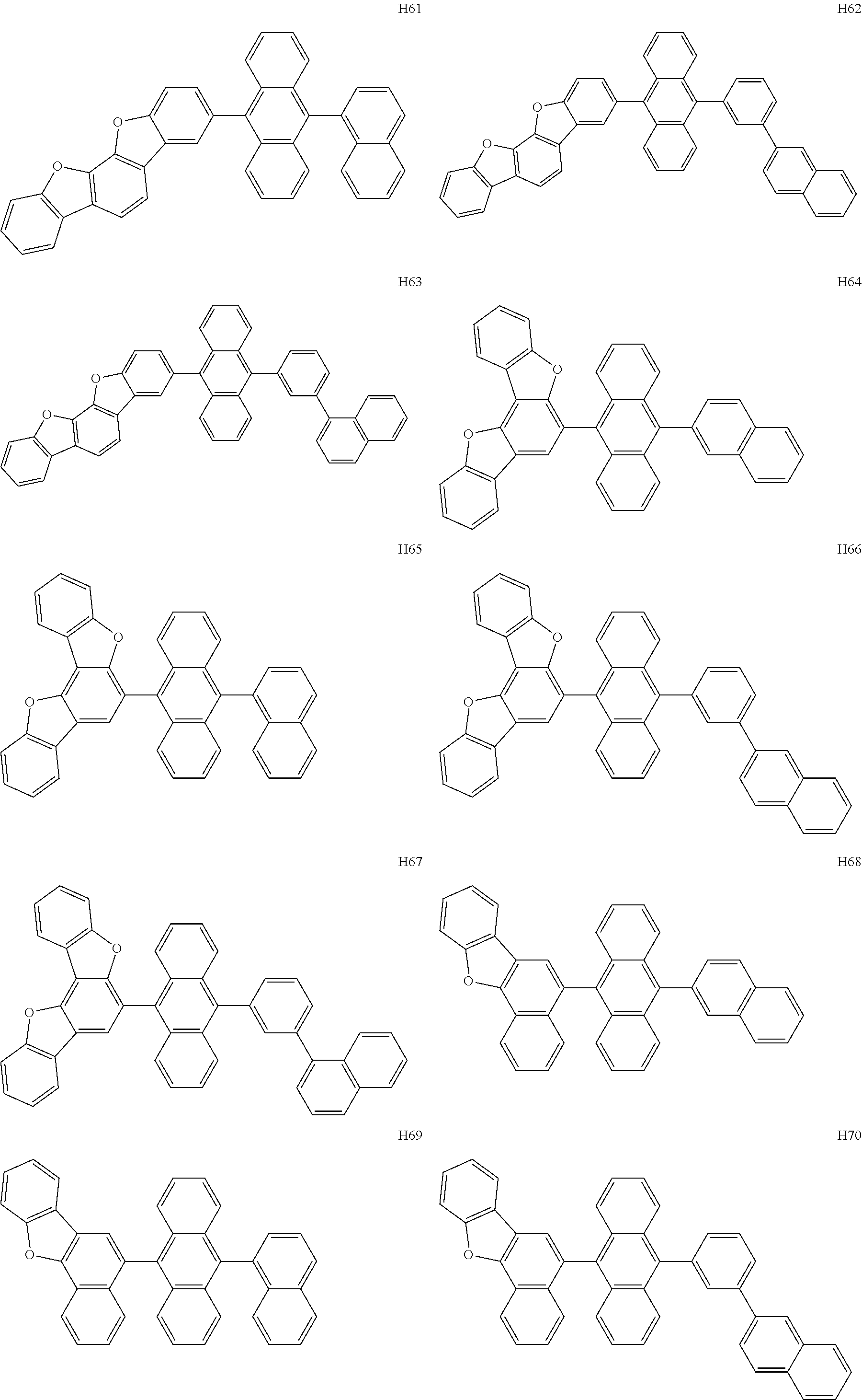

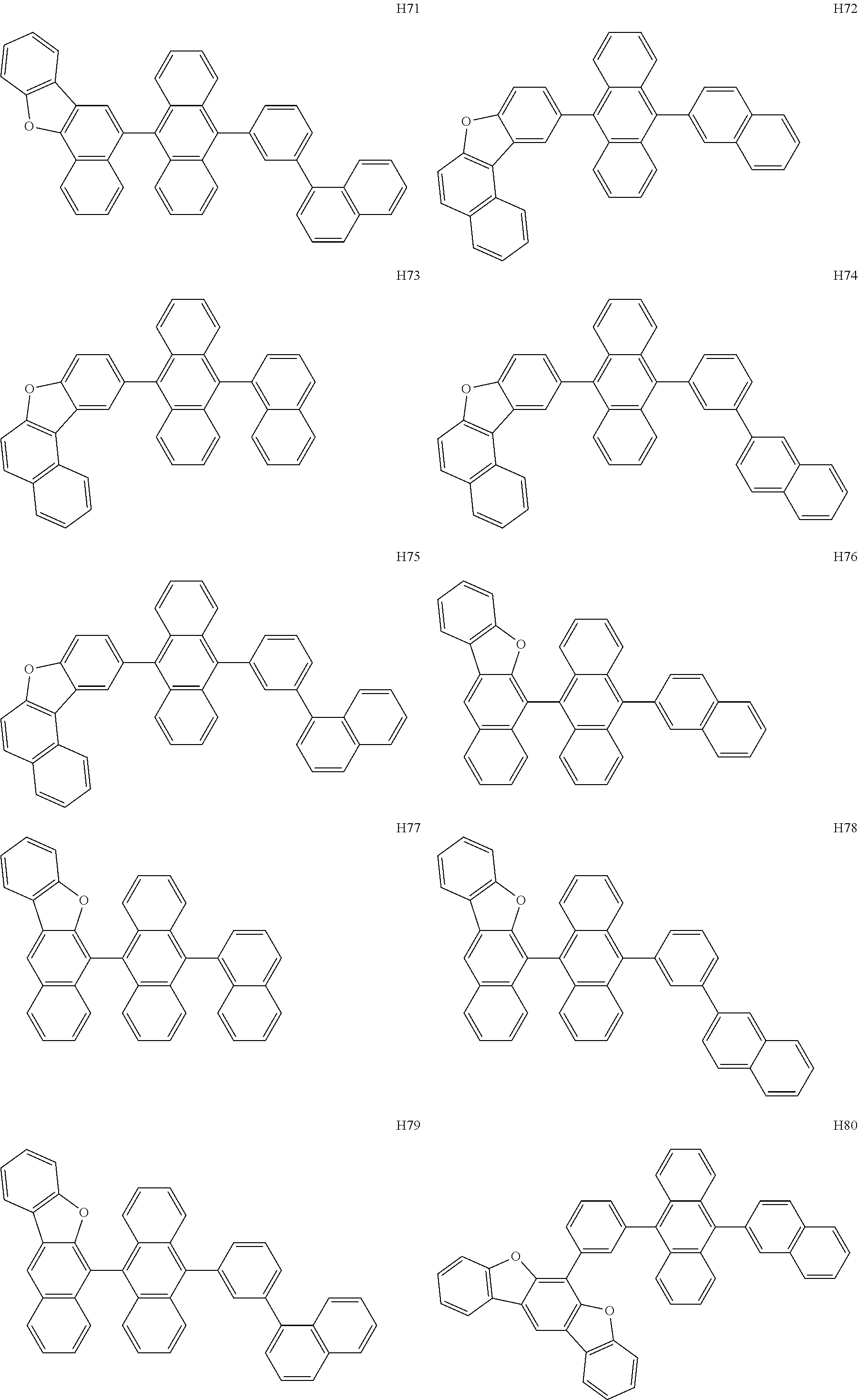

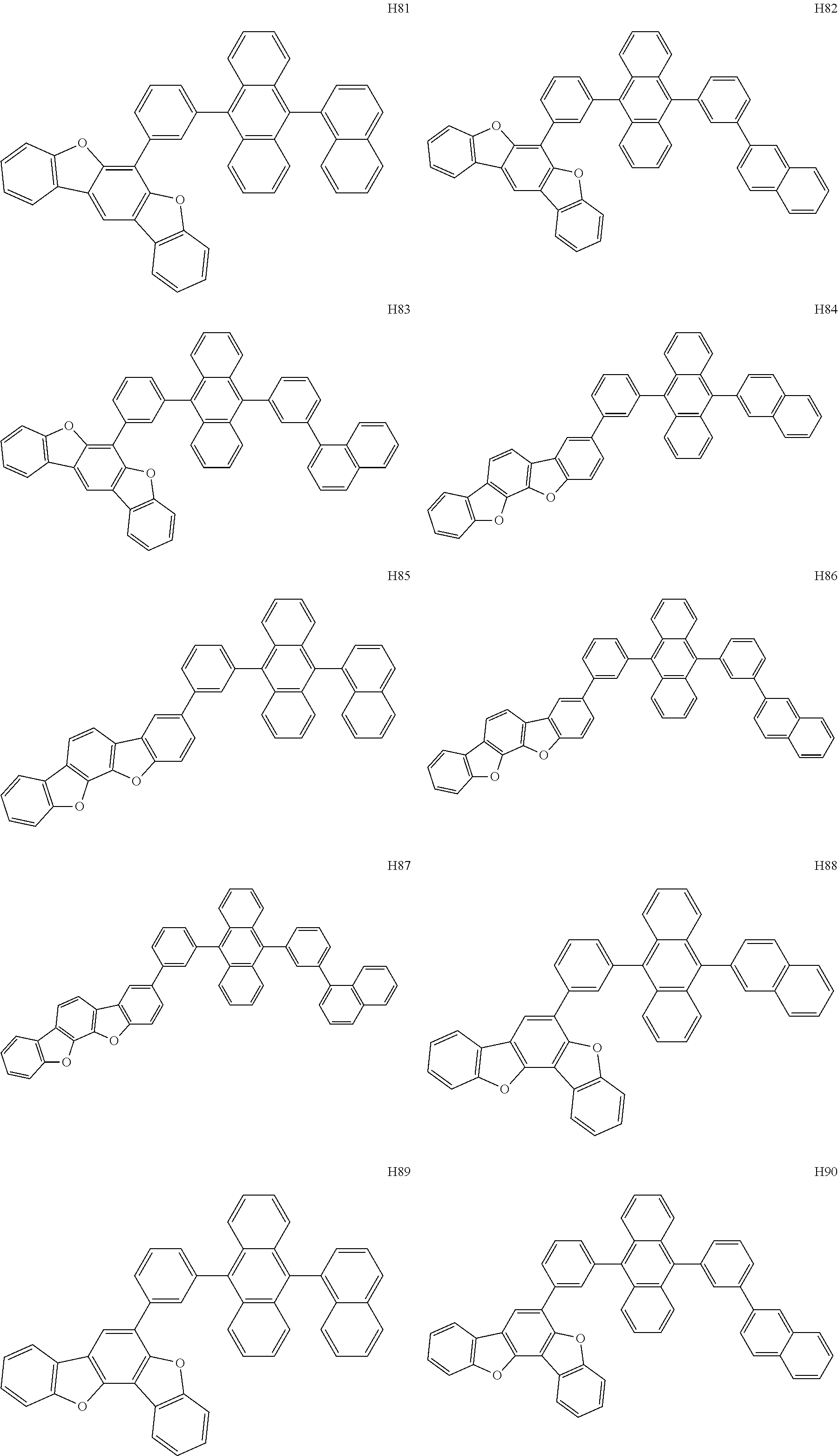

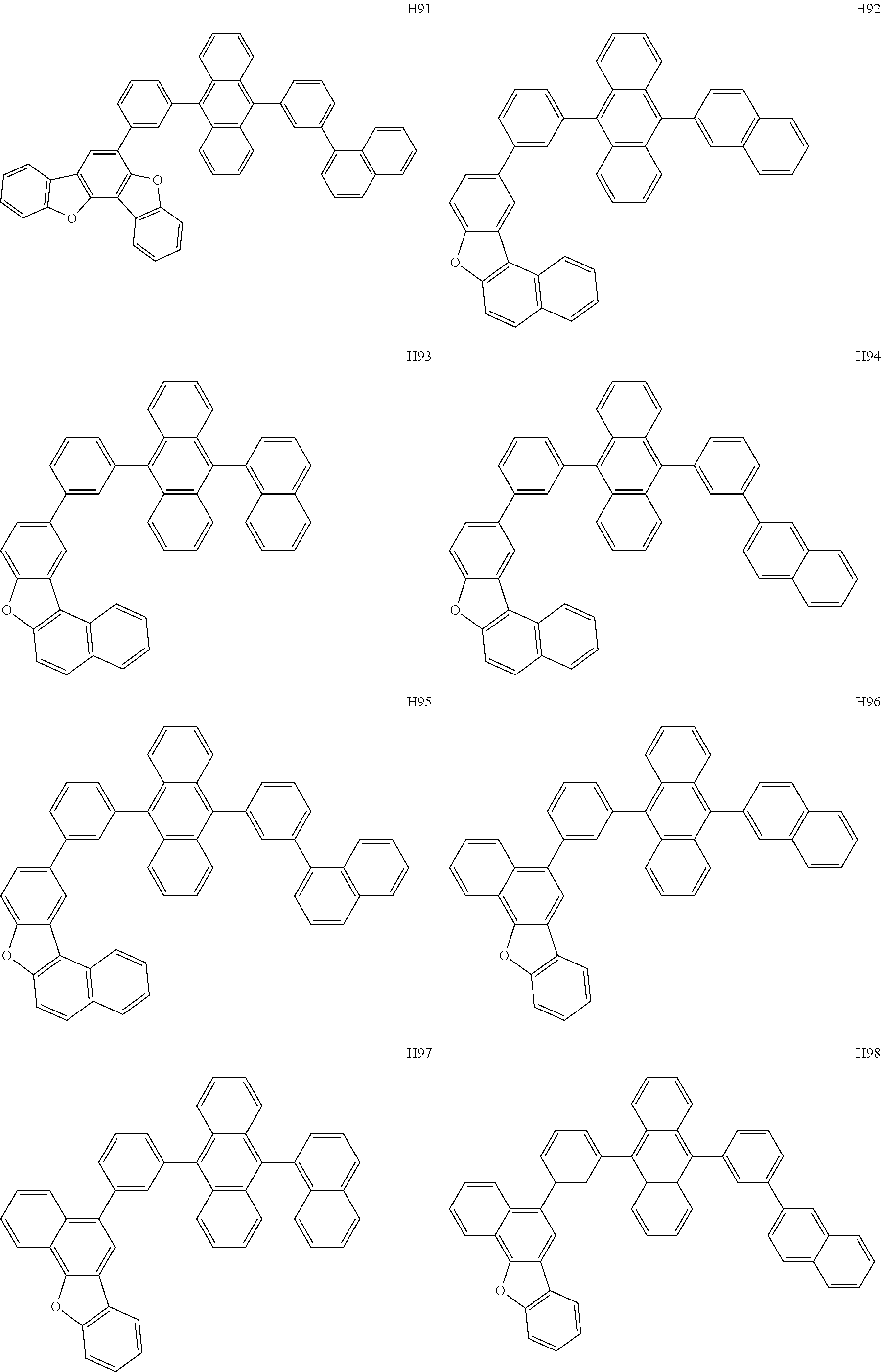

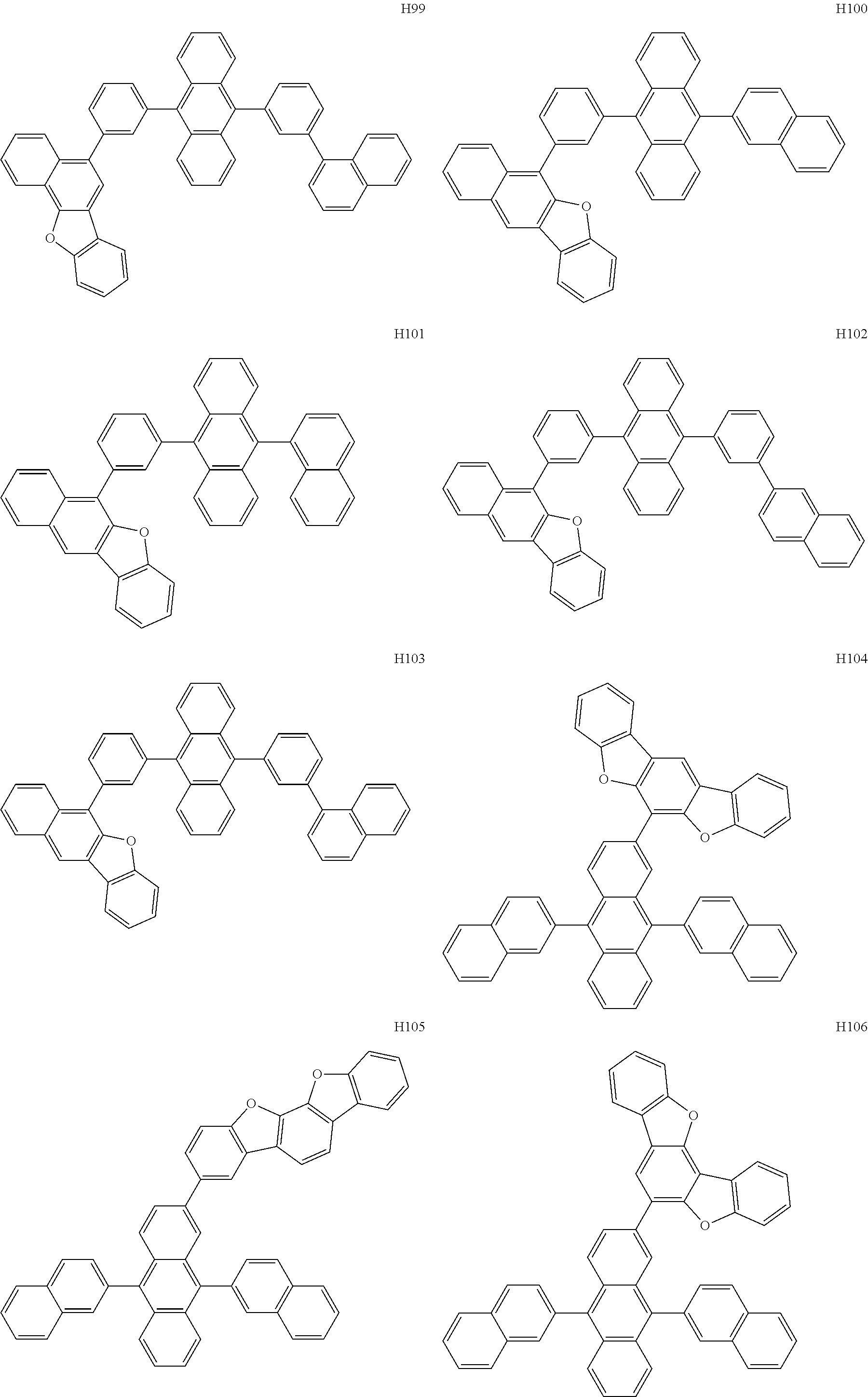

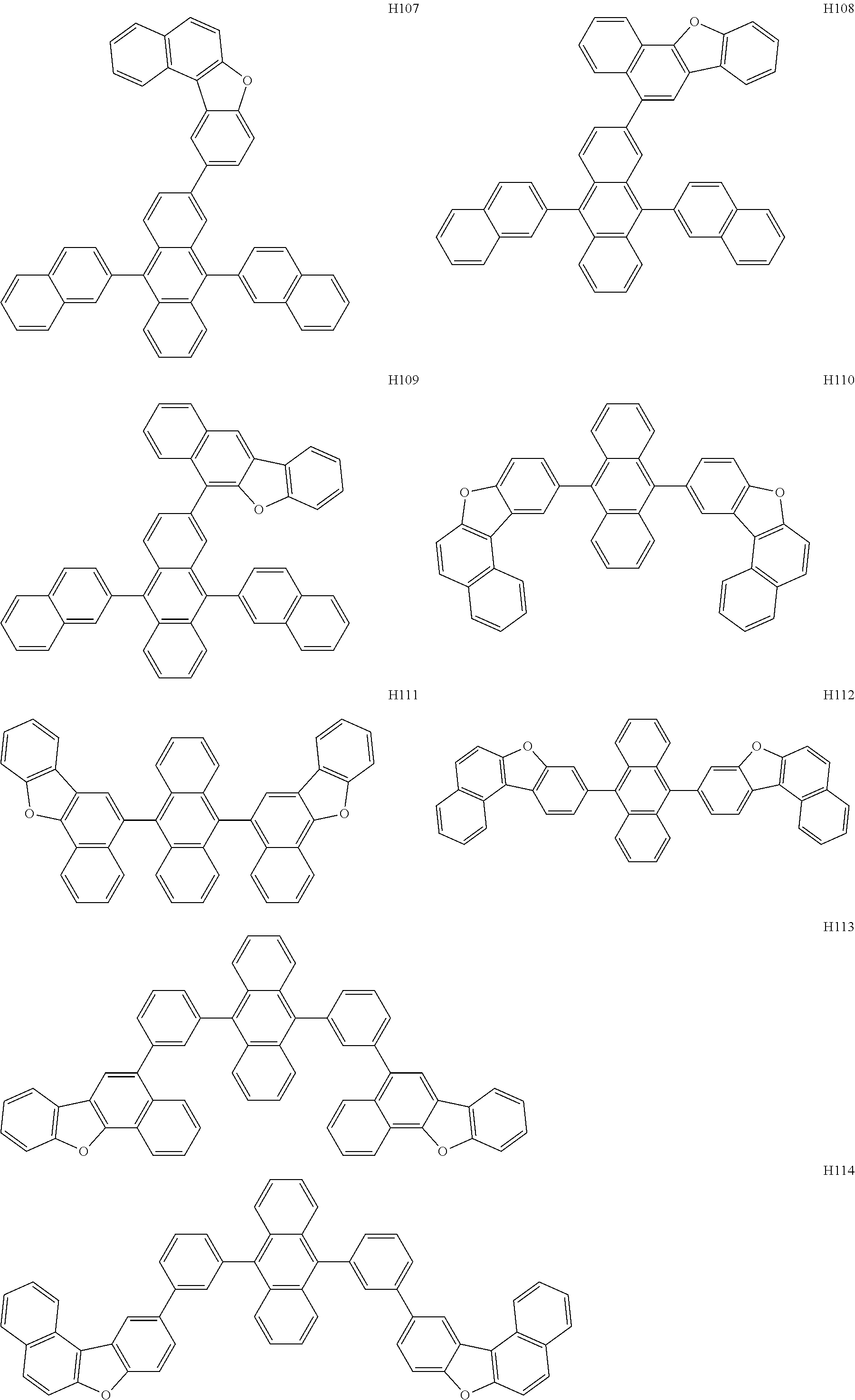

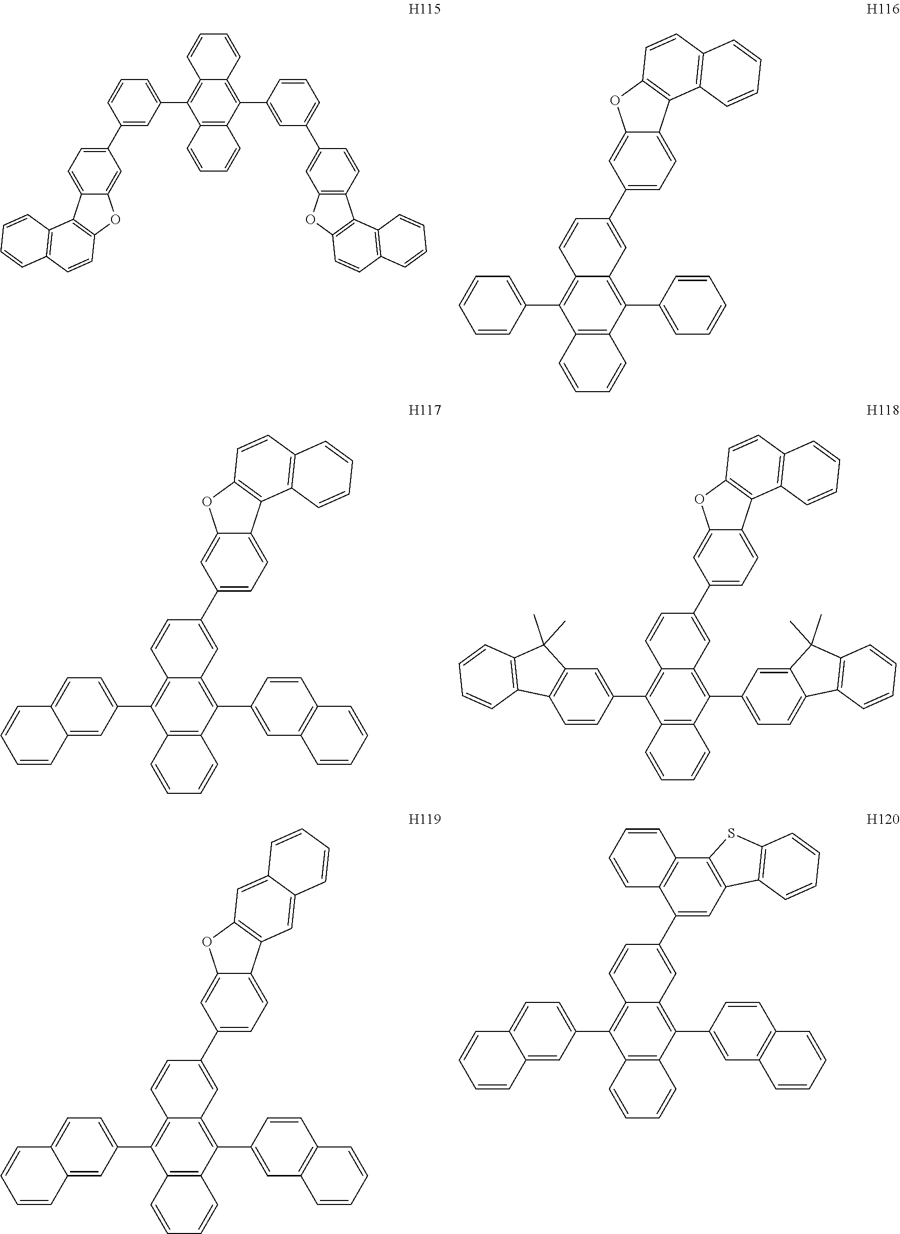

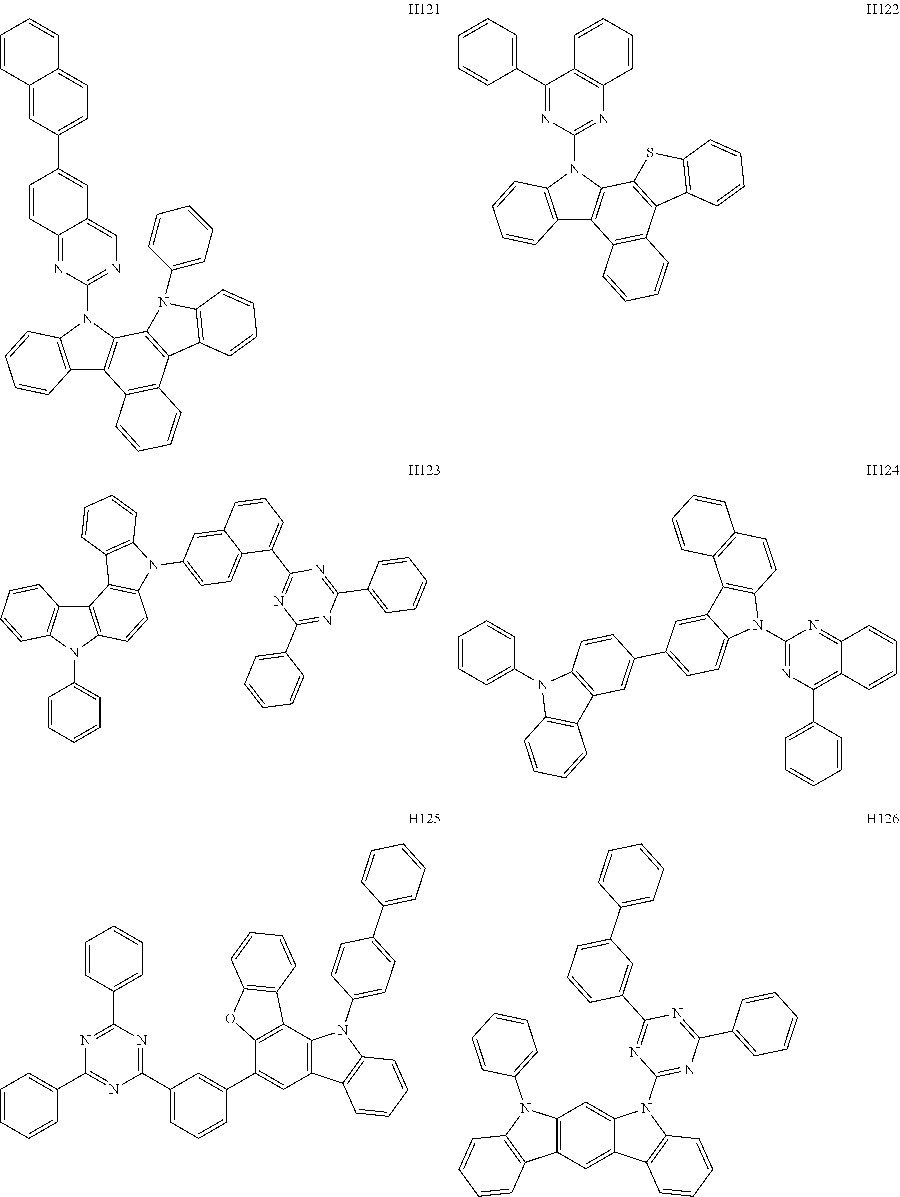

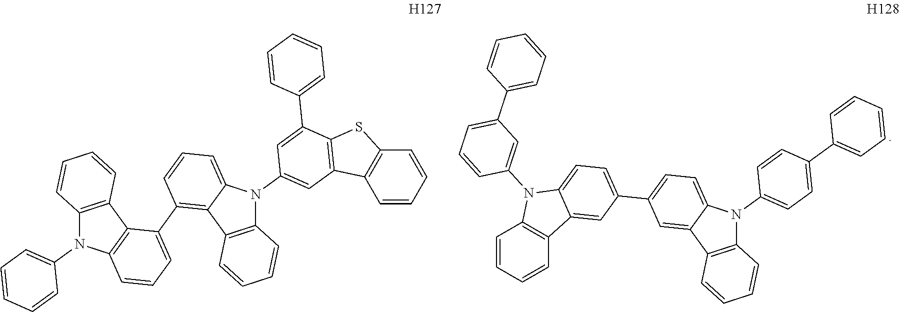

[Phosphorescent Dopant]

In some embodiments, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or a combination thereof.

The phosphorescent dopant may be electrically neutral.

For example, the phosphorescent dopant may include an organometallic compound represented by Formula 401:

M(L₄₀₁)_{xc1}(L₄₀₂)_{xc2} [Formula 401]

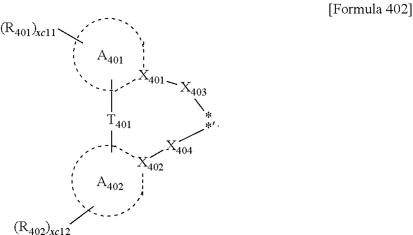

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is two or more, two or more of L₄₀₁(s) may be identical to or different from each other,
L₄₀₂ may be an organic ligand, and xc2 may be 0, 1, 2, 3, or 4, and when xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *═C(Q₄₁₁)=*′,
X₄₀₃ and X₄₀₄ may each independently be a chemical bond (for example, a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be as described for Q₁,
R₄₀₁ and R₄₀₂ may each independently be hydrogen, deuterium, —F, —Cl, —Br, —I, a hydroxyl group, a cyano group, a nitro group, a C₁-C₆₀) alkyl group unsubstituted or substituted with at least one R₁₀ₐ, a C₁-C₆₀) alkoxy group unsubstituted or substituted with at least one R₁₀ₐ, a C₃-C₆₀ carbocyclic group unsubstituted or substituted with at least one R₁₀ₐ, a C₁-C₆₀) heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be as described for Q₁,
xc11 and xc12 may each independently be an integer from 0 to 10, and
* and *′ in Formula 402 each may indicate a binding site to M in Formula 401.

For example, in Formula 402, X₄₀₁ may be nitrogen, and X₄₀₂ may be carbon, or each of X₄₀₁ and X₄₀₂ may be each nitrogen.

In some embodiments, in Formula 401, when xc1 in Formula 402 is 2 or more, two ring A₄₀₁(5) in two or more of L₄₀₁(5) may be optionally linked to each other via T₄₀₂, which is a linking group, or two ring A₄₀₂(5) may be optionally linked to each other via T₄₀₃, which is a linking group (see Compounds PD1 to PD4 and PD7). T₄₀₂ and T₄₀₃ may each independently be as described for T₄₀₁.

L₄₀₂ in Formula 401 may be an organic ligand. For example, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or a combination thereof.

The phosphorescent dopant may include, for example, one of compounds PD1 to PD39, or a combination thereof:

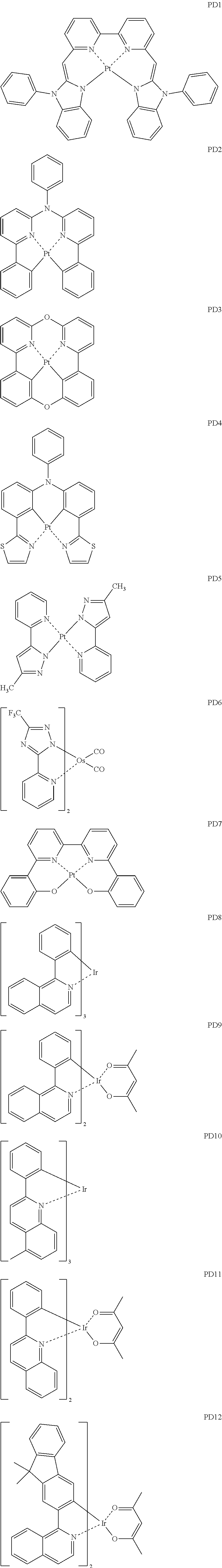

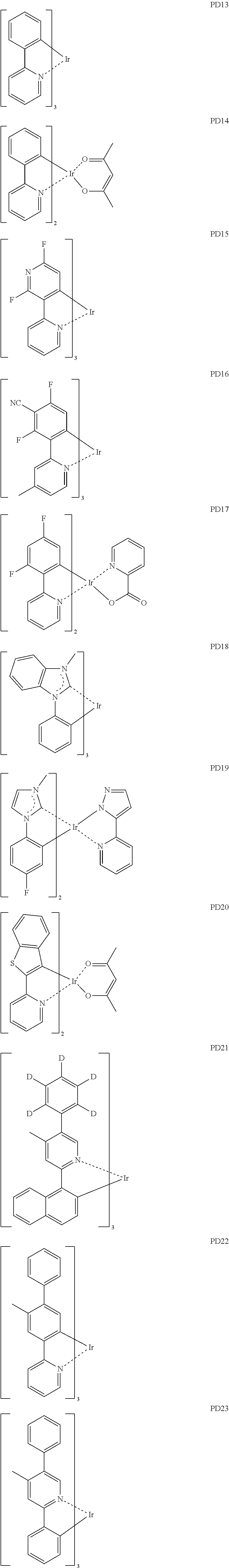

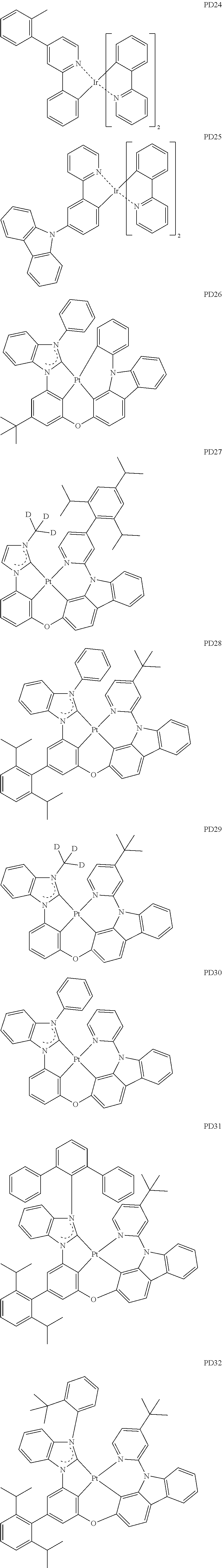

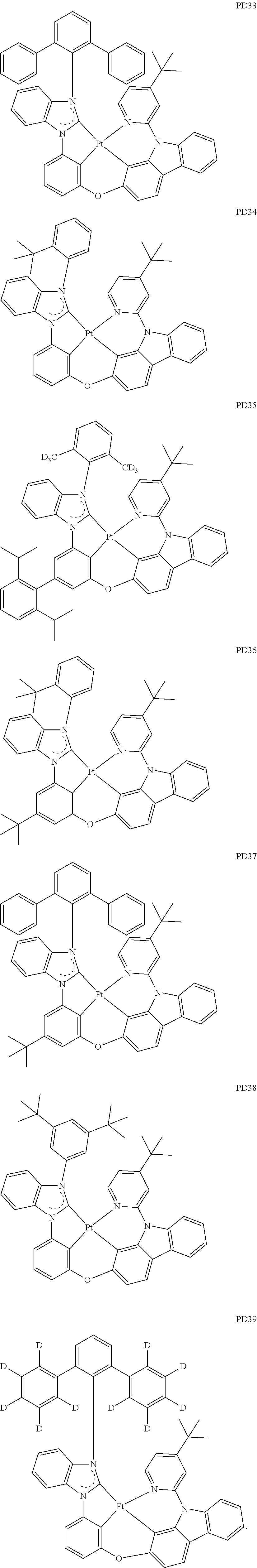

[Fluorescent Dopant]

The fluorescent dopant may include an amine group-containing compound, a styryl group-containing compound, or a combination thereof.

For example, the fluorescent dopant may include a compound represented by Formula 501:

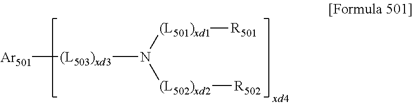

In Formula 501,
Ar₆₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, in Formula 501, Ar₆₀₁ may be a condensed cyclic group (for example, an anthracene group, a chrysene group, or a pyrene group) in which three or more monocyclic groups are condensed together.

In some embodiments, in Formula 501, xd4 may be 2.

In an embodiment, the fluorescent dopant may include: one of Compounds FD1 to FD37; DPVBi; DPAVBi; or a combination thereof:

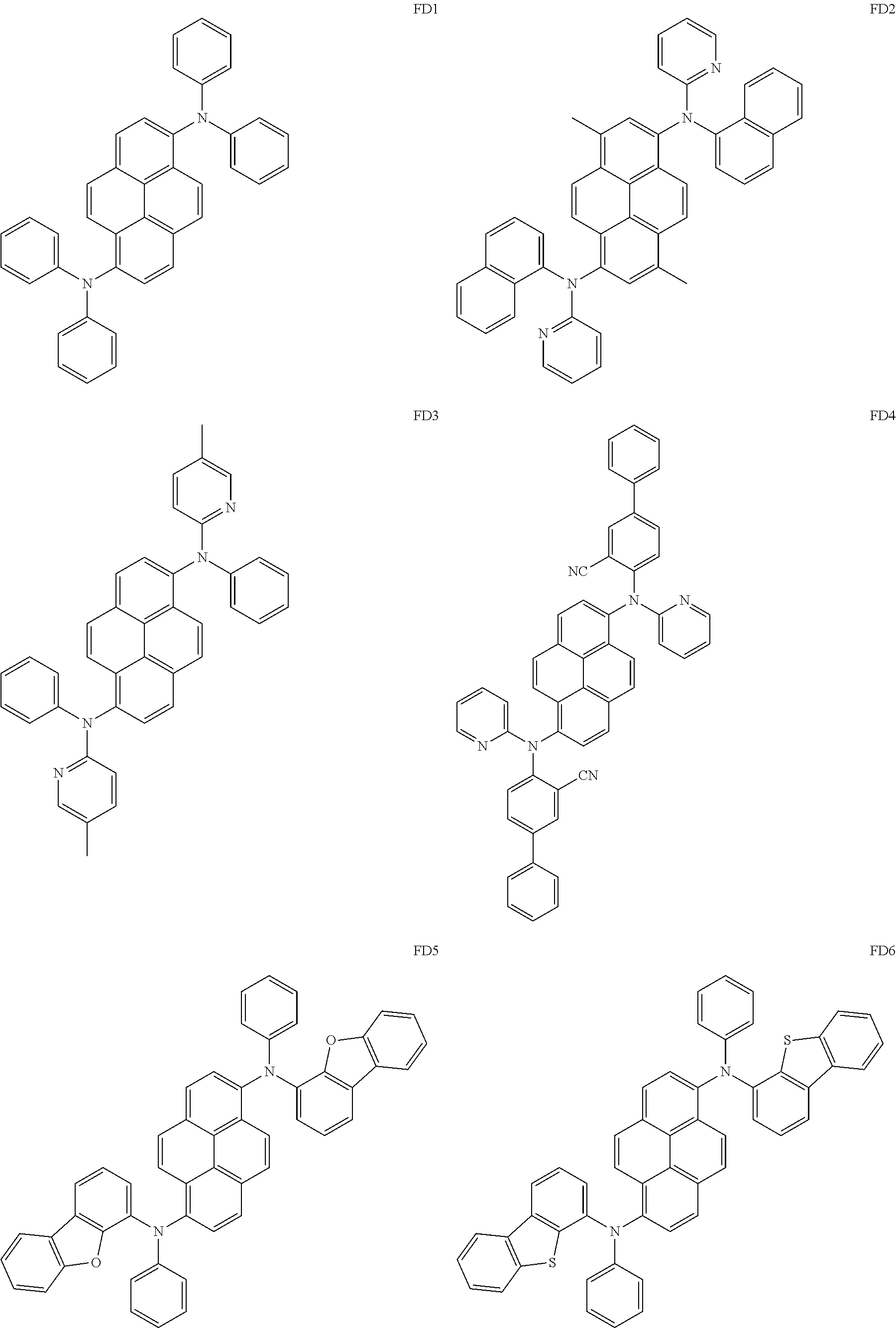

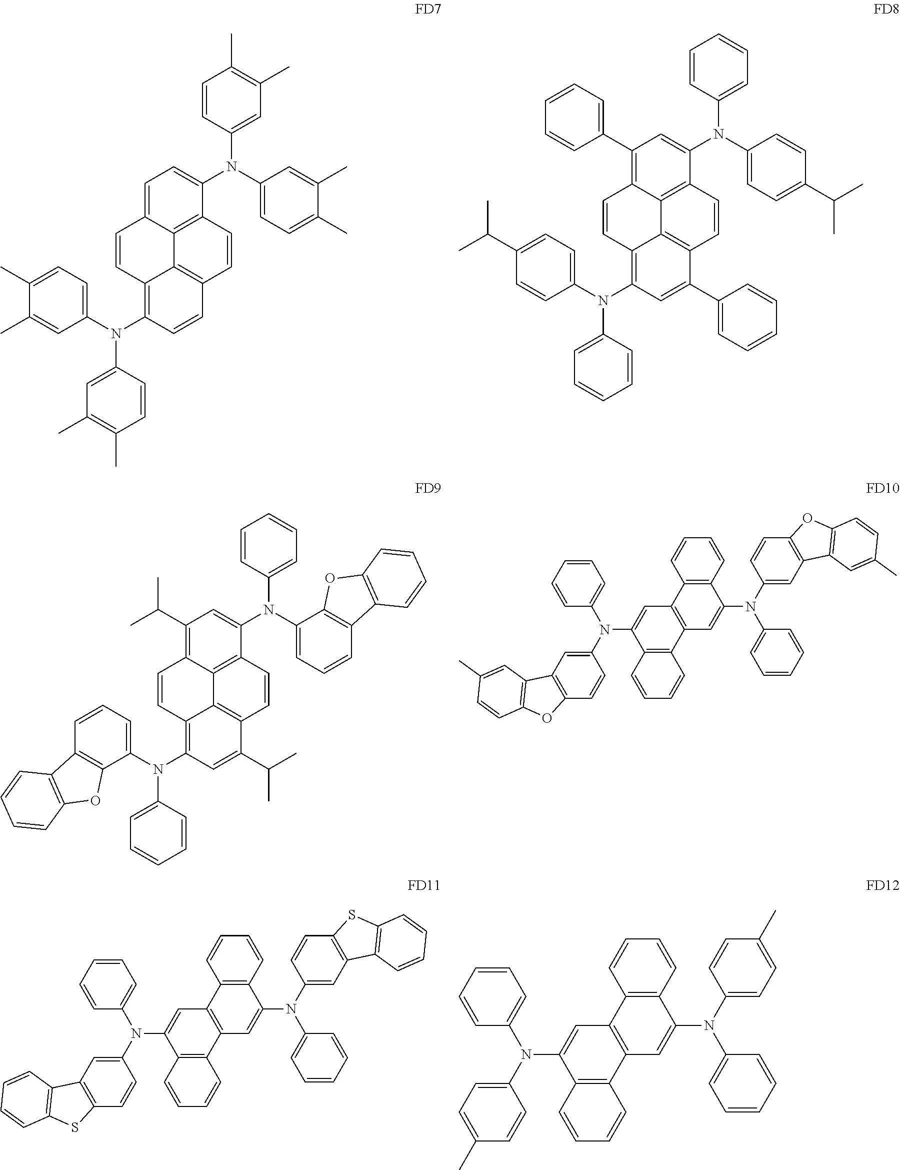

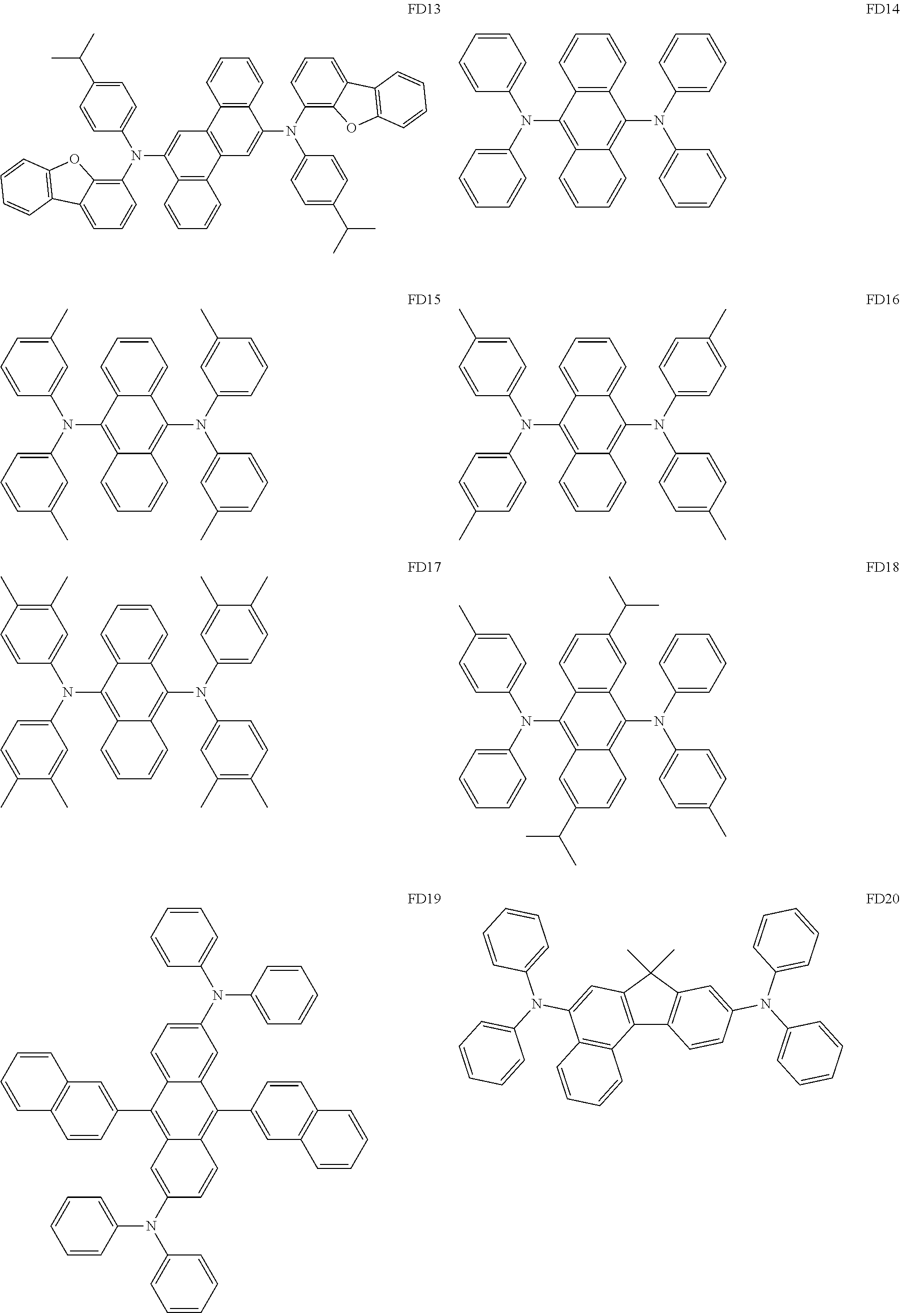

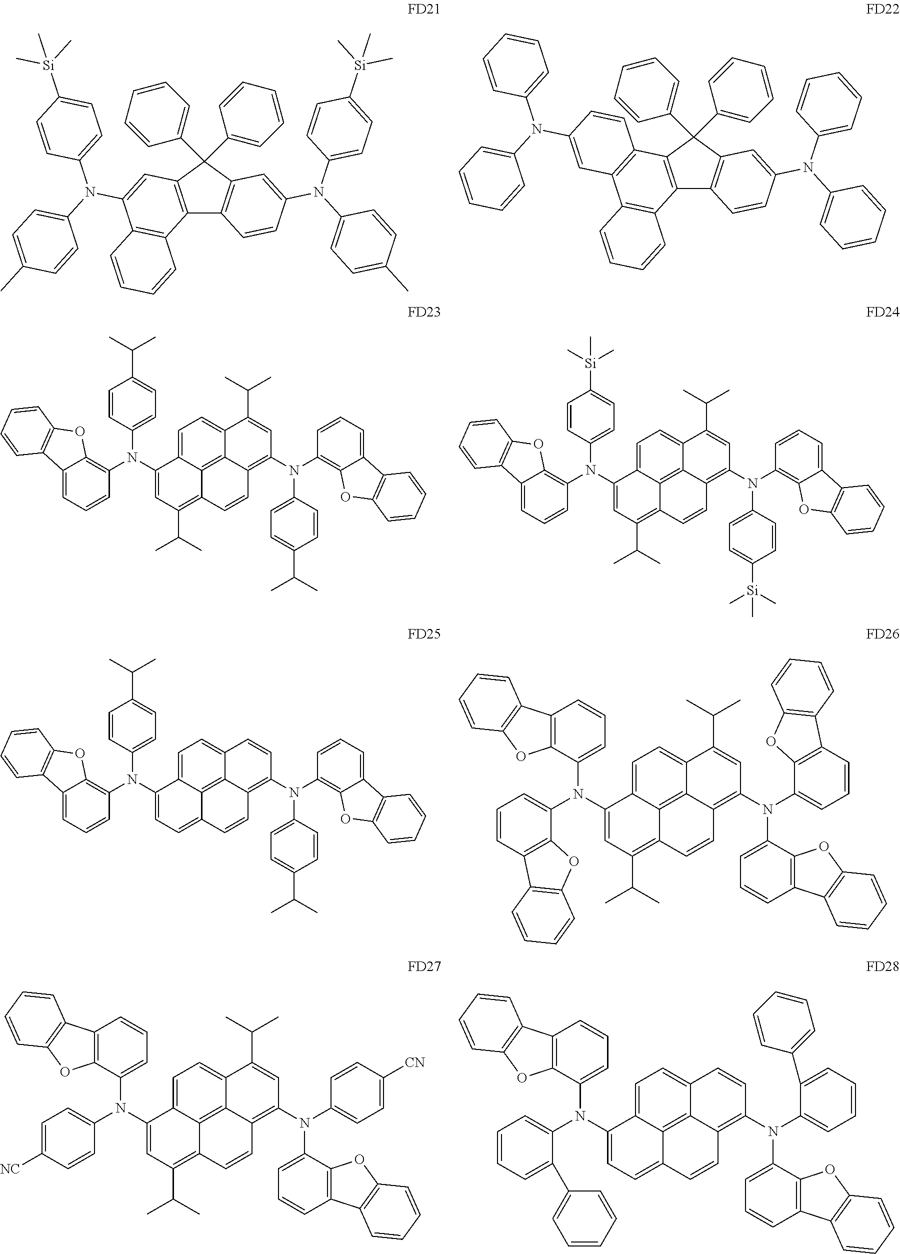

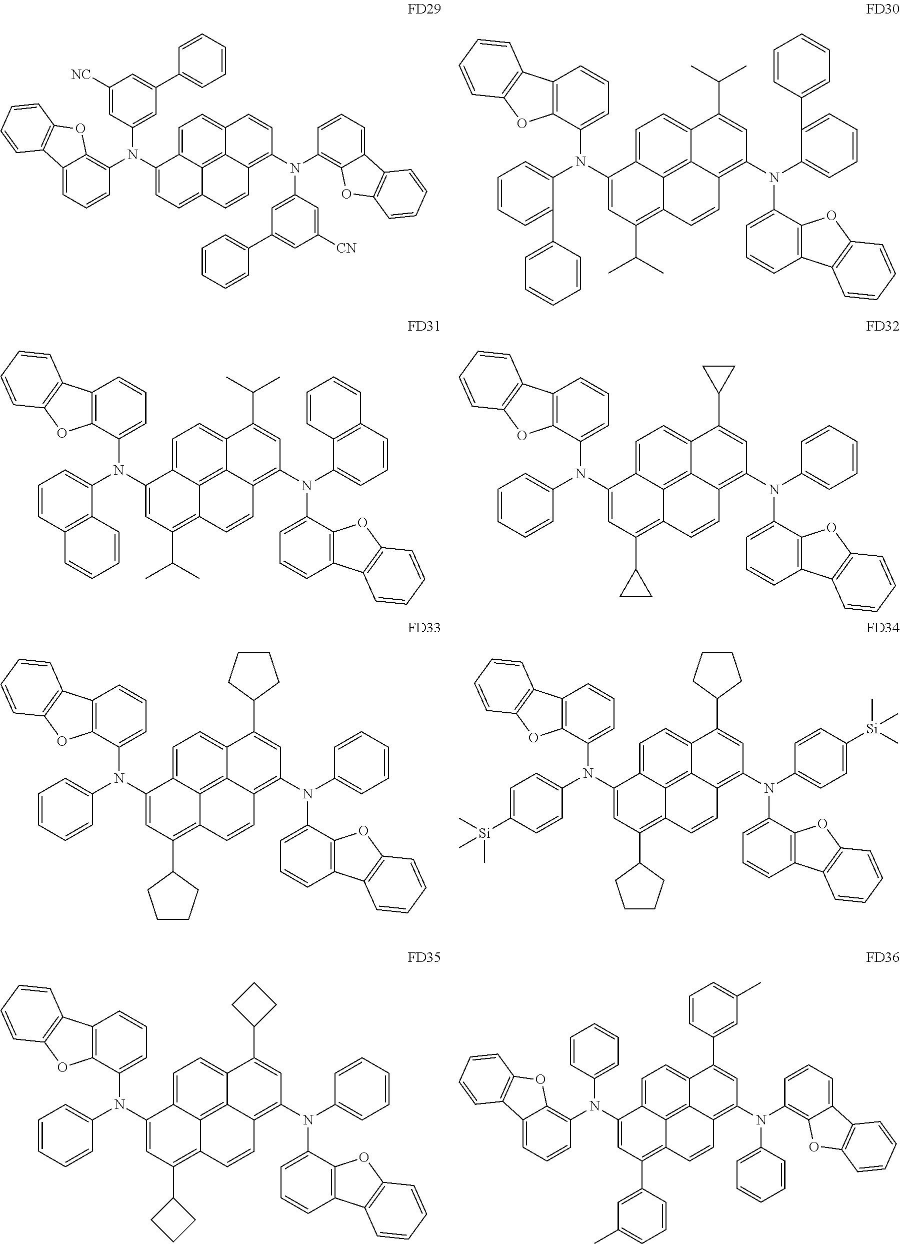

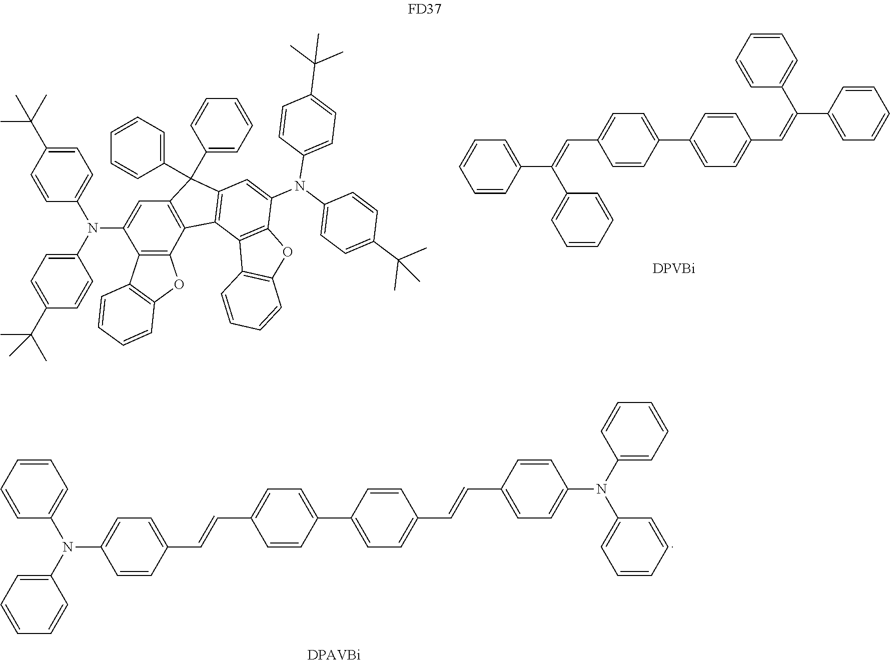

[Delayed Fluorescence Material]

The emission layer may include a delayed fluorescence material.

In the specification, a delayed fluorescence material may be selected from compounds capable of emitting delayed fluorescent light based on a delayed fluorescence emission mechanism.

The delayed fluorescence material included in the emission layer may serve as a host or as a dopant depending on the types of other materials included in the emission layer.

In some embodiments, the difference between the triplet energy level (eV) of the delayed fluorescence material and a singlet energy level (eV) of the delayed fluorescence material may be in a range of about 0 eV to about 0.5 eV. When a difference between a triplet energy level (eV) of the delayed fluorescence material and a singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be improved.

In embodiments, the delayed fluorescence material may include a material including at least one electron donor (for example, a π electron-rich C₃-C₆₀ cyclic group, such as a carbazole group) and at least one electron acceptor (for example, a sulfoxide group, a cyano group, or air electron-deficient nitrogen-containing C₁-C₆₀ cyclic group); or a material including a C₈-C₆₀ polycyclic group in which two or more cyclic groups are condensed while sharing boron (B); or the like.

Examples of a delayed fluorescence material may include at least one of Compounds DF1 to DF14:

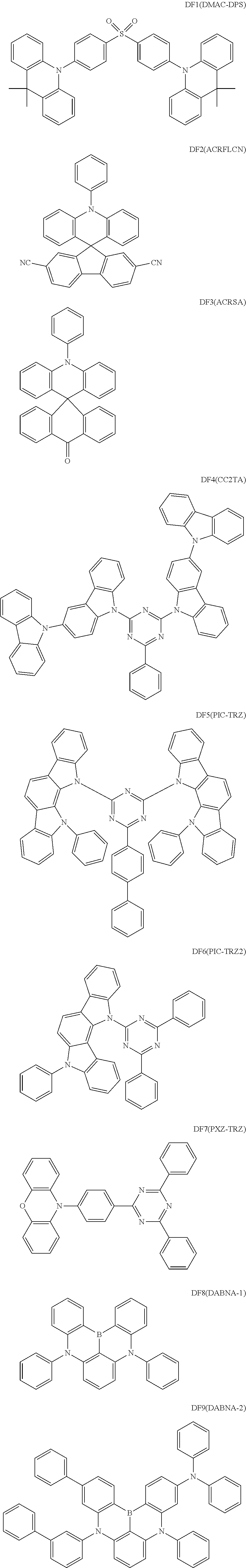

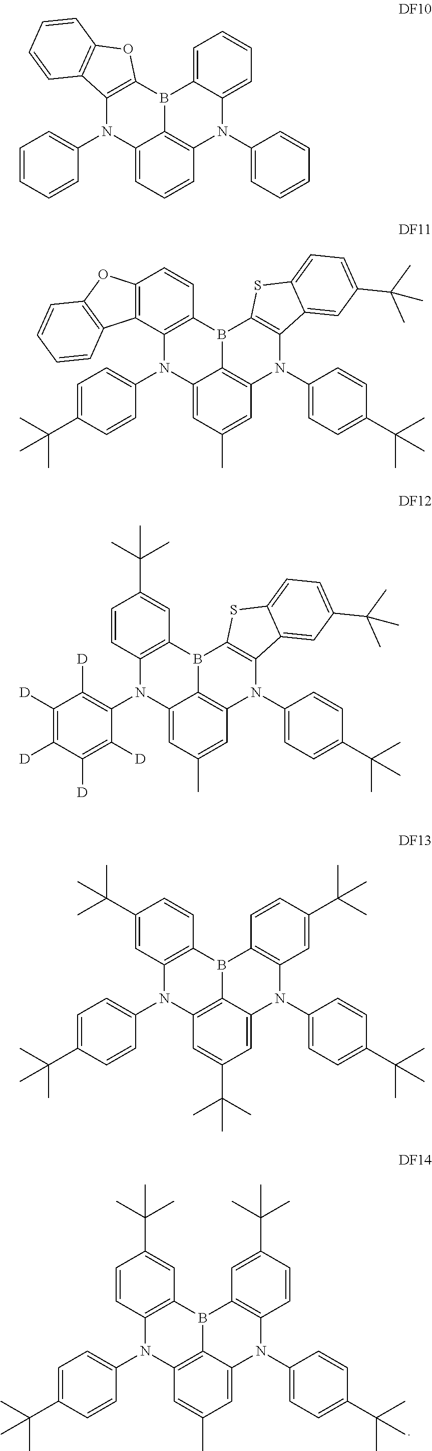

[Quantum Dot]

The emission layer may include a quantum dot.

In the specification, a quantum dot may be a crystal of a semiconductor compound, and may include any material capable of emitting light of various emission wavelengths according to a size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing a quantum dot particle crystal. When the crystal grows, the organic solvent naturally serves as a dispersant coordinated on the surface of the quantum dot crystal and controls the growth of the crystal so that the growth of quantum dot particles can be controlled through a process which costs less, and may be more readily performed than vapor deposition methods, such as metal organic chemical vapor deposition (MOCVD) or molecular beam epitaxy (MBE),

The quantum dot may include Group II-VI semiconductor compounds, Group III-V semiconductor compounds, Group III-VI semiconductor compounds, Group I-III-VI semiconductor compounds, Group IV-VI semiconductor compounds, a Group IV element or compound, or a combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or a combination thereof.

Examples of a Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or a combination thereof. A Group III-V semiconductor compound may further include a Group II element. Examples of a Group III-V semiconductor compound further including a Group II element may include InZnP, InGaZnP, InAlZnP, etc.

Examples of a Group III-VI semiconductor compound may include: a binary compound, such as GaS, GaSe, Ga₂Se₃, GaTe, InS, InSe, In₂S₃, In₂Se₃, or InTe; a ternary compound, such as InGaS₃, or InGaSe₃; and a combination thereof.

Examples of a Group I-III-VI semiconductor compound may include: a ternary compound, such as AgInS, AgInS₂, CuInS, CuInS₂, CuGaO₂, AgGaO₂, or AgAlO₂; or a combination thereof.

Examples of a Group 1V-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or a combination thereof.

Examples of a Group IV element or compound may include: a single element material, such as Si or Ge; a binary compound, such as SiC or SiGe; or a combination thereof.

Each element included in a multi-element compound such as a binary compound, a ternary compound, or a quaternary compound, may be present in a particle at a uniform concentration or at a non-uniform concentration.

In an embodiment, the quantum dot may have a single structure in which the concentration of each element in the quantum dot is uniform, or the quantum dot may have a core-shell structure. In an embodiment, in case that the quantum dot has a core-shell structure, the material included in the core and the material included in the shell may be different from each other.

The shell of the quantum dot may serve as a protective layer that prevents chemical degeneration of the core to maintain semiconductor characteristics, and/or may serve as a charging layer that imparts electrophoretic characteristics to the quantum dot. The shell may be a single-layer or a multi-layer. An interface between the core and the shell may have a concentration gradient in which the concentration of a material that is present in the shell decreases toward the core.

Examples of a shell of the quantum dot may include a metal oxide, a metalloid oxide, a non-metal oxide, a semiconductor compound, or a combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; and a combination thereof.

Examples of a semiconductor compound may include, as described herein, a Group II-VI semiconductor compound, a Group III-V semiconductor compound, a Group III-VI semiconductor compound, a Group I-III-VI semiconductor compound, a Group IV-VI semiconductor compound, and a combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

A full width at half maximum (FWHM) of the emission wavelength spectrum of the quantum dot may be about 45 nm or less. For example, the FWHM of the emission wavelength spectrum of the quantum dot may be about 40 nm or less. For example, the FWHM of the emission wavelength spectrum of the quantum dot may be about 30 nm or less. When the FWHM of the quantum dot is within these ranges, color purity or color reproducibility may be increased. Light emitted through a quantum dot may be emitted in all directions, so that a wide viewing angle may be improved.

In embodiments, the quantum dot may be in the form of a spherical particle, a pyramidal particle, a multi-arm particle, a cubic nanoparticle, a nanotube particle, a nanowire particle, a nanofiber particle, or a nanoplate particle.

Since the energy band gap may be adjusted by controlling the size of the quantum dot, light having various wavelength bands may be obtained from a quantum dot emission layer. Accordingly, by using quantum dots of different sizes, a light-emitting device that emits light of various wavelengths may be implemented. In some embodiments, the size of the quantum dot may be selected to emit red, green, and/or blue light. In an embodiment, the size of the quantum dot may be configured to emit white light by a combination of light of various colors.

[Electron Transport Region in Interlayer 130]

The electron transport region may have a structure consisting of a layer consisting of a single material, a structure consisting of a layer including different materials, or a structure including multiple layers including different materials.

The electron transport region may include a buffer layer, a hole blocking layer, an electron control layer, an electron transport layer, an electron injection layer, or a combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked from an emission layer in its respective stated order. However, the structure of the electron transport region is not limited thereto.

In embodiments, the electron transport region (for example, a buffer layer, a hole blocking layer, an electron control layer, or an electron transport layer in the electron transport region) may include a metal-free compound including at least one π electron-deficient nitrogen-containing C₁-C₆₀ cyclic group.

In embodiments, the electron transport region may include a compound represented by Formula 601:

[Ar₆₀₁]ₓₑ₁₁-[(L₆₀₁)ₓₑ₁-R₆₀₁]ₓₑ₂₁ [Formula 601]

In Formula 601,
Ar₆₀₁ and L₆₀₁ may each independently be a C₃-C₆₀ carbocyclic group unsubstituted or substituted with at least one R₁₀ₐ or a C₁-C₆₀) heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀) heterocyclic group unsubstituted or substituted with at least one R₁₀ₐ, —Si(Q₆₀₁)(Q₆₀₂)(Q₆₀₃), —C(═O)(Q₆₀₁), —S(═O)₂ (Q₆₀₁), or —P(═O)(Q₆₀₁)(Q₆₀₂),
Q₆₀₁ to Q₆₀₃ may each independently be as described for Q₁,
xe21 may be 1, 2, 3, 4, or 5,
at least one of Ar₆₀₁, L₆₀₁, and R₆ₒ₁ may each independently be air electron-deficient nitrogen-containing C₁-C₆₀ cyclic group unsubstituted or substituted with at least one R₁₀ₐ.

For example, in Formula 601, when xe11 is 2 or more, two or more of Ar₆₀₁(s) may be linked to each other via a single bond.

In other embodiments, in Formula 601, Ar₆₀₁ in Formula 601 may be a substituted or unsubstituted anthracene group.

In other embodiments, the electron transport region may include a compound represented by Formula 601-1:

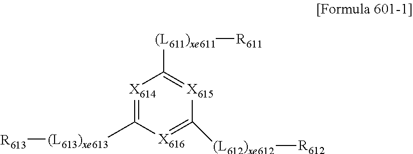

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each independently be N,
L₆₁₁ to L₆₁₃ may each independently be as described for L₆₀₁,
xe611 to xe613 may each independently be as described for xe1,
R₆₁₁ to R₆₁₃ may each independently be as described for R₆₀₁, and
R₆₁₄ to R₆₁₆ may each independently be hydrogen, deuterium, —F, —Cl, —Br, —I, a hydroxyl group, a cyano group, a nitro group, a C₁-C₆₀) alkyl group, a C₁-C₆₀) alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in Formulae 601 and 601-1, xe1 and xe611 to xe613 may each independently be 0, 1, or 2.

In embodiments, the electron transport region may include one of Compounds ET1 to ET45, 2,9-dimethyl-4,7-diphenyl-1,10-phenanthroline (BCP), 4,7-diphenyl-1,10-phenanthroline (Bphen), Alq3, BAlq, TAZ, NTAZ, or a combination thereof:

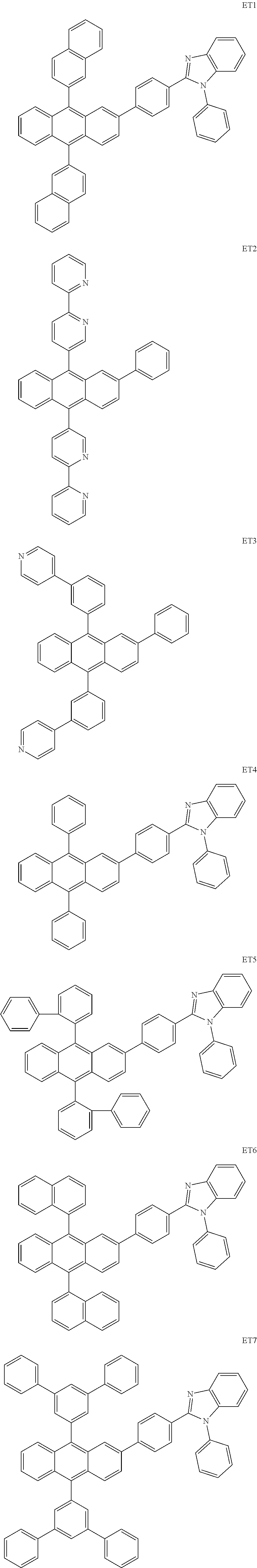

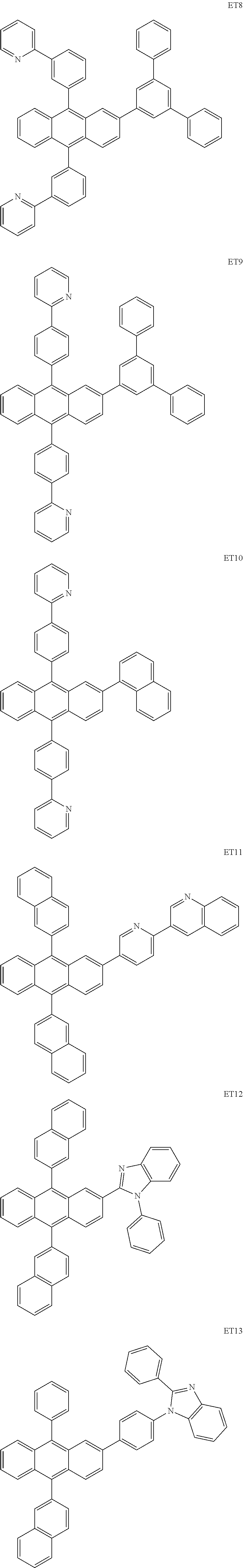

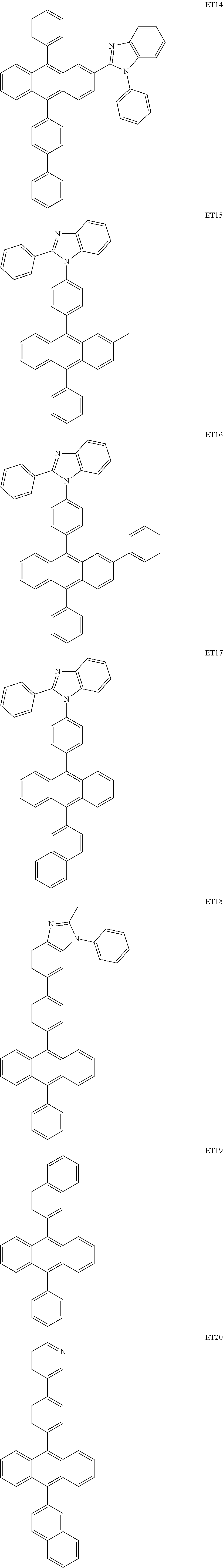

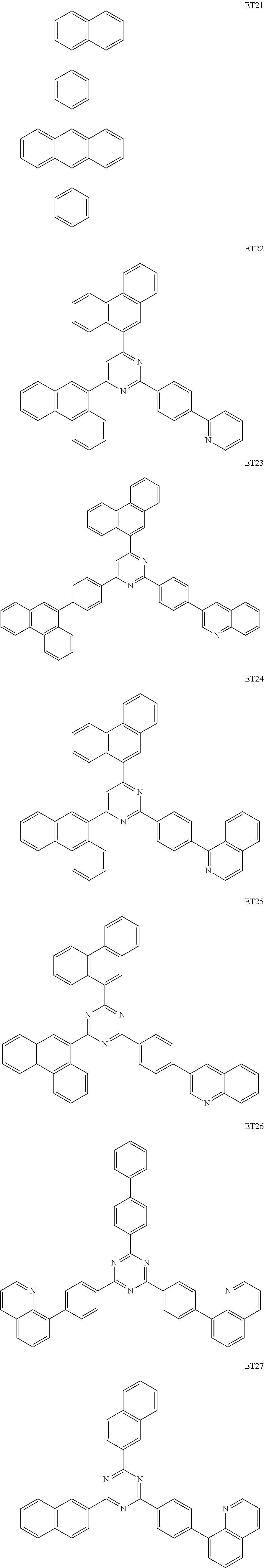

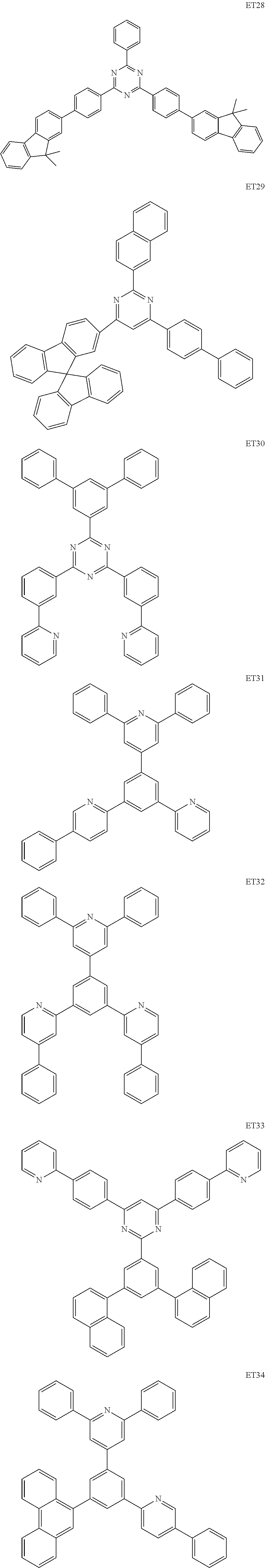

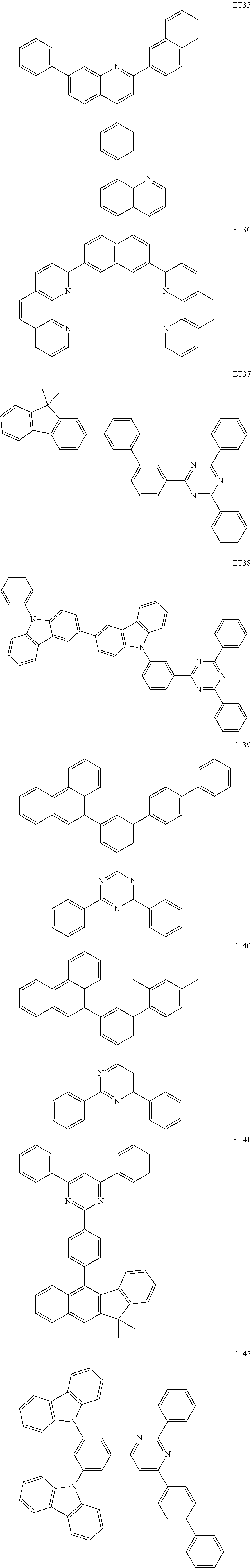

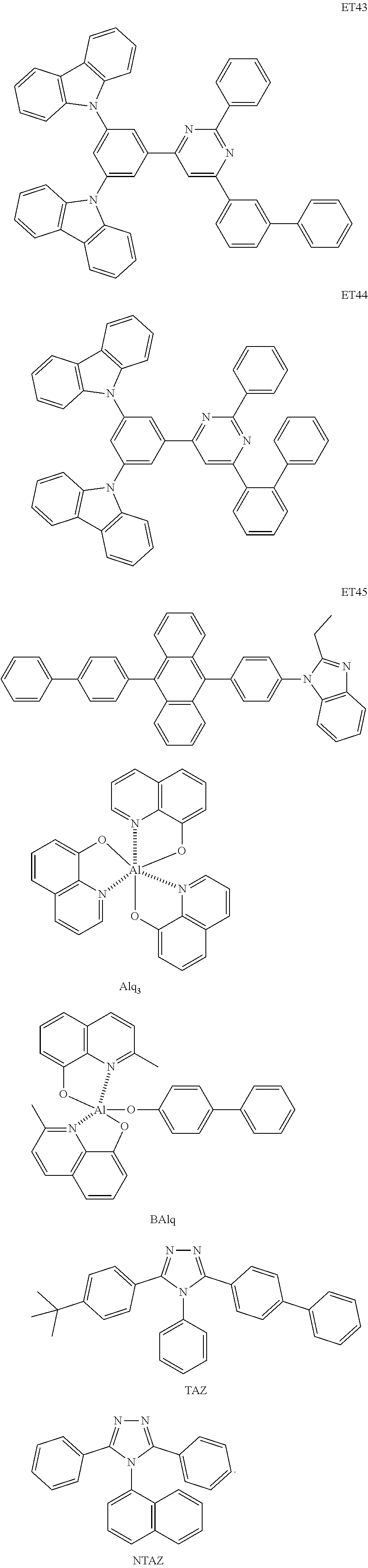

A thickness of the electron transport region may be in a range of about 100 Å to about 5,000 Å. For example, the thickness of the electron transport region may be in a range of about 160 Å to about 4,000 Å. In case that the electron transport region includes a buffer layer, a hole blocking layer, an electron control layer, an electron transport layer, or a combination thereof, the thickness of the buffer layer, the hole blocking layer, or the electron control layer may each independently be in a range of about 20 Å to about 1000 Å, and the thickness of the electron transport layer may be in a range of about 100 Å to about 1000 Å. For example, the thickness of the buffer layer, the hole blocking layer, or the electron control layer may each independently be in a range of about 30 Å to about 300 Å. For example, the thickness of the hole transport layer may be in a range of about 150 Å to about 500 Å. In case that the thickness of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, an electron transport layer in the electron transport region) may further include, in addition to the materials described above, a metal-containing material.

The metal-containing material may include an alkali metal complex, an alkaline earth metal complex, or a combination thereof. A metal ion of an alkali metal complex may be a Li ion, a Na ion, a K ion, a Rb ion, or a Cs ion, and a metal ion of an alkaline earth metal complex may be a Be ion, a Mg ion, a Ca ion, a Sr ion, or a Ba ion. A ligand coordinated with the metal ion of the alkali metal complex or with the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or a combination thereof.

For example, the metal-containing material may include a Li complex. The Li complex may include, for example, Compound ET-D1 (LiQ) or Compound ET-D2:

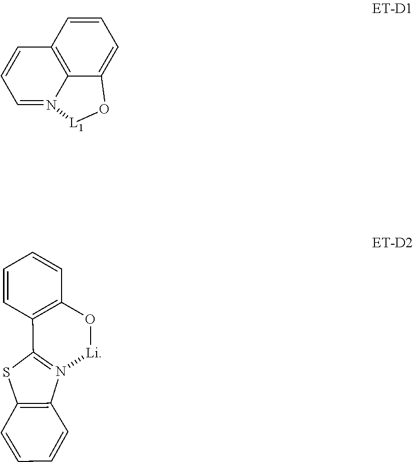

The electron transport region may include an electron injection layer that facilitates the injection of electrons from the second electrode 150. The electron injection layer may contact the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof.

The alkali metal may include Li, Na, K, Rb, Cs, or a combination thereof. The alkaline earth metal may include Mg, Ca, Sr, Ba, or a combination thereof. The rare earth metal may include Sc, Y, Ce, Tb, Yb, Gd, or a combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or a combination thereof.

The alkali metal-containing compound may include alkali metal oxides, such as Li₂O, Cs₂O, or K₂O; alkali metal halides, such as LiF, NaF, CsF, KF, LiI, NaI, CsI, or KI; or a combination thereof. The alkaline earth metal-containing compound may include: an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), or the like. The rare earth metal-containing compound may include: YbF₃, ScF₃, Sc₂O₃, Y₂O₃, Ce₂O₃, GdF₃, TbF₃, YbI₃, ScI₃, TbI₃, or a combination thereof. In some embodiments, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include one of an alkali metal ion, an alkaline earth metal ion, a rare earth metal ion, and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or a combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof, as described above. In some embodiments, the electron injection layer may further include an organic material (for example, a compound represented by Formula 601).

In some embodiments, the electron injection layer may consist of: an alkali metal-containing compound (for example, an alkali metal halide); or the electron injection layer may consist of an alkali metal-containing compound (for example, an alkali metal halide), and an alkali metal, an alkaline earth metal, a rare earth metal, or a combination thereof. For example, the electron injection layer may be a KI:Yb co-deposited layer, an RbI:Yb co-deposited layer, a LiF:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or a combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. In case that the thickness of the electron injection layer is within the ranges described above, satisfactory electron injection characteristics may be obtained without a substantial increase in driving voltage.

[Second Electrode 150]

The second electrode 150 may be located on the interlayer 130 having a structure as described above. The second electrode 150 may be a cathode, which is an electron injection electrode. A material for the second electrode 150 may be a material having a low work function, such as a metal, an alloy, an electrically conductive compound, or a combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure.

[Capping Layer]

The light-emitting device 10 may include a first capping layer outside the first electrode 110, and/or a second capping layer outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in an emission layer in the interlayer 130 of the light-emitting device 10 may be extracted toward the outside through the first electrode 110, which may be a semi-transmissive electrode or a transmissive electrode, and through the first capping layer. Light generated in an emission layer in the interlayer 130 of the light-emitting device 10 may be extracted toward the outside through the second electrode 150, which may be a semi-transmissive electrode or a transmissive electrode, and through the second capping layer.

The first capping layer and the second capping layer may each increase external emission efficiency according to the principle of constructive interference. Accordingly, the light extraction efficiency of the light-emitting device 10 may be increased, so that the luminescence efficiency of the light-emitting device 10 may be improved.

The first capping layer and the second capping layer may include a material having a refractive index of greater than or equal to about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include carbocyclic compounds, heterocyclic compounds, amine group-containing compounds, porphine derivatives, phthalocyanine derivatives, naphthalocyanine derivatives, alkali metal complexes, alkaline earth metal complexes, or a combination thereof. Optionally, the carbocyclic compound, the heterocyclic compound, and the amine group-containing compound may be substituted with a substituent including O, N, S, Se, Si, F, Cl, Br, I, or a combination thereof.

In some embodiments, at least one of the first capping layer and the second capping layer may each independently include an amine group-containing compound.

In some embodiments, at least one of the first capping layer and the second capping layer may each independently include a compound represented by Formula 201, a compound represented by Formula 202, or a combination thereof.

In some embodiments, at least one of the first capping layer and the second capping layer may each independently include: one of Compounds HT28 to HT33, one of Compounds CP1 to CP6, β-NPB, or a combination thereof:

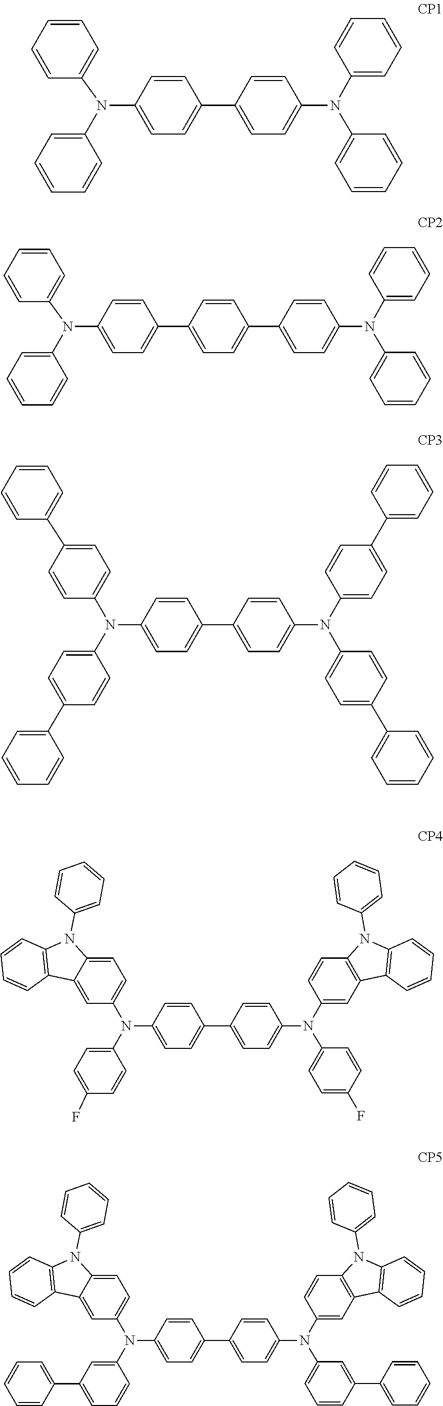 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

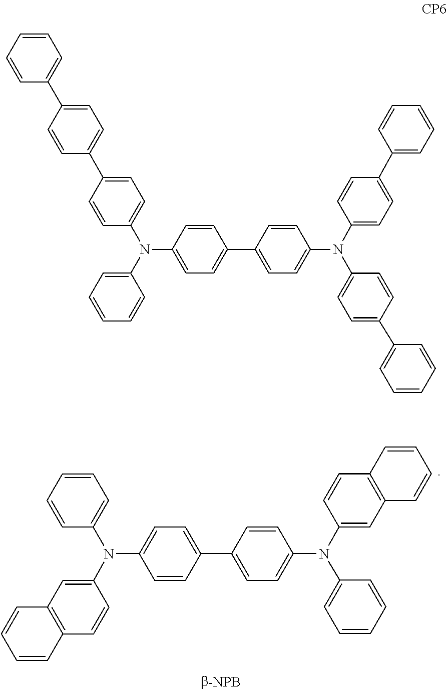 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

[Film]

The condensed cyclic compound represented by Formula 1 may be included in various films. Accordingly, another embodiment provides a film which may include the condensed cyclic compound represented by Formula 1. The film may be, for example, an optical member (or a light control means) (for example, a color filter, a color conversion member, a capping layer, a light extraction efficiency enhancement layer, a selective light absorbing layer, a polarizing layer, a quantum dot-containing layer, or like), a light-blocking member (for example, a light reflective layer, a light absorbing layer, or the like), or a protective member (for example, an insulating layer, a dielectric layer, or the like).

[Electronic Apparatus]

The light-emitting device may be included in various electronic apparatuses. In embodiments, an electronic apparatus including the light-emitting device may be a light-emitting apparatus, an authentication apparatus, or the like.

The electronic apparatus (for example, a light-emitting apparatus) may further include, in addition to the light-emitting device, a color filter, a color conversion layer, or a color filter and a color conversion layer. The color filter and/or the color conversion layer may be located in at least one direction in which light emitted from the light-emitting device travels. In embodiments, the light emitted from the light-emitting device may be blue light or white light. The light-emitting device, related description provided above may be the same as described herein. In some embodiments, the color conversion layer may include a quantum dot. The quantum dot may be, for example, a quantum dot as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be located between the subpixels to define each subpixel.

The color filter may further include color filter areas and light-shielding patterns located between the color filter areas, and the color conversion layer may further include color conversion areas and light-shielding patterns located between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. For example, the first color light may be red, the second color light may be green, and the third color light may be blue. For example, the color filter areas (or the color conversion areas) may include quantum dots. For example, the first area may include a red quantum dot, the second area may include a green quantum dot, and the third area may not include a quantum dot. The quantum dot may be a quantum dot as described herein. The first area, the second area, and/or the third area may each include a scatterer.

In an embodiment, the light-emitting device may emit first light, the first area may absorb the first light to emit first-first color light, the second area may absorb the first light to emit second-first color light, and the third area may absorb the first light to emit third-first color light. In this regard, the first-first color light, the second-first color light, and the third-first color light may have different maximum emission wavelengths from one another. For example, the first light may be blue, the first-first color light may be red, the second-first color light may be green, and the third-first color light may be blue.

The electronic apparatus may further include a thin-film transistor, in addition to the light-emitting device as described above. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, or the like.

The activation layer may include crystalline silicon, amorphous silicon, an organic semiconductor, an oxide semiconductor, or the like.

The electronic apparatus may further include a sealing portion for sealing the light-emitting device. The sealing portion may be located between the color filter and/or the color conversion layer and the light-emitting device. The sealing portion may allow light from the light-emitting device to be extracted to the outside, and may simultaneously prevent ambient air and moisture from penetrating into the light-emitting device. The sealing portion may be a sealing substrate including a transparent glass substrate or a plastic substrate. The sealing portion may be a thin-film encapsulation layer including an organic layer and/or an inorganic layer. In case that the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of a functional layer may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device as described above, a biometric information collector.

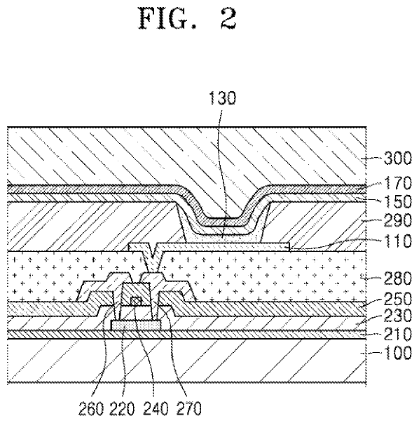

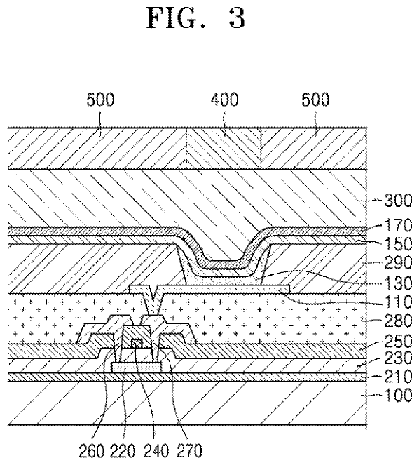

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

[Description of FIGS. 2 and 3]

FIG. 2 is a schematic cross-sectional view of an electronic apparatus according to an embodiment.

The electronic apparatus (e.g., a light-emitting apparatus) of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be located on the substrate 100. The buffer layer 210 may prevent penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be located between the gate electrode 240 and the source electrode 260 and between the gate electrode 240 and the drain electrode 270, to insulate from the gate electrode 240 from the drain electrode 270.

The source electrode 260 and the drain electrode 270 may be located on the interlayer insulating film 250. The interlayer insulating film 250 and the gate insulating film 230 may be formed to expose a source region and a drain region of the activation layer 220, and the source electrode 260 and the drain electrode 270 may respectively contact the exposed portions of the source region and the drain region of the activation layer 220.

The TFT may be electrically connected to a light-emitting device to drive the light-emitting device, and may be covered and protected by a passivation layer 280. The passivation layer 280 may include an inorganic insulating film, an organic insulating film, or a combination thereof. A light-emitting device may be provided on the passivation layer 280. The light-emitting device may include a first electrode 110, an interlayer 130, and a second electrode 150.

The first electrode 110 may be located on the passivation layer 280. The passivation layer 280 may not completely cover the drain electrode 270 and may be located to expose a portion of the drain electrode 270. The first electrode 110 may be electrically connected to the exposed portion of the drain electrode 270.

A pixel-defining layer 290 including an insulating material may be located on the first electrode 110. The pixel-defining layer 290 may expose a selected region of the first electrode 110, and an interlayer 130 may be formed in the exposed region of the first electrode 110. The pixel-defining layer 290 may be a polyimide or polyacrylic organic film. Although not shown in FIG. 2, at least some layers of the interlayer 130 may extend beyond the upper portion of the pixel-defining layer 290 to be provided in the form of a common layer.

The second electrode 150 may be located on the interlayer 130, and a capping layer 170 may be further included on the second electrode 150. The capping layer 170 may be formed to cover the second electrode 150.

The encapsulation portion 300 may be located on the capping layer 170. The encapsulation portion 300 may be located on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or a combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or a combination thereof; or any combination of the inorganic films and the organic films.

FIG. 3 is a schematic cross-sectional view of an electronic apparatus according to another embodiment.

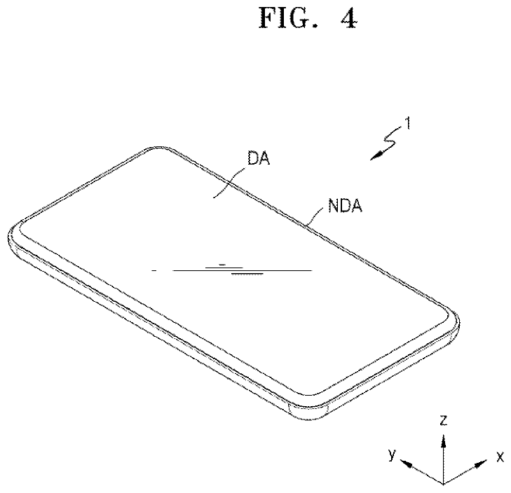

The electronic apparatus (e.g., a light-emitting apparatus) of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus of FIG. 3 may be a tandem light-emitting device.

[Description of FIG. 4]

FIG. 4 is a schematic perspective view of an electronic device 1 including a light-emitting device according to an embodiment.

The electronic device 1, which may be a device or apparatus that displays a moving image or still image, may be not only a portable electronic device, such as a mobile phone, a smartphone, a tablet personal computer (PC), a mobile communication terminal, an electronic notebook, an electronic book, a portable multimedia player (PMP), a navigation device, or an ultra-mobile PC (UMPC), but may also be various products, such as a television (TV), a laptop computer, a monitor, an advertisement board, or an Internet of things (IOT). The electronic device 1 may be such a product as above or a part thereof.

The electronic device 1 may be a wearable device, such as a smart watch, a watch phone, a glasses-type display, or a head mounted display (HMD), or a part of the wearable device. However, embodiments are not limited thereto.

For example, the electronic device 1 may be a center information display (CID) on an instrument panel and a center fascia or dashboard of a vehicle, a room mirror display instead of a side mirror of a vehicle, an entertainment display for a rear seat of a car or a display placed on the back of a front seat, a head up display (HUD) installed in front of a vehicle or projected on a front window glass, or a computer generated hologram augmented reality head up display (CGH AR HUD). FIG. 4 illustrates an embodiment in which the electronic device 1 is a smartphone for convenience of explanation.

The electronic device 1 may include a display area DA and a non-display area NDA outside the display area DA. A display device may implement an image through a two-dimensional array of pixels that are arranged in the display area DA.

The non-display area NDA may be an area that does not display an image, and may surround the display area DA. A driver for providing electrical signals or power to display devices arranged on the display area DA may be arranged in the non-display area NDA. A pad, which is an area to which an electronic element or a printing circuit board may be electrically connected, may be arranged in the non-display area NDA.

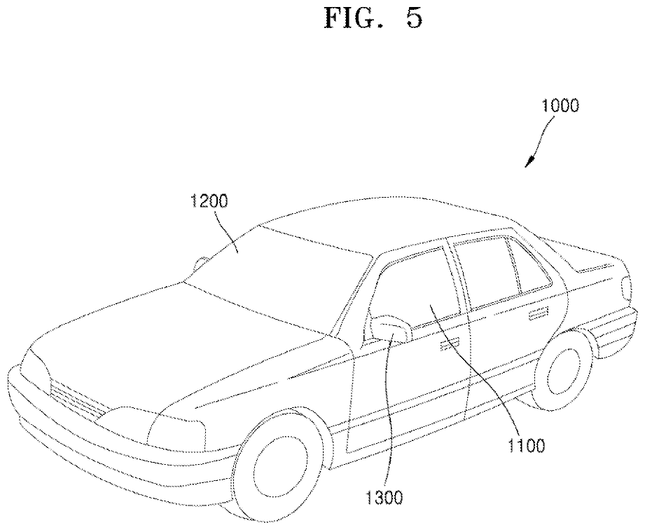

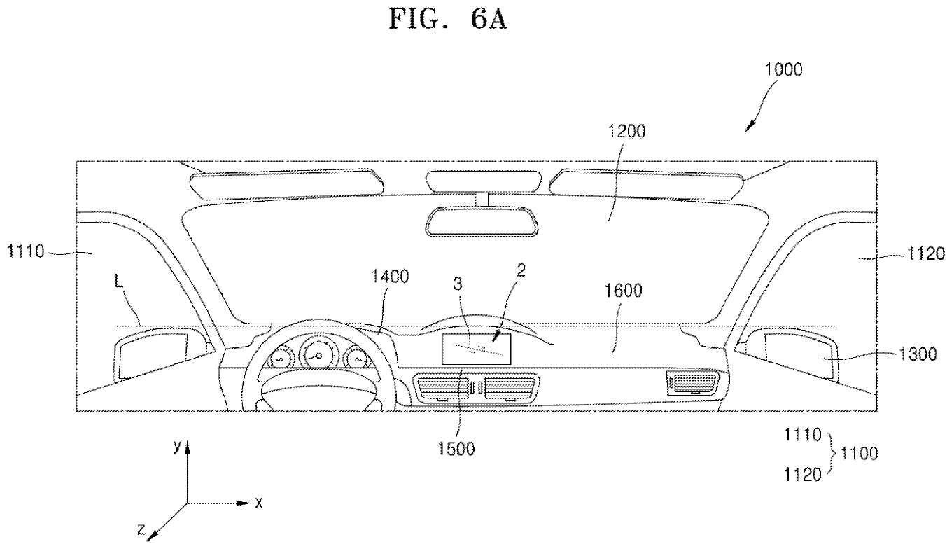

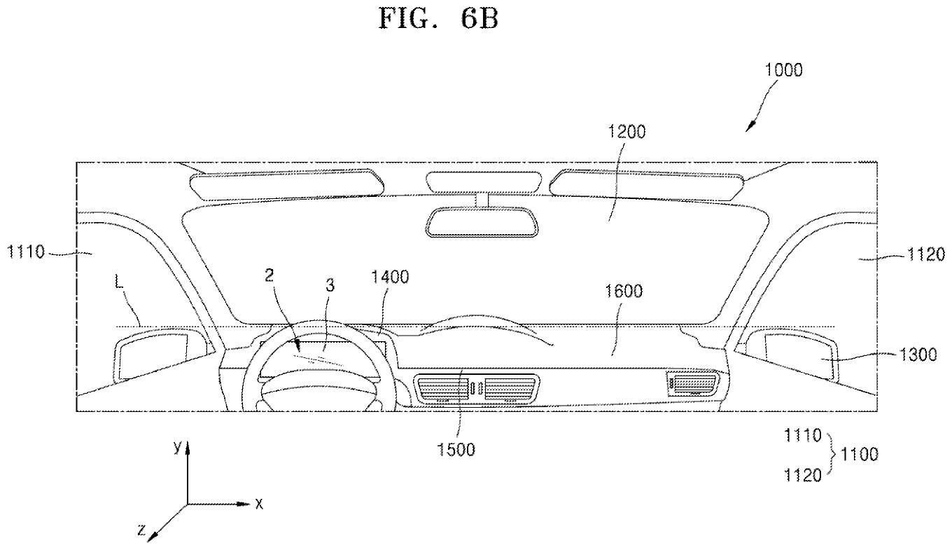

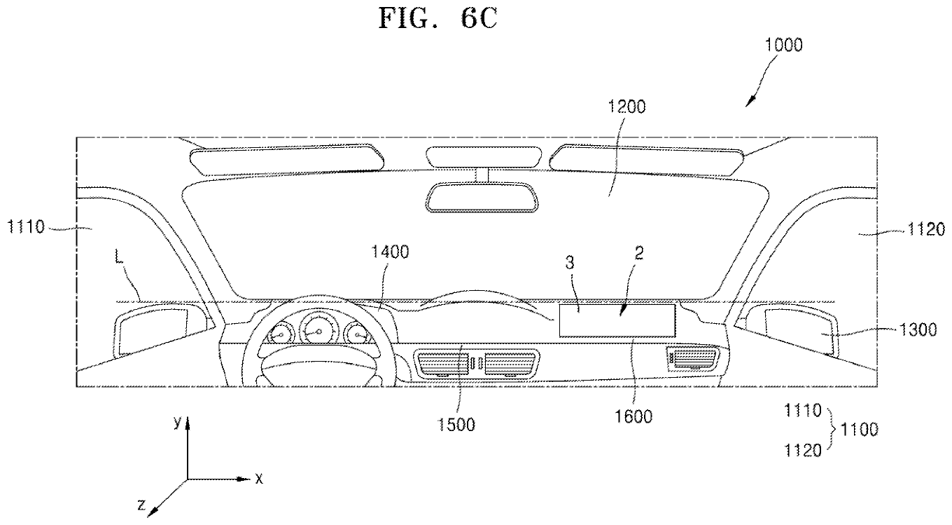

In an electronic device, a length in an x-axis direction and a length in the y-axis direction may be different from each other. For example, as shown in FIG. 4, the length in the x-axis direction may be shorter than the length in the y-axis direction. In some embodiments, the length in the x-axis direction may be the same as the length in the y-axis direction. In still other embodiments, the length in the x-axis direction may be longer than the length in the y-axis direction.

[Descriptions of FIGS. 5 and 6A to 6C]

FIG. 5 is a schematic view of an exterior of a vehicle 1000 as an electronic device including a light-emitting device according to another embodiment.

FIGS. 6A to 6C are each a schematic view of an interior of the vehicle 1000 as an electronic device including a light-emitting device according to another embodiment.

Referring to FIGS. 5, 6A, 6B, and 6C, the vehicle 1000 may refer to various apparatuses for moving a subject to be transported, such as a person, an object, or an animal, from a departure point to a destination. Examples of the vehicle 1000 may include a vehicle traveling on a road or track, a vessel moving over a sea or river, an airplane flying in the sky using the action of air, and the like.

The vehicle 1000 may travel on a road or a track. The vehicle 1000 may move in a given direction according to the rotation of at least one wheel. Examples of the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis that is a portion excluding the body in which mechanical apparatuses necessary for driving are installed. The exterior of the vehicle body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front, rear, left, and right wheels, and the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on the side of the vehicle 1000. In an embodiment, the side window glass 1100 may be installed in a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the passenger seat dashboard 1600.

In an embodiment, the side window glasses 1100 may be spaced apart from each other in an x-direction or in a −x-direction. For example, the first side window glass 1110 and the second side window glass 1120 may be spaced apart from each other in the x direction or the −x direction. An imaginary straight line L connecting the side window glasses 1100 may extend in the x-direction or in the −x-direction. For example, an imaginary straight line L connecting the first side window glass 1110 and the second side window glass 1120 to each other may extend in the x direction or in the −x direction.

The front window glass 1200 may be installed on the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In an embodiment, multiple side mirrors 1300 may be provided. Any one of the side mirrors 1300 may be arranged outside the first side window glass 1110. Another one of the side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a driving record system, an automatic shift selector indicator light, a door open warning light, an engine oil warning light, and/or a low fuel warning light.

The center fascia 1500 may include a control panel on which buttons for adjusting an audio device, an air conditioning device, and a seat heater are disposed. The center fascia 1500 may be arranged on a side of the cluster 1400.

A passenger seat dashboard 1600 may be spaced apart from the cluster 1400 with the center fascia 1500 arranged therebetween. In an embodiment, the cluster 1400 may be arranged to correspond to a driver seat (not shown), and the passenger seat dashboard 1600 may be disposed to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display device 2 may include a display panel 3, and the display panel 3 may display an image. The display device 2 may be arranged inside the vehicle 1000. In an embodiment, the display device 2 may be arranged between the side window glasses 1100 facing each other. The display device 2 may be arranged in at least one of the cluster 1400, the center fascia 1500, and the passenger seat dashboard 1600.

The display device 2 may include an organic light-emitting display device, an inorganic electroluminescent (EL) display device, a quantum dot display device, or the like. Hereinafter, as the display device 2 according to an embodiment, an organic light-emitting display device display including the light-emitting device according to the disclosure will be described as an example, but various types of display devices as described herein may be used as embodiments.

Referring to FIG. 6A, the display device 2 may be arranged in the center fascia 1500. In an embodiment, the display device 2 may display navigation information. In an embodiment, the display device 2 may display information regarding audio settings, video settings, or vehicle settings.

Referring to FIG. 6B, the display device 2 may be arranged in the cluster 1400. In case that the display device 2 is arranged in the cluster 1400, the cluster 1400 may display driving information and the like through the display device 2. For example, the cluster 1400 may digitally implement driving information. The cluster 1400 may digitally display vehicle information and driving information as images. For example, a needle and a gauge of a tachometer, and various warning lights or icons may be displayed by a digital signal.

Referring to FIG. 6C, the display device 2 may be arranged in the passenger seat dashboard 1600. The display device 2 may be embedded in the passenger seat dashboard 1600 or arranged on the passenger seat dashboard 1600. In an embodiment, the display device 2 arranged on the passenger seat dashboard 1600 may display an image related to information displayed on the cluster 1400 and/or information displayed on the center fascia 1500. In some embodiments, the display device 2 arranged on the passenger seat dashboard 1600 may display information that is different from information displayed on the cluster 1400 and/or information displayed on the center fascia 1500.

[Manufacturing Method]

Respective layers included in the hole transport region, the emission layer, and respective layers included in the electron transport region may be formed in a selected region by using one or more suitable methods selected from vacuum deposition, spin coating, casting, Langmuir-Blodgett (LB) deposition, ink-jet printing, laser-printing, and laser-induced thermal imaging.

In case that layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ to π to about 10⁻³ torr, and a deposition speed of about 0.01 Å/sec to about 100 Å/sec, depending on a material to be included in a layer to be formed and the structure of a layer to be formed.

### Definition of Terms

The term “C₃-C₆₀ carbocyclic group” as used herein may be a cyclic group consisting of carbon atoms as the only ring-forming atoms and having three to sixty carbon atoms, and the term “C₁-C₆₀ heterocyclic group” as used herein may be a cyclic group that has one to sixty carbon atoms and further has, in addition to a carbon atom, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, a C₁-C₆₀ heterocyclic group may have 3 to 61 ring-forming atoms.

The term “cyclic group” as used herein may be a C₃-C₆₀ carbocyclic group, or a C₁-C₆₀ heterocyclic group.

The term “π electron-rich C₃-C₆₀ cyclic group” as used herein may be a cyclic group that has three to sixty carbon atoms and does not include *—N═*′ as a ring-forming moiety, and the term “π electron-deficient nitrogen-containing C₁-C₆₀) cyclic group” as used herein may be a heterocyclic group that has one to sixty carbon atoms and may include *—N═*′ as a ring-forming moiety.

In embodiments,

a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

a C₁-C₆₀ heterocyclic group may be a T2 group T2, a group in which two or more T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

a π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.), wherein

the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may be a furan group, a thiophene group, a 1H-pyrrole group, a silole group, or a borole group, and

the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀) heterocyclic group”, “π electron-rich C₃-C₆₀ cyclic group”, or “π electron-deficient nitrogen-containing C₁-C₆₀ cyclic group” may each be a group condensed to any cyclic group, a monovalent group, or a polyvalent group (for example, a divalent group, a trivalent group, a tetravalent group, etc.) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, or a monovalent non-aromatic condensed heteropolycyclic group. Examples of a divalent C₃-C₆₀ carbocyclic group and a divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” may be a linear or branched aliphatic hydrocarbon monovalent group that has one to sixty carbon atoms. Examples of a C₁-C₆₀ alkyl group may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group. Examples of a C₂-C₆₀ alkenyl group may include an ethenyl group, a propenyl group, and a butenyl group. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group. Examples of a C₂-C₆₀ alkynyl group may include an ethynyl group and a propynyl group. The term “C₂-C₆₀ alkynylene group” as used herein may be a divalent group having the same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, and an isopropyloxy group.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein may be a divalent group having the same structure as the C₃-C₁₀ cycloalkyl group.

The term “C₁-C₁₀ heterocycloalkyl group” as used herein may be a monovalent cyclic group of 1 to 10 carbon atoms, further including, in addition to carbon atoms, at least one heteroatom, as ring-forming atoms, and specific examples may include a 1,2,3,4-oxatriazolidinyl group, a tetrahydrofuranyl group, and a tetrahydrothiophenyl group. The term “C₁-C₁₀ heterocycloalkylene group” as used herein may be a divalent group having a same structure as the C₁-C₁₀ heterocycloalkyl group.

The term C₃-C₁₀ cycloalkenyl group used herein may be a monovalent cyclic group that has three to ten carbon atoms and at least one carbon-carbon double bond in the ring thereof and no aromaticity, and specific examples thereof may be a cyclopentenyl group, a cyclohexenyl group, and a cycloheptenyl group. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group of 1 to 10 carbon atoms, further including, in addition to carbon atoms, at least one heteroatom, as ring-forming atoms, and having at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may be a divalent group having the same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the respective rings may be condensed with each other.

The term “C₁-C₆₀) heteroaryl group” as used herein may be a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom, as ring-forming atoms. Examples of the C₁-C₆₀ heteroaryl group may be a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group may be an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein may be a divalent group having the same structure as the monovalent non-aromatic condensed polycyclic group described above.

The term “monovalent non-aromatic condensed heteropolycyclic group” as used herein may be a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphtho silolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having a same structure as the monovalent non-aromatic condensed heteropolycyclic group described above.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (where A₁₀₄ may be a C₁-C₅₄ alkylene group, and A₁₀₅ may be a C₆-C₅₉ aryl group), and the term C₂-C₆₀ heteroarylalkyl group” as used herein may be a group represented by -(A₁₀₆)(A₁₀₇) (where A₁₀₆ may be a C₁-C₅₉ alkylene group, and A₁₀₇ may be a C₁-C₅₉ heteroaryl group).

The term “R₁₀ₐ” may be:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀) alkyl group, a C₁-C₆₀ alkoxy group, a phenyl group, a biphenyl group, or a combination thereof.

The term “heteroatom” as used herein may be any atom other than a carbon atom or a hydrogen atom. Examples of a heteroatom may include O, S, N, P, Si, B, Ge, Se, and any combinations thereof.

The term “third-row transition metal” used herein may be hafnium (Hf), tantalum (Ta), tungsten (W), rhenium (Re), osmium (Os), iridium (Ir), platinum (Pt), gold (Au), and the like.

The term “Ph” as used herein refers to a phenyl group, “Me” as used herein may be a methyl group, “Et” as used herein may be an ethyl group, “tert-Bu” or “But” as used herein may be a tert-butyl group, and “OMe” as used herein refers to a methoxy group.

The term “biphenyl group” as used herein refers to “a phenyl group substituted with a phenyl group.” The “biphenyl group” may be a substituted phenyl group having a C₆-C₆₀ aryl group as a substituent.

The term “terphenyl group” as used herein refers to “a phenyl group substituted with a biphenyl group”. For example, the “terphenyl group” may be a substituted phenyl group having, as a substituent, a C₆-C₆₀ aryl group substituted with a C₆-C₆₀ aryl group.

The symbols *, and *′, and *″ as used herein, unless defined otherwise, each refer to a binding site to a neighboring atom in a corresponding formula or moiety.

In the specification, the terms “x-axis”, “y-axis”, and “z-axis” are not limited to three axes in an orthogonal coordinate system (e.g., a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are those in different directions that are not orthogonal to each other.

Hereinafter, compounds according to embodiments and light-emitting devices according to embodiments will be described in detail with reference to the following Synthesis Examples and Examples. The wording “B was used instead of A” used in describing Synthesis Examples means that an identical molar equivalent of B was used in place of A.

### EXAMPLES

The condensed cyclic compound according to an embodiment may be synthesized, for example, as follows. However, synthesis methods of the condensed cyclic compound according to an embodiment are not limited thereto.

### Synthesis Example 1. Synthesis of Compound 3

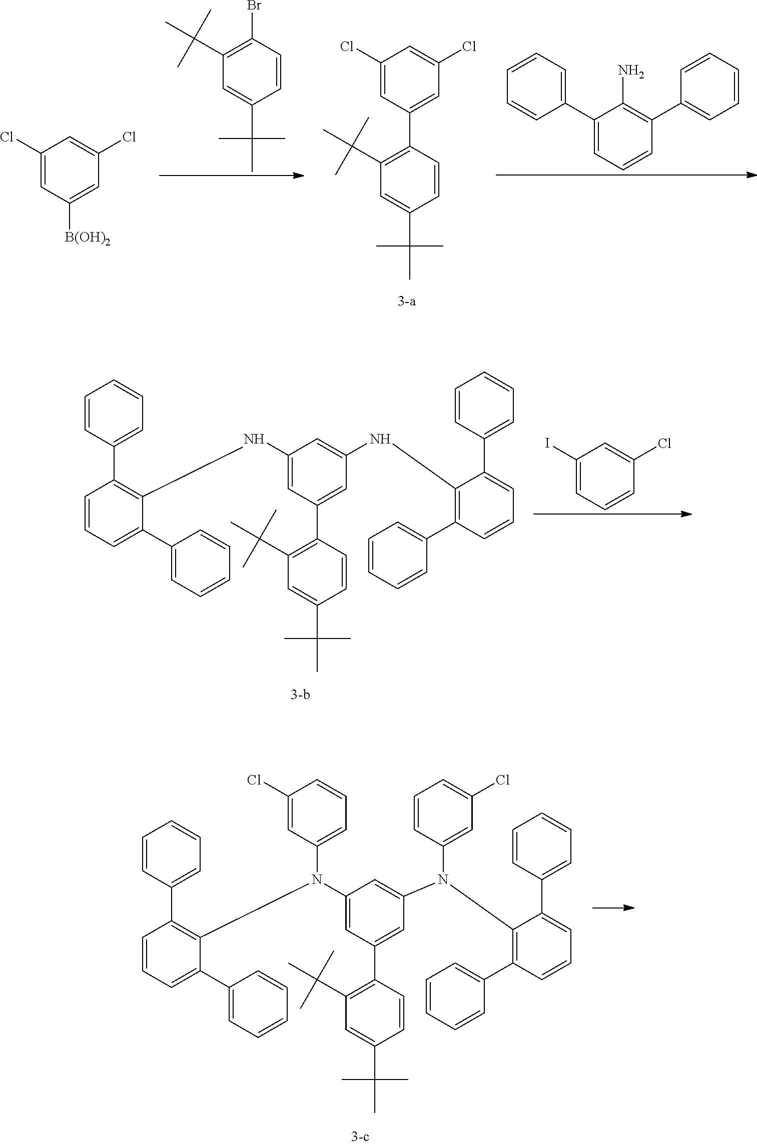

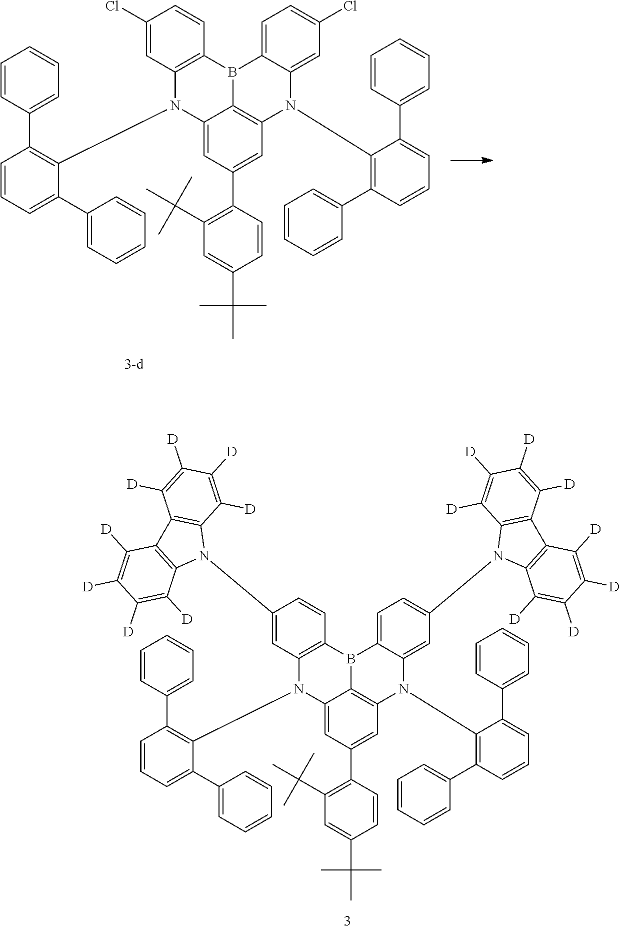 [SMILES: CC(C)(C)c1ccc(-c2cc3c4c(c2)N(c2c(-c5ccccc5)cccc2-c2ccccc2)c2cc(Cl)ccc2B4c2ccc(Cl)cc2N3c2c(-c3ccccc3)cccc2-c2ccccc2)c(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc(C(C)(C)C)cc3C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1]

### Synthesis of Intermediate Compound 3-a

Under argon conditions, (3,5-dichlorophenyl)boronic acid (15 g, 78.6 mmol), 1-bromo-2,4-di-tert-butylbenzene (21.2 g, 78.6 mmol), Pd(PPh₃)₄ (4.54 g, 3.93 mmol), and potassium carbonate (32.6 g, 235.8 mmol) were added to a 1 L flask and dissolved in 700 ml of toluene and 250 ml of H₂O to prepare a reaction solution. The reaction solution was stirred at a temperature of about 100° C. for about 12 hours. After the reaction solution was cooled, an organic layer was extracted from the reaction solution by using water (500 ml) and ethyl acetate (300 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 3-a (white solid, 17.1 g, 51.1 mmol, 65%). By ESI-LCMS, the obtained compound was identified as Intermediate compound 3-a.

ESI-LCMS: [M]⁺: C₂₀H₂₄Cl₂. 334.13.

### Synthesis of Intermediate Compound 3-b

Under argon conditions, Compound 3-a (17.1 g, 51.1 mmol), [1,1′:3′,1″-terphenyl]-2′-amine (27.6 g, 112.4 mmol), pd₂dba₃ (2.3 g, 2.6 mmol), tris-tert-butyl phosphine solution in toluene (2.4 ml, 5.11 mmol), and sodium tert-butoxide (14.7 g, 153.3 mmol) were added to a 1 L flask and dissolved in 500 ml of o-xylene to prepare a reaction solution. The reaction solution was stirred at a temperature of 140° C. for 12 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 3-b (white solid, 31.6 g, 41.9 mmol, 82%). By ESI-LCMS, the obtained compound was identified as Intermediate compound 3-b.

ESI-LCMS: [M]⁺: C₅₆H₅₂N₂. 752.41.

### Synthesis of Intermediate Compound 3-c

Under argon conditions, Compound 3-b (31.6 g, 41.9 mmol), 1-chloro-3-iodobenzene (50.0 g, 209.5 mmol), pd₂dba₃ (3.8 g, 4.2 mmol), tris-tert-butyl phosphine solution in toluene (3.9 ml, 8.4 mmol), and sodium tert-butoxide (20.1 g, 210 mmol) were added to a 1 L flask and dissolved in 500 ml of o-xylene to prepare a reaction solution. The reaction solution was stirred at a temperature of 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was separated by column chromatography (development solvent: CH₂Cl₂ and hexane) using silica gel and purified by recrystallization to obtain Intermediate compound 3-c (white solid, 31.0 g, 31.8 mmol, 76%). By ESI-LCMS, the obtained compound was identified as Intermediate compound 3-c.

ESI-LCMS: [M]⁺: C₆₈H₅₈Cl₂N₂. 972.40.

### Synthesis of Intermediate Compound 3-d

Under argon conditions, Compound 3-c (10 g, 10.3 mmol) was added to a 500 ml flask and dissolved in 200 ml of o-dichlorobenzene to prepare a reaction solution. The reaction solution was cooled with ice water, and BBr₃ (5 equiv.) was slowly added dropwise thereto. The reaction solution was stirred at a temperature of 180° C. for 12 hours. After the reaction solution was cooled, triethylamine (5 equiv.) was added thereto to terminate the reaction. An organic layer was extracted from the reaction solution by using water/CH₂Cl₂. The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 3-d (yellow solid, 5.4 g, 5.5 mmol, 53%). By ESI-LCMS, the obtained compound was identified as Intermediate compound 3-d.

ESI-LCMS: [M]⁺: C₆₈H₅₅BCl₂N₂. 980.38.

### Synthesis of Compound 3

Under argon conditions, Compound 3-d (5.4 g, 5.5 mmol), 9H-carbazole-1,2,3,4,5,6,7,8-d8 (2.1 g, 12.1 mmol), Pd₂(dba)₃ (0.25 g, 0.28 mmol), tris-tert-butyl phosphine solution in toluene (0.26 mL, 0.55 mmol), and sodium tert-butoxide (1.6 g, 16.5 mmol) were added to a 250 ml flask and dissolved in 100 ml of o-xylene to prepare a reaction solution. The reaction solution was stirred at a temperature of 150° C. for 12 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 3 (yellow solid, 3.6 g, 2.86 mmol, 52%). By ESI-LCMS and ¹H-NMR, the obtained compound was identified as Compound 3.

ESI-LCMS: [M]⁺: C₉₂H₅₅D₁₆BN₄. 1258.68.

¹H-NMR (400 MHz, CDCl₃): δ=8.83 (d, 2H), 7.62 (d, 4H), 7.59 (t, 2H), 7.32-7.28 (m, 2H), 7.18 (d, 1H), 7.11-7.08 (m, 4H), 7.02-6.98 (m, 20H), 6.38 (s, 2H), 1.35 (s, 9H), 1.29 (s, 9H) ppm.

### Synthesis Example 2. Synthesis of Compound 11

Compound 11 was synthesized in the same order and method as Compound 3, except that 5′-(tert-butyl)-[1,1′:3′,1″-terphenyl]-2′-amine was used instead of [1,1′:3′,1″-terphenyl]-2′-amine. By ESI-LCMS and ¹H-NMR, the obtained compound was identified as Compound 11.

ESI-LCMS: [M]⁺: C₁₀₀H₇₁D₁₆BN₄. 1371.81.

¹H-NMR (400 MHz, CDCl₃): δ=8.84 (d, 2H), 7.63 (s, 4H), 7.33-7.28 (m, 2H), 7.20 (d, 1H), 7.11-7.05 (m, 4H), 7.01-6.95 (m, 20H), 6.35 (s, 2H), 1.37 (s, 9H), 1.30 (s, 18H), 1.27 (s, 9H) ppm.

### Synthesis Example 3. Synthesis of Compound 65

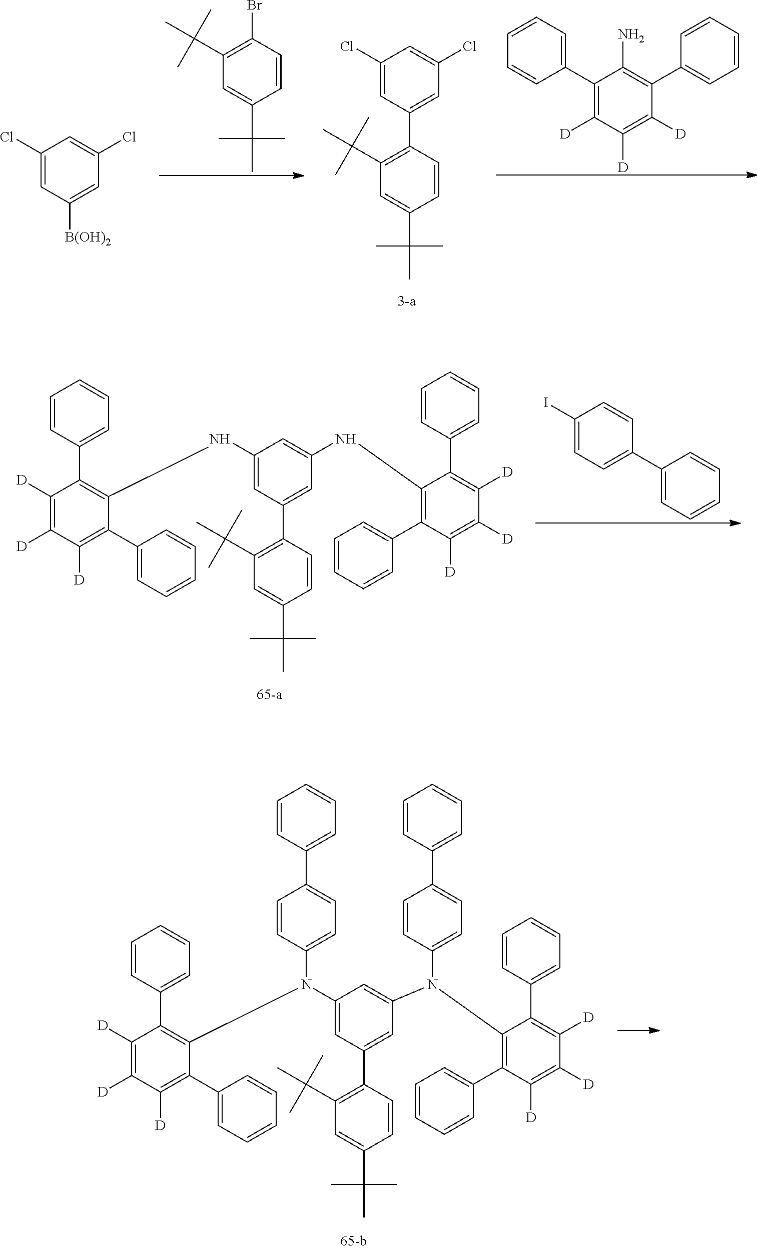

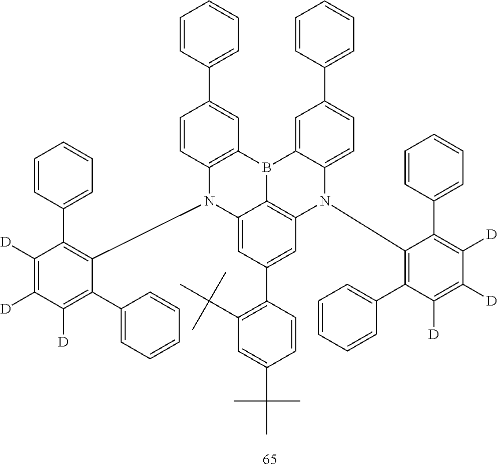 [SMILES: [2H]c1c([2H])c(-c2ccccc2)c(N2c3ccc(-c4ccccc4)cc3B3c4cc(-c5ccccc5)ccc4N(c4c(-c5ccccc5)c([2H])c([2H])c([2H])c4-c4ccccc4)c4cc(-c5ccc(C(C)(C)C)cc5C(C)(C)C)cc2c43)c(-c2ccccc2)c1[2H]]

(Synthesis of Intermediate compound 65-a)

Under argon conditions, Compound 3-a (20.1 g, 60.0 mmol), [1,1′:3′,1″-terphenyl]-4′,5′,6′-d3-2′-amine (31.3 g, 126.0 mmol), pd₂dba₃ (2.7 g, 3.0 mmol), tris-tert-butyl phosphine solution in toluene (2.8 ml, 6.0 mmol), and sodium tert-butoxide (17.3 g, 180.0 mmol) were added to a 1 L flask and dissolved in 500 ml of o-xylene to prepare a reaction solution. The reaction solution was stirred at a temperature of 140° C. for 12 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 65-a (white solid, 35.1 g, 46.2 mmol, 77%). By ESI-LCMS, the obtained compound was identified as Intermediate compound 65-a.

ESI-LCMS: [M]⁺: C₅₆H₄₆D₆N₂. 758.45.

### Synthesis of Intermediate Compound 65-b

Under argon conditions, Compound 65-a (35.1 g, 46.2 mmol), 4-iodo-1,1′-biphenyl (64.7 g, 231 mmol), pd₂dba₃ (4.2 g, 4.6 mmol), tris-tert-butyl phosphine solution in toluene (4.3 mL, 9.2 mmol), and sodium tert-butoxide (22.2 g, 231 mmol) were added to a 1 L flask and dissolved in 500 mL of o-xylene. The reaction solution was stirred at 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 65-b (white solid, 33.4 g, 31.4 mmol, 68%). By ESI-LCMS, the obtained compound was identified as Intermediate compound 65-b.

ESI-LCMS: [M]⁺: C₈₀H₆₂D₆N₂. 1062.58.

### Synthesis of Compound 65

Under argon conditions, Compound 65-b (10.6 g, 10.0 mmol) was added to a 500 ml flask and dissolved in 200 ml of o-dichlorobenzene to prepare a reaction solution. The reaction solution was cooled with ice water, and BBr₃ (5 equiv.) was slowly added dropwise thereto. The reaction solution was stirred at a temperature of 180° C. for 12 hours. After the reaction solution was cooled, triethylamine (5 equiv.) was added thereto to terminate the reaction. An organic layer was extracted from the reaction solution by using water/CH₂Cl₂. The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 65 (yellow solid, 4.8 g, 4.5 mmol, 45%). By ESI-LCMS and ¹H-NMR, the obtained compound was identified as Compound 65.

ESI-LCMS: [M]⁺: C₈₀H₅₉D₆BN₂. 1070.56.

¹H-NMR (400 MHz, CDCl₃): δ=9.01 (s, 2H), 7.31-7.26 (m, 2H), 7.22 (d, 1H), 7.15-7.13 (m, 4H), 7.08-7.04 (m, 8H) 7.00-6.92 (m, 22H), 6.35 (s, 2H), 1.39 (s, 9H), 1.30 (s, 9H) ppm.

### Synthesis Example 4. Synthesis of Compound 99

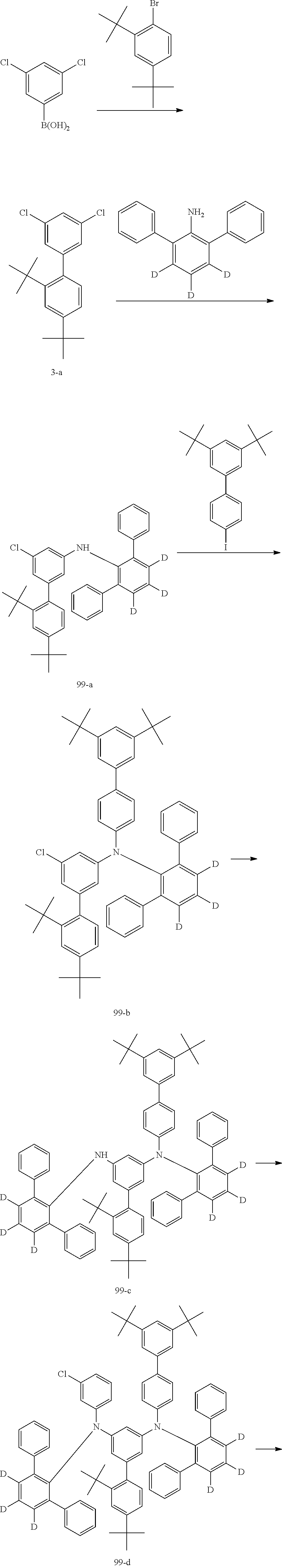

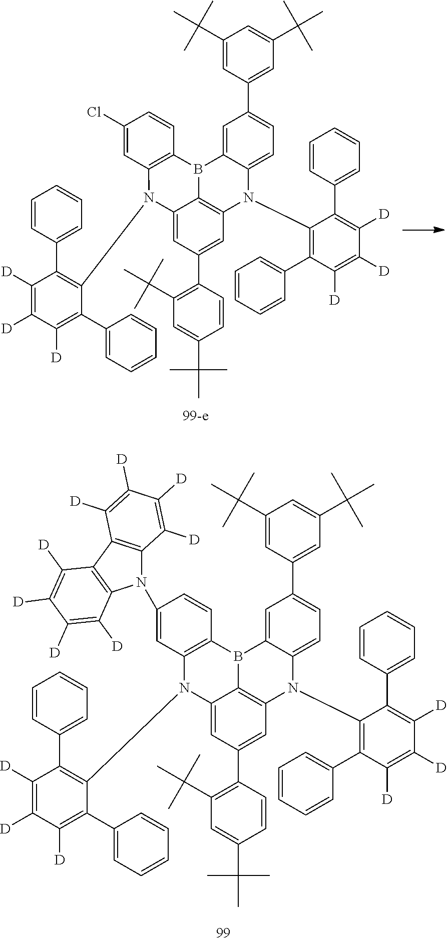 [SMILES: [2H]c1c([2H])c(-c2ccccc2)c(N2c3ccc(-c4cc(C(C)(C)C)cc(C(C)(C)C)c4)cc3B3c4ccc(Cl)cc4N(c4c(-c5ccccc5)c([2H])c([2H])c([2H])c4-c4ccccc4)c4cc(-c5ccc(C(C)(C)C)cc5C(C)(C)C)cc2c43)c(-c2ccccc2)c1[2H] ; [2H]c1c([2H])c(-c2ccccc2)c(N2c3ccc(-c4cc(C(C)(C)C)cc(C(C)(C)C)c4)cc3B3c4ccc(-n5c6c([2H])c([2H])c([2H])c([2H])c6c6c([2H])c([2H])c([2H])c([2H])c65)cc4N(c4c(-c5ccccc5)c([2H])c([2H])c([2H])c4-c4ccccc4)c4cc(-c5ccc(C(C)(C)C)cc5C(C)(C)C)cc2c43)c(-c2ccccc2)c1[2H]]

### Synthesis of Intermediate Compound 99-a

Under argon conditions, Compound 3-a (20.1 g, 60.0 mmol), [1,1′:3′,1″-terphenyl]-4′,5′,6′-d3-2′-amine (12.4 g, 50.0 mmol), pd₂dba₃ (2.3 g, 2.5 mmol), tris-tert-butyl phosphine solution in toluene (2.3 ml, 5.0 mmol), and sodium tert-butoxide (9.6 g, 100.0 mmol) were added to a 1 L flask and dissolved in 500 ml of toluene to prepare a reaction solution. The reaction solution was stirred at a temperature of 8° C. for 12 hours. After the reaction solution was cooled, an organic layer was extracted from the reaction solution by using water (500 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 99-a (white solid, 21.9 g, 40.0 mmol, 80%). By ESI-LCMS, the obtained compound was identified as Intermediate compound 99-a.

ESI-LCMS: [M]⁺: C₃₈H₃₅D₃ClN. 546.29.

### Synthesis of Intermediate Compound 99-b

Under argon conditions, Compound 99-a (21.9 g, 40.0 mmol), 3,5-di-tert-butyl-4′-iodo-1,1′-biphenyl (78.5 g, 200.0 mmol), pd₂dba₃ (3.7 g, 4.0 mmol), tris-tert-butyl phosphine solution in toluene (3.7 mL, 8.0 mmol), and sodium tert-butoxide (19.2 g, 200.0 mmol) were added to a 1 L flask and dissolved in 400 ml of o-xylene to prepare a reaction solution. The reaction solution was stirred at a temperature of 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was separated by column chromatography (development solvent: CH₂Cl₂ and hexane) using silica gel and purified by recrystallization to obtain Intermediate compound 99-b (white solid, 25.0 g, 30.8 mmol, 77%). By ESI-LCMS, the obtained compound was identified as Intermediate compound 99-b.

ESI-LCMS: [M]⁺: C₅₈H₅₃D₃ClN. 810.48.

### Synthesis of Intermediate Compound 99-c

Under argon conditions, Compound 99-b (25.0 g, 30.8 mmol), [1,1′:3′,1″-terphenyl]-4′,5′,6′-d3-2′-amine (9.2 g, 37.0 mmol), pd₂dba₃ (1.4 g, 1.5 mmol), tris-tert-butyl phosphine solution in toluene (1.4 ml, 3.1 mmol), and sodium tert-butoxide (5.9 g, 61.6 mmol) were added to a 1 L flask and dissolved in 500 ml of toluene to prepare a reaction solution. The reaction solution was stirred at a temperature of 80° C. for 12 hours. After the reaction solution was cooled, an organic layer was extracted from the reaction solution by using water (500 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 99-c (white solid, 23.6 g, 23.1 mmol, 75%). By ESI-LCMS, the obtained compound was identified as Intermediate compound 99-c.

ESI-LCMS: [M]⁺: C₇₆H₇₀D₆N₂. 1022.64.

### Synthesis of Intermediate Compound 99-d

Under argon conditions, Compound 99-c (23.6 g, 23.1 mmol), 1-chloro-3-iodobenzene (27.5 g, 115.5 mmol), pd₂dba₃ (2.1 g, 2.3 mmol), tris-tert-butyl phosphine solution in toluene (2.2 ml, 4.6 mmol), and sodium tert-butoxide (11.1 g, 115.5 mmol) were added to a 1 L flask and dissolved in 250 ml of o-xylene to prepare a reaction solution. The reaction solution was stirred at a temperature of 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was separated by column chromatography (development solvent: CH₂Cl₂ and hexane) using silica gel and purified by recrystallization to obtain Intermediate compound 99-d (white solid, 18.3 g, 16.2 mmol, 70%). By ESI-LCMS, the obtained compound was identified as Intermediate compound 99-d.

ESI-LCMS: [M]⁺: C₈₂H₇₃D₆ClN₂. 1132.63.

### Synthesis of Intermediate Compound 99-e

Under argon conditions, Compound 99-d (18.3 g, 16.2 mmol) was added to a 1 L flask and dissolved in 400 ml of o-dichlorobenzene to prepare a reaction solution. The reaction solution was cooled with ice water, and BBr₃ (5 equiv.) was slowly added dropwise thereto. The reaction solution was stirred at a temperature of 180° C. for 12 hours. After the reaction solution was cooled, triethylamine (5 equiv.) was added thereto to terminate the reaction, and an organic layer was extracted from the reaction solution by using water/CH₂Cl₂. The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 99-e (yellow solid, 7.2 g, 6.3 mmol, 39%). By ESI-LCMS, the obtained compound was identified as Intermediate compound 99-e.

ESI-LCMS: [M]⁺: C₈₂H₇₀D₆BClN₂. 1140.62.

### Synthesis of Compound 99

Under argon conditions, Compound 99-e (7.2 g, 6.3 mmol), 9H-carbazole-1,2,3,4,5,6,7,8-d8 (1.3 g, 7.6 mmol), pd₂dba₃ (0.29 g, 0.32 mmol), tris-tert-butyl phosphine solution in toluene (0.29 mL, 0.63 mmol), and sodium tert-butoxide (1.2 g, 12.6 mmol) were added to a 250 ml flask and dissolved in 100 ml of o-xylene to prepare a reaction solution. The reaction solution was stirred at a temperature of 150° C. for 12 hours. After the reaction solution was cooled, an organic layer was extracted from the reaction solution by using water (200 ml) and ethyl acetate (100 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 99 (yellow solid, 4.7 g, 3.65 mmol, 58%). By ESI-LCMS and ¹H-NMR, the obtained compound was identified as Compound 99.

ESI-LCMS: [M]⁺: C₉₄H₇₀D₁₄BN₃. 1280.77.

¹H-NMR (400 MHz, CDCl₃): δ=9.05 (s, 1H), 8.86 (d, 1H), 7.23-7.20 (m, 5H), 7.18-7.15 (m, 4H), 7.11 (s, 1H), 7.00-6.92 (m, 20H), 6.40 (s, 2H), 1.35 (s, 9H), 1.32 (s, 18H), 1.29 (s, 9H) ppm.

### Synthesis Example 5. Synthesis of Compound 154

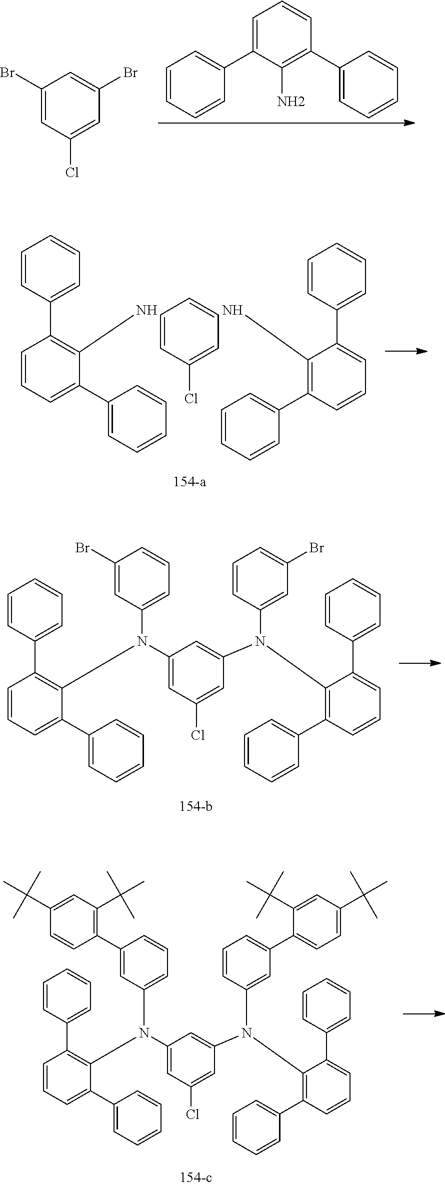

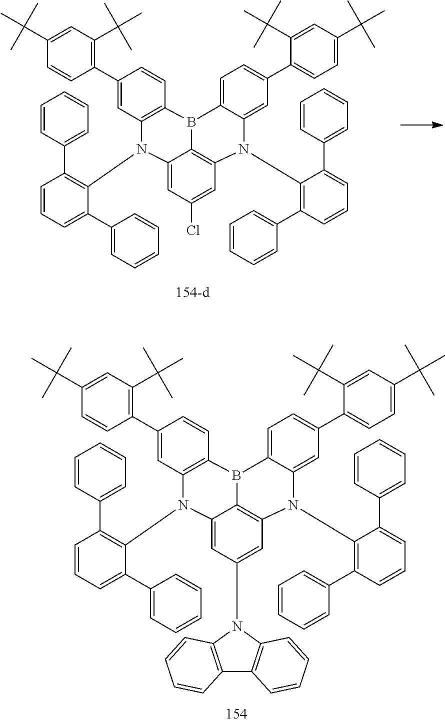

### Synthesis of Intermediate Compound 154-a

Under argon conditions, 1,3-dibromo-5-chlorobenzene (13.5 g, 50.0 mmol), [1,1′:3′,1″-terphenyl]-2′-amine (24.5 g, 100.0 mmol), pd₂dba₃ (2.3 g, 2.5 mmol), tris-tert-butyl phosphine solution in toluene (2.3 mL, 5.0 mmol), and sodium tert-butoxide (14.4 g, 150.0 mmol) were added to a 1 L flask and dissolved in 500 ml of toluene to prepare a reaction solution. The reaction solution was stirred at a temperature of 100° C. for 12 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 154-a (white solid, 23.7 g, 39.5 mmol, 79%). By ESI-LCMS, the obtained compound was identified as Intermediate compound 154-a.

ESI-LCMS: [M]⁺: C₄₂H₃₁ClN₂. 598.22.

### Synthesis of Intermediate Compound 154-b

Under argon conditions, Compound 154-a (23.7 g, 39.5 mmol), 1-bromo-3-iodobenzene (55.9 g, 197.5 mmol), pd₂dba₃ (3.6 g, 4.0 mmol), tris-tert-butyl phosphine solution in toluene (3.7 mL, 7.9 mmol), and sodium tert-butoxide (19.0 g, 197.5 mmol) were added to a 1 L flask and dissolved in 400 ml of o-xylene to prepare a reaction solution. The reaction solution was stirred at a temperature of 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was separated by column chromatography (development solvent: CH₂Cl₂ and hexane) using silica gel and purified by recrystallization to obtain Intermediate compound 154-b (white solid, 25.1 g, 27.7 mmol, 70%). By ESI-LCMS, the obtained compound was identified as Intermediate compound 154-b.

ESI-LCMS: [M]⁺: C₅₄H₃₇Br₂ClN₂. 909.16.

### Synthesis of Intermediate Compound 154-c

Under argon conditions, Intermediate compound 154-b (25.1 g, 27.7 mmol), (2,4-di-tert-butylphenyl)boronic acid (14.3 g, 60.9 mmol), Pd(PPh₃)₄ (1.6 g, 1.4 mmol), and potassium carbonate (11.5 g, 83.1 mmol) were added to a 1 L flask and dissolved in 300 ml of toluene, 60 ml of ethanol, and 120 ml of H₂O to prepare a reaction solution. The reaction solution was stirred at a temperature of 100° C. for 12 hours. After the reaction solution was cooled, an organic layer was extracted from the reaction solution by using water (500 ml) and ethyl acetate (300 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 154-c (white solid, 21.2 g, 18.8 mmol, 68%). By ESI-LCMS, the obtained compound was identified as Intermediate compound 154-c.

ESI-LCMS: [M]⁺: C₈₂H₇₃ClN₂. 1126.59.

### Synthesis of Intermediate Compound 154-d

Under argon conditions, Compound 154-c (10.0 g, 8.9 mmol) was added to a 1 L flask and dissolved in 200 ml of o-dichlorobenzene to prepare a reaction solution. The reaction solution was cooled with ice water, and BBr₃ (5 equiv.) was slowly added dropwise thereto. The reaction solution was stirred at a temperature of 180° C. for 12 hours. After the reaction solution was cooled, triethylamine (5 equiv.) was added thereto to terminate the reaction, and an organic layer was extracted from the reaction solution by using water/CH₂Cl₂. The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 154-d (yellow solid, 4.5 g, 4.0 mmol, 45%). By ESI-LCMS, the obtained compound was identified as Intermediate compound 154-d.

ESI-LCMS: [M]⁺: C₈₂H₇₆BClN₂. 1134.58.

### Synthesis of Compound 154

Under argon conditions, Compound 154-d (4.5 g, 4.0 mmol), 9H-carbazole (0.8 g, 4.8 mmol), pd₂dba₃ (0.18 g, 0.20 mmol), tris-tert-butyl phosphine solution in toluene (0.19 ml, 0.40 mmol), and sodium tert-butoxide (0.77 g, 12.0 mmol) were added to a 250 ml flask and dissolved in 50 ml of o-xylene to prepare a reaction solution. The reaction solution was stirred at a temperature of 150° C. for 12 hours. After the reaction solution was cooled, an organic layer was extracted from the reaction solution by using water (100 ml) and ethyl acetate (100 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 154 (yellow solid, 1.8 g, 1.4 mmol, 35%). By ESI-LCMS and ¹H-NMR, the obtained compound was identified as Compound 154.

ESI-LCMS: [M]⁺: C₃₄H₈₄BN₃. 1265.68.

¹H-NMR (400 MHz, CDCl₃): δ=9.05 (d, 2H), 8.20 (d, 2H), 7.81 (t, 2H), 7.60 (d, 4H), 7.55-7.50 (m, 4H), 7.30-7.26 (m, 6H), 7.20-7.11 (m, 6H), 7.08-6.99 (m, 10H), 6.95-6.89 (m, 10H), 6.35 (s, 2H), 1.38 (s, 18H), 1.35 (s, 18H) ppm.

### Synthesis Example 6. Synthesis of Compound 201

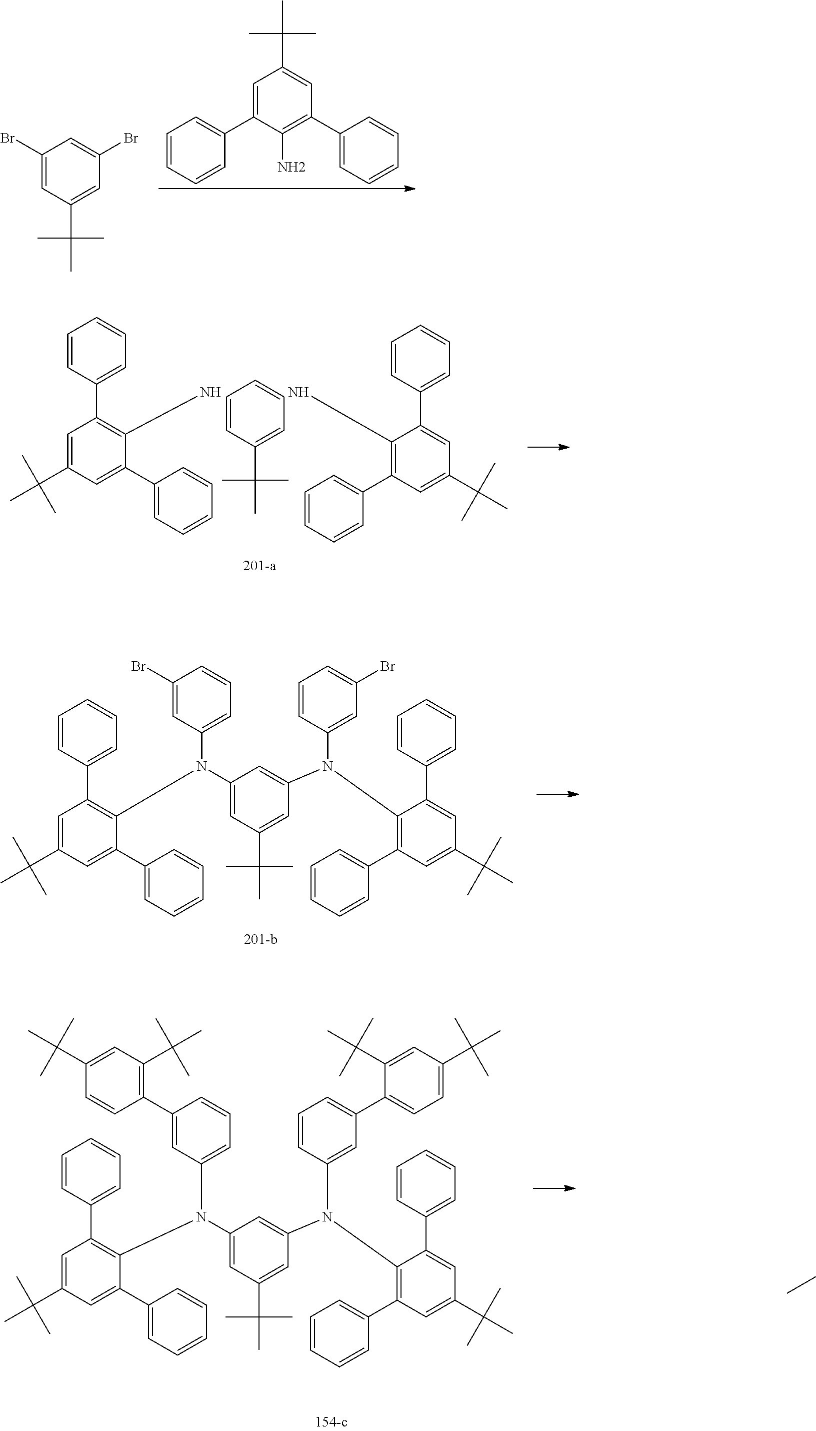

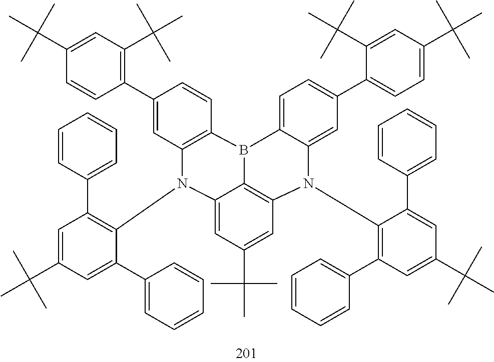 [SMILES: CC(C)(C)c1cc(-c2ccccc2)c(N2c3cc(-c4ccc(C(C)(C)C)cc4C(C)(C)C)ccc3B3c4ccc(-c5ccc(C(C)(C)C)cc5C(C)(C)C)cc4N(c4c(-c5ccccc5)cc(C(C)(C)C)cc4-c4ccccc4)c4cc(C(C)(C)C)cc2c43)c(-c2ccccc2)c1]

### Synthesis of Intermediate Compound 201-a

Under argon conditions, 1,3-dibromo-5-(tert-butyl)benzene (11.7 g, 40.0 mmol), 5′-(tert-butyl)[1,1′:3′,1″-terphenyl]-2′-amine (26.5 g, 88.0 mmol), pd₂dba₃ (1.8 g, 2.0 mmol), tris-tert-butyl phosphine solution in toluene (1.9 ml, 4.0 mmol), and sodium tert-butoxide (11.5 g, 120.0 mmol) were added to a 1 L flask and dissolved in 500 ml of toluene to prepare a reaction solution. The reaction solution was stirred at a temperature of 100° C. for 12 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 201-a (white solid, 24.9 g, 34.0 mmol, 85%). By ESI-LCMS, the obtained compound was identified as Intermediate compound 201-a.

ESI-LCMS: [M]⁺: C₅₄H₅₆N₂. 732.44.

### Synthesis of Intermediate Compound 201-b

Under argon conditions, Compound 201-a (24.9 g, 34.0 mmol), 1-bromo-3-iodobenzene (48.1 g, 170.0 mmol), Pd₂(dba)₃ (3.1 g, 3.4 mmol), tris-tert-butyl phosphine solution in toluene (3.2 ml, 6.8 mmol), and sodium tert-butoxide (16.3 g, 170.0 mmol) were added to a 1 L flask and dissolved in 400 ml of o-xylene to prepare a reaction solution. The reaction solution was stirred at a temperature of 140° C. for 72 hours. After the reaction solution was cooled, an organic layer was extracted from the reaction solution by using water (500 ml) and ethyl acetate (200 ml). The organic layer was dried and filtered with MgSO₄. A solvent was removed from the solution under a reduced pressure condition and a solid was obtained. The solid was separated by column chromatography (development solvent: CH₂Cl₂ and hexane) using silica gel and purified by recrystallization to obtain Intermediate compound 201-b (white solid, 23.1 g, 22.1 mmol, 65%). By ESI-LCMS, the obtained compound was identified as Intermediate compound 201-b.

ESI-LCMS: [M]⁺: C₆₆H₆₂Br₂N₂. 1042.33.

### Synthesis of Intermediate Compound 201-c

Under argon conditions, Intermediate compound 201-b (23.1 g, 22.1 mmol), (2,4-di-tert-butylphenyl)boronic acid (11.4 g, 48.6 mmol), Pd(PPh₃)₄ (1.3 g, 1.1 mmol), and potassium carbonate (9.2 g, 66.3 mmol) were added to a 1 L flask and dissolved in 300 ml of toluene, 60 ml of ethanol, and 120 ml of H₂O to prepare a reaction solution. The reaction solution was stirred at a temperature of 100° C. for 12 hours. After the reaction solution was cooled, an organic layer was extracted from the reaction solution by using water (500 ml) and ethyl acetate (300 ml). The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Intermediate compound 201-c (white solid, 20.1 g, 15.9 mmol, 72%). By ESI-LCMS, the obtained compound was identified as Intermediate compound 201-c.

ESI-LCMS: [M]⁺: C₃₄H₁₀₄N₂. 1261.82.

### Synthesis of Compound 201

Under argon conditions, Compound 201-c (10.0 g, 7.9 mmol) was added to a 1 L flask and dissolved in 200 ml of o-dichlorobenzene to prepare a reaction solution. The reaction solution was cooled with ice water, and BBr₃ (5 equiv.) was slowly added dropwise thereto. The reaction solution was stirred at a temperature of 180° C. for 12 hours. After the reaction solution was cooled, triethylamine (5 equiv.) was added thereto to terminate the reaction, and an organic layer was extracted from the reaction solution by using water/CH₂Cl₂. The organic layer was dried and filtered with MgSO₄. A solvent was removed from the solution under a reduced pressure condition and a solid was obtained. The solid was purified and separated by column chromatography (development solvent: CH₂Cl₂ and hexane) using silica gel to obtain Compound 201 (yellow solid, 4.6 g, 3.6 mmol, 46%). By ESI-LCMS and ¹H-NMR, the obtained compound was identified as Compound 201.

ESI-LCMS: [M]⁺: C₃₄H₁₀₁BN₂. 1268.81.

¹H-NMR (400 MHz, CDCl₃): δ=9.03 (d, 2H), 7.60 (s, 4H), 7.50-7.43 (m, 4H), 7.20-7.11 (m, 6H), 7.05-6.96 (m, 10H), 6.94-6.87 (m, 10H), 6.30 (s, 2H), 1.38 (s, 18H), 1.35 (s, 18H), 1.32 (s, 9H), 1.28 (s, 18H) ppm.

### Evaluation Example 1

The HOMO and LUMO energy level values (prediction) calculated by B3LYP/6-311+G** are shown in Table 1. The HOMO and LUMO energy levels of each compound were evaluated according to the method of Table 2, and the result (actual measurement value) is shown in Table 3.

TABLE 1

| Compound | HOMO (eV) | LUMO (eV) |
|---|---|---|
| 3 | −5.29 | −1.71 |
| 11 | −5.28 | −1.71 |
| 65 | −5.17 | −1.68 |
| 99 | −5.23 | −1.72 |
| 154 | −5.27 | −1.62 |
| 201 | −5.20 | −1.6 |
| Compound A | −4.74 | −1.14 |
| Compound B | −4.96 | −1.29 |
| Compound C | −4.83 | −1.22 |
| Compound D | −5.04 | −1.38 |
| Compound E | −5.18 | −1.97 |
| Compound F | −5.32 | −1.85 |

TABLE 2

| | |
|---|---|
| HOMO | By using cyclic voltammetry (CV) (electrolyte: 0.1M |
| energy level | Bu₄NPF₆/solvent: dimethylforamide (DMF)/electrode: |
| evaluation | 3-electrode system (working electrode: GC, reference |
| method | electrode: Ag/AgCl, and auxiliary electrode: Pt)), the |
| | potential (V)-current (A) graph of each compound was |
| | obtained, and from the oxidation onset of the graph, the |
| | HOMO energy level of each compound was calculated. |
| LUMO | By using cyclic voltammetry (CV) (electrolyte: 0.1M |
| energy level | Bu₄NPF₆/solvent: dimethylforamide (DMF)/electrode: |
| evaluation | 3-electrode system (working electrode: GC, reference |
| method | electrode: Ag/AgCl, and auxiliary electrode: Pt)), the |
| | potential (V)-current (A) graph of each compound was |
| | obtained, and from the reduction onset of the graph, the |
| | LUMO energy level of each compound was calculated. |

TABLE 3

| Compound | HOMO (eV) | LUMO (eV) |
|---|---|---|
| 3 | −5.50 | −2.29 |
| 11 | −5.49 | −2.28 |
| 65 | −5.30 | −2.19 |
| 99 | −5.42 | −2.26 |
| 154 | −5.45 | −2.19 |
| 201 | −5.40 | −2.18 |
| Compound A | −5.12 | −1.92 |
| Compound B | −5.18 | −2.26 |
| Compound C | −5.17 | −1.93 |
| Compound D | −5.23 | −1.97 |
| Compound E | −5.32 | −2.47 |
| Compound F | −5.49 | −2.37 |

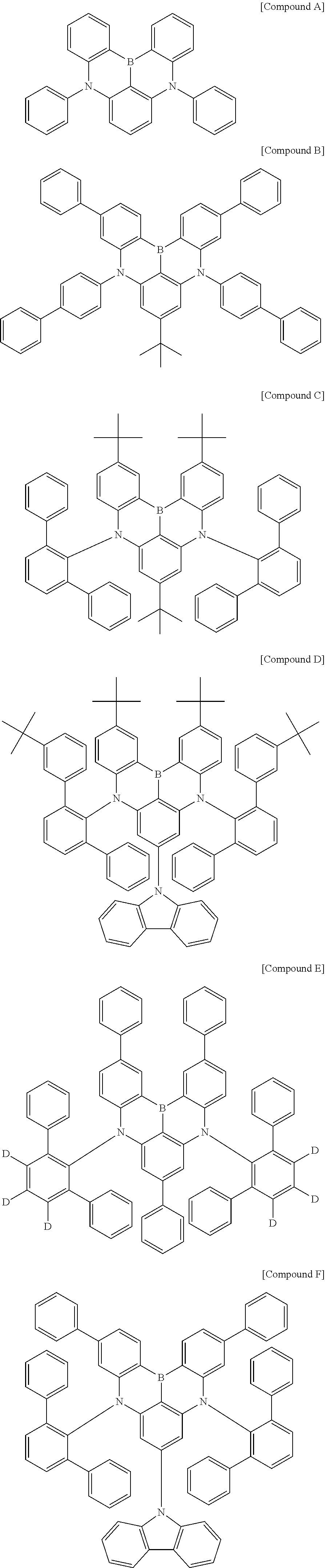

### Example 1

As an anode, a glass substrate with a 15 Ω/cm² (1,200 Å) ITO deposited thereon was cut to a size of 50 mm×50 mm×0.7 mm, sonicated with isopropyl alcohol and pure water each for 5 minutes, and cleaned by irradiation of ultraviolet rays and exposure of ozone thereto for 30 minutes. The resultant glass substrate was loaded onto a vacuum deposition apparatus.

NPB was vacuum-deposited on the ITO substrate to form a hole injection layer having a thickness of 300 Å, and HT6 was vacuum-deposited on the hole injection layer to form a hole transport layer having a thickness of 200 Å.

A first host (ETH33), a second host (HTH41), a phosphorescent sensitizer (PS-1), and Compound 3 of Example 1 were co-deposited on the hole transport layer at a weight ratio of 50:50:15:3 to form an emission layer having a thickness of 350 Å.

TSPO1 was deposited on the emission layer to form an electron transport layer having a thickness of 200 Å, and a buffer electron transport compound TPBI was deposited on the electron transport layer to form a buffer layer having a thickness of 300 Å.

LiF, which is a halogenated alkali metal, was deposited on the electron transport layer to form an electron injection layer having a thickness of 10 Å, and Al was vacuum-deposited thereon to form a LiF/AI cathode having a thickness of 3,000 Å. HT28 was deposited on the cathode to form a capping layer having a thickness of 700 Å, thereby completing the manufacture of a light-emitting device.

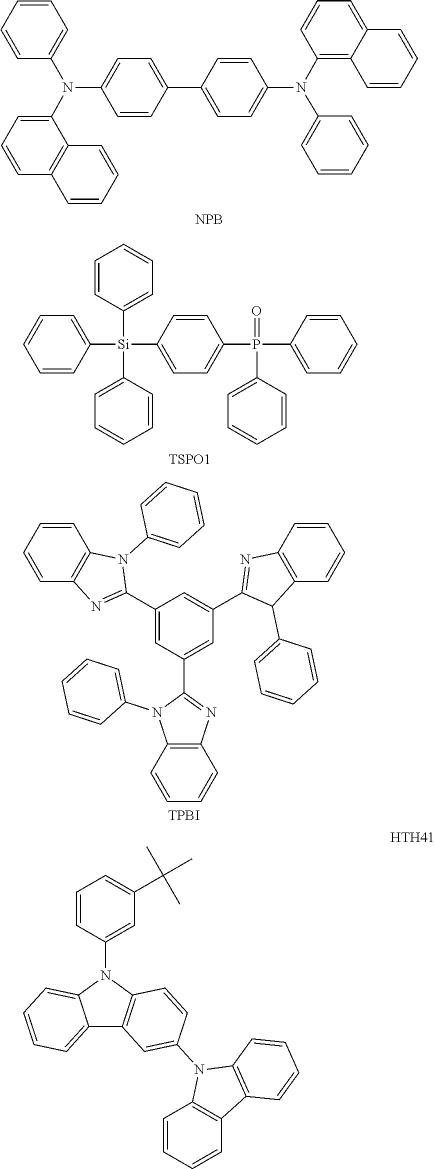

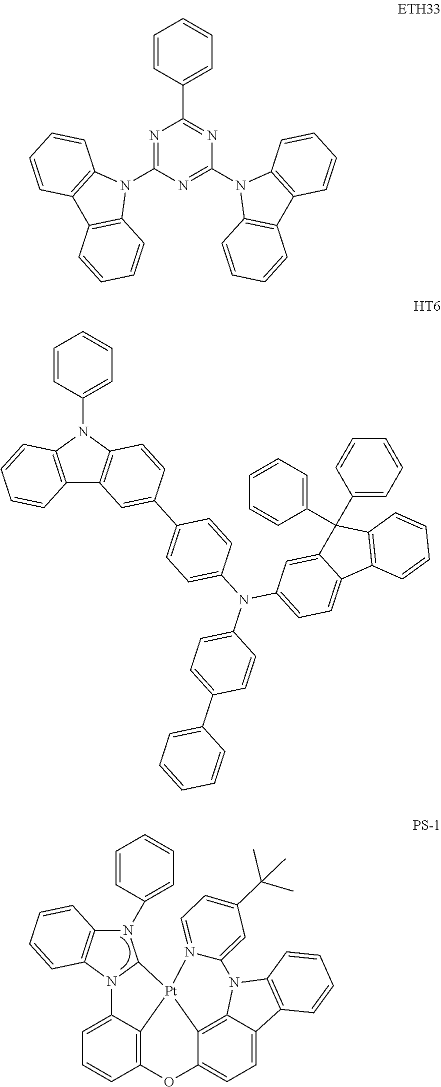

### Examples 2 to 6 and Comparative Examples 1 to 6

Examples 2 to 6 and Comparative Examples 1 to 6 were prepared in the same manner as Example 1, except that the types of the dopants are different as in Table 4.

The driving voltage (V), luminescence efficiency (cd/A), maximum emission wavelength (nm), and lifespan ratio (T₅₀) of the light-emitting devices manufactured in Examples 1 to 6 and Comparative Examples 1 to 6 were measured at a current density of 10 mA/cm 2. Keithley MU 236 and a luminance meter were used for measuring each data. The results thereof are shown in Table 4.

In Table 4, the lifespan ratio (T₅₀) refers to a relative ratio of time taken for the luminance of the light-emitting device to decline to 50% of its initial luminance when the time taken for the light-emitting device of Comparative Example 1 to decline to 50% of its initial luminance is set as 1.

TABLE 4

| | | | | Maximum | |
|---|---|---|---|---|---|
| | | Driving | Luminescence | Luminescence | Lifespan |
| | | Voltage | Efficiency | Wavelength | ratio |
| No. | Dopant | (V) | (cd/A) | (nm) | (T₅₀) |
| Example 1 | 3 | 4.2 | 27.3 | 457 | 4.9 |
| Example 2 | 11 | 4.1 | 28.3 | 457 | 5.3 |
| Example 3 | 65 | 4.2 | 28.1 | 459 | 4.5 |
| Example 4 | 99 | 4.2 | 26.9 | 458 | 4.6 |
| Example 5 | 154 | 4.3 | 27.2 | 456 | 4.7 |
| Example 6 | 201 | 4.3 | 27.2 | 459 | 4.1 |
| Comparative | Compound A | 4.8 | 17.6 | 458 | 1 |
| Example 1 | | | | | |
| Comparative | Compound B | 4.7 | 20.9 | 465 | 2.0 |
| Example 2 | | | | | |
| Comparative | Compound C | 4.7 | 20.2 | 455 | 1.8 |
| Example 3 | | | | | |
| Comparative | Compound D | 4.6 | 19.5 | 450 | 1.2 |
| Example 4 | | | | | |
| Comparative | Compound E | 4.6 | 19.1 | 467 | 2.2 |
| Example 5 | | | | | |
| Comparative | compound F | 4.6 | 20.5 | 462 | 2.1 |
| Example 6 | | | | | |

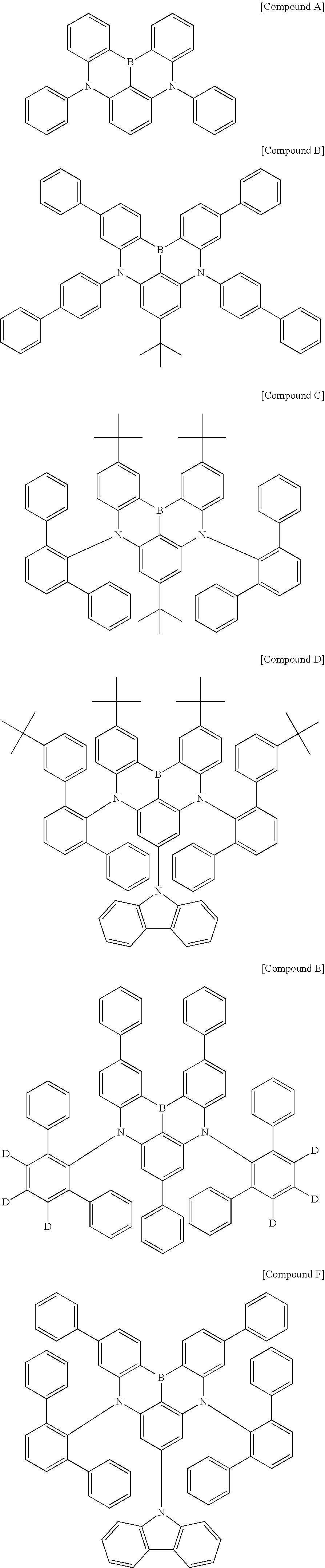

From Table 4, it may be confirmed that the light-emitting device including the condensed cyclic compound according to each Example had excellent driving voltage (V), luminescence efficiency (cd/A), and device lifespan (T₅₀), as compared to the light-emitting devices of Comparative Examples 1 to 6.

According to embodiments, the use of the condensed cyclic compound may enable to manufacture a light-emitting device having high efficiency and a long lifespan, and thus a high-quality electronic apparatus including the light-emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting device comprising:
a first electrode;
a second electrode facing the first electrode;
an interlayer between the first electrode and the second electrode and comprising an emission layer; and
a condensed cyclic compound represented by Formula 1: 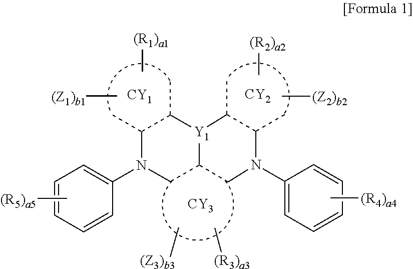
wherein in Formula 1,
Y₁ is B or N,
rings CY₁ to CY3 are each independently a C₃-C₃₀ carbocyclic group or a C₁-C₃₀ heterocyclic group,
R₁ to R₃ are each independently a C₃-C₆₀ carbocyclic group substituted with L_{D} or a C₁-C₆₀ heterocyclic group substituted with L_{D},
L_{D} is a C₁-C₆₀ alkyl group unsubstituted or substituted with deuterium or —Si(Q₁)(Q₂)(Q₃),
when two or more of L_{D} are included, the two or more L_{D} are identical to or different from each other,
R₄ and R₅ are each independently a C₁-C₆₀ alkyl group unsubstituted or substituted with R₁₀ₐ or a C₃-C₆₀ carbocyclic group unsubstituted or substituted with R₁₀ₐ,
Z₁ to Z₃ are each independently a C₃-C₆₀ carbocyclic group unsubstituted or substituted with R_{10b} or a π electron-rich C₃-C₆₀ cyclic group unsubstituted or substituted with R_{10b},
a1 to a3 are each independently an integer from 0 to 3,
a sum of a1 to a3 is 1 or more,
a4 and a5 are each independently an integer from 2 to 5,
b1 to b3 are each independently an integer from 0 to 3,
a sum of b1 to b3 is 1 or more, and
R₁₀ₐ and R_{10b} are each independently:
deuterium, —F, —Cl, —Br, —I, a hydroxyl group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀) alkyl group, a C₂-C₆₀ alkenyl group, a C₂-C₆₀ alkynyl group, a C₁-C₆₀) alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a group unsubstituted or substituted with deuterium, —F, a cyano group, or a combination thereof; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

2. The light-emitting device of claim 1, wherein the interlayer comprises the condensed cyclic compound.

3. The light-emitting device of claim 1, wherein the emission layer comprises the condensed cyclic compound.

4. The light-emitting device of claim 3, wherein the emission layer further comprises at least one of a first host, a second host, and a phosphorescent sensitizer.

5. The light-emitting device of claim 4, wherein the first host comprises a compound represented by Formula 5: 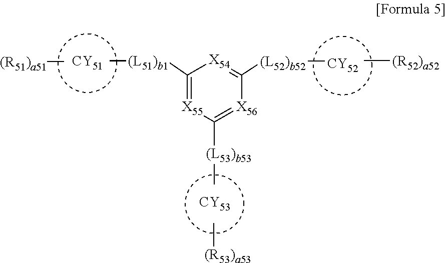
wherein in Formula 5,
X₅₄ to X₅₆ are each independently C(R₅₀), CH, or N,
at least one of X₅₄ to X₅₆ is each N,
rings CY₅₁ to CY53 are each independently a C₅-C₆₀ carbocyclic group or a C₁-C₆₀ heterocyclic group,
L₅₁ to L₅₃ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
b51 to b53 are each independently an integer from 0 to 3,
when b51 is 0, *-(L₅₁)_{b51}-*′ is a single bond,
when b52 is 0, *-(L₅₂)_{b52}-*′ is a single bond,
when b53 is 0, *-(L₅₃)_{ab3}-*′ is a single bond,
* and *′ each indicate a binding site to a neighboring atom,
R₅₀ to R₅₃ are each independently as described for R₁₀ₐ in Formula 1, and
a51 to a53 are each independently an integer from 0 to 10.

6. The light-emitting device of claim 4, wherein the second host comprises a moiety represented by Formula 7: 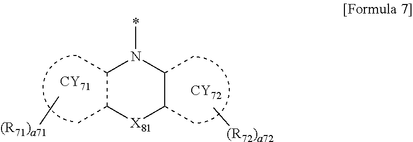
wherein in Formula 7,
rings CY₇₁ and CY₇₂ are each independently a C₅-C₆₀ carbocyclic group or a C₁-C₆₀ heterocyclic group,
X₈₁ is a single bond, O, S, N(R₅₁), B(R₅₁), C(R₈₁ₐ)(R_{81b}), or Si(R₈₁ₐ)(R_{81b}),
R₇₁, R₇₂, R₈₁, R₈₁ₐ and R_{81b} are each independently as described for R₁₀ₐ in Formula 1,
a71 and a72 are each independently an integer from 0 to 10, and
* indicates a binding site to a neighboring atom.

7. The light-emitting device of claim 1, wherein the emission layer emits blue light.

8. The light-emitting device of claim 1, wherein
the first electrode is an anode,
the second electrode is a cathode,
the interlayer further comprises:
a hole transport region between the first electrode and the emission layer; and
an electron transport region between the emission layer and the second electrode,
the hole transport region comprises a hole injection layer, a hole transport layer, an emission auxiliary layer, an electron blocking layer, or a combination thereof, and
the electron transport region comprises a hole blocking layer, an electron transport layer, an electron injection layer, or a combination thereof.

9. An electronic apparatus comprising the light-emitting device of claim 1.

10. The electronic apparatus of claim 9, further comprising:
a thin-film transistor; and
a color filter, a color conversion layer, a touch screen layer, a polarizing layer, or a combination thereof, wherein
the thin-film transistor comprises a source electrode and a drain electrode, and
the first electrode of the light-emitting device is electrically connected to the source electrode or the drain electrode.

11. An electronic device comprising the light-emitting device of claim 1, wherein
the electronic device is a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall including multiple displays tiled together, a theater screen, a stadium screen, a phototherapy device, or a sign.

12. A condensed cyclic compound represented by Formula 1: 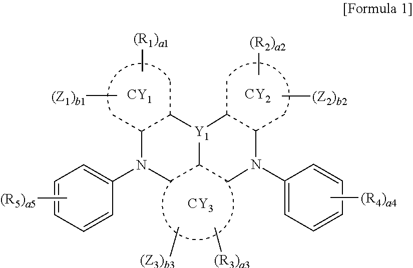
wherein in Formula 1,
Y₁ is B or N,
rings CY₁ to CY3 are each independently a C₃-C₃₀ carbocyclic group or a C₁-C₃₀ heterocyclic group,
R₁ to R₃ are each independently a C₃-C₆₀ carbocyclic group substituted with L_{D} or a C₁-C₆₀ heterocyclic group substituted with L_{D},
L_{D} is a C₁-C₆₀) alkyl group unsubstituted or substituted with deuterium or —Si(Q₁)(Q₂)(Q₃),
when two or more of L_{D} are included, the two or more L_{D} are identical to or different from each other,
R₄ and R₅ are each independently a C₁-C₆₀ alkyl group unsubstituted or substituted with R₁₀ₐ or a C₃-C₆₀ carbocyclic group unsubstituted or substituted with R₁₀ₐ,
Z₁ to Z₃ are each independently a C₃-C₆₀ carbocyclic group unsubstituted or substituted with R_{10b} or a π electron-rich C₃-C₆₀ cyclic group unsubstituted or substituted with R_{10b},
a1 to a3 are each independently an integer from 0 to 3,
a sum of a1 to a3 is 1 or more,
a4 and a5 are each independently an integer from 2 to 5,
b1 to b3 are each independently an integer from 0 to 3,
a sum of b1 to b3 is 1 or more, and
R₁₀ₐ and R_{10b} are each independently:
deuterium, —F, —Cl, —Br, —I, a hydroxyl group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀) alkyl group, a C₂-C₆₀ alkenyl group, a C₂-C₆₀ alkynyl group, a C₁-C₆₀) alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a group unsubstituted or substituted with deuterium, —F, a cyano group, or a combination thereof; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

13. The condensed cyclic compound of claim 12, wherein Y₁ is B.

14. The condensed cyclic compound of claim 12, wherein ring CY₁ is represented by one of Formulae CY1-1 to CY1-4: 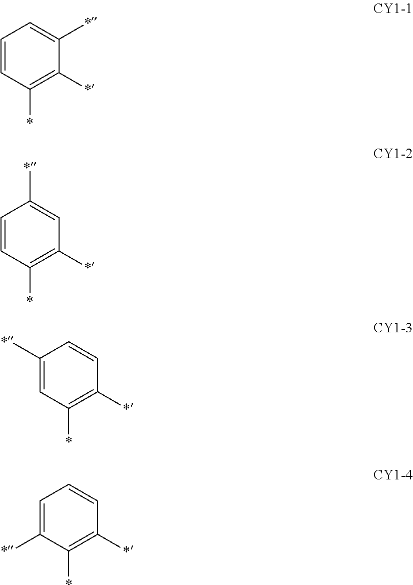
wherein in Formulae CY1-1 to CY1-4,
* indicates a binding site to a neighboring N,
*′ indicates a binding site to a neighboring Y₁,
*″ indicates a binding site to an atom included in R₁ or to an atom included in Z₁, and
Y₁, R₁, and Z₁ are as described in Formula 1.

15. The condensed cyclic compound of claim 12, wherein ring CY₂ is represented by one of Formulae CY2-1 to CY2-4: 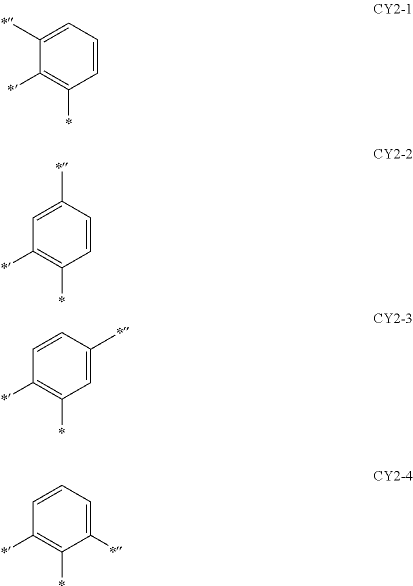
wherein in Formulae CY2-1 to CY2-4,
* indicates a binding site to a neighboring N,
*′ indicates a binding site to a neighboring Y₁,
*″ indicates a binding site to an atom included in R₂ or to an atom included in Z₂, and
Y₁, R₂, and Z₂ are each as described in Formula 1.

16. The condensed cyclic compound of claim 12, wherein ring CY₃ is represented by one of Formulae CY3-1 to CY3-3: 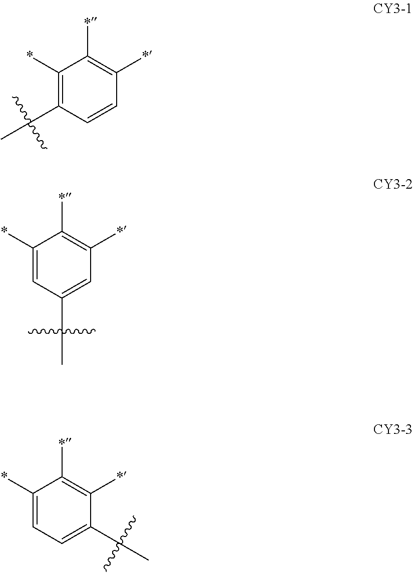
wherein in Formulae CY3-1 to CY3-3,
* and *′ each independently indicate a binding site to a neighboring N,
*″ indicates a binding site to a neighboring Y₁, and [symbol]
indicates a binding site to an atom included in R₃ or to an atom included in Z₃.

17. The condensed cyclic compound of claim 12, wherein R₁ to R₃ are each independently a group represented by one of Formulae 1-2-1 to 1-2-16: 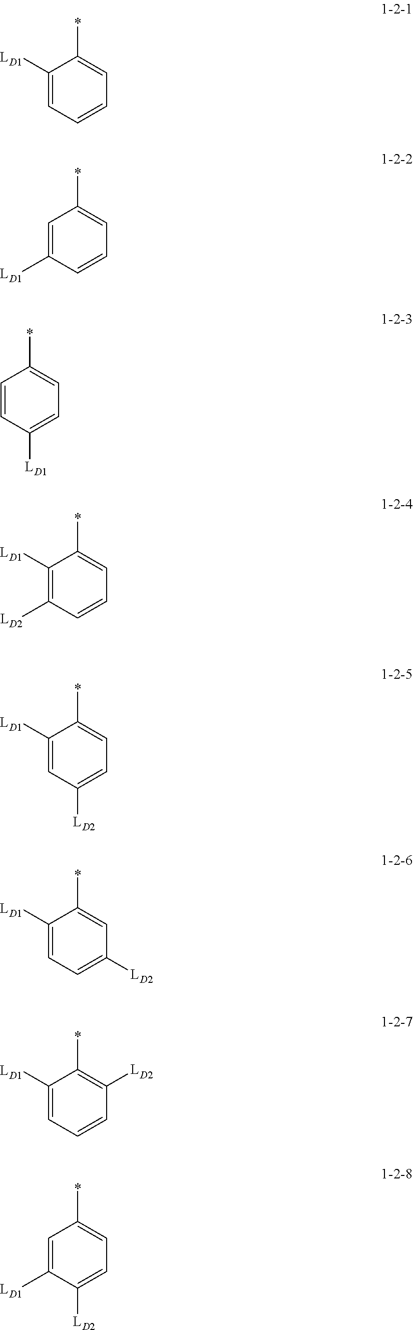 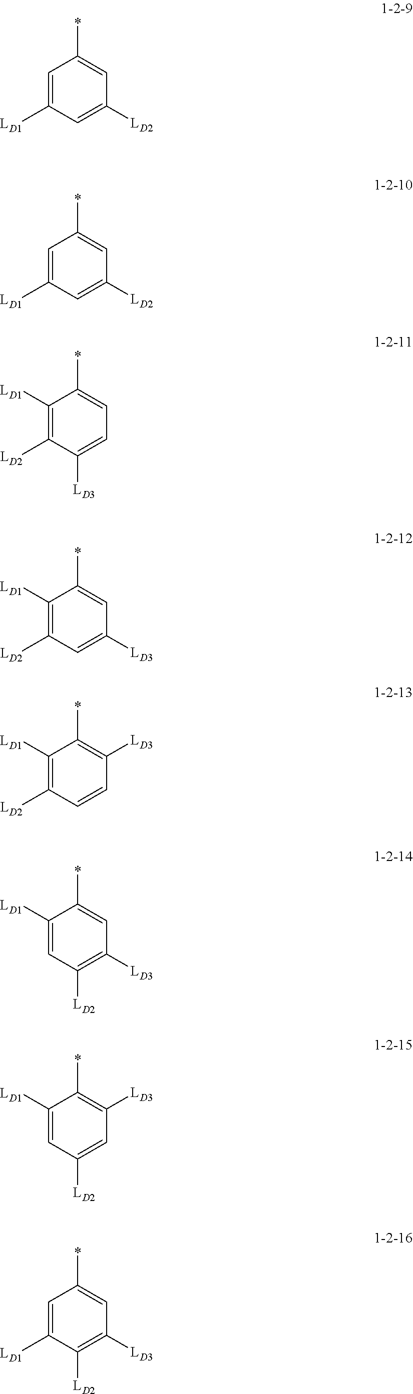
wherein in Formulae 1-2-1 to 1-2-16,
* indicates a binding site to an atom included in one of rings CY₁ to CY3, and
L_{D1}, L_{D2}, and L_{D3} are each independently as described for L_{D} in Formula 1.

18. The condensed cyclic compound of claim 12, wherein L_{D} is a methyl group, an ethyl group, a propyl group, an iso-propyl group, a butyl group, an isobutyl group, a sec-butyl group, a tert-butyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, a 3-cyclohexylpentyl group, or a deuterated derivative group thereof.

19. The condensed cyclic compound of claim 12, wherein in Formula 1, a moiety represented by 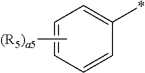
and a moiety represented by 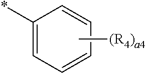
are each independently a moiety represented by one of Formulae 1-3-1 to 1-3-34: 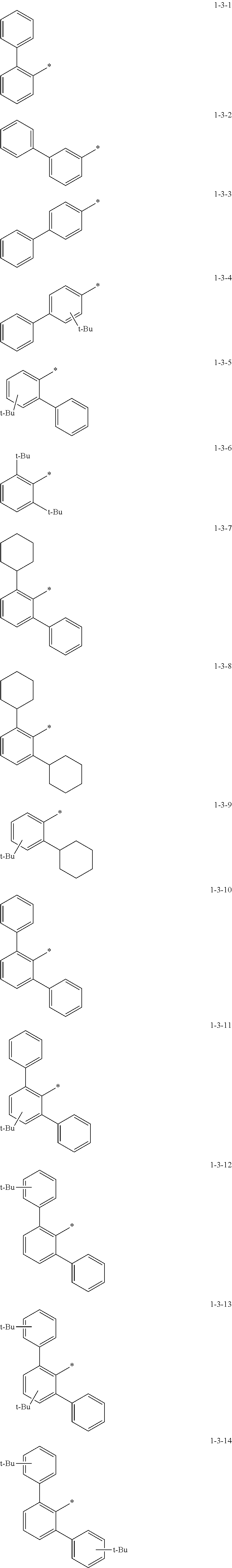 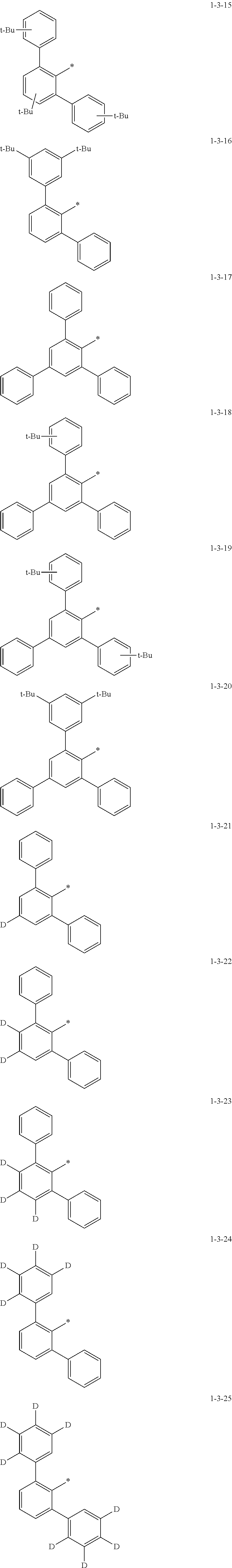 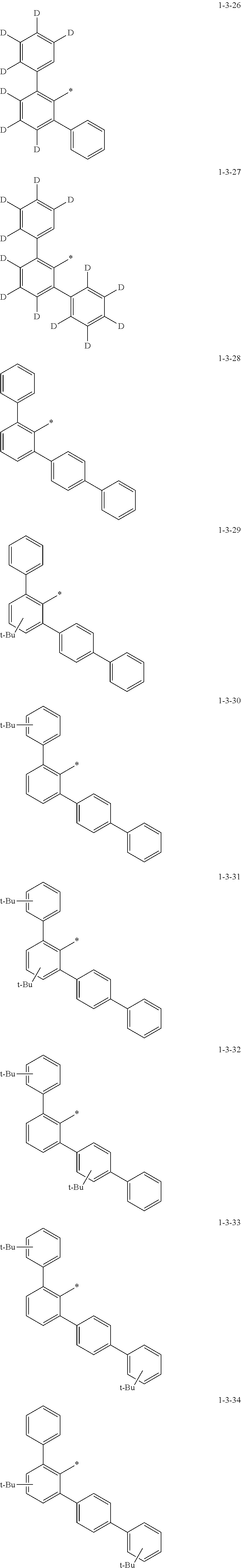
wherein in Formulae 1-3-1 to 1-3-34,
* indicates a binding site to a neighboring nitrogen atom.

20. The condensed cyclic compound of claim 12, wherein:
the condensed cyclic compound satisfies one of Conditions i to ix:
[Condition i]
a1 is 1, a2 and a3 are each 0, b1 is 0, and b2 and b3 are each 1;
[Condition ii]
a2 is 1, a1 and a3 are each 0, b2 is 0, and b1 and b3 are each 1;
[Condition iii]
a3 is 1, a1 and a2 are each 0, b3 is 0, and b1 and b2 are each 1;
[Condition iv]
b1 is 1, b2 and b3 are each 0, a1 is 0, and a2 and a3 are each 1;
[Condition v]
b2 is 1, b1 and b3 are each 0, a2 is 0, and a1 and a3 are each 1;
[Condition vi]
b3 is 1, b1 and b2 are each 0, a3 is 0, and a1 and a2 are each 1;
[Condition vii]
a1 to a3 are each 0, and b1 to b3 are each 1;
[Condition ix]
a1 to a3 are each 1, and b1 to b3 are each 0.
